(19) United States
(12) Patent Application Publication
(10) Pub. No.: US 2013/0175515 A1
(43) Pub. Date: Jul. 11, 2013

(54) LIGHT EMITTING APPARATUS

(71) Applicant: The Procter & Gamble Company, Cincinnati, OH (US)

(72) Inventors: William Johnstone Ray, Fountain Hills, AZ (US); Mark D. Lowenthal, Gilbert, AZ (US); Neil O. Shotton, Tempe, AZ (US); Richard A. Blanchard, Los Altos, CA (US); Mark Allan Lewandowski, North Port, FL (US); Brad Oraw, Mesa, AZ (US); Mark John Steinhardt, Cincinnati, OH (US); Corey Michael Bischoff, Cincinnati, OH (US); Edward Mack Sawicki, Cincinnati, OH (US); Kenneth Stephen McGuire, Cincinnati, OH (US)

(73) Assignee: THE PROCTER & GAMBLE COMPANY, Cincinnati, OH (US)

(21) Appl. No.: 13/781,789

(22) Filed: Mar. 1, 2013

Related U.S. Application Data
(63) Continuation of application No. PCT/US2011/050292, filed on Sep. 2, 2011.

(30) Foreign Application Priority Data
Sep. 2, 2011 (EP) 11757479.8

(51) Int. Cl. H01L 33/56; H01L 51/00

(52) U.S. Cl. CPC H01L 33/56
USPC 257/40

(57) ABSTRACT

A lighting apparatus comprising a plurality of diodes and an electrical interface configured to receive an electrical signal and transmit the electrical signal to the plurality of diodes is provided.

### FIELD OF THE INVENTION

The present invention in general is related to light emitting and photovoltaic technology and, in particular, is related to a light emitting apparatus having light emitting or photovoltaic diodes and methods of making the same.

### BACKGROUND OF THE INVENTION

Lighting devices having light emitting diodes (“LEDs”) have typically required creating the LEDs on a semiconductor wafer using integrated circuit process steps. The resulting LEDs are substantially planar and comparatively large, on the order of two hundred or more microns across. Each such LED is a two terminal device, typically having two metallic terminals on the same side of the LED, to provide Ohmic contacts for p-type and n-type portions of the LED. The LED wafer is then divided into individual LEDs, typically through a mechanical process such as sawing. The individual LEDs are then placed in a reflective casing, and bonding wires are individually attached to each of the two metallic terminals of the LED. This process is time consuming, labor intensive and expensive, resulting in LED-based lighting devices which are generally too expensive for many consumer applications.

Similarly, energy generating devices such as photovoltaic panels have also typically required creating the photovoltaic diodes on a semiconductor wafer or other substrates using integrated circuit process steps. The resulting wafers or other substrates are then packaged and assembled to create the photovoltaic panels. This process is also time consuming, labor intensive and expensive, resulting in photovoltaic devices which are also too expensive for widespread use without being subsidized by third parties or without other governmental incentives.

Various technologies have been brought to bear in an attempt to create new types of diodes or other semiconductor devices for light emission or energy generation purposes. For example, it has been proposed that quantum dots, which are functionalized or capped with organic molecules to be miscible in an organic resin and solvent, may be printed to form graphics which then emit light when the graphics are pumped with a second light. Various approaches for device formation have also been undertaken using semiconductor nanoparticles, such as particles in the range of about 1.0 nm to about 100 nm (one-tenth of a micron). Another approach has utilized larger scale silicon powder, dispersed in a solvent-binder carrier, with the resulting colloidal suspension of silicon powder utilized to form an active layer in a printed transistor. Yet another different approach has used very flat AlInGaP LED structures, formed on a GaAs wafer, with each LED having a breakaway photoresist anchor to each of two neighboring LEDs on the wafer, and with each LED then picked and placed to form a resulting device.

None of these approaches have utilized an ink or suspension containing semiconductor devices, which are completed and capable of functioning, which can be formed into an apparatus or system in a non-inert, atmospheric air environment, using a printing process.

These recent developments for diode-based technologies remain too complex and expensive for LED-based devices and photovoltaic devices to achieve commercial viability. As a consequence, a need remains for light emitting and/or photovoltaic apparatuses which are designed to be less expensive, in terms of incorporated components and in terms of ease of manufacture. A need also remains for methods to manufacture such light emitting or photovoltaic devices using less expensive and more robust processes, to thereby produce LED-based lighting devices and photovoltaic panels which may be available for widespread use and adoption by consumers and businesses. Various needs remain, therefore, for a liquid suspension of completed, functioning diodes which is capable of being printed to create LED-based devices and photovoltaic devices, for a method of printing to create such LED-based devices and photovoltaic devices, and for the resulting printed LED-based devices and photovoltaic devices.

### SUMMARY OF THE INVENTION

The exemplary embodiments provide a “diode ink”, namely, a liquid suspension of diodes which is capable of being printed, such as through screen printing or flexographic printing, for example. As described in greater detail below, the diodes themselves, prior to inclusion in the diode ink composition, are fully formed semiconductor devices which are capable of functioning when energized to emit light (when embodied as LEDs) or provide power when exposed to a light source (when embodied as photovoltaic diodes). An exemplary method also comprises a method of manufacturing diode ink which, as discussed in greater detail below, suspends a plurality of diodes in a solvent and viscous resin or polymer mixture which is capable of being printed to manufacture LED-based devices and photovoltaic devices. Exemplary apparatuses and systems formed by printing such a diode ink are also disclosed. While the description is focused on diodes, those having skill in the art will recognize that other types of semiconductor devices may be substituted equivalently to form what is referred to more broadly as a “semiconductor device ink”, and that all such variations are considered equivalent and within the scope of the disclosure.

An exemplary embodiment is a composition comprising: a plurality of diodes; a first solvent; and a viscosity modifier. In an exemplary embodiment, the first solvent may comprise at least one solvent selected from the group consisting of: water; alcohols such as methanol, ethanol, N-propanol (including 1-propanol, 2-propanol (IPA)), butanol (including 1-butanol, 2-butanol (isobutanol)), pentanol (including 1-pentanol, 2-pentanol, 3-pentanol), octanol, tetrahydrofurfuryl alcohol (THFA), cyclohexanol, terpineol; ethers such as methyl ethyl ether, diethyl ether, ethyl propyl ether, and polyethers; esters such ethyl acetate; glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof.

In an exemplary embodiment, the first solvent comprises N-propanol. The first solvent may be present in an amount of about 5 percent to 50 percent by weight. In an exemplary embodiment, the viscosity modifier comprises a methoxyl cellulose resin or a hydroxypropyl cellulose resin. The viscosity modifier may be present in an amount of about 0.75% to 5% by weight.

The viscosity modifier, in an exemplary embodiment, comprises at least one viscosity modifier selected from the group consisting of: clays such as hectorite clays, garamite clays, organo-modified clays; saccharides and polysaccharides such as guar gum, xanthan gum; celluloses and modified celluloses such as hydroxylmethyl cellulose, methyl cellulose, methoxyl cellulose, carboxymethyl cellulose, hydroxyethyl cellulose and hydroxypropyl cellulose, cellulose ether, cellulose ethyl ether, chitosan; polymers such as acrylate and (meth)acrylate polymers and copolymers, diethylene glycol, propylene glycol, fumed silica, silica powders; modified ureas; and mixtures thereof.

In an exemplary embodiment, the composition further comprises a second solvent different from the first solvent. The second solvent may be at least one solvent selected from the group consisting of: water; alcohols such as methanol, ethanol, N-propanol (including 1-propanol, 2-propanol (isopropanol)), isobutanol, butanol (including 1-butanol, 2-butanol), pentanol (including 1-pentanol, 2-pentanol, 3-pentanol), octanol, tetrahydrofurfuryl alcohol, cyclohexanol; ethers such as methyl ethyl ether, diethyl ether, ethyl propyl ether, and polyethers; esters such ethyl acetate, dimethyl adipate, proplyene glycol monomethyl ether acetate, dimethyl glutarate, dimethyl succinate; glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof.

The second solvent may be at least one dibasic ester. The second solvent may comprise a solvating agent or a wetting solvent. In an exemplary embodiment, the second solvent comprises: dimethyl glutarate and dimethyl succinate; wherein the ratio of dimethyl glutarate to dimethyl succinate is about two to one (2:1). In another exemplary embodiment, the second solvent may be present in an amount of about 0.1% to 10% by weight. In another exemplary embodiment, the second solvent may be present in an amount of about 0.5% to 6% by weight.

In an exemplary embodiment, the first solvent comprises N-propanol, terpineol or diethylene glycol, ethanol, tetrahydrofurfuryl alcohol, cyclohexanol or mixtures thereof, and present in an amount of about 5% to 50% by weight; the viscosity modifier comprises methoxyl cellulose or hydroxypropyl cellulose resin, and present in an amount of about 0.75% to 5.0% by weight; the second solvent comprises a nonpolar resin solvent present in an amount of about 0.5% to 10% by weight; and wherein the balance of the composition further comprises water.

A method of making the composition is also disclosed, and an exemplary method embodiment comprises: mixing the plurality of diodes with N-propanol; adding the mixture of the N-propanol and plurality of diodes to the methyl cellulose resin; adding the dimethyl glutarate and dimethyl succinate; and mixing the plurality of diodes, N-propanol, methyl cellulose resin, dimethyl glutarate and dimethyl succinate for about 25 to 30 minutes in an air atmosphere.

The exemplary method may further comprise releasing the plurality of diodes from a wafer. In an exemplary embodiment, the step of releasing the plurality of diodes from the wafer further may further comprise grinding and polishing a back side of the wafer. In another exemplary embodiment, the step of releasing the plurality of diodes from the wafer further may further comprise a laser lift-off from a back side of the wafer.

In another exemplary embodiment, the first solvent comprises about 15% to 40% by weight of N-propanol, terpineol or diethylene glycol, ethanol, tetrahydrofurfuryl alcohol, or cyclohexanol; the viscosity modifier comprises about 1.25% to 2.5% by weight of methoxyl cellulose or hydroxypropyl cellulose resin; the second solvent comprises about 0.5% to 10% by weight of a nonpolar resin solvent; and the balance of the composition further comprises water.

In another exemplary embodiment, the first solvent comprises about 17.5% to 22.5% by weight of N-propanol, terpineol or diethylene glycol, ethanol, tetrahydrofurfuryl alcohol, or cyclohexanol; the viscosity modifier comprises about 1.5% to 2.25% by weight of methoxyl cellulose or hydroxypropyl cellulose resin; the second solvent comprises about 0.01% to 6.0% by weight of at least one dibasic ester; the balance of the composition further comprises water; and the viscosity of the composition is substantially between about 5,000 cps to about 20,000 cps at 25° C.

In yet another exemplary embodiment, the first solvent comprises about 20% to 40% by weight of N-propanol, terpineol or diethylene glycol, ethanol, tetrahydrofurfuryl alcohol, and/or cyclohexanol; the viscosity modifier comprises about 1.25% to 1.75% by weight of methoxyl cellulose or hydroxypropyl cellulose resin; the second solvent comprises about 0.01% to 6.0% by weight of at least one dibasic ester; the balance of the composition further comprises water; and wherein the viscosity of the composition is substantially between about 1,000 cps to about 5,000 cps at 25° C.

In various exemplary embodiments, the composition may have a viscosity substantially between about 1,000 cps and about 20,000 cps at about 25° C., or may have a viscosity of about 10,000 cps at about 25° C.

In an exemplary embodiment, each diode of the plurality of diodes comprises GaN and a silicon substrate. In another exemplary embodiment, each diode of the plurality of diodes comprises a GaN heterostructure and GaN substrate. In various exemplary embodiments, the GaN portion of each diode of the plurality of diodes is substantially lobed, stellate, or toroidal.

In various exemplary embodiments, each diode of the plurality of diodes has a first metal terminal on a first side of the diode and a second metal terminal on a second, back side of the diode. In other exemplary embodiments, each diode of the plurality of diodes has only one metal terminal or electrode.

In another exemplary embodiment, each diode of the plurality of diodes has at least one metal via structure extending between at least one p+ or n+ GaN layer on a first side of the diode to a second, back side of the diode. In various exemplary embodiments, the metal via structure comprises a central via, a peripheral via, or a perimeter via.

In various exemplary embodiments, each diode of the plurality of diodes is less than about 450 microns in any dimension. In another exemplary embodiment, each diode of the plurality of diodes is less than about 200 microns in any dimension. In another exemplary embodiment, each diode of the plurality of diodes is less than about 100 microns in any dimension. In yet another exemplary embodiment, each diode of the plurality of diodes is less than about 50 microns in any dimension.

In an exemplary embodiment, each diode of the plurality of diodes may be substantially hexagonal, is about 20 to 30 microns in diameter, and is about 10 to 15 microns in height.

In an exemplary embodiment, the plurality of diodes comprises at least one inorganic semiconductor selected from the group consisting of: silicon, gallium arsenide (GaAs), gallium nitride (GaN), GaP, InAlGaP, InAlGaP, AlinGaAs, InGaNAs, and AlInGASb. In another exemplary embodiment, the plurality of diodes comprises at least one organic semiconductor selected from the group consisting of: π-conjugated polymers, poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, polynaphthalene, polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, polynaphthalene derivatives, polyisothianaphthene (PITN), polyheteroarylenvinylene (ParV) in which the heteroarylene group is thiophene, furan or pyrrol, polyphenylene-sulphide (PPS), polyperinaphthalene (PPN), polyphthalocyanine (PPhc), and their derivatives, copolymers thereof and mixtures thereof.

In various exemplary embodiments, the viscosity modifier further comprises an adhesive viscosity modifier. The viscosity modifier, when dried or cured in an exemplary embodiment, may form a polymer or resin lattice or structure substantially about the periphery of each diode of the plurality of diodes.

In an exemplary embodiment, the composition is visually opaque when wet and substantially optically clear when dried or cured.

In an exemplary embodiment, the first solvent is substantially electrically non-insulating.

In another exemplary embodiment, the composition has a contact angle greater than about 25 degrees or greater than about 40 degrees.

In another exemplary embodiment, the composition has a relative evaporation rate less than one, wherein the evaporation rate is relative to butyl acetate having a rate of one.

An exemplary method of using the composition is also disclosed, including printing the composition over a first conductor coupled to a base.

Another exemplary embodiment is disclosed, in which the composition comprises: a plurality of diodes; and a viscosity modifier, such as a methoxyl cellulose resin or a hydroxypropyl cellulose resin. The viscosity modifier may be present in an amount of about 0.75% to 5% by weight. The exemplary embodiment may further comprise a first solvent, and also may further comprise a second solvent different from the first solvent.

In another exemplary embodiment, a composition comprises: a plurality of diodes; a first solvent; a second solvent; and a viscosity modifier to provide a viscosity of the composition substantially between about 5,000 cps and about 15,000 cps at about 25° C.

In another exemplary embodiment, a composition comprises: a plurality of diodes; and a first, wetting solvent. In another exemplary embodiment, a composition comprises: a plurality of diodes; and an adhesive viscosity modifier.

Another exemplary composition comprises: a plurality of diodes; and a viscosity modifier to provide a viscosity of the composition substantially between about 1,000 cps and about 20,000 cps at about 25° C.

In another exemplary embodiment, a composition comprises: a plurality of diodes; a first solvent comprising N-propanol, terpineol or diethylene glycol, ethanol, tetrahydrofurfuryl alcohol, or cyclohexanol; a viscosity modifier comprising methoxyl cellulose or hydroxypropyl cellulose resin; and a second, nonpolar resin solvent.

In yet another exemplary embodiment, a composition comprises: a plurality of diodes; a first solvent comprising about 15% to 40% by weight of N-propanol, terpineol or diethylene glycol, ethanol, tetrahydrofurfuryl alcohol, or cyclohexanol, or mixtures thereof; a viscosity modifier comprising about 1.25% to 2.5% by weight of methoxyl cellulose or hydroxypropyl cellulose resin or mixtures thereof; and about 0.5% to 10% by weight of a dibasic ester.

In another exemplary embodiment, a composition comprises: a plurality of diodes; a first solvent comprising about 17.5% to 22.5% by weight of N-propanol, terpineol or diethylene glycol, ethanol, tetrahydrofurfuryl alcohol, or cyclohexanol or mixtures thereof; a viscosity modifier comprising about 1.5% to 2.25% by weight of methoxyl cellulose or hydroxypropyl cellulose resin or mixtures thereof; and about 0.01% to 6.0% by weight of at least one dibasic ester; wherein the viscosity of the composition is substantially between about 5,000 cps to about 20,000 cps at 25° C.

Another exemplary composition comprises: a plurality of diodes; a first solvent comprising about 20% to 40% by weight of N-propanol, terpineol or diethylene glycol, ethanol, tetrahydrofurfuryl alcohol, or cyclohexanol or mixtures thereof; a viscosity modifier comprising about 1.25% to 1.75% by weight of methoxyl cellulose or hydroxypropyl cellulose resin or mixtures thereof; and about 0.01% to 6.0% by weight of at least one dibasic ester; wherein the viscosity of the composition is substantially between about 1,000 cps to about 5,000 cps at 25° C.

In another exemplary embodiment, a composition comprises: a plurality of diodes; N-propanol; methoxyl cellulose resin; and dimethyl glutarate. In yet another exemplary embodiment, a composition comprises: a plurality of diodes; N-propanol; hydroxypropyl cellulose resin; and dimethyl glutarate. And in yet another exemplary embodiment, a composition comprises: a plurality of diodes; N-propanol; methoxyl cellulose resin or hydroxypropyl cellulose resin or mixtures thereof; dimethyl glutarate; and dimethyl succinate.

An exemplary lighting apparatus is also disclosed, with the exemplary lighting apparatus comprising: a flexible base having an adhesive on a first side; a plurality of first conductors coupled to the base; a plurality of light emitting diodes distributed substantially randomly and in parallel on a first conductor of the plurality of first conductors, at least some of the plurality of light emitting diodes having a first, forward-bias orientation and at least one of the plurality of light emitting diodes having a second, reverse-bias orientation; at least one second conductor coupled to the plurality of diodes and coupled to a second conductor of the plurality of first conductors; a luminescent layer coupled to the at least one second conductor or an intervening stabilization layer; a protective coating coupled to the luminescent layer; and an electrical interface coupled to the plurality of first conductors.

An exemplary apparatus may further comprise a polymer or resin lattice coupled to the plurality of light emitting diodes. The exemplary apparatus may emit light in an amount of at least about 10 lm/W. The plurality of light emitting diodes may comprise an average particle size of from about 20 microns to about 30 microns in diameter. An exemplary base may be selected from the group consisting of flexible materials, porous materials, permeable materials, transparent materials, translucent materials, opaque materials and mixtures thereof. An exemplary base may be selected from the group consisting of plastics, polymer materials, natural rubber, synthetic rubber, natural fabrics, synthetic fabrics, glass, ceramics, silicon-derived materials, silica-derived materials, concrete, stone, extruded polyolefinic films, polymeric nonwovens, cellulosic paper, and mixtures thereof. An exemplary base may be sufficient to provide electrical insulation and wherein the protective coating forms a weatherproof seal.

In another exemplary embodiment, the apparatus has an average surface area concentration of the plurality of light emitting diodes from about 5 to 10,000 diodes per square centimeter.

In another exemplary embodiment, the electrical interface comprises at least one interface selected from the group consisting of: ES, E27, SES, E14, L1, PL—2 pin, PL—4 pin, G9 halogen capsule, G4 halogen capsule, GU10, GU5.3, bayonet, and small bayonet.

In another exemplary embodiment, a lighting apparatus comprises: a translucent or transparent housing; an electrical interface coupled to the housing and couplable to a power source; a base; a plurality of first conductors coupled to the base and coupled to the electrical interface; a plurality of light emitting diodes distributed substantially randomly and in parallel on a first conductor of the plurality of first conductors, at least some of the plurality of light emitting diodes having a first, forward-bias orientation and at least one of the plurality of light emitting diodes having a second, reverse-bias orientation; at least one second conductor coupled to the plurality of diodes and coupled to a second conductor of the plurality of first conductors; a luminescent layer coupled to the at least one second conductor or an intervening stabilization layer; and a protective coating coupled to the luminescent layer. In an exemplary embodiment, the housing has a size adapted to fit into a user's hand.

Numerous other advantages and features of the present invention will become readily apparent from the following detailed description of the invention and the embodiments thereof, from the claims and from the accompanying drawings.

### BRIEF DESCRIPTION OF THE DRAWINGS

The objects, features and advantages of the present invention will be more readily appreciated upon reference to the following disclosure when considered in conjunction with the accompanying drawings, wherein like reference numerals are used to identify identical components in the various views, and wherein reference numerals with alphabetic characters are utilized to identify additional types, instantiations or variations of a selected component embodiment in the various views, in which:

FIG. 1 is a perspective view illustrating an exemplary first diode embodiment.

FIG. 2 is a top view illustrating the exemplary first diode embodiment.

FIG. 3 is a cross-sectional view illustrating the exemplary first diode embodiment.

FIG. 4 is a perspective view illustrating an exemplary second diode embodiment.

FIG. 5 is a top view illustrating the exemplary second diode embodiment.

FIG. 6 is a perspective view illustrating an exemplary third diode embodiment.

FIG. 7 is a top view illustrating the exemplary third diode embodiment.

FIG. 8 is a perspective view illustrating an exemplary fourth diode embodiment.

FIG. 9 is a top view illustrating the exemplary fourth diode embodiment.

FIG. 10 is a cross-sectional view illustrating an exemplary second, third and/or fourth diode embodiment.

FIG. 11 is a perspective view illustrating exemplary fifth and sixth diode embodiments.

FIG. 12 is a top view illustrating the exemplary fifth and sixth diode embodiments.

FIG. 13 is a cross-sectional view illustrating the exemplary fifth diode embodiment.

FIG. 14 is a cross-sectional view illustrating the exemplary sixth diode embodiment.

FIG. 15 is a perspective view illustrating an exemplary seventh diode embodiment.

FIG. 16 is a top view illustrating the exemplary seventh diode embodiment.

FIG. 17 is a cross-sectional view illustrating the exemplary seventh diode embodiment.

FIG. 18 is a perspective view illustrating an exemplary eighth diode embodiment.

FIG. 19 is a top view illustrating the exemplary eighth diode embodiment.

FIG. 20 is a cross-sectional view illustrating the exemplary eighth diode embodiment.

FIG. 21 is a cross-sectional view of a wafer having an oxide layer, such as silicon dioxide.

FIG. 22 is a cross-sectional view of a wafer having an oxide layer etched in a grid pattern.

FIG. 23 is a top view of a wafer having an oxide layer etched in a grid pattern.

FIG. 24 is a cross-sectional view of a wafer having a buffer layer (such as aluminum nitride or silicon nitride), a silicon dioxide layer in a grid pattern, and gallium nitride (GaN) layers.

FIG. 25 is a cross-sectional view of a substrate having a buffer layer and a complex GaN heterostructure (n+ GaN layer, quantum well region, and p+ GaN layer).

FIG. 26 is a cross-sectional view of a substrate having a buffer layer and a first mesa-etched complex GaN heterostructure.

FIG. 27 is a cross-sectional view of a substrate having a buffer layer and a second mesa-etched complex GaN heterostructure.

FIG. 28 is a cross-sectional view of a substrate having a buffer layer, a mesa-etched complex GaN heterostructure, and etched substrate for via connections.

FIG. 29 is a cross-sectional view of a substrate having a buffer layer, a mesa-etched complex GaN heterostructure, metallization forming an ohmic contact with the p+ GaN layer, and metallization forming vias.

FIG. 30 is a cross-sectional view of a substrate having a buffer layer, a mesa-etched complex GaN heterostructure, metallization forming an ohmic contact with the p+ GaN layer, metallization forming vias, and lateral etched trenches.

FIG. 31 is a cross-sectional view of a substrate having a buffer layer, a mesa-etched complex GaN heterostructure, metallization forming an ohmic contact with the p+ GaN layer, metallization forming vias, lateral etched trenches, and passivation layers (such as silicon nitride).

FIG. 32 is a cross-sectional view of a substrate having a buffer layer, a mesa-etched complex GaN heterostructure, metallization forming an ohmic contact with the p+ GaN layer, metallization forming vias, lateral etched trenches, passivation layers, and metallization forming a protruding or bump structure.

FIG. 33 is a cross-sectional view of a substrate having a complex GaN heterostructure (n+ GaN layer, quantum well region, and p+ GaN layer).

FIG. 34 is a cross-sectional view of a substrate having a third mesa-etched complex GaN heterostructure.

FIG. 35 is a cross-sectional view of a substrate having a mesa-etched complex GaN hetero structure, an etched substrate for via connections, and lateral etched trenches.

FIG. 36 is a cross-sectional view of a substrate having a mesa-etched complex GaN heterostructure, metallization forming an ohmic contact with the n+ GaN layer and forming through vias, and lateral etched trenches.

FIG. 37 is a cross-sectional view of a substrate having a mesa-etched complex GaN heterostructure, metallization forming an ohmic contact with the n+ GaN layer and forming through vias, metallization forming an ohmic contact with the p+ GaN layer, and lateral etched trenches.

FIG. 38 is a cross-sectional view of a substrate having a mesa-etched complex GaN heterostructure, metallization forming an ohmic contact with the n+ GaN layer and forming through vias, metallization forming an ohmic contact with the p+ GaN layer, lateral etched trenches, and passivation layers (such as silicon nitride).

FIG. 39 is a cross-sectional view of a substrate having a mesa-etched complex GaN heterostructure, metallization forming an ohmic contact with the n+ GaN layer and forming through vias, metallization forming an ohmic contact with the p+ GaN layer, lateral etched trenches, passivation layers (such as silicon nitride), and metallization forming a protruding or bump structure.

FIG. 40 is a cross-sectional view of a substrate having a buffer layer, a complex GaN heterostructure (n+ GaN layer, quantum well region, and p+ GaN layer), and metallization forming an ohmic contact with the p+ GaN layer.

FIG. 41 is a cross-sectional view of a substrate having a buffer layer, a fourth mesa-etched complex GaN heterostructure, and metallization forming an ohmic contact with the p+ GaN layer.

FIG. 42 is a cross-sectional view of a substrate having a buffer layer, a mesa-etched complex GaN heterostructure, metallization forming an ohmic contact with the p+ GaN layer, and metallization forming an ohmic contact with the n+ GaN layer.

FIG. 43 is a cross-sectional view of a substrate having a buffer layer, a mesa-etched complex GaN heterostructure, metallization forming an ohmic contact with the n+ GaN layer, and lateral etched trenches.

FIG. 44 is a cross-sectional view of a substrate having a buffer layer, a mesa-etched complex GaN heterostructure, metallization forming an ohmic contact with the p+ GaN layer, metallization forming an ohmic contact with the n+ GaN layer, and lateral etched trenches having metallization forming through, perimeter vias.

FIG. 45 is a cross-sectional view of a substrate having a buffer layer, a mesa-etched complex GaN heterostructure, metallization forming an ohmic contact with the p+ GaN layer, metallization forming an ohmic contact with the n+ GaN layer, and lateral etched trenches having metallization forming through, perimeter vias, passivation layers (such as silicon nitride), and metallization forming a protruding or bump structure.

FIG. 46 is a cross-sectional view illustrating an exemplary diode wafer embodiment adhered to a holding apparatus.

FIG. 47 is a cross-sectional view illustrating an exemplary diode wafer embodiment adhered to a holding apparatus.

FIG. 48 is a cross-sectional view illustrating an exemplary diode embodiment adhered to a holding apparatus.

FIG. 49 is a flow diagram illustrating an exemplary first method embodiment for diode fabrication.

FIG. 50A is a flow diagram illustrating an exemplary second method embodiment for diode fabrication.

FIG. 50B is a flow diagram illustrating an exemplary second method embodiment for diode fabrication.

FIG. 51A is a flow diagram illustrating an exemplary third method embodiment for diode fabrication.

FIG. 51B is a flow diagram illustrating an exemplary third method embodiment for diode fabrication.

FIG. 52 is a cross-sectional view illustrating an exemplary ground and polished diode wafer embodiment adhered to a holding apparatus and suspended in a dish with adhesive solvent.

FIG. 53 is a flow diagram illustrating an exemplary method embodiment for diode suspension fabrication.

FIG. 54 is a perspective view of an exemplary apparatus embodiment.

FIG. 55 is a top view illustrating an exemplary electrode structure of a first conductive layer for an exemplary apparatus embodiment.

FIG. 56 is a first cross-sectional view of an exemplary apparatus embodiment.

FIG. 57 is a second cross-sectional view of an exemplary apparatus embodiment.

FIG. 58 is a second cross-sectional view of exemplary diodes coupled to a first conductor.

FIG. 59 is a block diagram of a first exemplary system embodiment.

FIG. 60 is a block diagram of a second exemplary system embodiment.

FIG. 61 is a flow diagram illustrating an exemplary method embodiment for apparatus fabrication.

FIG. 62 is a photograph of an energized exemplary apparatus embodiment emitting light.

FIG. 63 is a scanning electron micrograph of an exemplary second diode embodiment.

FIG. 64 is a scanning electron micrograph of a plurality of exemplary second diode embodiments.

FIG. 65 is a perspective view of an exemplary embodiment of a lighting assembly.

FIG. 66 is a perspective view of an exemplary embodiment of a lighting assembly.

FIG. 67 is a perspective view of an exemplary embodiment of a lighting assembly.

FIG. 68 is a perspective view of an exemplary embodiment of a lighting assembly.

FIG. 69 is a perspective view of an exemplary embodiment of a lighting assembly.

FIG. 70 is a perspective view of an exemplary embodiment of a lighting assembly.

FIG. 71 is a sectional view of an exemplary embodiment of a lighting assembly.

FIG. 72 is a sectional view of an exemplary embodiment of a lighting assembly.

FIG. 73 is a perspective view of an exemplary embodiment of a lighting assembly.

FIG. 74 is a sectional view of an exemplary embodiment of a lighting assembly.

FIG. 75 is a side view of an exemplary embodiment of a lighting assembly.

FIG. 76 is a side view of an exemplary embodiment of a lighting assembly.

FIG. 77 is a side view of an exemplary embodiment of a lighting assembly.

FIG. 78A is a side view of an exemplary embodiment of a lighting assembly.

FIG. 78B is a perspective view of the embodiment of FIG. 78A.

FIG. 79 is a perspective view of an exemplary embodiment of a lighting assembly.

FIG. 80 is a perspective view of an exemplary embodiment of a lighting assembly.

FIG. 81 is a perspective view of an exemplary embodiment of a lighting assembly.

FIG. 82 is a perspective view of an exemplary embodiment of a lighting assembly.

FIG. 83 is a perspective view of an exemplary embodiment of a lighting assembly.

FIG. 84 is a sectional view of an exemplary embodiment of a lighting assembly.

FIG. 85 is a perspective view of an exemplary embodiment of a lighting assembly.

FIG. 86 is a perspective view of an exemplary embodiment of a lighting assembly.

FIG. 87A is a side view of an exemplary embodiment of a lighting assembly.

FIG. 87B is a side view of the embodiment of FIG. 87A.

FIG. 88 is a perspective view of an exemplary embodiment of a lighting assembly.

FIG. 89A is a side view of an exemplary embodiment of a lighting assembly.

FIG. 89B is a side view of the embodiment of FIG. 89A.

FIG. 90A is a side view of an exemplary embodiment of a lighting assembly.

FIG. 90B is a sectional view of the embodiment of FIG. 90A taken along section line 90B-90B.

FIG. 90C is a perspective view of an exemplary embodiment of a lighting assembly.

FIG. 91A is a top view of an exemplary embodiment of a lighting assembly.

FIG. 91B is a perspective view of an exemplary embodiment of a lighting assembly.

FIG. 91C is a perspective view of an exemplary embodiment of a lighting assembly.

FIG. 91D is a perspective view of an exemplary embodiment of a lighting assembly.

FIG. 92A is a perspective view of an exemplary embodiment of a lighting assembly.

FIG. 92B is a partial perspective view of an exemplary embodiment of a lighting assembly.

FIG. 92C is a partial perspective view of an exemplary embodiment of a lighting assembly.

FIG. 92D is a partial perspective view of an exemplary embodiment of a lighting assembly.

FIG. 92E is a perspective view of an exemplary embodiment of a lighting assembly.

FIG. 93 is a perspective view of an exemplary embodiment of a lighting assembly.

FIG. 94A is a perspective view of an exemplary embodiment of a lighting assembly.

FIG. 94B is a perspective view of an exemplary embodiment of roll of sheets.

FIG. 94C is a perspective view of an exemplary embodiment of a lighting assembly.

FIG. 95 is a perspective view of an exemplary bulb assembly having two illuminating surfaces.

FIG. 96 is a cross-sectional view of an exemplary apparatus for forming the bulb assembly of FIG. 95.

FIG. 97 is an illustration of an exemplary apparatus in accordance with the presently described embodiments.

FIG. 98 is a cross-sectional view of the exemplary apparatus of FIG. 97 taken along the line A-A.

FIG. 99 is a perspective view of an apparatus adapted to be used with another exemplary coupling mechanism.

FIG. 100 is a side view of two apparatus connected to a power supply via the exemplary coupling mechanism of FIG. 99.

FIG. 101A is a perspective view of an exemplary embodiment of a lighting assembly.

FIG. 101B is a perspective view of the an embodiment of FIG. 101A

FIG. 102A is a perspective view of an exemplary embodiment of a lighting assembly.

FIG. 102B is a perspective view of an embodiment of FIG. 102A.

FIG. 103A is a perspective view of an exemplary embodiment of a lighting assembly.

FIG. 103B is a perspective view of the an embodiment of FIG. 103A.

FIG. 104A is a perspective view of an exemplary embodiment of a lighting assembly.

FIG. 104B is a perspective view of the an embodiment of FIG. 104A.

FIG. 105A is a perspective view of an exemplary embodiment of a lighting assembly.

FIG. 105B is a perspective view of the an embodiment of FIG. 105A.

FIG. 106 is a perspective view of an exemplary embodiment of a lighting assembly.

FIG. 107 is a perspective view of an exemplary embodiment of a lighting strip assembly.

FIG. 108 is a side view of the lighting strip assembly of FIG. 107 disposed in a slot of an embodiment of a base assembly.

FIG. 109 is a perspective view of an exemplary embodiment of a lighting assembly.

FIG. 110 is a perspective view of an exemplary embodiment of a lighting assembly.

FIG. 111A is a perspective view of an exemplary embodiment of a lighting assembly.

FIG. 111B is a perspective view of the an embodiment of FIG. 111A.

FIG. 112A is a perspective view of an exemplary embodiment of a lighting assembly.

FIG. 112B is a perspective view of the an embodiment of FIG. 112A.

FIG. 113A is a perspective view of an exemplary embodiment of a lighting assembly.

FIG. 113B is a top view of the embodiment of FIG. 113A.

FIG. 114A is a perspective view of an exemplary embodiment of a lighting assembly.

FIG. 114B is a top view of the embodiment of FIG. 114A.

FIG. 115A is a perspective view of an exemplary embodiment of a lighting assembly.

FIG. 115B is a top view of the embodiment of FIG. 115A.

FIG. 116A is a perspective view of an exemplary embodiment of a lighting assembly.

FIG. 116B is a top view of the embodiment of FIG. 116A.

### DETAILED DESCRIPTION OF THE INVENTION

While the present invention is susceptible of embodiment in many different forms, there are shown in the drawings and will be described herein in detail specific exemplary embodiments thereof, with the understanding that the present disclosure is to be considered as an exemplification of the principles of the invention and is not intended to limit the invention to the specific embodiments illustrated. In this respect, before explaining at least one embodiment consistent with the present invention in detail, it is to be understood that the invention is not limited in its application to the details of construction and to the arrangements of components set forth above and below, illustrated in the drawings, or as described in the examples. Methods and apparatuses consistent with the present invention are capable of other embodiments and of being practiced and carried out in various ways. Also, it is to be understood that the phraseology and terminology employed herein, as well as the abstract included below, are for the purposes of description and should not be regarded as limiting.

Exemplary embodiments of the invention provide a liquid and/or gel suspension of diodes 100, 100A, 100B, 100C, 100D, 100E, 100F, 100G, 100H, 100I, 100J (collectively referred to herein and in the Figures as “diodes 100-100J”) which is capable of being printed, and may be referred to equivalently herein as “diode ink”, it being understood that “diode ink” means and refers to a liquid and/or gel suspension of diodes, such as exemplary diodes 100-100J. As described in greater detail below, the diodes 100-100J themselves, prior to inclusion in the diode ink composition, are fully formed semiconductor devices which are capable of functioning when energized to emit light (when embodied as LEDs) or provide power when exposed to a light source (when embodied as photovoltaic diodes). An exemplary method of the invention also comprises a method of manufacturing diode ink which, as discussed in greater detail below, suspends a plurality of diodes 100-100J in a solvent and viscous resin or polymer mixture which is capable of being printed to manufacture LED-based devices and photovoltaic devices. While the description is focused on diodes 100-100J, those having skill in the art will recognize that other types of semiconductor devices may be substituted equivalently to form what is referred to more broadly as a “semiconductor device ink”, such as any type of transistor (field effect transistor (FET), metal oxide semiconductor field effect transistor (MOSFET), junction field effect transistor (JFET), bipolar junction transistor (BJT), etc.), diac, triac, silicon controlled rectifier, etc., without limitation.

The diode ink (or semiconductor device ink) may be printed or applied to any article of commerce or packaging associated with the article. An “article of commerce”, as used herein, means any product of any kind, such as a consumer product, a personal product, a business product, an industrial product, etc., including products which may be sold at a point of sale for the use of an end user. For example, an article of commerce may be an industrial or business product, sold at a point of sale (such as a distributor or over the internet) for the business or industrial use of the end user. A “consumer article of commerce”, as used herein, means any consumer product, which is sold at a point of sale for the personal use of an end user. For example, a consumer article of commerce may be a consumer product, sold at a point of sale (such as a store or over the internet) for the personal use of the end user. The diode ink (or semiconductor device ink) may be printed onto the article, or packaging thereof, as either a functional or decorative component of the article, package, or both. In one embodiment, the diode ink is printed in the form of indicia. The article or package may be formed from any consumer-acceptable material.

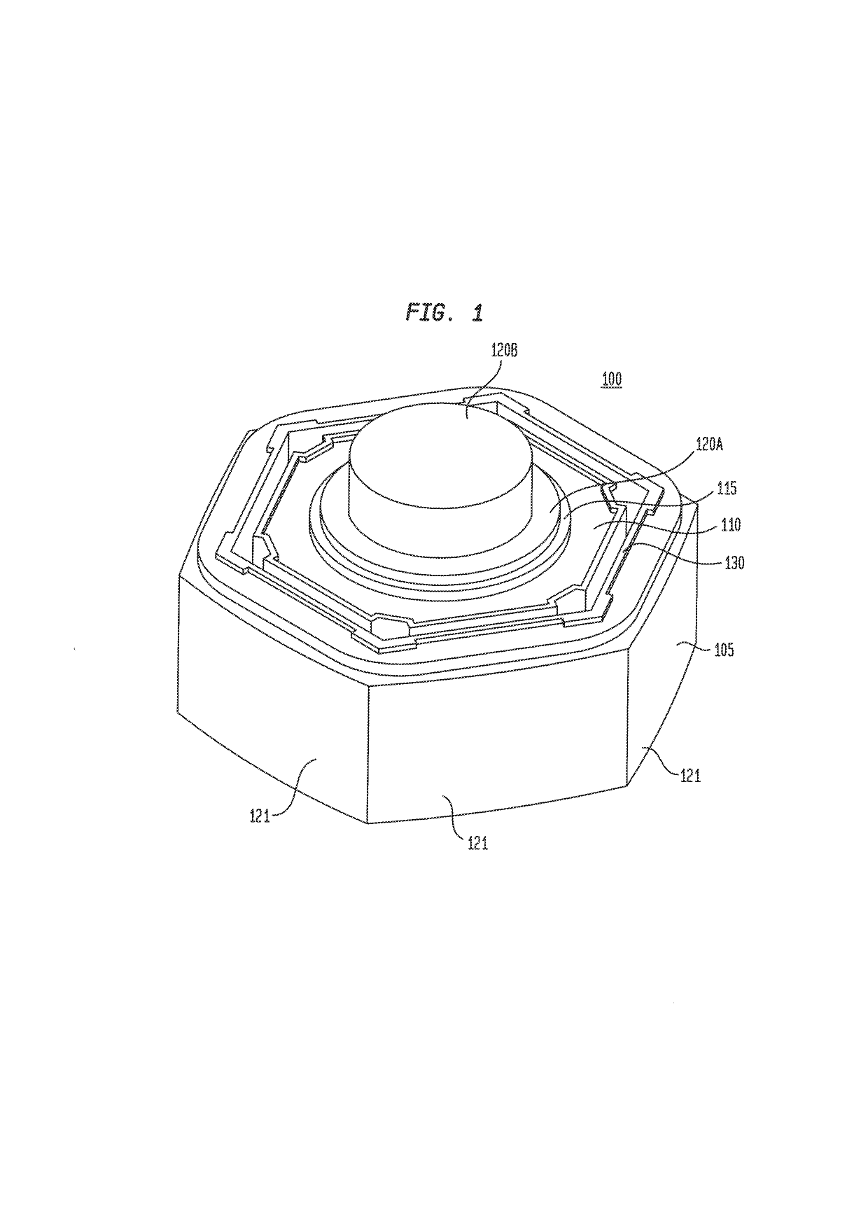

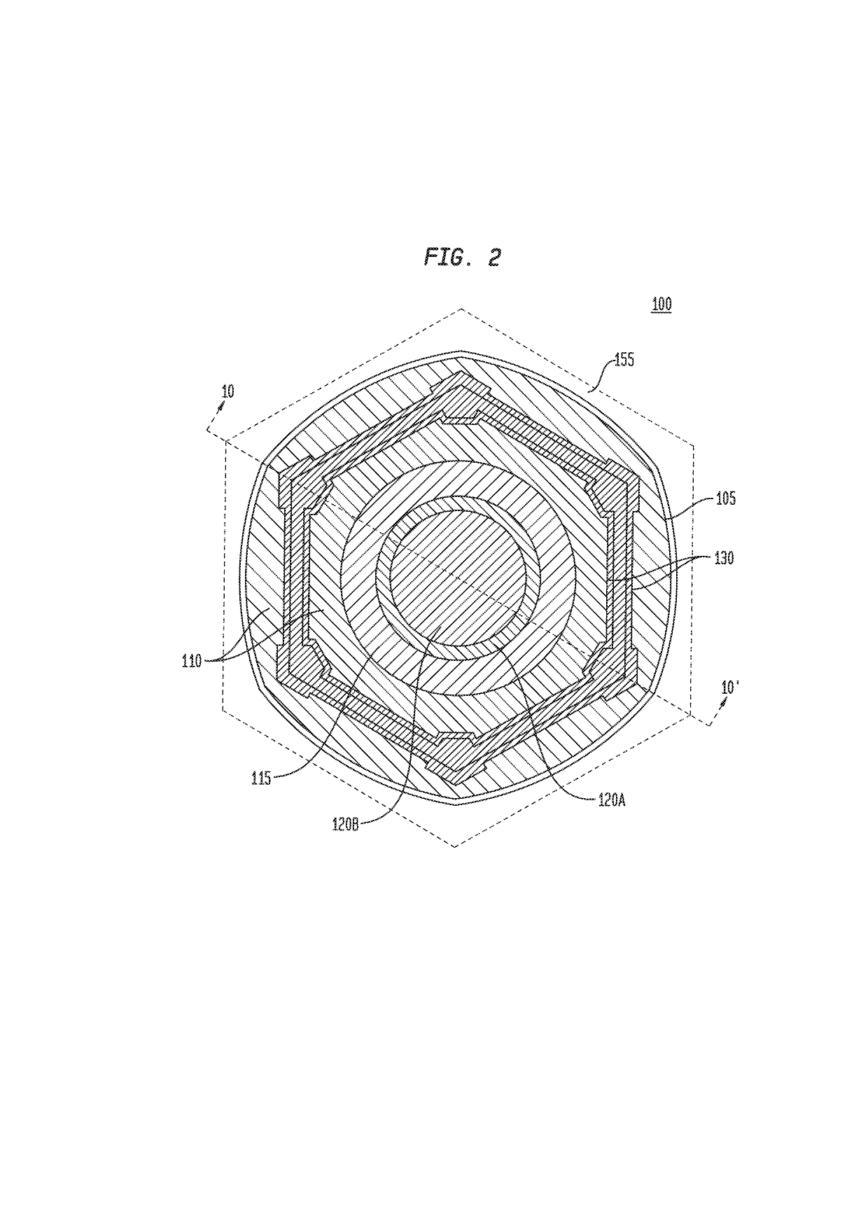

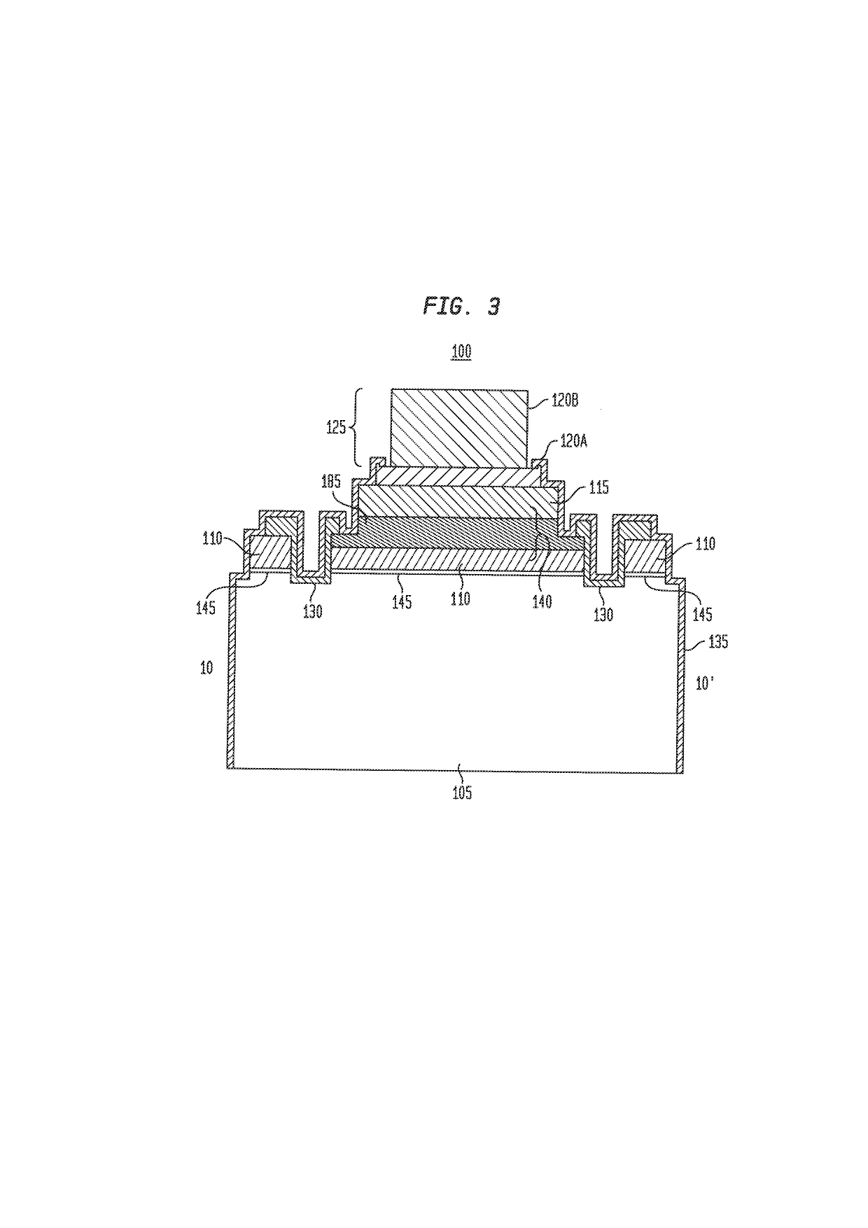

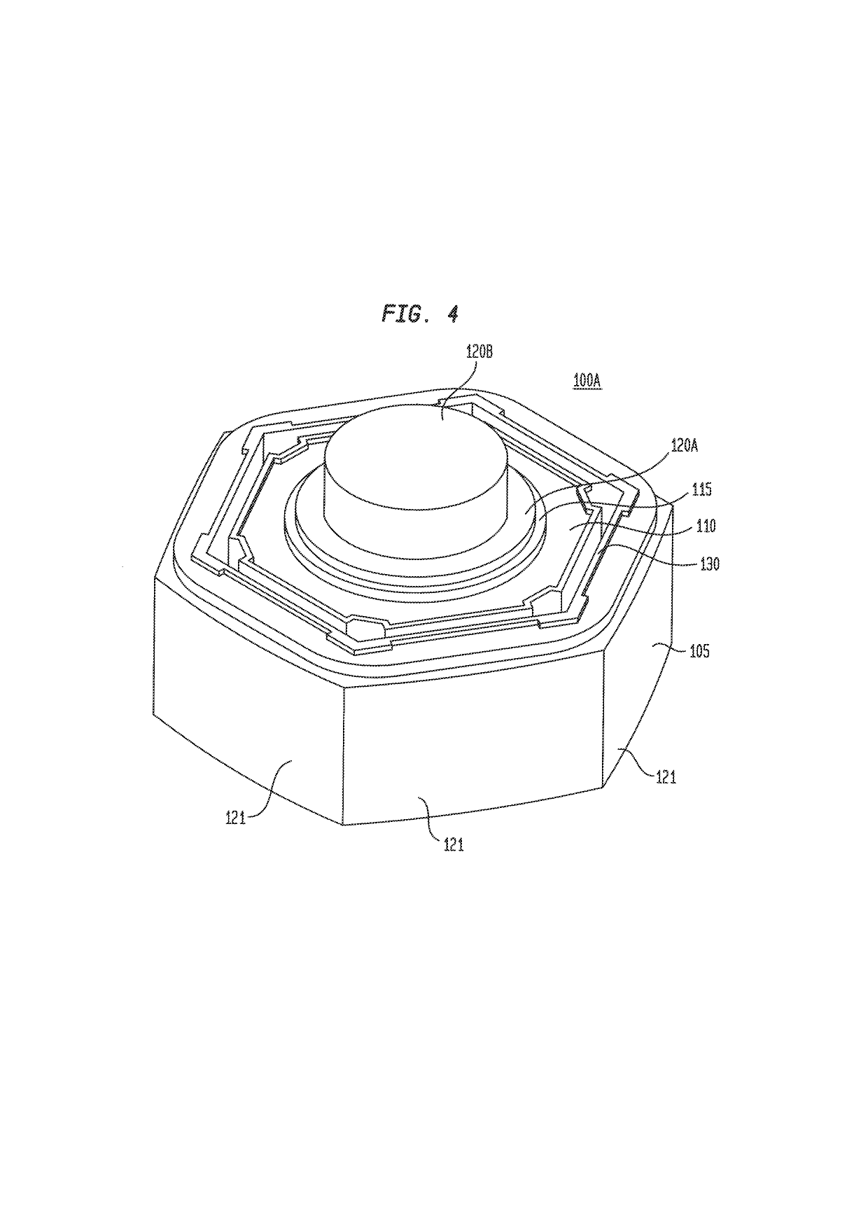

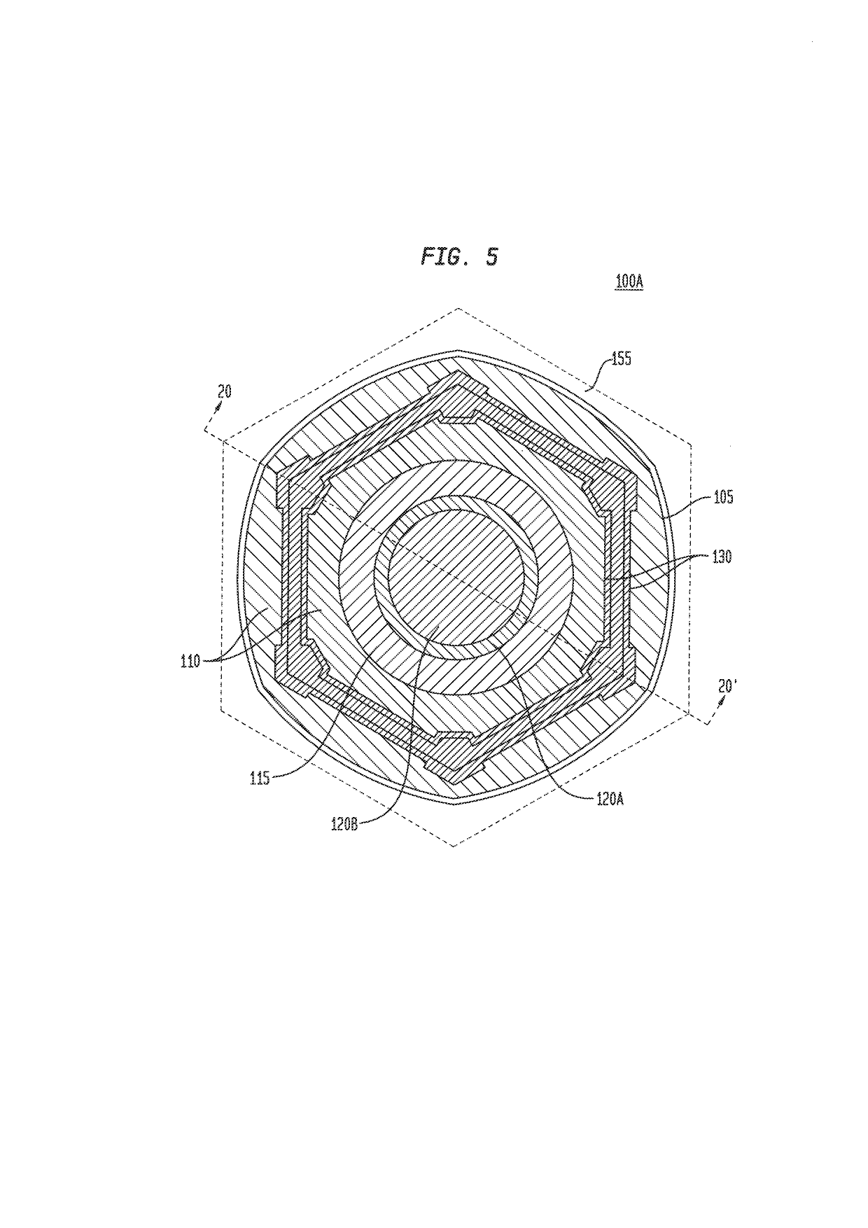

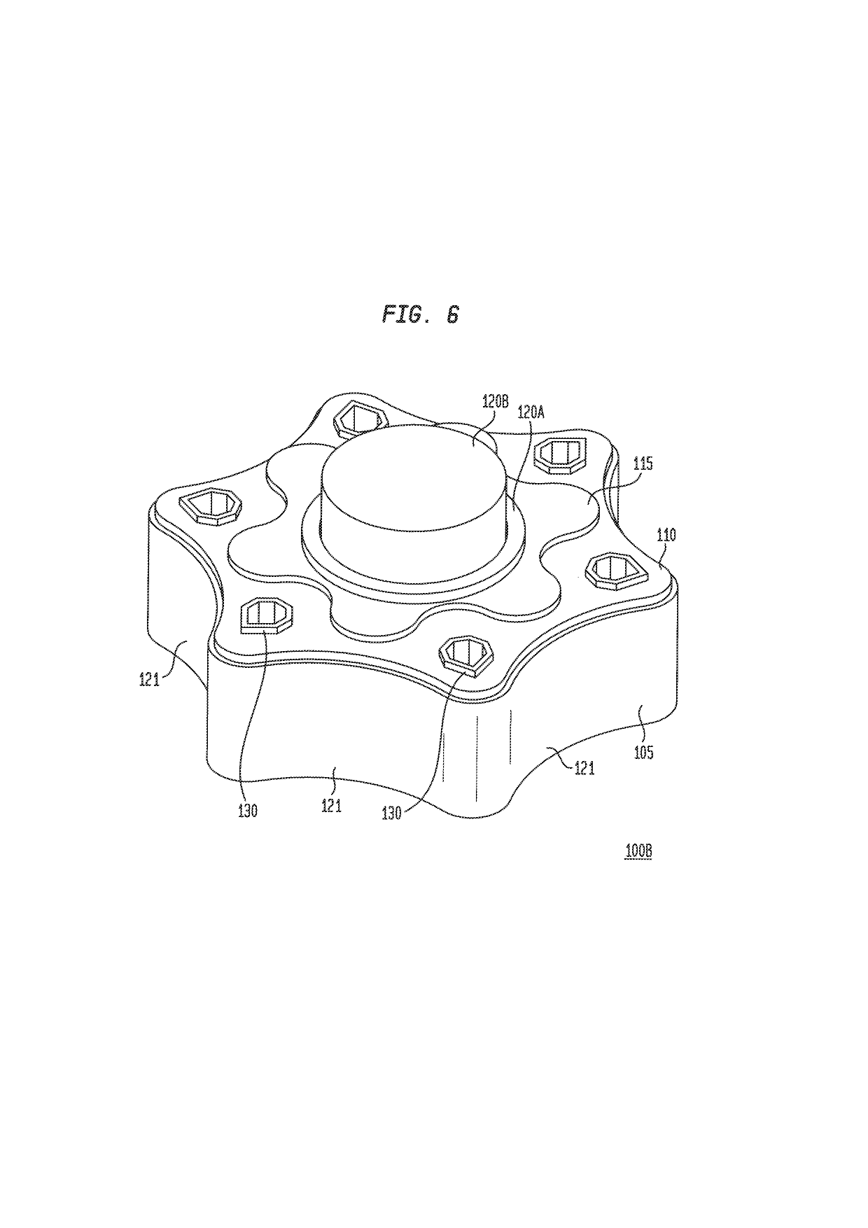

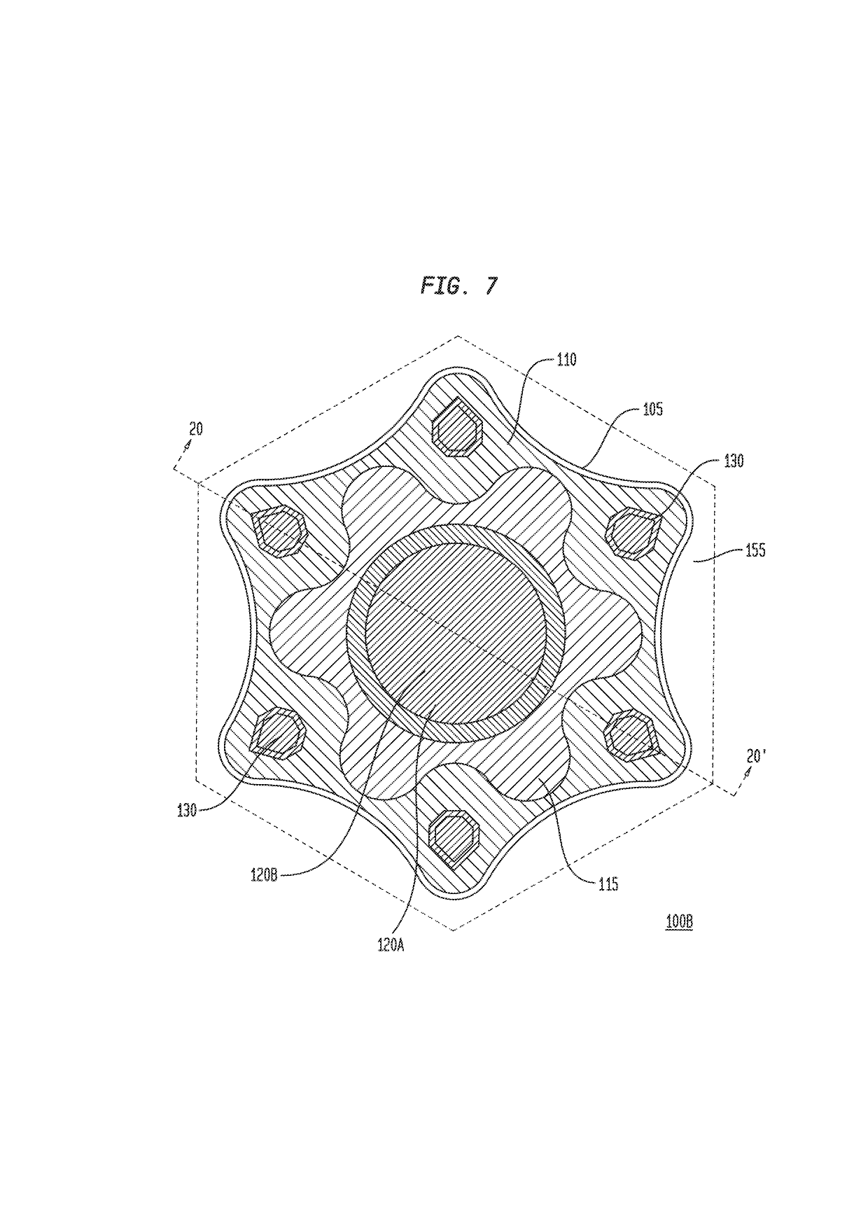

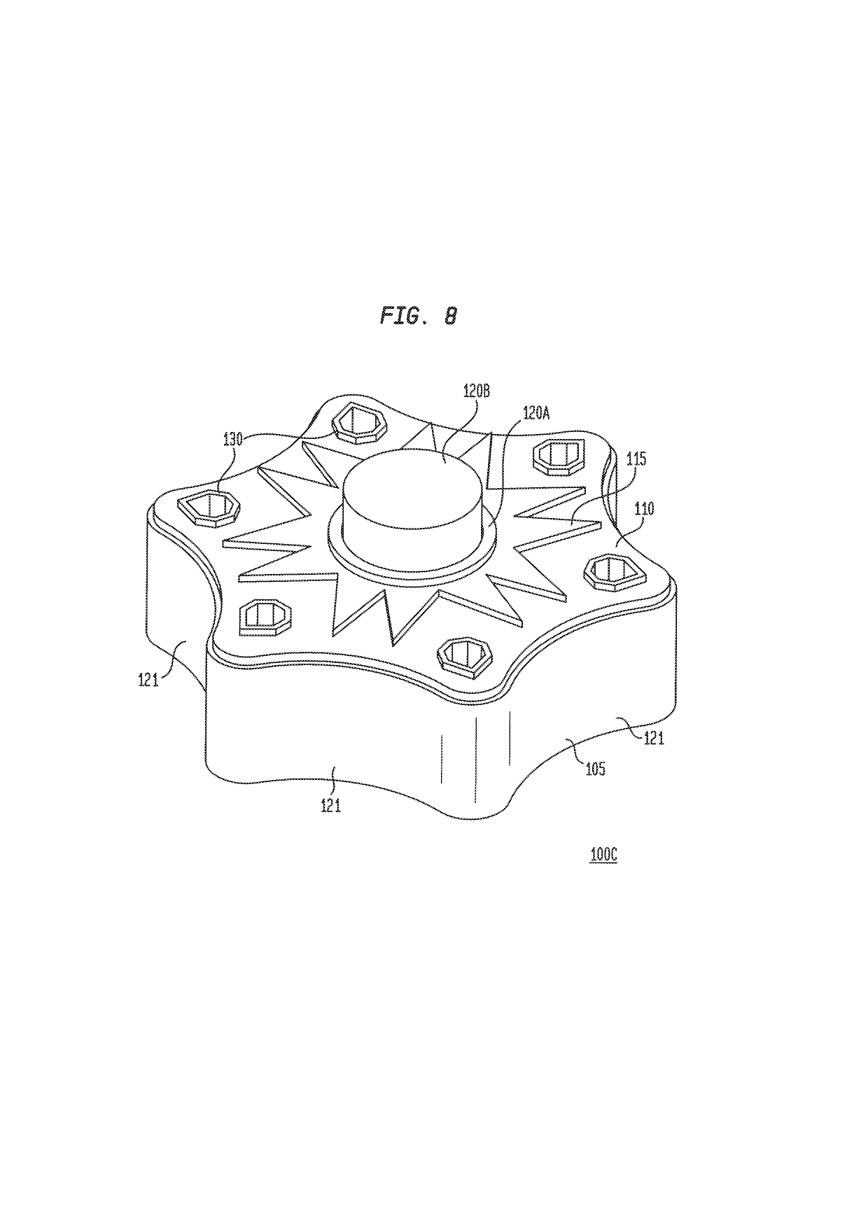

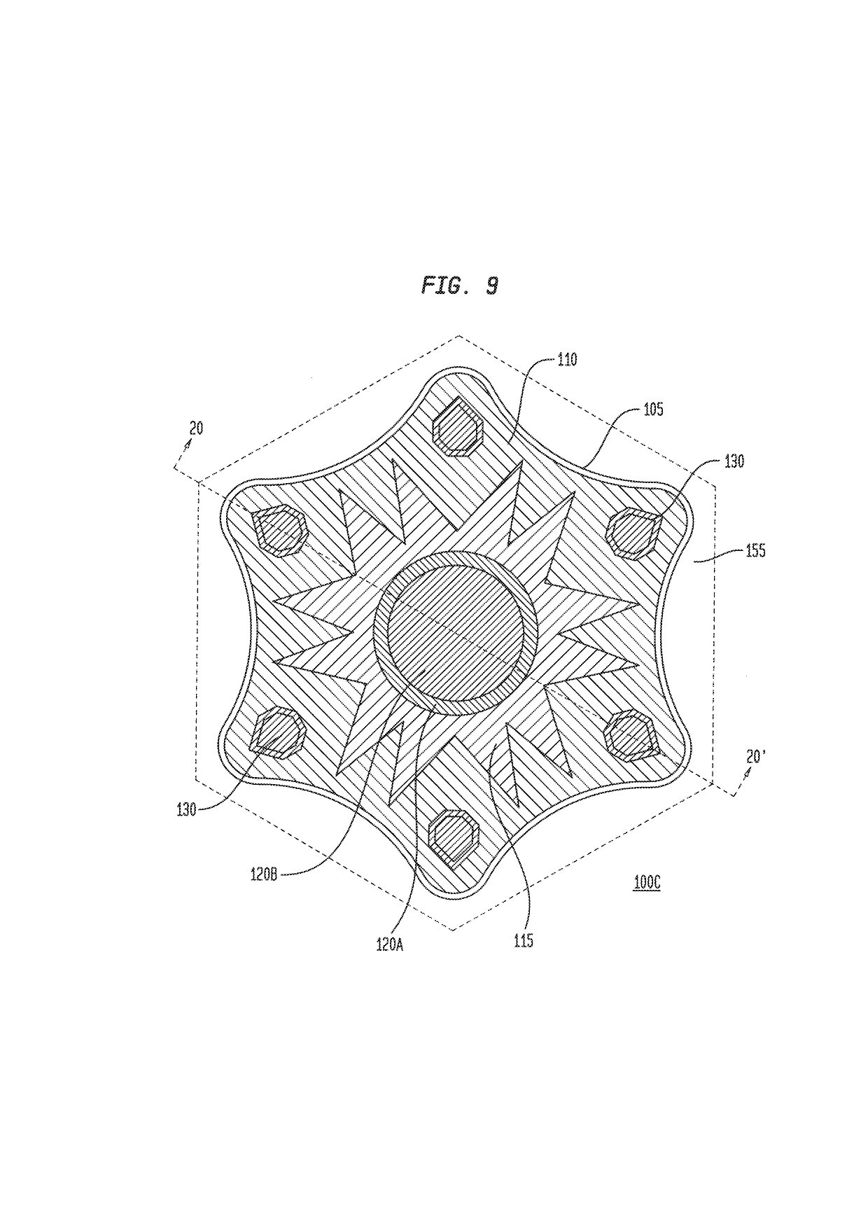

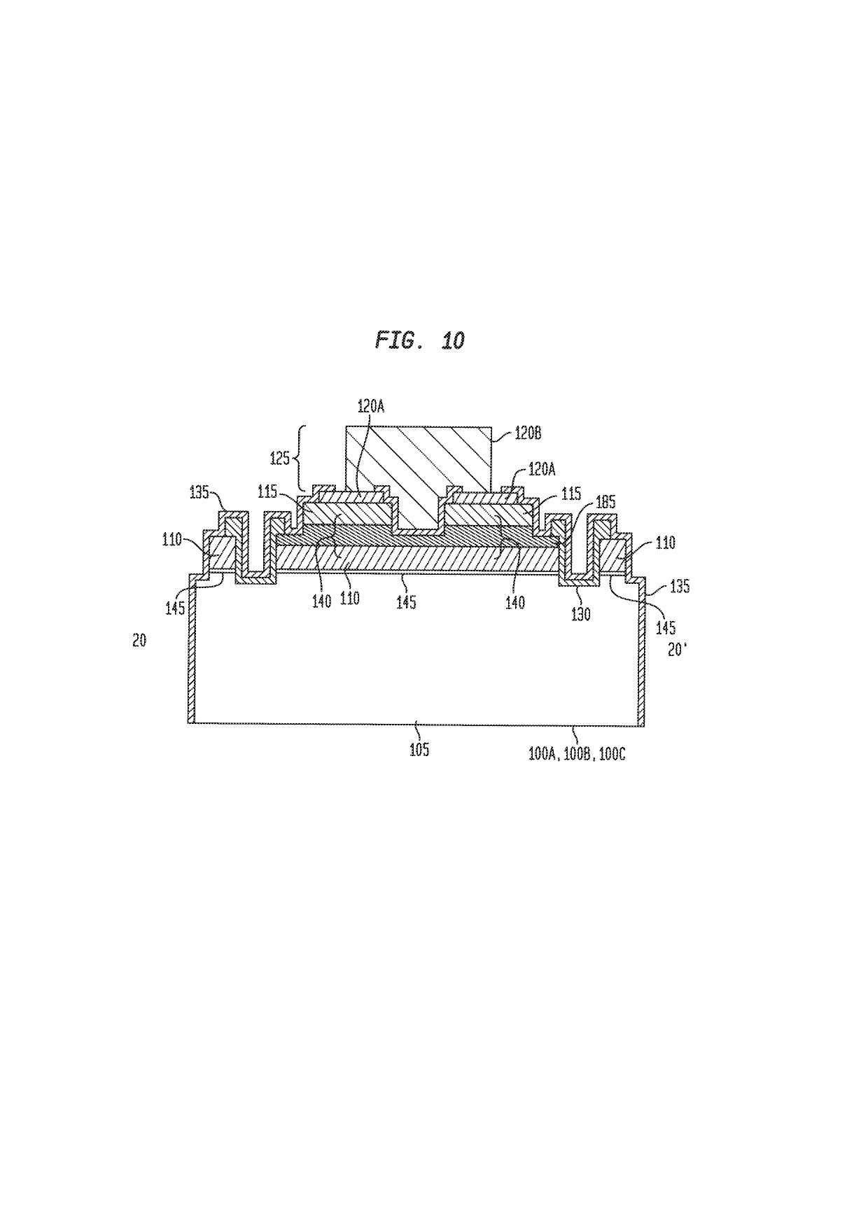

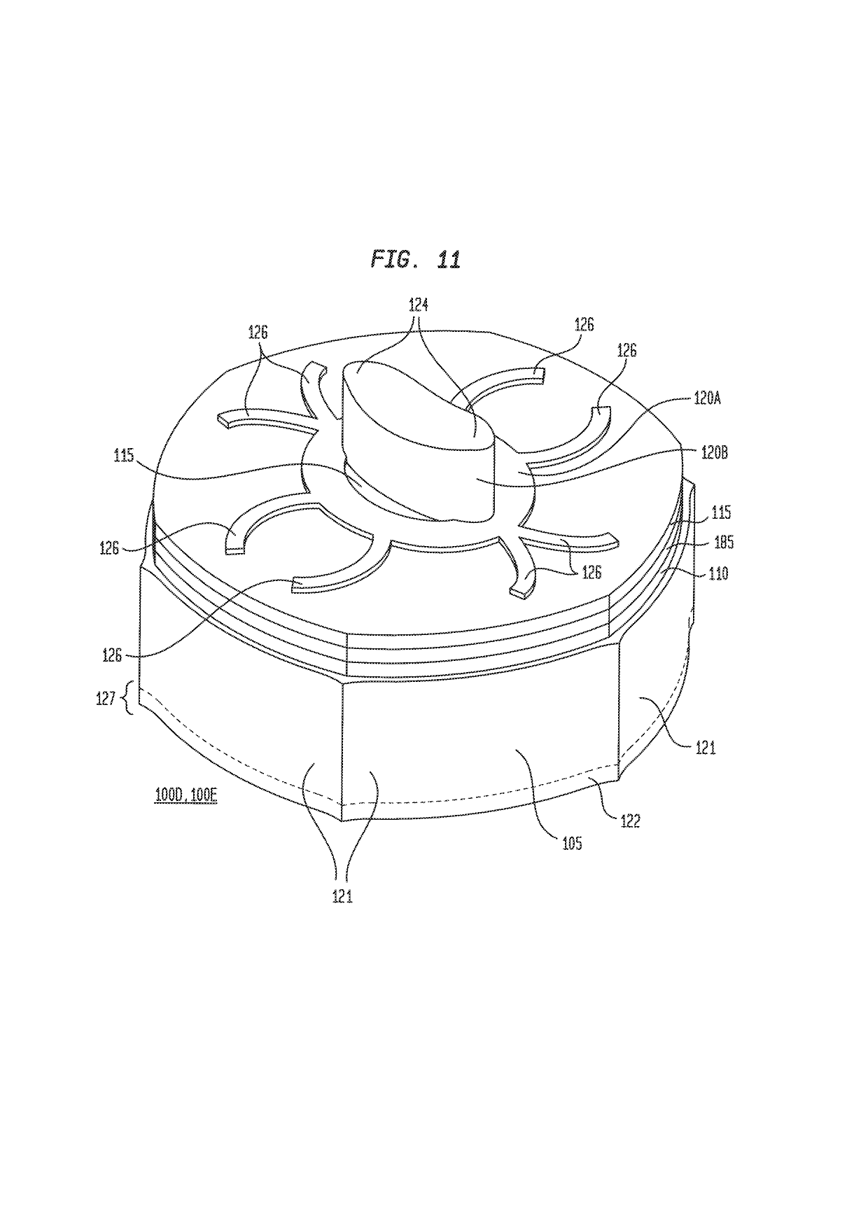

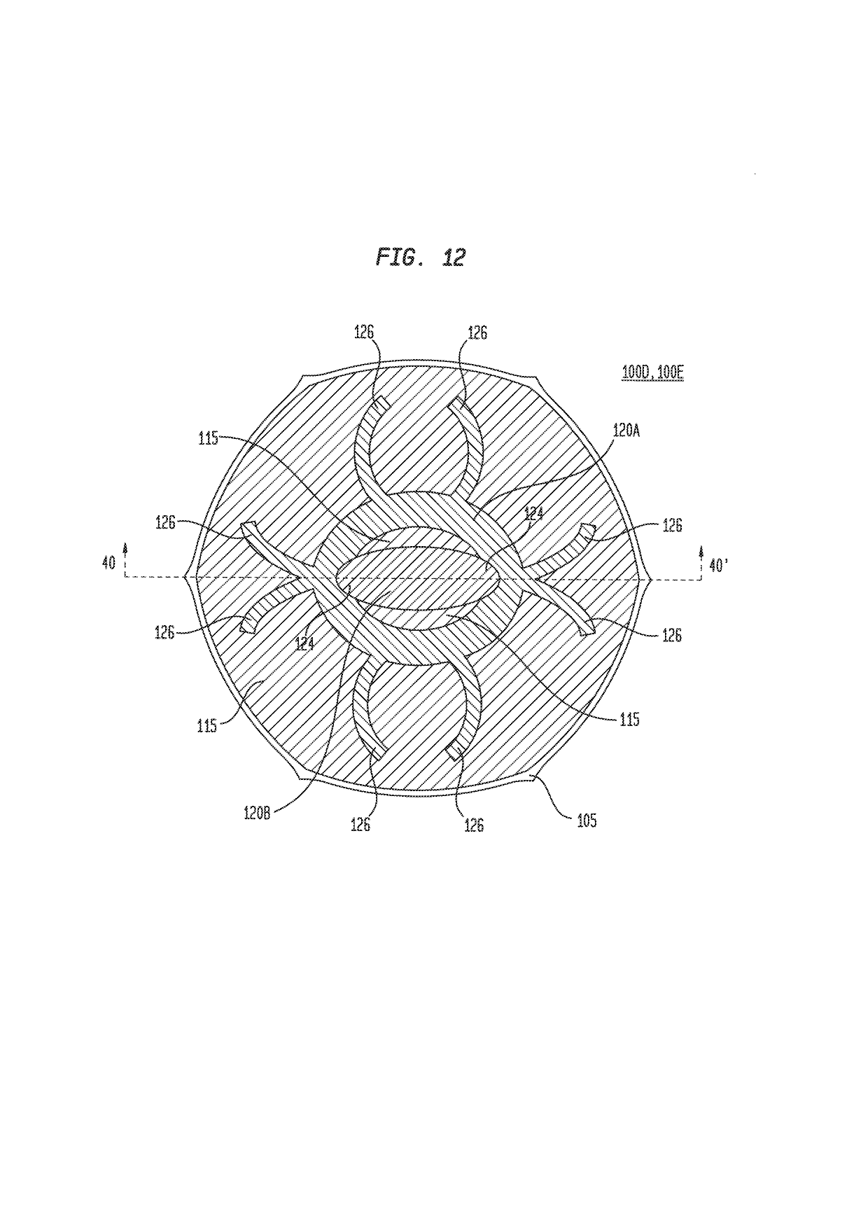

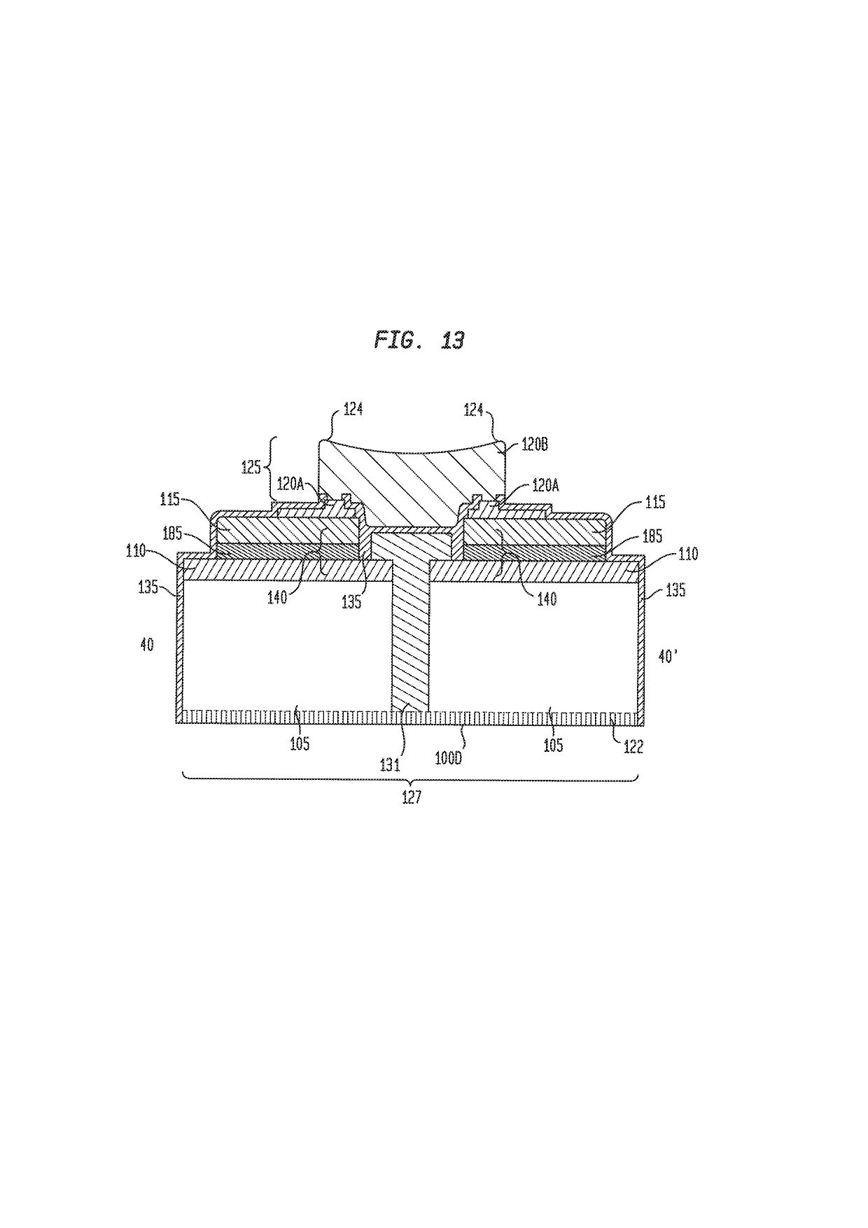

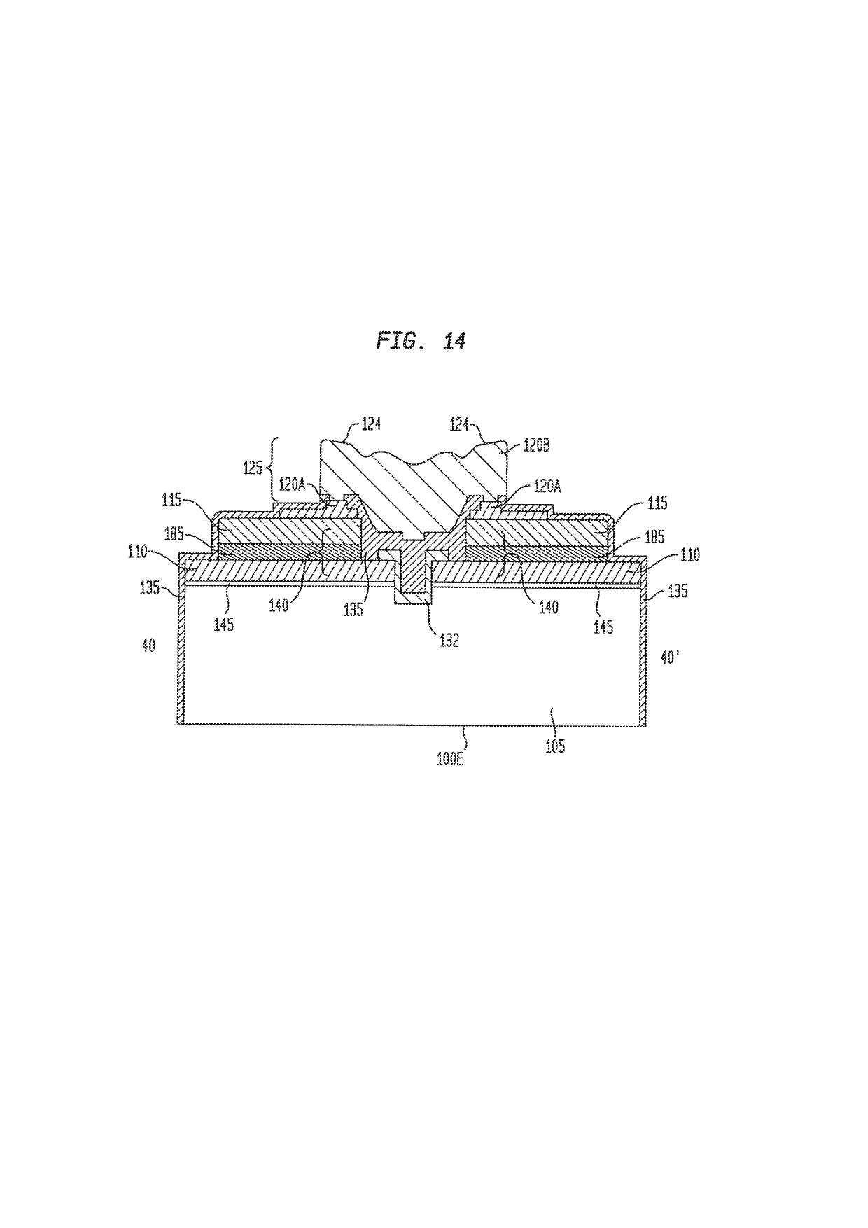

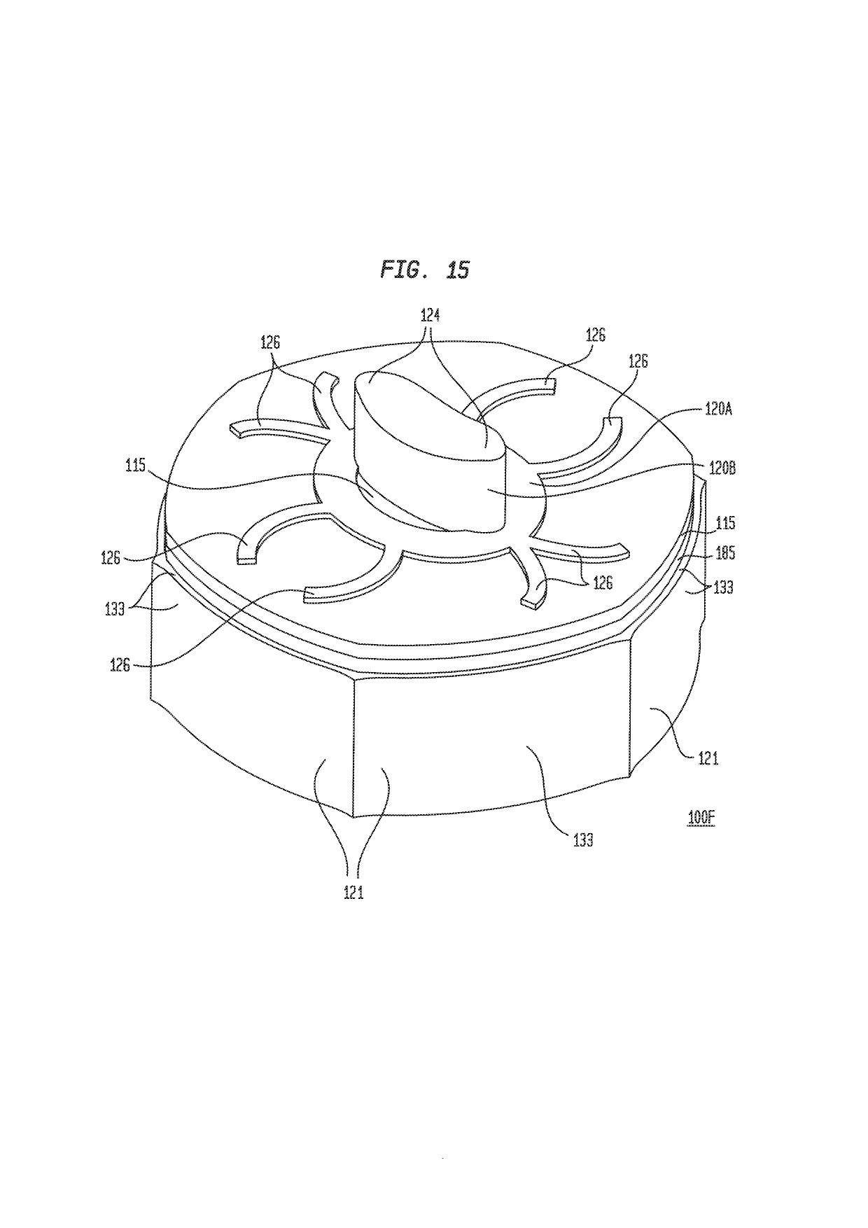

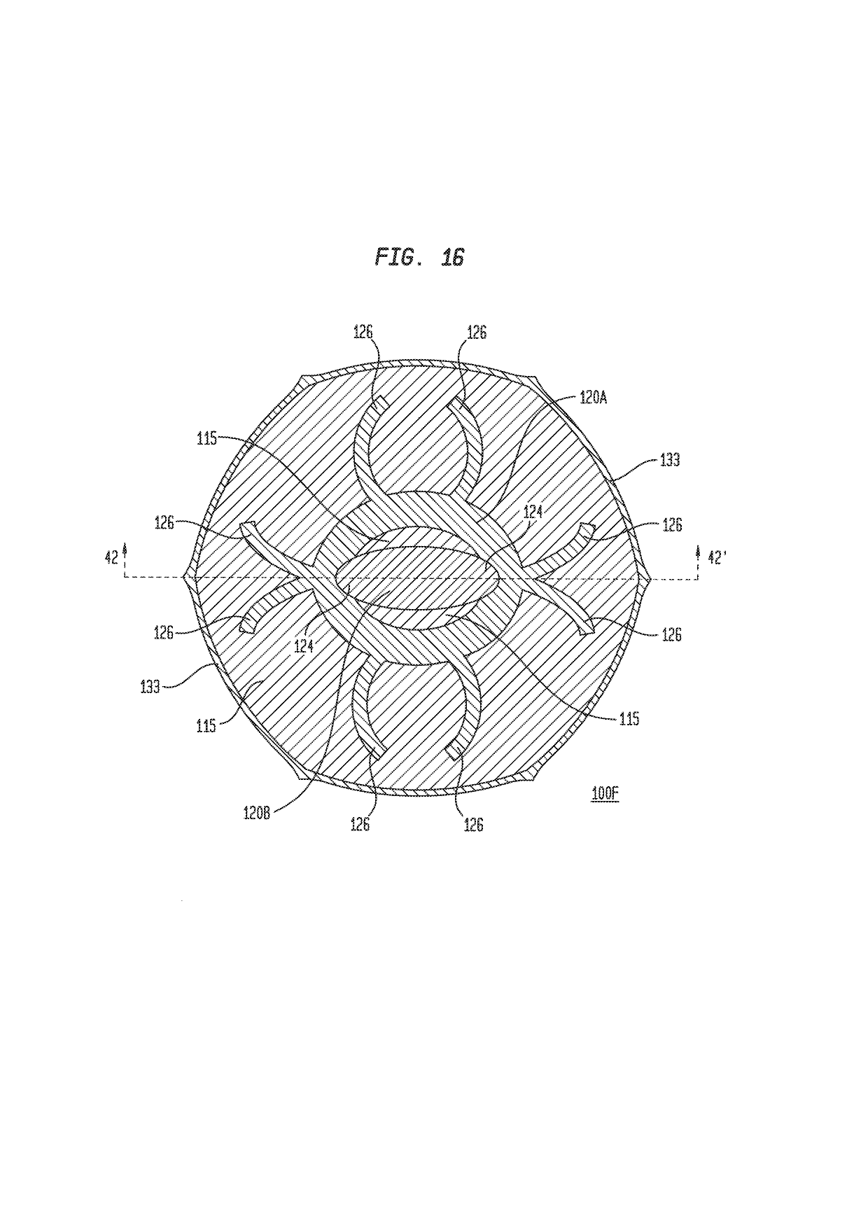

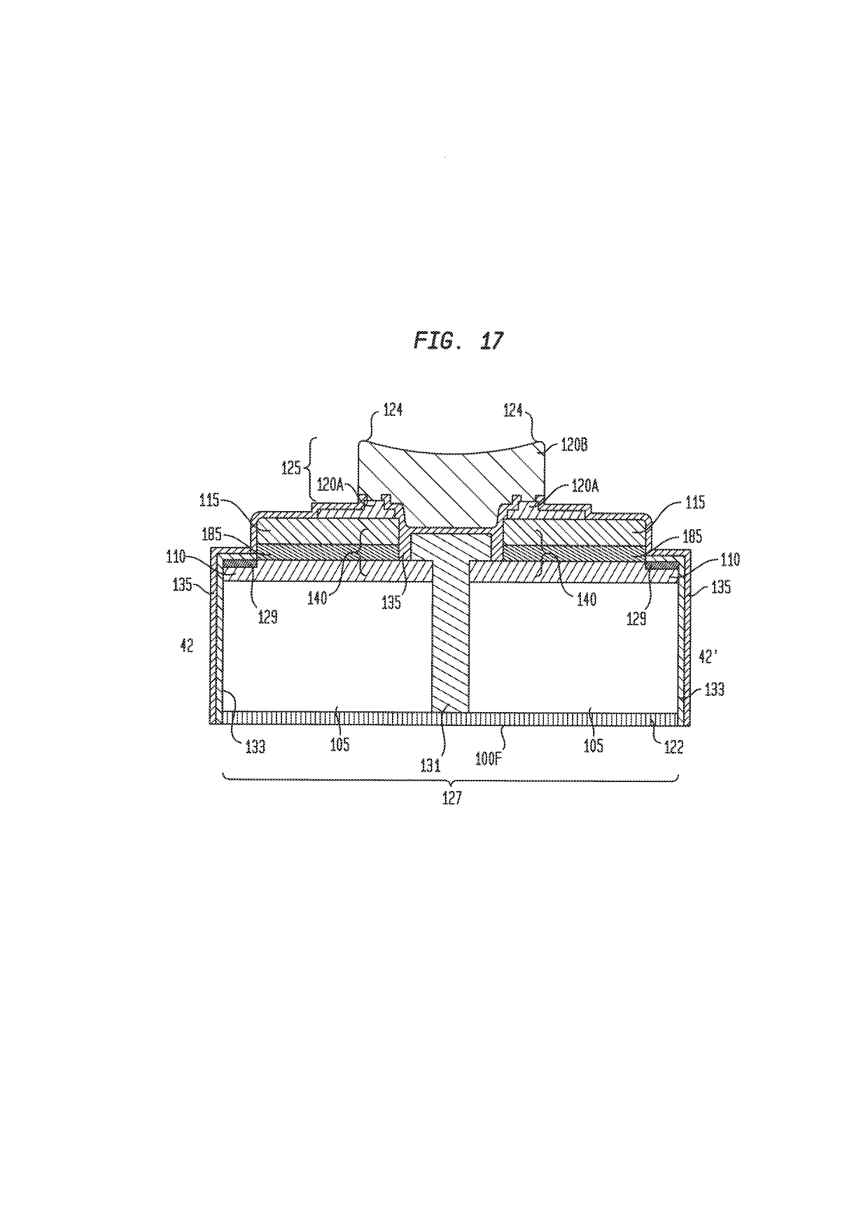

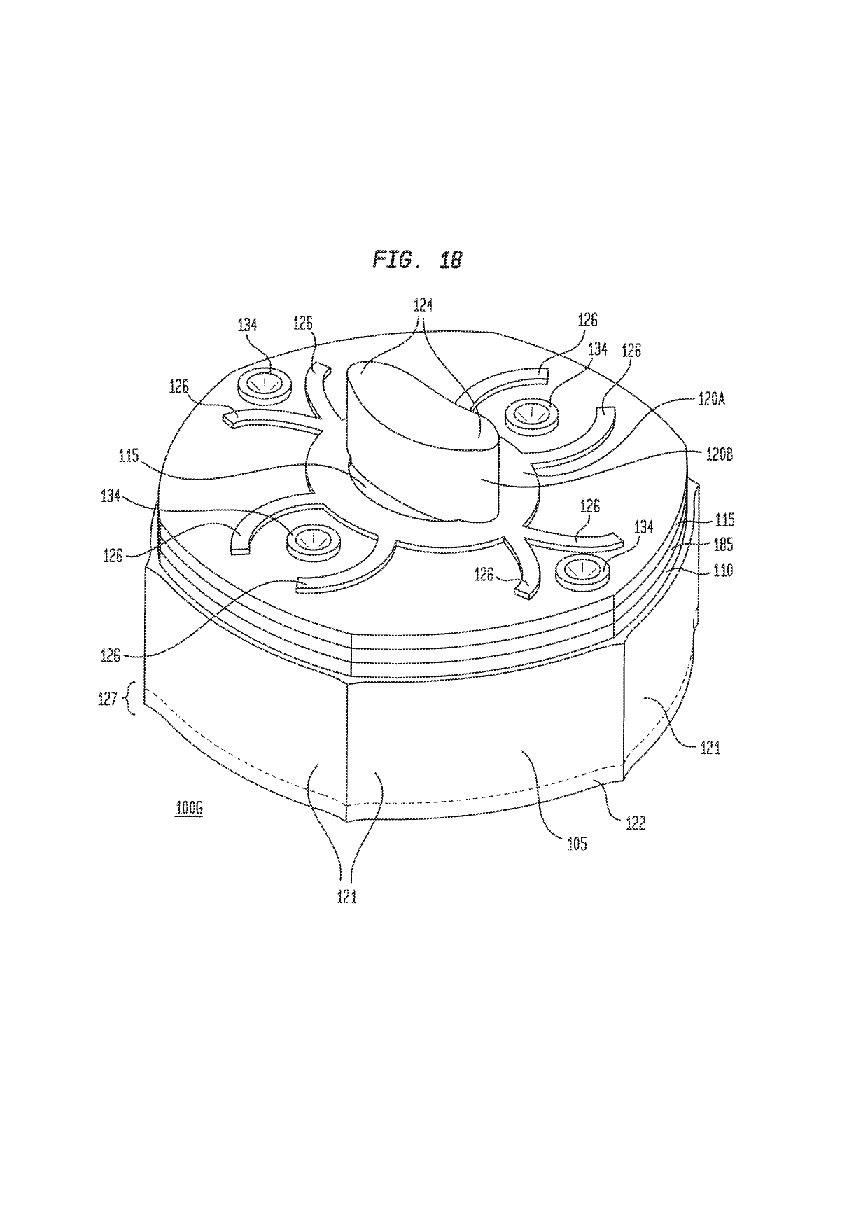

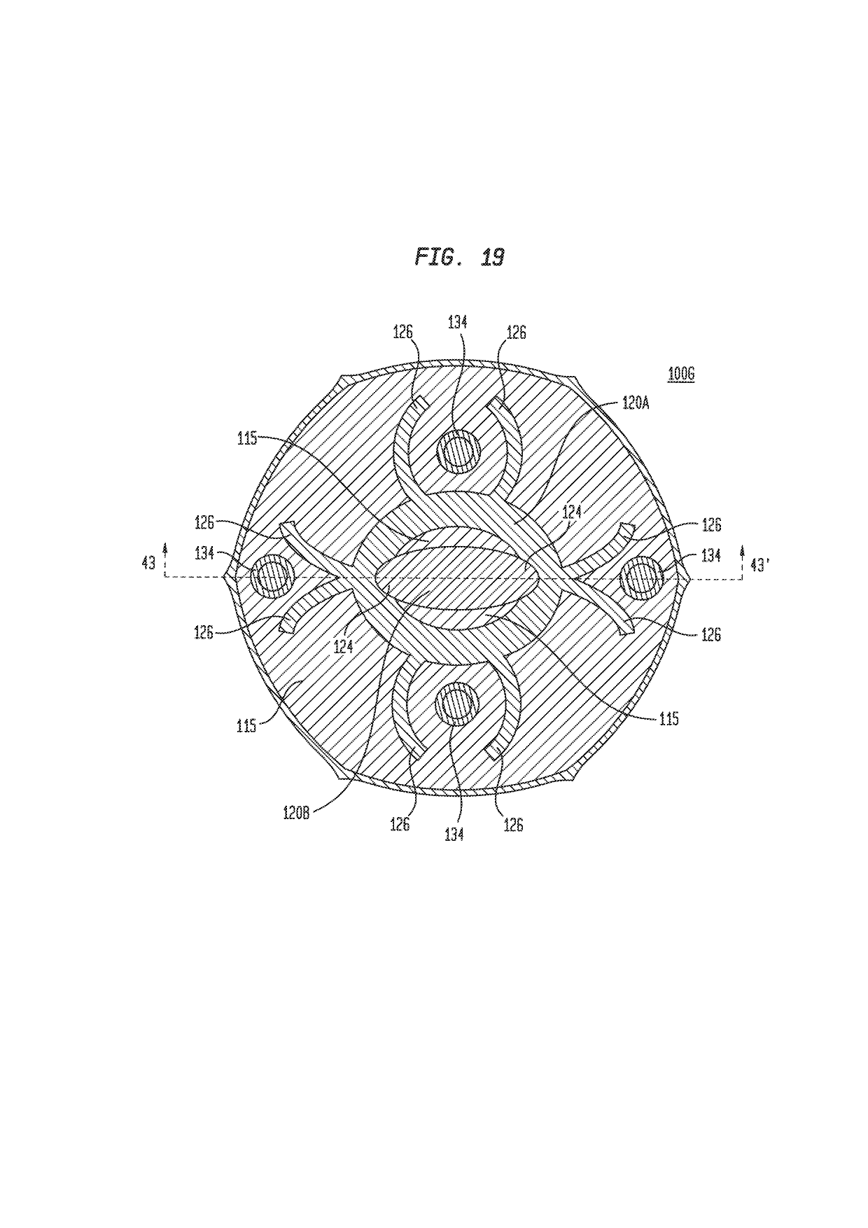

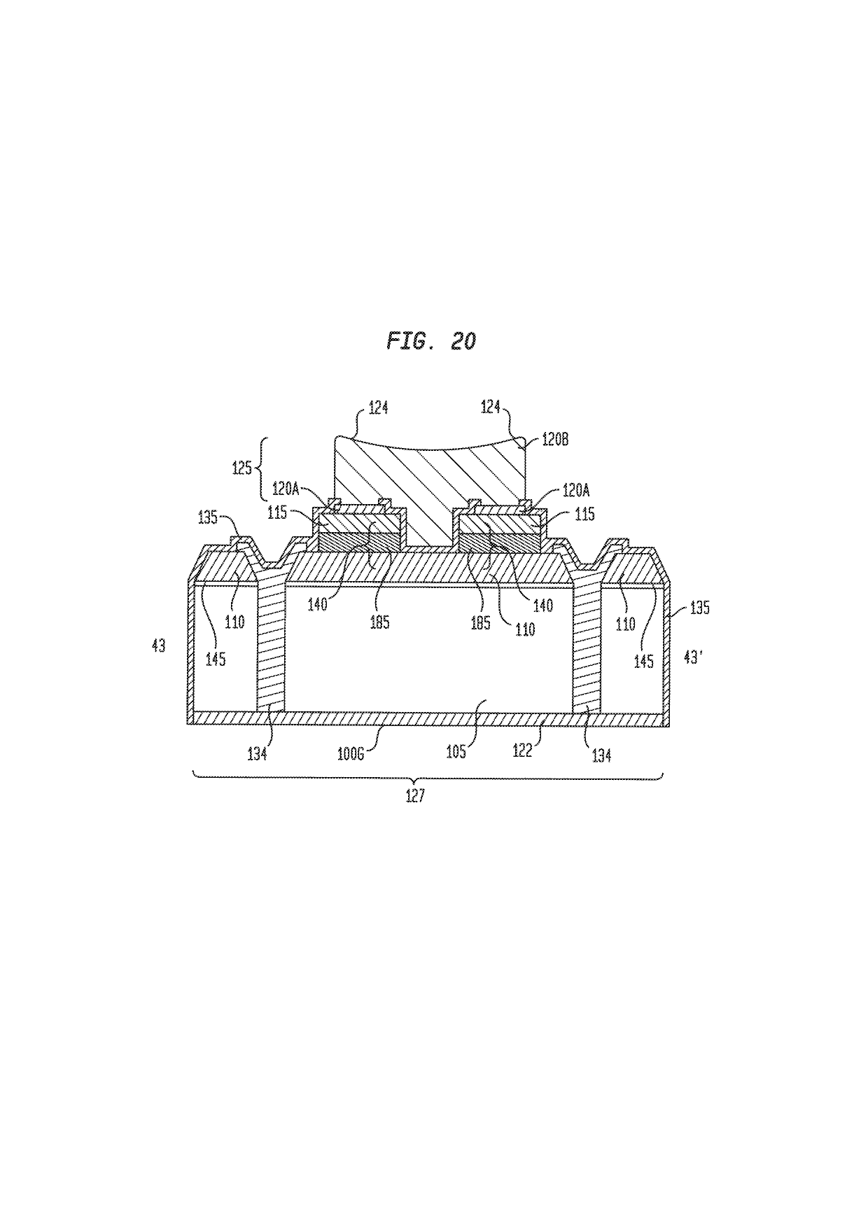

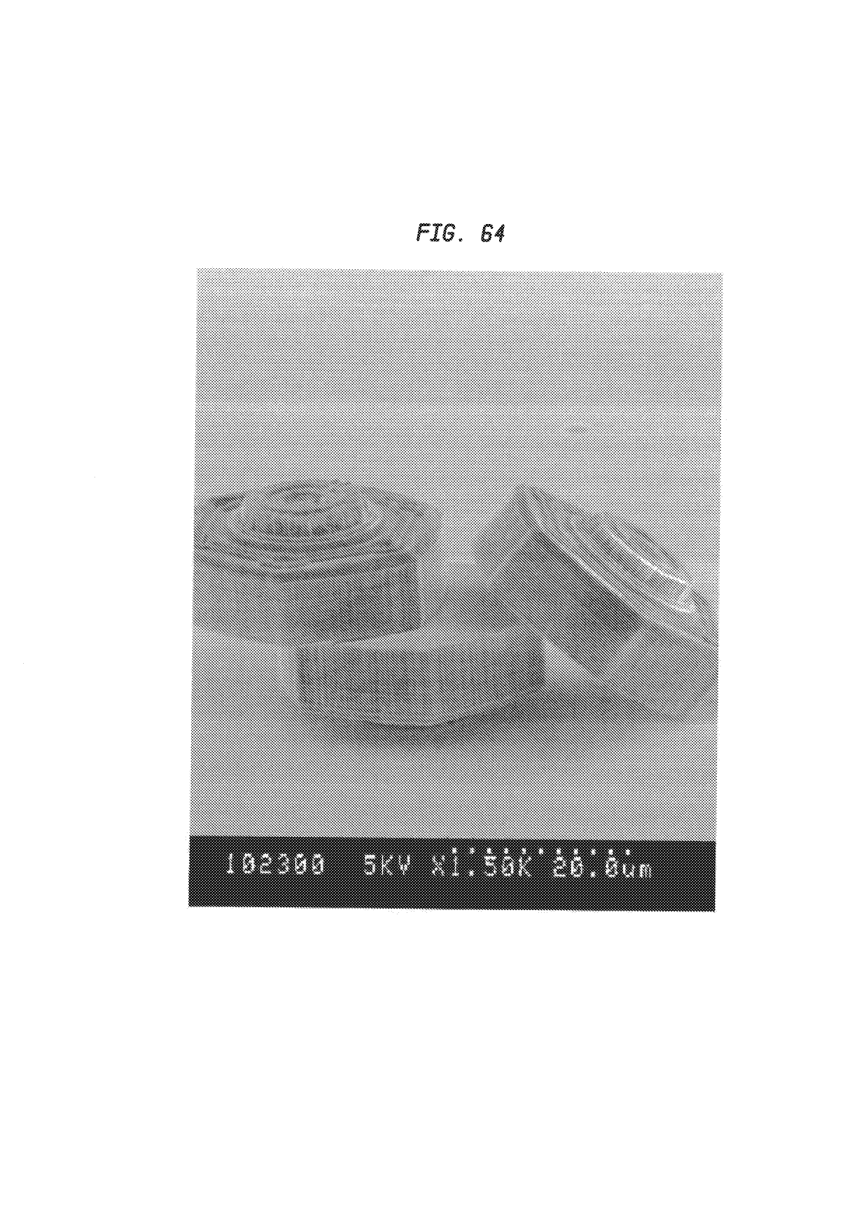

FIG. 1 is a perspective view illustrating an exemplary first diode 100 embodiment. FIG. 2 is a top view illustrating the exemplary first diode 100 embodiment. FIG. 3 is a cross-sectional view (through the 10-10′ plane of FIG. 2) illustrating the exemplary first diode 100 embodiment. FIG. 4 is a perspective view illustrating an exemplary second diode 100A embodiment. FIG. 5 is a top view illustrating the exemplary second diode 100A embodiment. FIG. 6 is a perspective view illustrating an exemplary third diode 100B embodiment. FIG. 7 is a top view illustrating the exemplary third diode 100B embodiment. FIG. 8 is a perspective view illustrating an exemplary fourth diode 100C embodiment. FIG. 9 is a top view illustrating the exemplary fourth diode 100C embodiment. FIG. 10 is a cross-sectional view (through the 20-20′ plane of FIGS. 5, 7, 9) illustrating exemplary second, third and/or fourth diode 100A, 100B, 100C embodiments. FIG. 11 is a perspective view illustrating exemplary fifth and sixth diode 100D, 100E embodiments. FIG. 12 is a top view illustrating the exemplary fifth and sixth diode 100D, 100E embodiments. FIG. 13 is a cross-sectional view (through the 40-40′ plane of FIG. 12) illustrating the exemplary fifth diode 100D embodiment. FIG. 14 is a cross-sectional view (through the 40-40′ plane of FIG. 12) illustrating the exemplary sixth diode 100E embodiment. FIG. 15 is a perspective view illustrating an exemplary seventh diode 100F embodiment. FIG. 16 is a top view illustrating the exemplary seventh diode 100F embodiment. FIG. 17 is a cross-sectional view (through the 42-42′ plane of FIG. 16) illustrating the exemplary seventh diode 100F embodiment. FIG. 18 is a perspective view illustrating an exemplary eighth diode 100G embodiment. FIG. 19 is a top view illustrating the exemplary eighth diode 100G embodiment. FIG. 20 is a cross-sectional view (through the 43-43′ plane of FIG. 19) illustrating the exemplary eighth diode 100G embodiment. Cross-sectional views of ninth, tenth and eleventh diode 100H, 100I, and 100J embodiments are illustrated in FIGS. 39, 45, and 48, respectively, as part of illustrations of exemplary fabrication processes. FIG. 63 is a scanning electron micrograph of an exemplary second diode 100A embodiment. FIG. 64 is a scanning electron micrograph of a plurality of exemplary second diode 100A embodiments.

In the perspective and top view diagrams, FIGS. 1, 2, 4-9, 11, 12, 15, 16, 18 and 19, illustration of a passivation layer 135 has been omitted in order to provide a view of other underlying layers and structures which would otherwise be covered by such a passivation layer 135 (and therefore not visible). The passivation layer 135 is illustrated in the cross-sectional views of FIGS. 3, 10, 13, 14, 17, 20, 39, 45, and 48, and those having skill in the electronic arts will recognize that fabricated diodes 100-100J generally will include at least one such passivation layer 135. In addition, referring to FIGS. 1-48, 52, and 54-58, those having skill in the art will also recognize that the various Figures are for purposes of description and explanation, and are not drawn to scale.

As described in greater detail below, the exemplary first through eleventh diode embodiments 100-100J differ primarily in the shapes, materials, doping and other compositions of the substrates 105 and wafers 150, 150A which may be utilized, the fabricated shape of the light emitting region of the diode, the depth and locations of vias (130, 131, 132, 133, 134) (such as shallow or “blind”, deep or “through”, center, peripheral, and perimeter), the use of back-side (second side) metallization (122) to form a second terminal 127, the shapes, extent and locations of other contact metals, and may also differ in the shapes or locations of other features, as described in greater detail below. Exemplary methods and method variations for fabricating the exemplary diodes 100-100J are also described below. One or more of the exemplary diodes 100-100J are also available from and may be obtained through NthDegree Technologies Worldwide, Inc. of Tempe, Ariz., USA.

Referring to FIGS. 1-20, exemplary diodes 100, 100A, 100B, 100C are formed using a substrate 105, such as a heavily-doped n+ (n plus) or p+ (p plus) substrate 105, e.g., a heavily doped n+ or p+ silicon substrate, which may be a silicon wafer or may be a more complex substrate or wafer, such as comprising a silicon substrate (105) on insulator (“SOT”), or a gallium nitride (GaN) substrate 105 on a sapphire (106) wafer 150A (illustrated in FIGS. 11-20), for example and without limitation. Other types of substrates (and/or wafers forming or having a substrate) 105 may also be utilized equivalently, including Ga, GaAs, GaN, SiC, SiO₂, sapphire, organic semiconductor, etc., for example and without limitation, and as discussed in greater detail below. Accordingly, reference to a substrate 105 should be understood broadly to also include any types of substrates, such as n+ or p+ silicon, n+ or p+ GaN, such as a n+ or p+ silicon substrate formed using a silicon wafer 150 or the n+ or p+ GaN fabricated on a sapphire wafer 105A (described below with reference to FIGS. 11-20 and 33-45). When embodied using silicon, the substrate 105 typically has a <111> or <110> crystal structure or orientation, although other crystalline structures may be utilized equivalently. An optional buffer layer 145 is typically fabricated on a silicon substrate 105, such as aluminum nitride or silicon nitride, to facilitate subsequent fabrication of GaN layers having a different lattice constant. GaN layers are fabricated over the buffer layer 145, such as through epitaxial growth, to form a complex GaN heterostructure, generally illustrated as n+ GaN layer 110, quantum well region 185, and p+ GaN layer 115. In other embodiments, a buffer layer 145 is not or may not be utilized, such as when a complex GaN heterostructure (n+ GaN layer 110, quantum well region 185, and p+ GaN layer 115) is fabricated over a GaN substrate 105, as illustrated in FIGS. 15-17 as a more specific option. Those having skill in the electronic arts will understand that there may by many quantum wells within and potentially multiple p+ and n+ GaN layers to form a light emitting (or light absorbing) region 140, with n+ GaN layer 110, quantum well region 185, and p+ GaN layer 115 being merely illustrative and providing a generalized or simplified description of a complex GaN heterostructure forming one or more light emitting (or light absorbing) regions 140. Those having skill in the electronic arts will also understand that the locations of the n+ GaN layer 110 and p+ GaN layer 115 may be the same or may be reversed equivalently, such as for use of a p+ silicon substrate 105, and that other compositions and materials may be utilized to form one or more light emitting (or light absorbing) regions 140 (many of which are described below), and all such variations are within the scope of the disclosure.

The n+ or p+ substrate 105 conducts current, which flows to the n+ GaN layer 110. The current flow path is also through a metal layer forming one or more vias 130 (which may also be utilized to provide an electrical bypass of a very thin (about 25 Angstroms) buffer layer 145 between the n+ or p+ substrate 105 and the n+ GaN layer 110). Additional types of vias 131-134 are described below. One or more metal layers 120, illustrated as two (or more) separately deposited metal layers 120A and 120B (which also may be used to form vias 130) provides an ohmic contact with the p+ GaN layer 115, with the second additional metal layer 120B utilized to form a “bump” or protruding structure, with metal layers 120A, 120B forming a first electrical terminal (or contact) 125 for a diode 100-100J. For the illustrated exemplary diode 100, 100A, 100B, 100C embodiments, electrical terminal 125 may be the only ohmic, metallic terminal formed on the diodes 100, 100A, 100B, 100C during fabrication for subsequent power (voltage) delivery (for LED applications) or reception (for photovoltaic applications), with the n+ or p+ substrate 105 utilized to provide the second electrical terminal for a diode 100, 100A, 100B, 100C for power delivery or reception. It should be noted that electrical terminal 125 and the n+ or p+ substrate 105 are on opposing sides, top (first side) and bottom (or back, second side) respectively, and not on the same side, of a diode 100, 100A, 100B, 100C. As an option for these diode 100, 100A, 100B, 100C embodiments and as illustrated for other exemplary diode embodiments, an optional, second ohmic, metallic terminal 127 is formed using metallic layer 122 on the second, back side of a diode (e.g., diode 100D, 100F, 100G, 100J). Silicon nitride passivation 135 (or any other equivalent passivation) is utilized, among other things, for electrical insulation and environmental stability. Not separately illustrated, a plurality of trenches 155 were formed during fabrication along the lateral sides of the diodes 100-100J, as discussed below, which are utilized both to separate the diodes 100-100J from each other on a wafer 150, 150A, and to separate the diodes 100-100J from the remainder of the wafer 150, 150A.

FIGS. 1-20 also illustrate some of the various shapes and form factors of the one or more light emitting (or light absorbing) regions 140, illustrated as a GaN heterostructure (n+ GaN layer 110, quantum well region 185, and p+ GaN layer 115) and the various shapes and form factors of the substrate 105. Also as illustrated, while an exemplary diode 100-100J is substantially hexagonal in the x-y plane (with curved or arced lateral sides 121, concave or convex, as discussed in greater detail below), to provide greater device density per silicon wafer, other diode shapes and forms are considered equivalent and within the scope of the claimed invention, such as square, triangular, octagonal, circular, etc. Also as illustrated in the exemplary embodiments, the hexagonal lateral sides 121 may also be curved or arced slightly, convex (FIGS. 1, 2, 4, 5, 11, 12, 15, 16, 18, 19), concave (FIGS. 6-9), such that when released from the wafer and suspended in liquid, the diodes 100-100J may avoid adhering or sticking to one another, and also for apparatus 300, 300A, 300B fabrication, to prevent individual die (individual diodes 100-100J) from standing on their lateral sides or edges (121). Also as illustrated in the exemplary embodiments, the hexagonal lateral sides 121 may also be curved or arced slightly, to be both convex about the center of each side 121 and concave peripherally/laterally to form somewhat pointed vertices (FIGS. 11-20), such that when released from the wafer and suspended in liquid, the diodes 100-100J also may avoid adhering or sticking to one another and may push off one another when rolling or moving against another diode), and again, also for apparatus 300, 300A, 300B fabrication, to prevent individual die (individual diodes 100-100J) from standing on their lateral sides or edges (121).

Various shapes and form factors of the light emitting (or light absorbing) regions 140 (n+ GaN layer 110, quantum well region 185 and p+ GaN layer 115) are also illustrated, with FIGS. 1-3 illustrating a substantially circular or disk-shaped light emitting (or light absorbing) region 140 (n+ GaN layer 110, quantum well region 185 and p+ GaN layer 115), and with FIGS. 4 and 5 illustrating a substantially torus-shaped (or toroidal) light emitting (or light absorbing) region 140 (n+ GaN layer 110, quantum well region 185 and p+ GaN layer 115) with the second metal layer 120B extending into the center of the toroid (and potentially providing a reflective surface). In FIGS. 6 and 7, the light emitting (or light absorbing) region 140 (n+ GaN layer 110, quantum well region 185 and p+ GaN layer 115) has a substantially circular inner (lateral) surface and a substantially lobed outer (lateral) surface, while in FIGS. 8 and 9, the light emitting (or light absorbing) region 140 (n+ GaN layer 110, quantum well region 185 and p+ GaN layer 115) also has a substantially circular inner (lateral) surface while the outer (lateral) surface is substantially stellate- or star-shaped. In FIGS. 11-20, the one or more light emitting (or light absorbing) regions 140 have a substantially hexagonal (lateral) surface (which may or may not extend to the perimeter of the die) and may have (at least partially) a substantially circular inner (lateral) surface. In other exemplary embodiments not separately illustrated, there may be multiple light emitting (or light absorbing) regions 140, which may be continuous or which may be spaced apart on the die. These various configurations of the one or more light emitting (or light absorbing) regions 140 (n+ GaN layer 110, quantum well region 185 and p+ GaN layer 115) having a circular inner surface may be implemented to increase the potential for light output (for LED applications) and light absorption (for photovoltaic applications).

In an exemplary embodiment, the terminal 125 comprised of one or more metal layers 120A, 120B has a bump or protruding structure, to allow a significant portion of a diode 100-100J to be covered by one or more insulating layers (following formation of an electrical contact to the n+ or p+ silicon substrate 105 (or to a second terminal formed by metal layer 122) by a first conductor 310A), while simultaneously providing sufficient structure for contact with the electrical terminal 125 by one or more other conductive layers, such as a transparent conductor 320 discussed below. In addition, the bump or protruding structure of terminal 125 potentially may also be a factor affecting rotation of a diode 100-100J within the diode ink and its subsequent orientation (top up (forward bias) or bottom up (reverse bias)) in a fabricated apparatus 300, 300A, 300B, in addition to the curvature of the lateral sides 121.

Referring to FIGS. 11-20, exemplary diodes 100D, 100E, 100F, 100G, in various combinations, illustrate several additional and optional features. As illustrated, metal layer 120B forming a bump or protruding structure is substantially elliptical (or oval) in its circumference rather than substantially circular in circumference, although other shapes and form factors of the terminal 125 are also within the scope of the disclosure. In addition, the metal layer 120B forming a bump or protruding structure has two or more elongated extensions 124, which serve several additional purposes in apparatus 300, 300A, 300B fabrication, such as facilitating electrical contact formation with a second, transparent conductor 320 and facilitating flow of an insulating dielectric 315 off of the terminal 125 (metal layer 120B). The elliptical form factor also may allow for additional light emission (or absorption) from or to light emitting (or light absorbing) region 140 along the major axis sides of the elliptical metal layer 120B forming a bump or protruding structure. Metal layer 120A, forming an ohmic contact with p+ GaN layer 115, which also may be deposited as multiple layers in multiple steps, also has elongated extensions over p+ GaN layer 115, illustrated as curved metal contact extensions 126, facilitating current conduction to the p+ GaN layer 115 while simultaneously allowing for (and not blocking excessively) the potential for light emission or light absorption by the light emitting (or light absorbing) regions 140. Innumerable other shapes of the metal contact extensions 126 may be utilized equivalently, such as a grid pattern, other curvilinear shapes, etc.

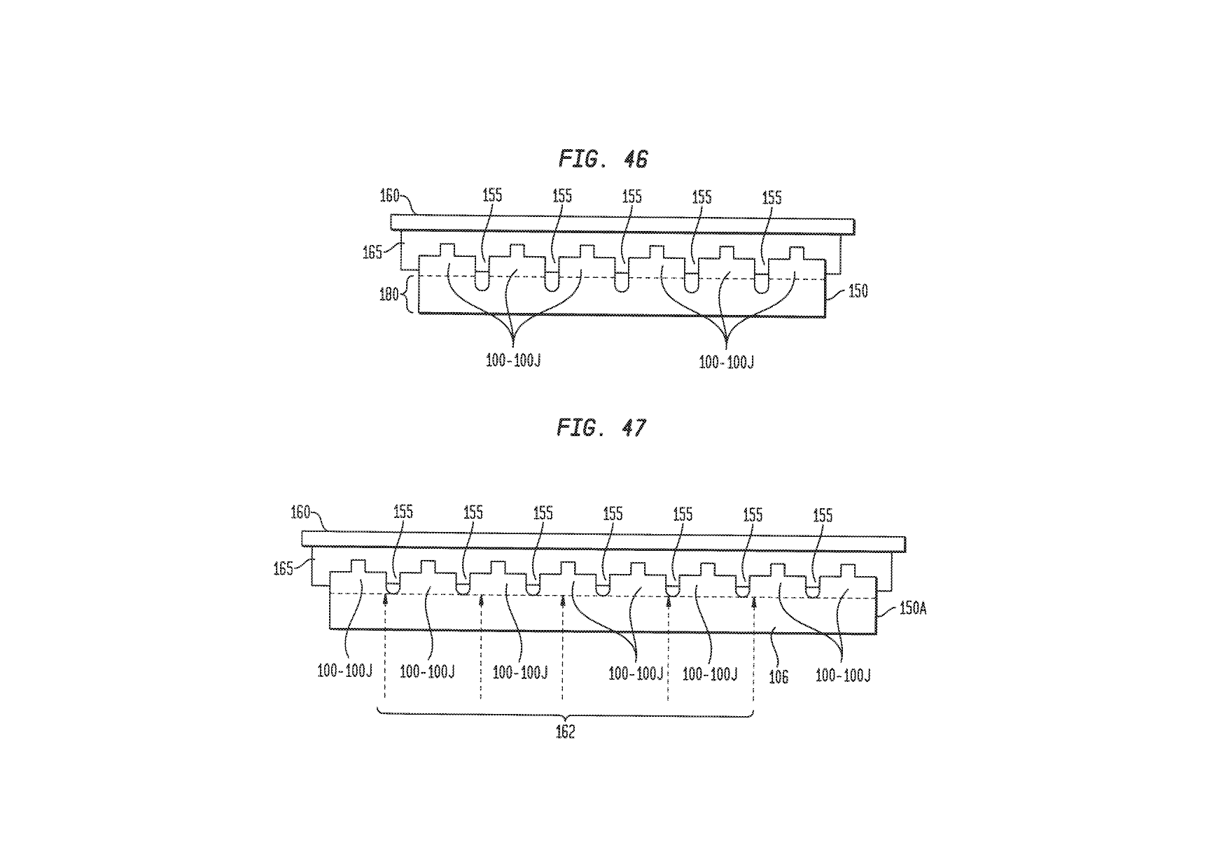

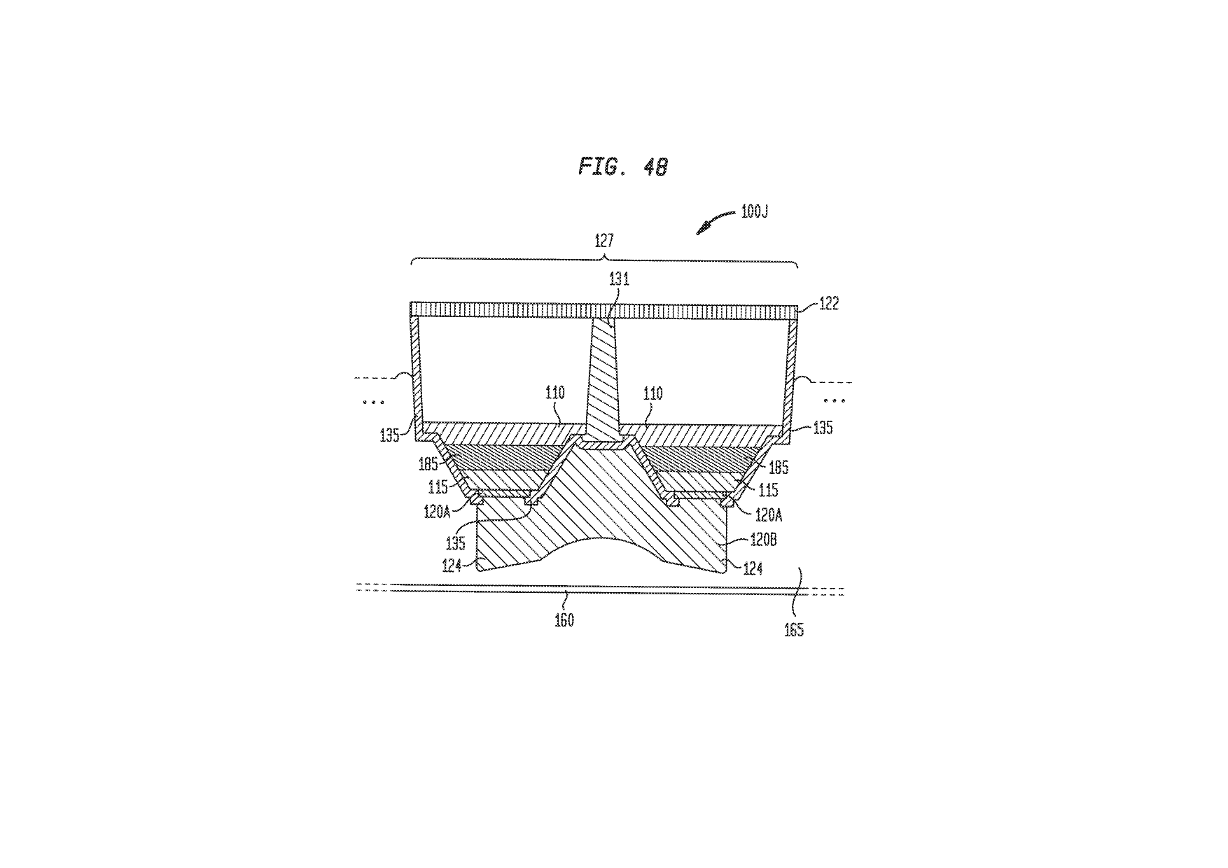

Additional types of via structures (131, 132, 133, 134) are also illustrated in FIGS. 11-20, in addition to the peripheral (i.e., off center), comparatively shallow or “blind” via 130 previously described which extends through the buffer layer 145 and into the substrate 105 but not comparatively deeply into or through the substrate 105 in the fabricated diode 100, 100A, 100B, 100C. As illustrated in FIG. 13 (and FIGS. 39, 48), a center (or centrally located), comparatively deep, “through” via 131 extends completely through the substrate 105, and is utilized to make an ohmic contact with the n+ GaN layer 110 and to conduct current (or otherwise make an electrical contact) between the second (back) side metal layer 122 and the n+ GaN layer 110. As illustrated in FIG. 14, a center (or centrally located), comparatively shallow or blind via 132, also referred to as a “blind” via 132, extends through a buffer layer 145 and into the substrate 105, and it utilized to make an ohmic contact with the n+ GaN layer 110 and to conduct current (or otherwise make an electrical contact) between the n+ GaN layer 110 and the substrate 105. As illustrated in FIGS. 15-17 and 44-45, a perimeter, comparatively deep or through via 133 extends along the lateral sides 121 (although covered by passivation layer 135) from the n+ GaN layer 110 and to the second, back-side of the diode 100F, which in this embodiment also includes second (back) side metal layer 122, completely around the lateral sides of the substrate 105, and it utilized to make an ohmic contact with the n+ GaN layer 110 and to conduct current (or otherwise make an electrical contact) between the second (back) side metal layer 122 and the n+ GaN layer 110. As illustrated in FIGS. 18-20, a peripheral, comparatively deep, through via 134 extends completely through the substrate 105, and it utilized to make an ohmic contact with the n+ GaN layer 110 and to conduct current (or otherwise make an electrical contact) between the second (back) side metal layer 122 and the n+ GaN layer 110. In embodiments which do not utilize a second (back) side metal layer 122, such through via structures (131, 133, 134) may be utilized to make an electrical contact with the conductor 310A (in an apparatus 300, 300A, 300B) and to conduct current (or otherwise make an electrical contact) between the conductor 310A and the n+ GaN layer 110. These through via structures (131, 133, 134) are exposed on the second, back side of a diode 110D, 100F, 100G during fabrication, following singulation of the diodes through either a back side grind and polish or laser lift off (discussed below with reference to FIGS. 46 and 47), and may be left exposed or may be covered by (and form an electrical contact with) second (back) side metal layer 122 (as illustrated in FIG. 48).

The through via structures (131, 133, 134) are considerably narrower than typical vias known in the art. The through via structures (131, 133, 134) are on the order of about 7-9 microns deep (height extending through the substrate 105) and about 3-5 microns wide, compared to about a 30 micron or greater width of traditional vias.

An optional second (back) side metal layer 122, forming a second terminal or contact 127, is also illustrated in FIGS. 11-13, 17, 18, 20 and 48. Such a second terminal or contact 127, for example and without limitation, may be utilized to facilitate current conduction to the n+ GaN layer 110, such as through the various through via structures (131, 133, 134), and/or to facilitate forming an electrical contact with the conductor 310A.

The diodes 100-100J are generally less than about 450 microns in all dimensions, and more specifically less than about 200 microns in all dimensions, and more specifically less than about 100 microns in all dimensions, and more specifically less than 50 microns in all dimensions. In the illustrated exemplary embodiments, the diodes 100-100J are generally on the order of about 15 to 40 microns in width, or more specifically about 20 to 30 microns in width, and about 10 to 15 microns in height, or from about 25 to 28 microns in diameter (measured side face to face rather than apex to apex) and 10 to 15 microns in height. In exemplary embodiments, the height of the diodes 100-100J excluding the metal layer 120B forming the bump or protruding structure (i.e., the height of the lateral sides 121 including the GaN heterostructure) is on the order of about 5 to 15 microns, or more specifically 7 to 12 microns, or more specifically 8 to 11 microns, or more specifically 9 to 10 microns, or more specifically less than 10 to 30 microns, while the height of the metal layer 120B forming the bump or protruding structure is generally on the order of about 3 to 7 microns. As the dimensions of the diodes are engineered to within a selected tolerance during device fabrication, the dimensions of the diodes may be measured, for example, using a light microscope (which may also include measuring software). As additional examples, the dimensions of the diodes may be measured using, for example, a scanning electron microscope (SEM), or Horiba's LA-920. The Horiba LA-920 instrument uses the principles of low-angle Fraunhofer Diffraction and Light Scattering to measure the particle size and distribution in a dilute solution of particles, such as when embodied in a diode ink. All particle sizes are measured in terms of their number average particle diameters.

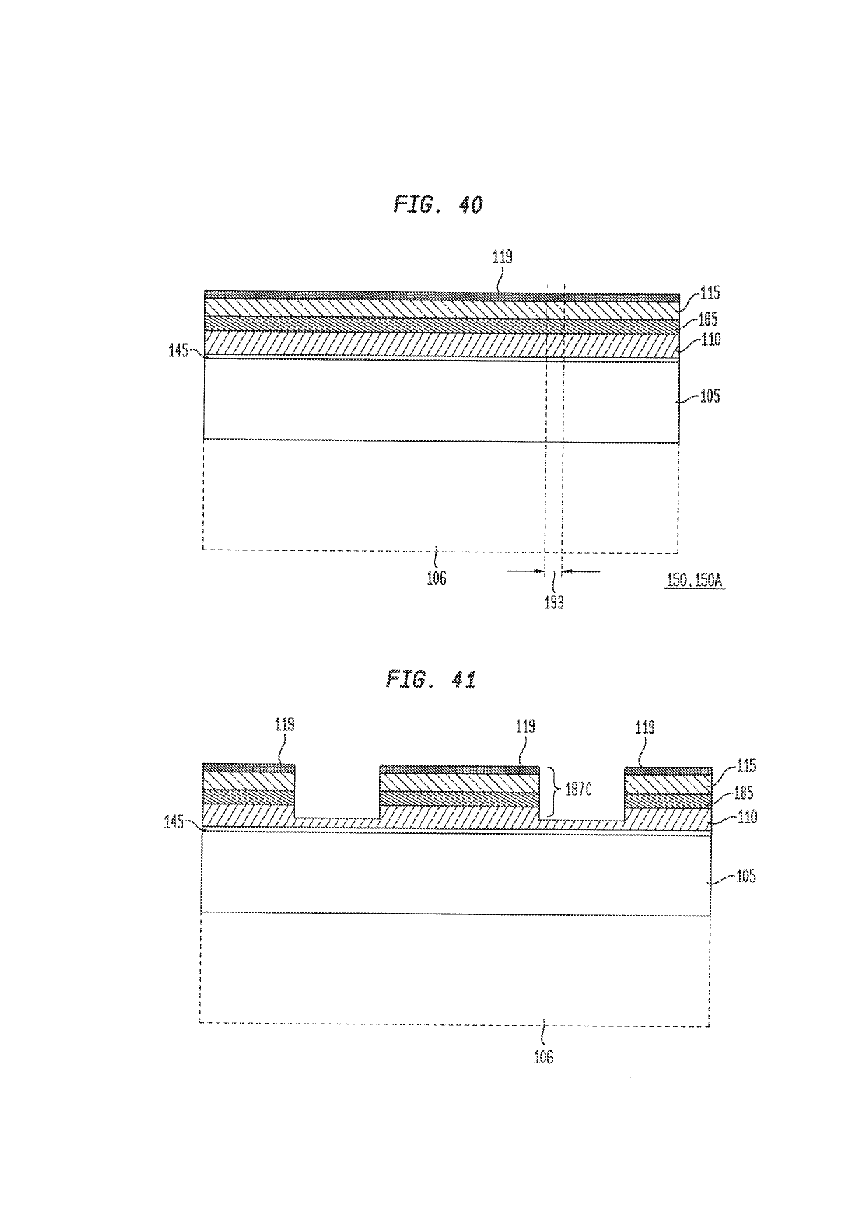

The diodes 100-100J may be fabricated using any semiconductor fabrication techniques which are known currently or which are developed in the future. FIGS. 21-48 illustrate a plurality of exemplary methods of fabricating exemplary diodes 100-100J and illustrate several additional exemplary diodes 100H, 100I and 100J (in cross-section). Those having skill in the art will recognize that many of the various steps of diode 100-100J fabrication may occur in any of various orders, may be omitted or included in other sequences, and may result in innumerable diode structures, in addition to those illustrated. For example, FIGS. 33-39 illustrate creation of a diode 100H which includes both central and peripheral through (or deep) vias 131 and 134, respectively, combining features of diodes 100D and 100G, with or without optional second (back) side metal layer 122, while FIGS. 40-45 illustrate creation of a diode 100I which includes a perimeter via 133, with or without optional second (back) side metal layer 122, and which may be combined with the other illustrated fabrication steps to include central or peripheral through vias 131 and 134, for example, such as to form a diode 100F.

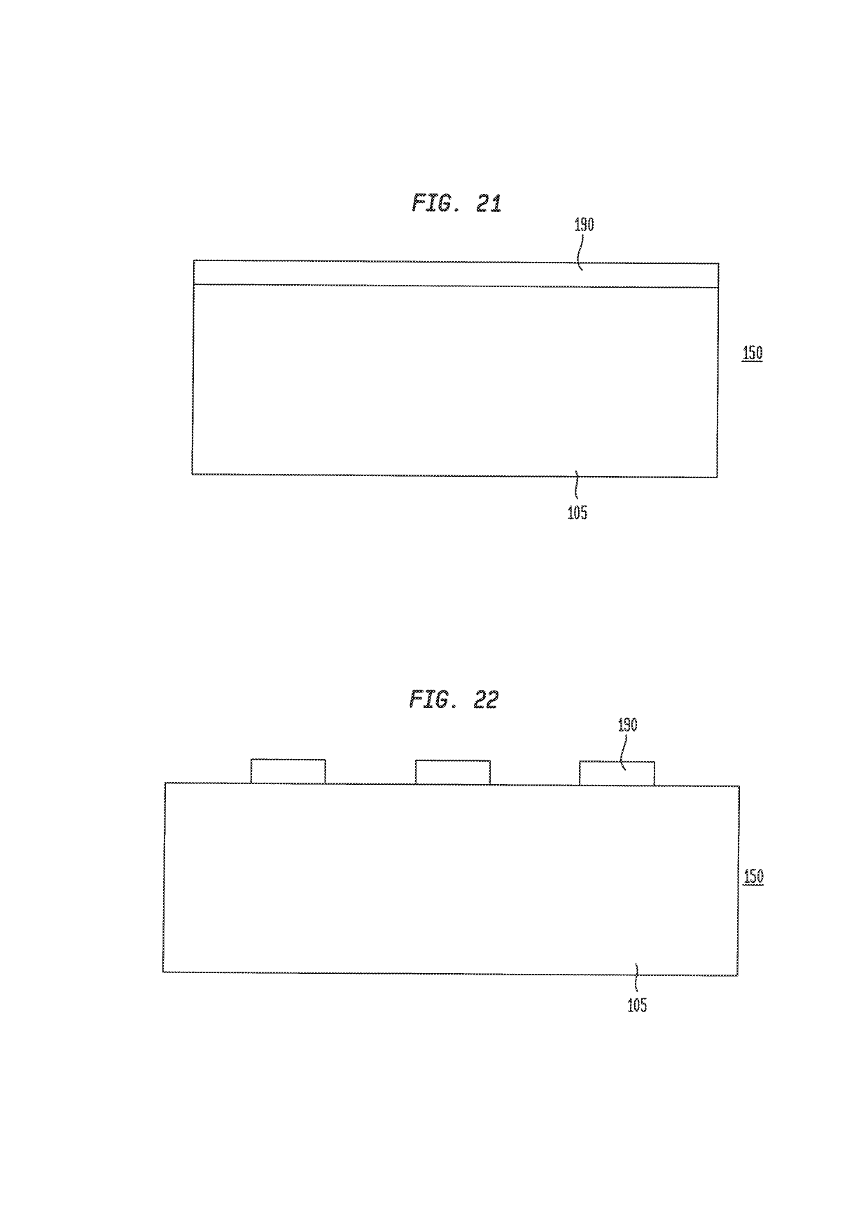

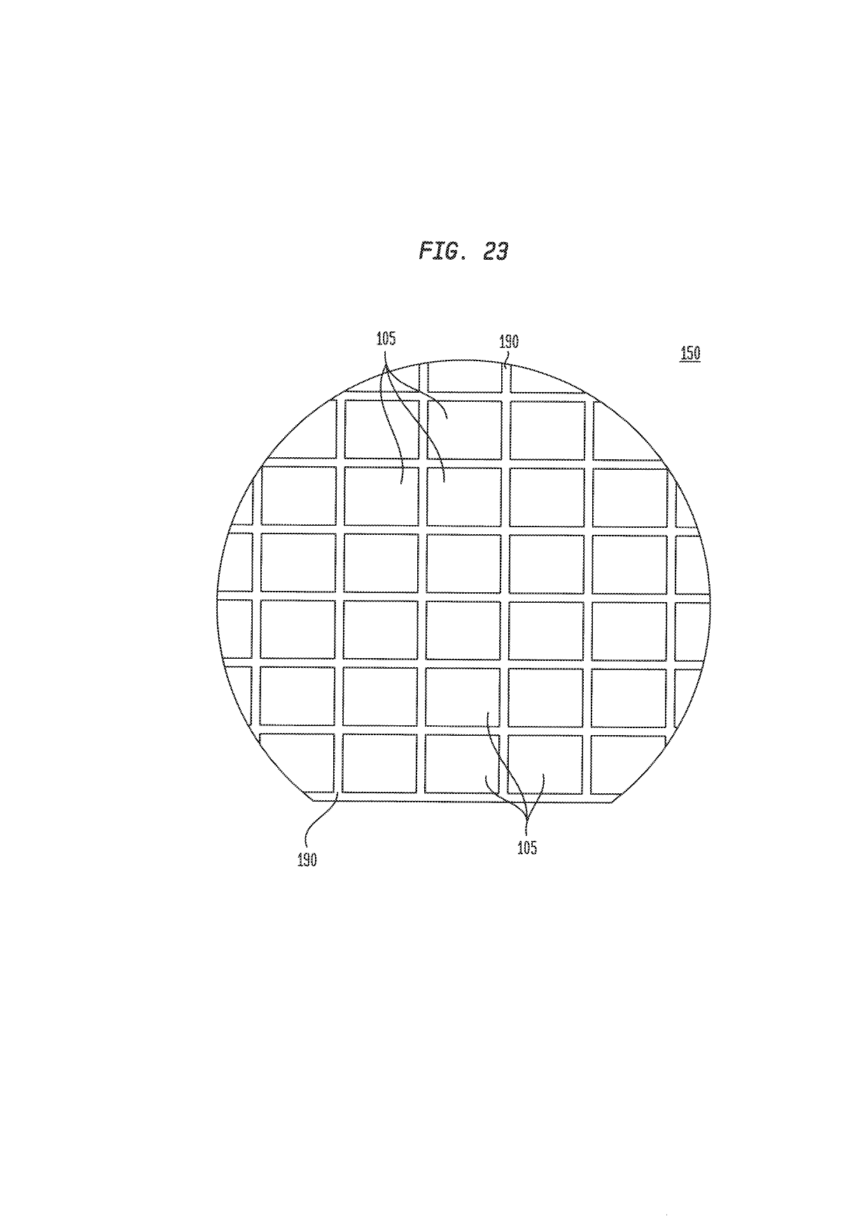

FIGS. 21, 22 and 24-32 are cross-sectional views illustrating an exemplary method of diode 100, 100A, 100B, 100C fabrication in accordance with the teachings of the present invention, with FIGS. 21-24 illustrating fabrication at the wafer 150 level and FIGS. 25-32 illustrating fabrication at the diode 100, 100A, 100B, 100C level. FIG. 21 and FIG. 22 are cross-sectional views of a wafer 150 (such as a silicon wafer) having a silicon dioxide (or “oxide”) layer 190. FIG. 23 is a top view of a silicon wafer 150 having a silicon dioxide layer 190 etched in a grid pattern. The oxide layer 190 (generally about 0.1 microns thick) is deposited or grown over the wafer 150, as shown in FIG. 21. As illustrated in FIG. 22, through appropriate or standard mask and/or photoresist layers and etching as known in the art, portions of the oxide layer 190 have been removed, leaving oxide 190 in a grid pattern (also referred to as “streets”), as illustrated in FIG. 23.

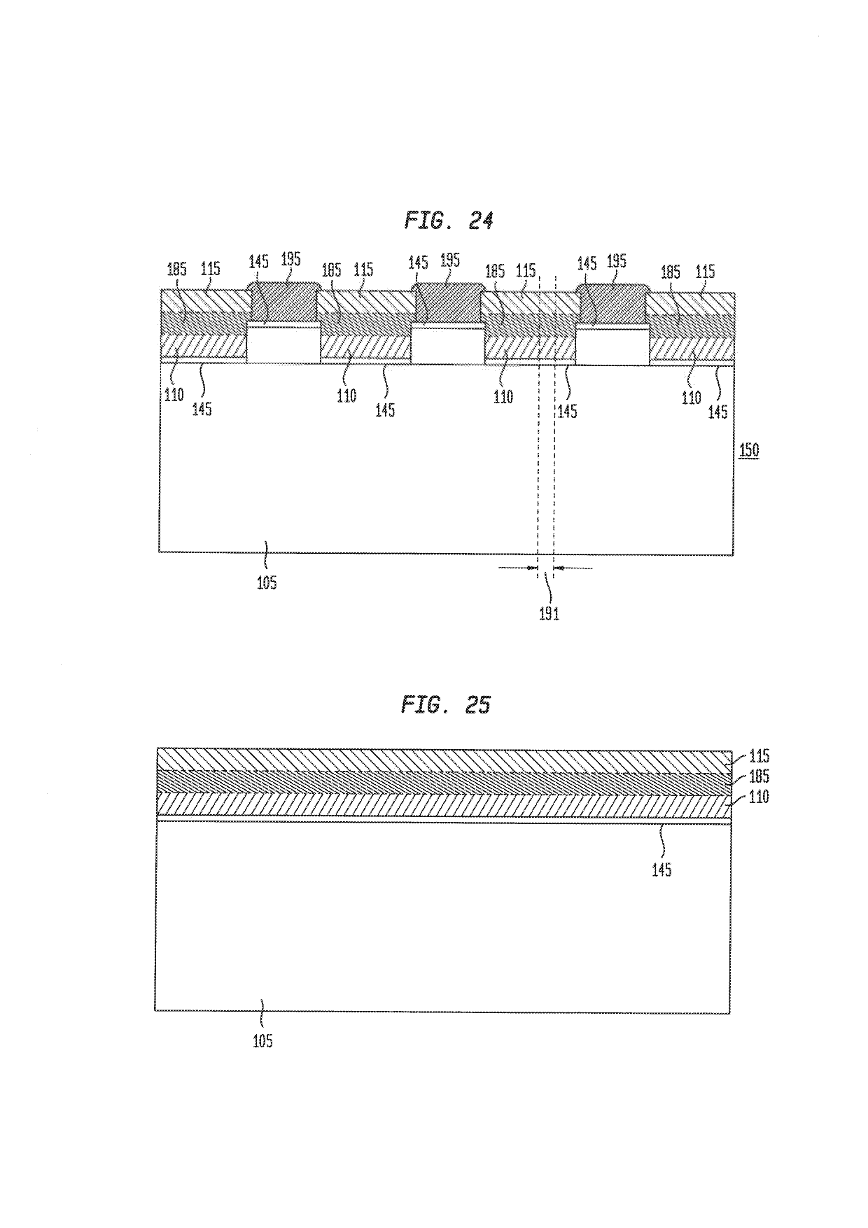

FIG. 24 is a cross-sectional view of a wafer 150 (such as a silicon wafer) having a buffer layer 145, a silicon dioxide (or “oxide”) layer 190, and GaN layers (typically epitaxially grown or deposited to a thickness of about 1.25-2.50 microns in an exemplary embodiment, although lesser or greater thicknesses are also within the scope of the disclosure), illustrated as polycrystalline GaN 195 over the oxide 190, and n+ GaN layer 110, quantum well region 185 and p+ GaN layer 115 forming a complex GaN heterostructure as mentioned above. As indicated above, a buffer layer 145 (such as aluminum nitride or silicon nitride and generally about 25 Angstroms thick) is deposited on the silicon wafer 150 to facilitate subsequent GaN deposition. The polycrystalline GaN 195 grown or deposited over the oxide 190 is utilized to reduce the stress and/or strain (e.g., due to thermal mismatch of the GaN and a silicon wafer) in the complex GaN heterostructure (n+ GaN layer 110, quantum well region 185 and p+ GaN layer 115), which typically has a single crystal structure. Other equivalent methods within the scope of the invention to provide such stress and/or strain reduction, for example and without limitation, include roughening the surface of the silicon wafer 150 and/or buffer layer 145 in selected areas, so that corresponding GaN regions will not be a single crystal, or etching trenches in the silicon wafer 150, such that there is also no continuous GaN crystal across the entire wafer 150. Such street formation and stress reduction fabrication steps may be omitted in other exemplary fabrication methods, such as when other substrates are utilized, such as GaN (a substrate 105) on a sapphire wafer 150A. The GaN deposition or growth to form a complex GaN heterostructure may be provided through any selected process as known or becomes known in the art and/or may be proprietary to the device fabricator. In an exemplary embodiment, the complex GaN heterostructure comprised of n+ GaN layer 110, quantum well region 185 and p+ GaN layer 115 has been fabricated by Blue Photonics Inc. of Walnut, Calif., USA.

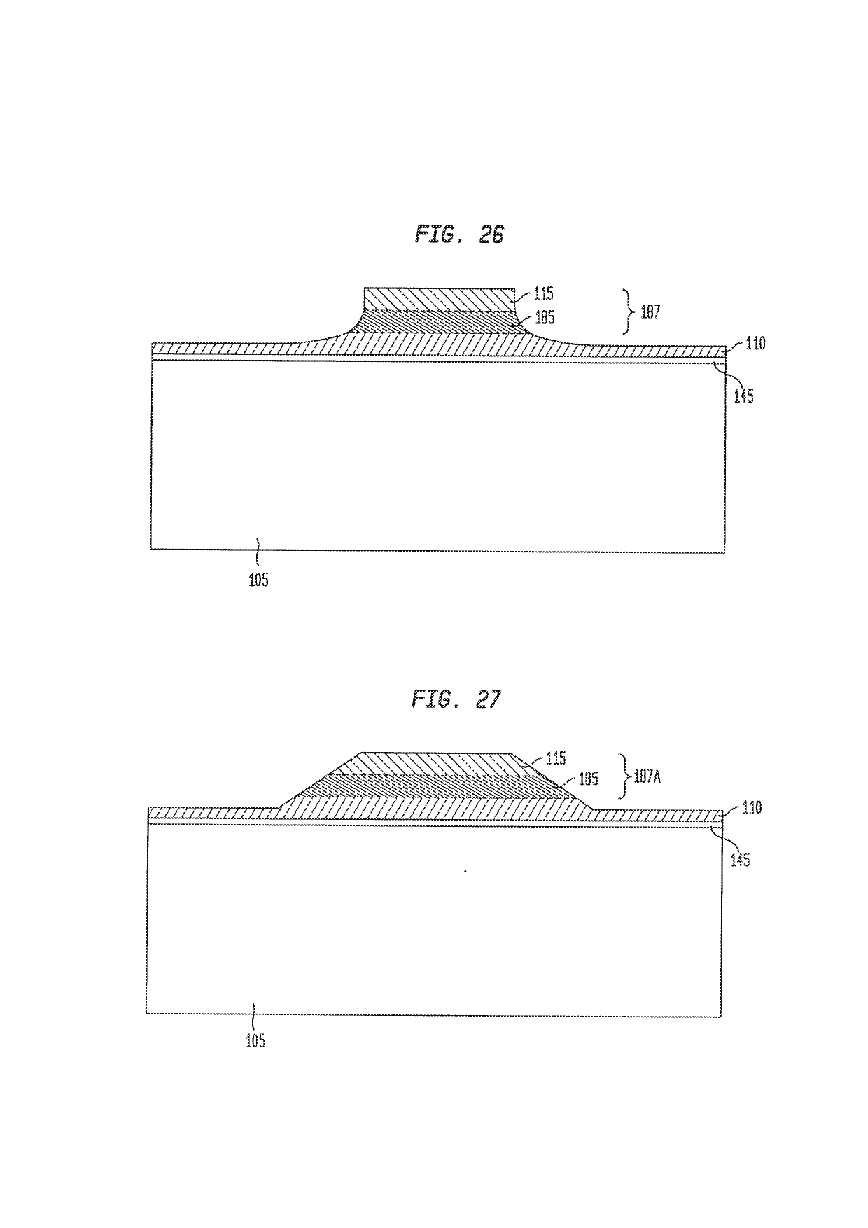

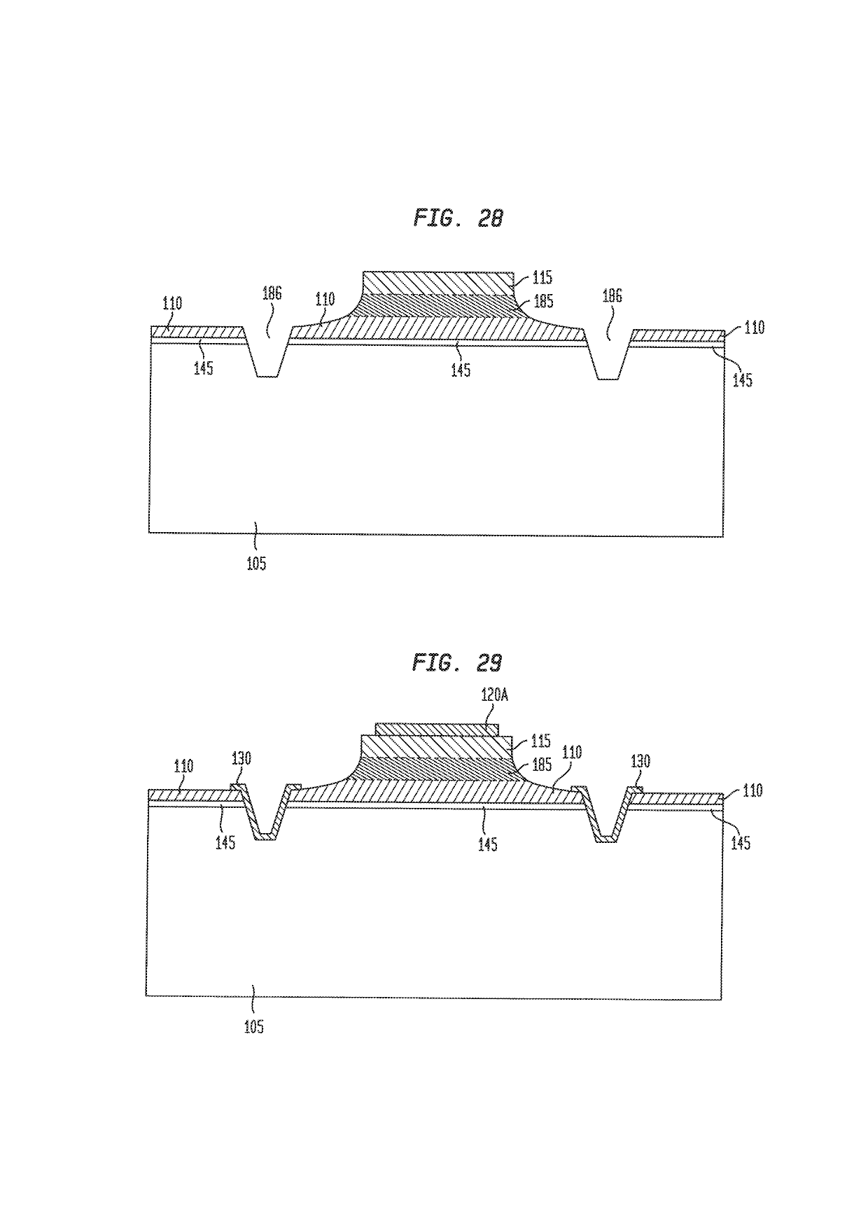

FIG. 25 is a cross-sectional view of a substrate 105 having buffer layer 145 and the complex GaN heterostructure (n+ GaN layer 110, quantum well region 185 and p+ GaN layer 115) in accordance with the teachings of the present invention, illustrating a much smaller portion of the wafer 150 (such as region 191 of FIG. 24), to illustrate fabrication of a single diode 100, 100A, 100B, 100C. Through appropriate or standard mask and/or photoresist layers and etching as known in the art, the complex GaN heterostructure (n+ GaN layer 110, quantum well region 185 and p+ GaN layer 115) is etched to form a GaN mesa structure 187, as illustrated in FIGS. 26 and 27, with FIG. 27 illustrating the GaN mesa structure 187A having comparatively more angled sides, which potentially may facilitate light production and/or absorption. Other GaN mesa structures 187 may also be implemented, such as a partially or substantially toroidal GaN mesa structure 187, as illustrated in FIGS. 10, 13, 14, 17, 20, 34-39, and 48. Following the GaN mesa etch, also through appropriate or standard mask and/or photoresist layers and etching as known or becomes known in the art, a (shallow or blind) via etch is performed, as illustrated in FIG. 28, creating a comparatively shallow trench 186 through the GaN layers and buffer layer 145 and into the silicon substrate 105.

Also through appropriate or standard mask and/or photoresist layers and etching as known in the art, metallization layers are then deposited, forming a metal contact 120A to p+ GaN layer 115 and forming vias 130, as illustrated in FIG. 29. In exemplary embodiments, several layers of metal are deposited, a first or initial layer to form an ohmic contact to p+ GaN layer 115, typically comprising two metal layers about 50 to 200 Angstroms each, of nickel followed by gold, followed by annealing at about 450-500° C. in an oxidizing atmosphere of about 20% oxygen and 80% nitrogen, resulting in nickel rising to the top with a layer of nickel oxide, and forming a metal layer (as part of 120A) having a comparatively good ohmic contact with the p+ GaN layer 115. Another metallization layer may also be deposited, such as to form thicker interconnect metal to contour and fully form metal layer 120A (e.g., for current distribution) and to form the vias 130. In another exemplary embodiment (illustrated in FIGS. 40-45), the metal contact 120A forming an ohmic contact to p+ GaN layer 115 may be formed prior to the GaN mesa etch, followed by the GaN mesa etch, via etch, etc. Innumerable other metallization processes and corresponding materials comprising metal layers 120A and 120B are also within the scope of the disclosure, with different fabrication facilities often utilizing different processes and material selections. For example and without limitation, either or both metal layers 120A and 120B may be formed by deposition of titanium to form an adhesion or seed layer, typically 50-200 Angstroms thick, followed by deposition of 2-4 microns of nickel and a thin layer or “flash” of gold (a “flash” of gold being a layer of about 50-500 Angstroms thick), 3-5 microns of aluminum, followed by nickel (about 0.5 microns, physical vapor deposition or plating) and a “flash” of gold, or by deposition of titanium, followed by gold, followed by nickel (typically 3-5 microns thick for 120B), followed by gold, or by deposition of aluminum followed by nickel followed by gold, etc. In addition, the height of the metal layer 120B forming a bump or protruding structure may also be varied, typically between about 3.5-5.5 microns in exemplary embodiments, depending upon the thickness of the substrate 105 (e.g., about 7-8 microns of GaN versus about 10 microns of silicon), for the resulting diodes 100-100J to have a substantially uniform height and form factor.

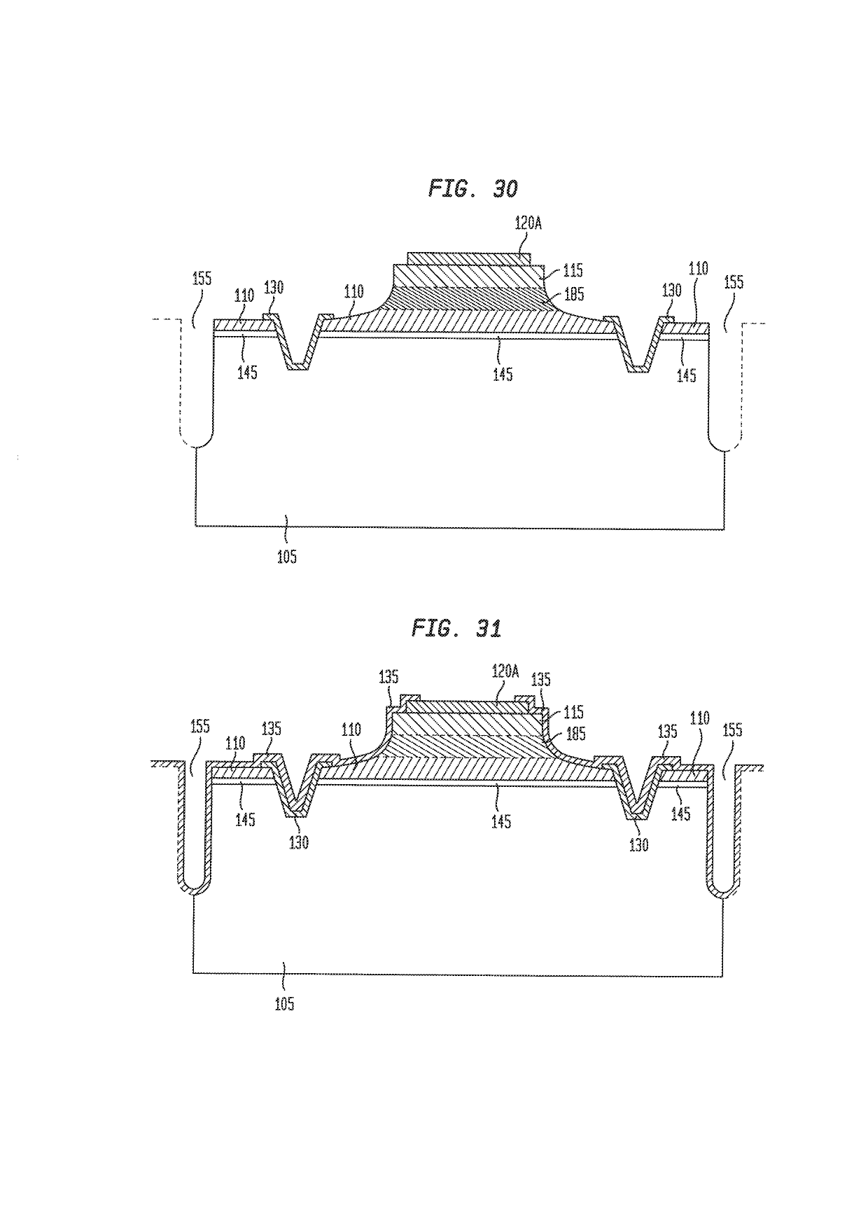

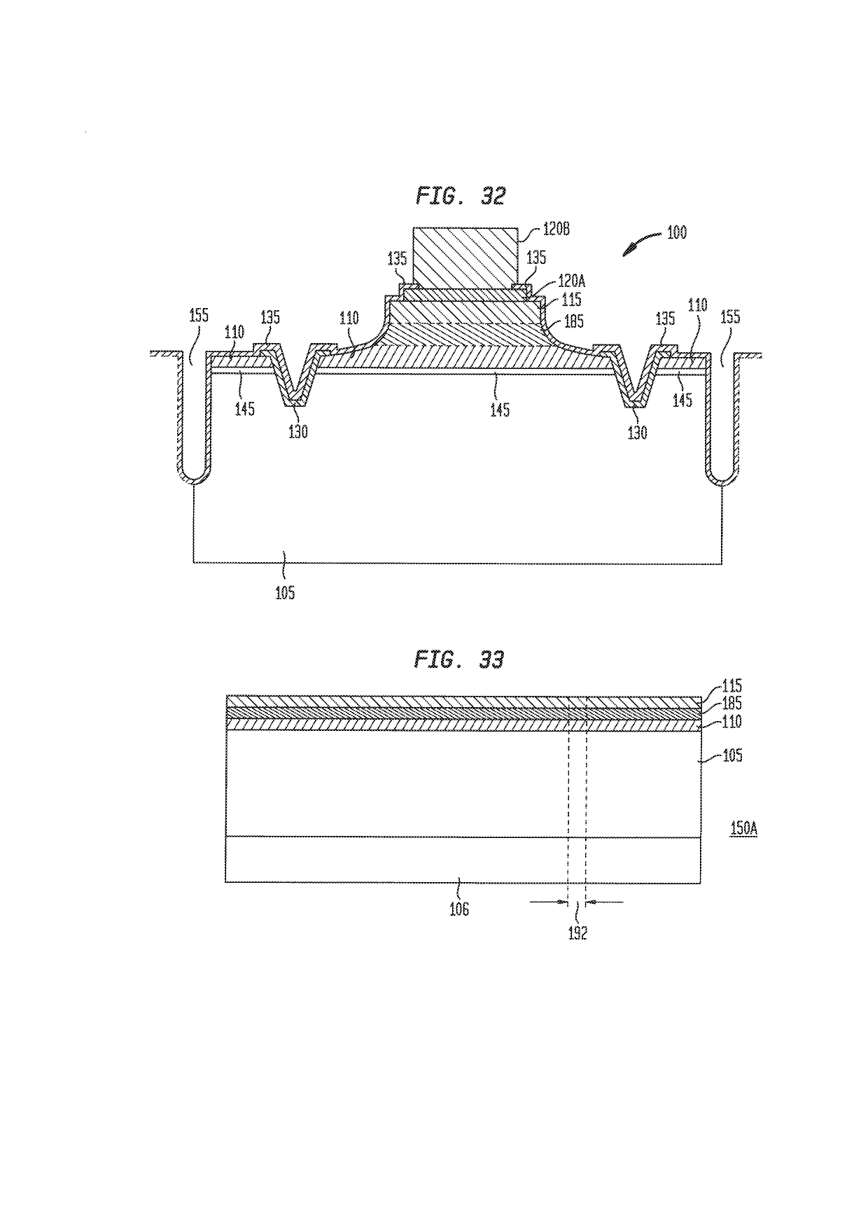

For subsequent singulation of the diodes 100-100J from each other and from the wafer 150, through appropriate or standard mask and/or photoresist layers and etching as known in the art, as illustrated in FIG. 30 and other FIGS. 35 and 43, trenches 155 are formed around the periphery of each diode 100-100J (e.g., also as illustrated in FIGS. 2, 5, 7 and 9). The trenches 155 are generally about 3-5 microns wide and 10-12 microns deep. Also using appropriate or standard mask and/or photoresist layers and etching as known in the art, nitride passivation layer 135 is then grown or deposited, as illustrated in FIG. 31, generally to a thickness of about 0.35-1.0 microns, such as by plasma-enhanced chemical vapor deposition (PECVD) of silicon nitride, for example and without limitation, followed by photoresist and etching steps to remove unwanted regions of silicon nitride. Through appropriate or standard mask and/or photoresist layers and etching as known in the art, metal layer 120B having a bump or protruding structure is then formed, typically having a height of 3-5 microns tall, as illustrated in FIG. 32. In an exemplary embodiment, formation of metal layer 120B is performed in several steps, using a metal seed layer, followed by more metal deposition using electroplating or a lift off process, removing the resist and clearing the field of the seed layer. Other than subsequent singulation of the diodes (in this case diodes 100, 100A, 100B, 100C) from the wafer 150, as described below, the diodes 100, 100A, 100B, 100C are otherwise complete, and it should be noted that these completed diodes 100, 100A, 100B, 100C have only one metal contact or terminal on the upper surface of each diode 100, 100A, 100B, 100C (first terminal 125). As an option, a second (back) side metal layer 122 may be fabricated, as described below and as mentioned above with reference to other exemplary diodes, such as to form a second terminal 127.

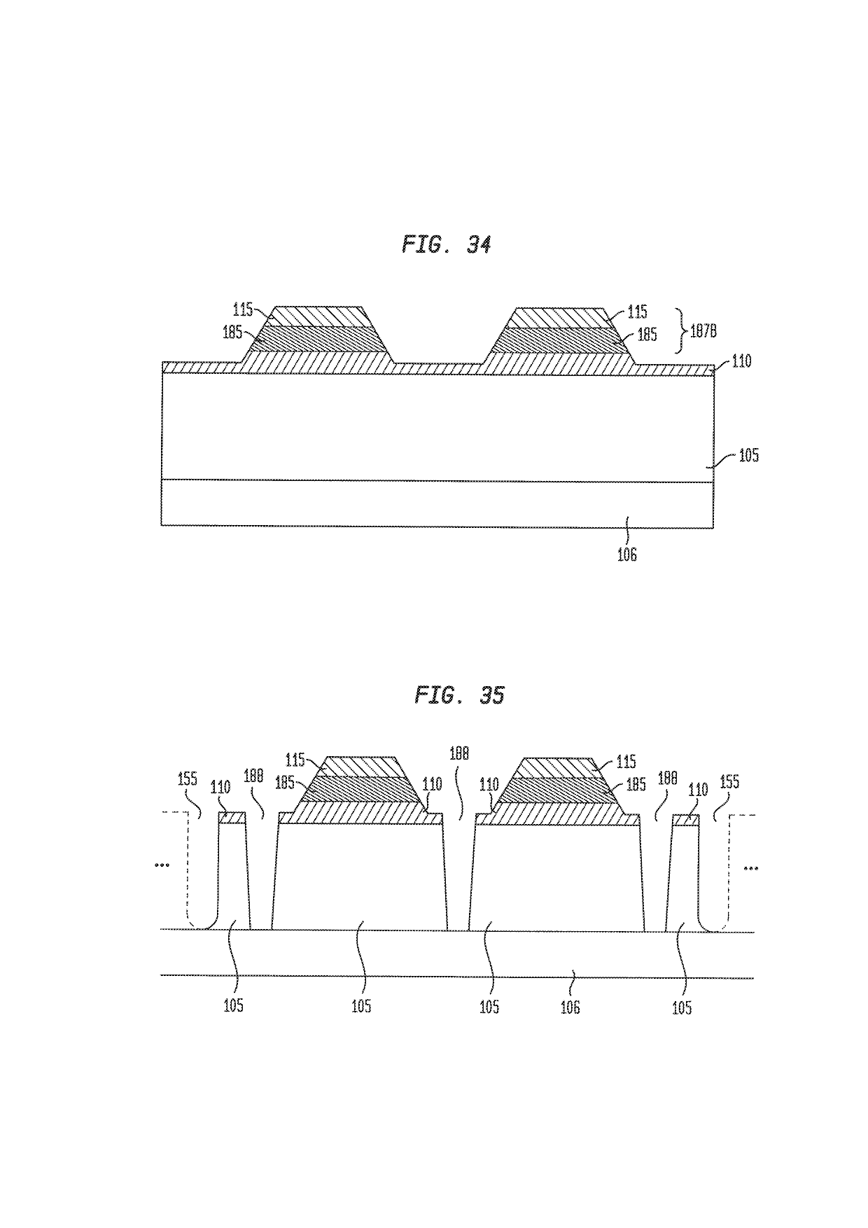

FIGS. 33-39 illustrate another exemplary method of diode 100-100J fabrication, with FIG. 33 illustrating fabrication at the wafer 150A level and FIGS. 34-39 illustrating fabrication at the diode 100-100J level. FIG. 33 is a cross-sectional view of a wafer 150A having a substrate 105 and having a complex GaN heterostructure (n+ GaN layer 110, quantum well region 185, and p+ GaN layer 115). In this exemplary embodiment, a comparatively thick layer of GaN is grown or deposited (to form a substrate 105) on sapphire (106) (of the sapphire wafer 150A), followed by deposition or growth of the GaN heterostructure (n+ GaN layer 110, quantum well region 185, and p+ GaN layer 115).

FIG. 34 is a cross-sectional view of a substrate 105 having a third mesa-etched complex GaN heterostructure, illustrating a much smaller portion of the wafer 150A (such as region 192 of FIG. 33), to illustrate fabrication of a single diode (e.g., diode 100H). Through appropriate or standard mask and/or photoresist layers and etching as known in the art, the complex GaN heterostructure (n+ GaN layer 110, quantum well region 185 and p+ GaN layer 115) is etched to form a GaN mesa structure 187B. Following the GaN mesa etch, also through appropriate or standard mask and/or photoresist layers and etching as known or becomes known in the art, a (through or deep) via trench and a singulation trench etch is performed, as illustrated in FIG. 35, creating one or more comparatively deep via trenches 188 through the non-mesa portion of the GaN heterostructure (n+ GaN layer 110) and though the GaN substrate 105 to the sapphire (106) of the wafer 150A and creating singulation trenches 155 described above. As illustrated, a center via trench 188 and a plurality of peripheral via trenches 188 have been formed.

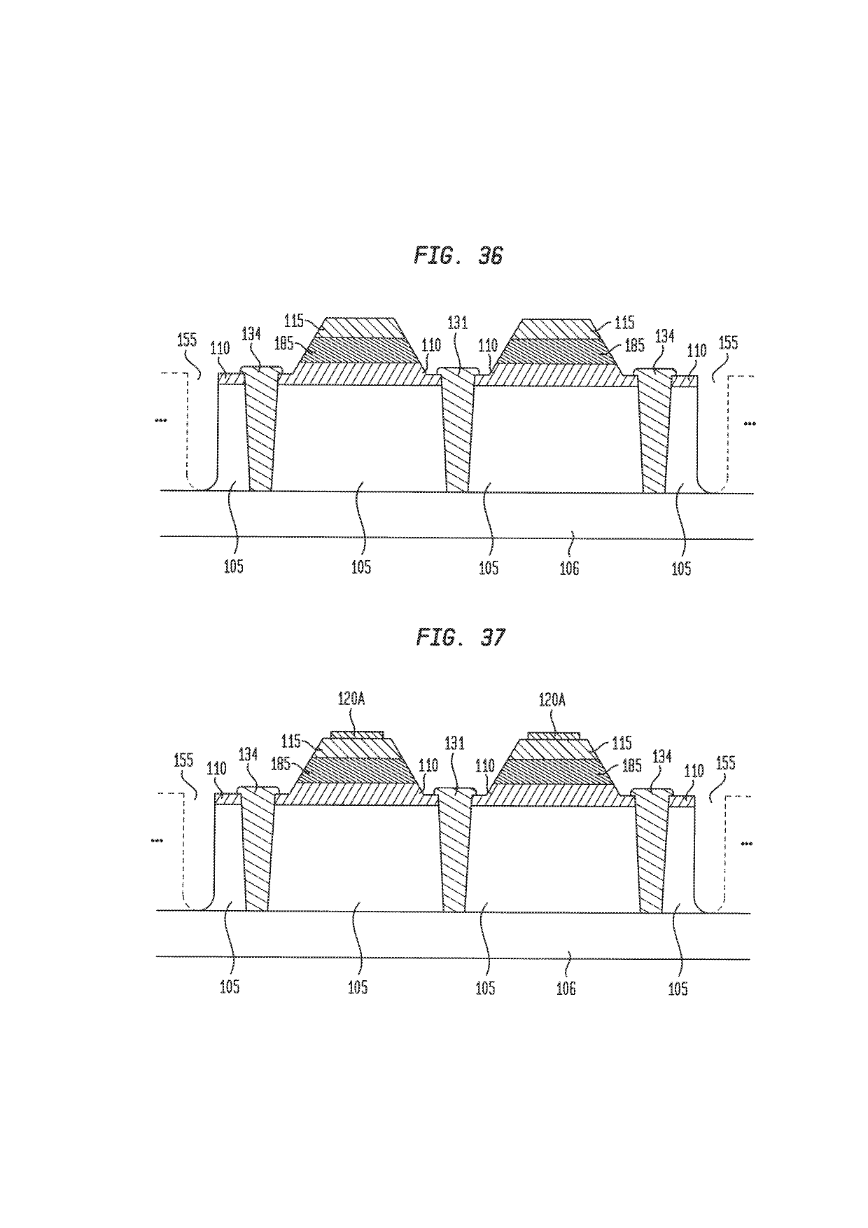

Also through appropriate or standard mask and/or photoresist layers and etching as known in the art, metallization layers are then deposited, forming a center through via 131 and a plurality of peripheral through vias 134, which also form an ohmic contact with the n+ GaN layer 110, as illustrated in FIG. 36. In exemplary embodiments, several layers of metal are deposited to form the through vias 131, 134. For example, titanium and tungsten may be sputtered to coat the sides and bottom of the trenches 188, to form a seed layer, followed by plating with nickel, to form solid metal vias 131, 134.

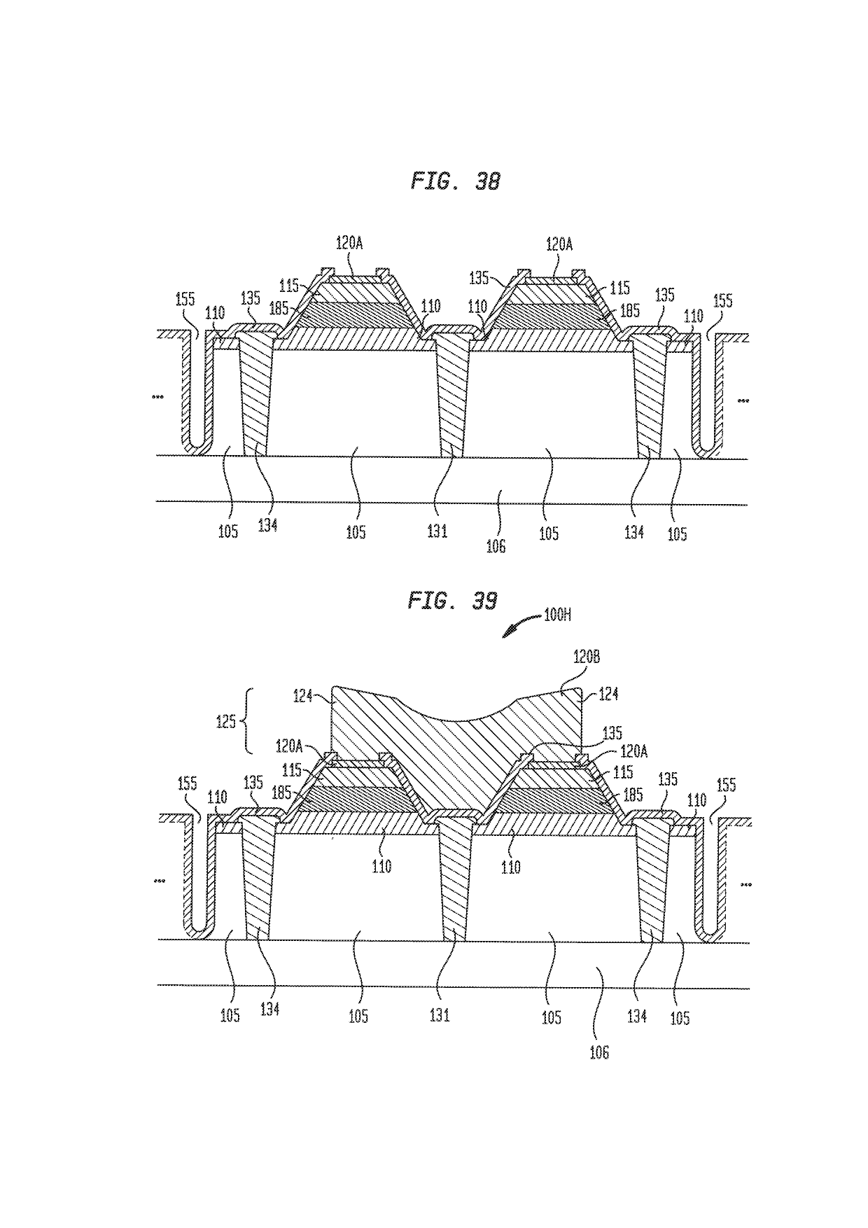

Also through appropriate or standard mask and/or photoresist layers and etching as known in the art, metallization layers are then deposited, forming a metal layer 120A providing an ohmic contact to p+ GaN layer 115, as illustrated in FIG. 37. In exemplary embodiments, several layers of metal may be deposited as previously described to form metal layer 120A and an ohmic contact to p+ GaN layer 115. Also using appropriate or standard mask and/or photoresist layers and etching as known in the art, nitride passivation layer 135 is then grown or deposited, as illustrated in FIG. 38, generally to a thickness of about 0.35-1.0 microns, such as by plasma-enhanced chemical vapor deposition (PECVD) of silicon nitride or silicon oxynitride, for example and without limitation, followed by photoresist and etching steps to remove unwanted regions of silicon nitride. Through appropriate or standard mask and/or photoresist layers and etching as known in the art, metal layer 120B having a bump or protruding structure is then formed, as illustrated in FIG. 39. In an exemplary embodiment, formation of metal layer 120B is performed in several steps, using a metal seed layer, followed by more metal deposition using electroplating or a lift off process, removing the resist and clearing the field of the seed layer, also as described above. Other than subsequent singulation of the diodes (in this case diode 100H) from the wafer 150A, as described below, the diodes 100H are otherwise complete, and it should be noted that these completed diodes 100H also have only one metal contact or terminal on the upper surface of each diode 100H (also a first terminal 125). Also as an option, a second (back) side metal layer 122 may be fabricated, as described below and as mentioned above with reference to other exemplary diodes, such as to form a second terminal 127.

FIGS. 40-45 illustrate another exemplary method of diode 100-100J fabrication, with FIG. 40 illustrating fabrication at the wafer 150 or 150A level and FIGS. 41-45 illustrating fabrication at the diode 100-100J level. FIG. 40 is a cross-sectional view of a substrate 105 having a buffer layer 145, a complex GaN heterostructure (n+ GaN layer 110, quantum well region 185, and p+ GaN layer 115), and metallization (metal layer 120A) forming an ohmic contact with the p+ GaN layer. As mentioned above, buffer layer 145 is typically fabricated when the substrate 105 is silicon (e.g., using a silicon wafer 150), and may be omitted for other substrates, such as a GaN substrate 105. In addition, sapphire 106 is illustrated as an option, such as for a thick GaN substrate 105 grown or deposited on a sapphire wafer 150A. Also as mentioned above, a metal layer 119 (as a seed layer for subsequent deposition of metal layer 120A) has been deposited at an earlier step, following deposition or growth of the GaN heterostructure (n+ GaN layer 110, quantum well region 185, and p+ GaN layer 115), rather than at a later step of diode fabrication. For example, metal layer 119 may be nickel with a flash of gold having a total thickness of about a few hundred Angstroms.

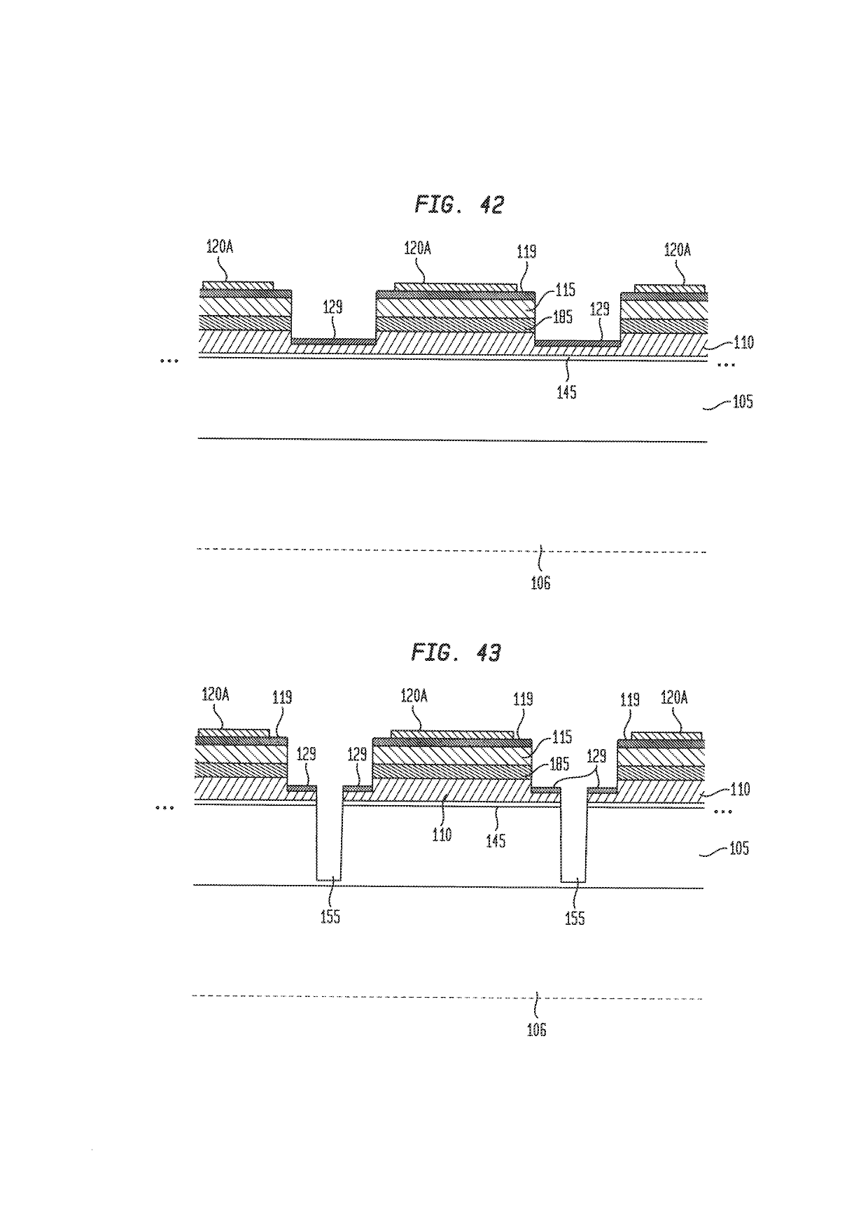

FIG. 41 is a cross-sectional view of a substrate having a buffer layer, a fourth mesa-etched complex GaN heterostructure, and metallization (metal layer 119) forming an ohmic contact with the p+ GaN layer, illustrating a much smaller portion of the wafer 150 or 150A (such as region 193 of FIG. 40), to illustrate fabrication of a single diode (e.g., diode 100I). Through appropriate or standard mask and/or photoresist layers and etching as known in the art, the complex GaN heterostructure (n+ GaN layer 110, quantum well region 185 and p+ GaN layer 115) (with metal layer 119) is etched to form a GaN mesa structure 187C (with metal layer 119). Following the GaN mesa etch, also through appropriate or standard mask and/or photoresist layers as known or becomes known in the art, metallization is deposited (using any of the processes and metals previously described, such as titanium and aluminum, followed by annealing) to form metal layer 120A and also to form a metal layer 129 having an ohmic contact with the n+ GaN layer 110, as illustrated in FIG. 42.

Following the metallization, also through appropriate or standard mask and/or photoresist layers and etching as known or becomes known in the art, a singulation trench etch is performed, as illustrated in FIG. 43, through the non-mesa portion of the GaN heterostructure (n+GaN layer 110) and though or comparatively deeply into the substrate 105 (e.g., through the GaN substrate 105 to the sapphire (106) of the wafer 150A or through part of the silicon substrate 105 as previously described) and creating singulation trenches 155 described above.

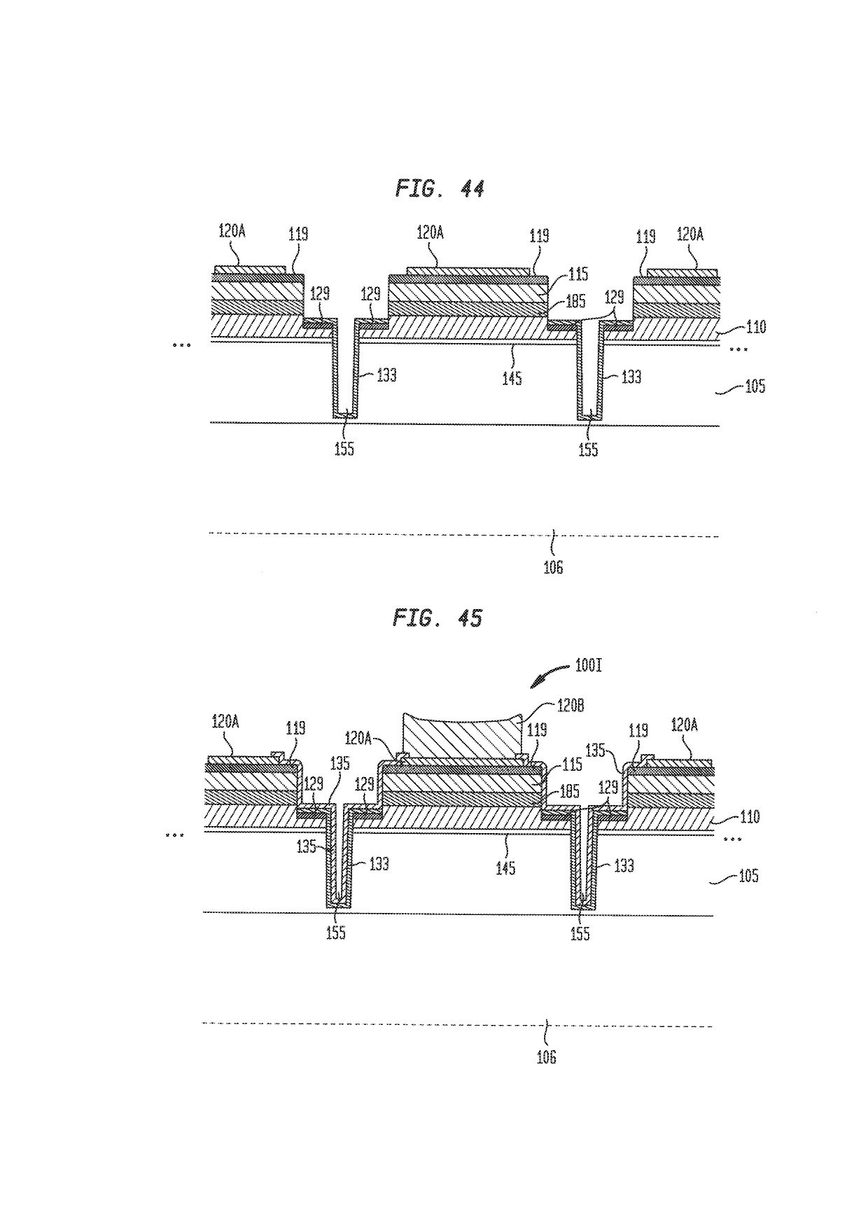

Also through appropriate or standard mask and/or photoresist layers and etching as known in the art, metallization layers are then deposited within trenches 155, forming a through or deep perimeter via 133 (providing conduction around the entire outside or lateral perimeter of the diode (100I), which also form an ohmic contact with the n+ GaN layer 110, as illustrated in FIG. 44. In exemplary embodiments, several layers of metal also may be deposited to form the through perimeter via 133. For example, titanium and tungsten may be sputtered to coat the sides and bottom of the trenches 155, to form a seed layer, followed by plating with nickel, to form a solid metal perimeter via 133.

Again also using appropriate or standard mask and/or photoresist layers and etching as known in the art, nitride passivation layer 135 is then grown or deposited, as illustrated in FIG. 45, generally to a thickness of about 0.35-1.0 microns, such as by plasma-enhanced chemical vapor deposition (PECVD) of silicon nitride, for example and without limitation, followed by photoresist and etching steps to remove unwanted regions of silicon nitride. Through appropriate or standard mask and/or photoresist layers and etching as known in the art, metal layer 120B having a bump or protruding structure is then formed as previously described, as illustrated in FIG. 45. Other than subsequent singulation of the diodes (in this case diode 100I) from the wafer 150 or 150A, as described below, the diodes 100I are otherwise complete, and it should be noted that these completed diodes 100I also have only one metal contact or terminal on the upper surface of each diode 100I (also a first terminal 125). Also as an option, a second (back) side metal layer 122 may be fabricated, as described below and as mentioned above with reference to other exemplary diodes, such as to form a second terminal 127.

Numerous variations of the methodology for fabrication of diodes 100-100J may be readily apparent in light of the teachings of the disclosure, all of which are considered equivalent and within the scope of the disclosure. In other exemplary embodiments, such trench 155 formation and (nitride) passivation layer formation may be performed earlier or later in the device fabrication process. For example, trenches 155 may be formed later in fabrication, after formation of metal layer 120B, and may leave exposed substrate 105, or may be followed by a second passivation. Also for example, trenches 155 may be formed earlier in fabrication, such as after the GaN mesa etch, followed by deposition of (nitride) passivation layer 135. In the latter example, to maintain planarization during the balance of the device fabrication process, the passivated trenches 155 may be filled in with oxide, photoresist or other material (deposition of the layer followed by removal of unwanted areas using a photoresist mask and etch or an unmasked etch process) or may be filled in (and potentially refilled following metal contact 120A formation) with resist. In another example, silicon nitride 135 deposition (followed by mask and etch steps) may be performed following the GaN mesa etch and before metal contact 120A deposition.

It should also be noted that while many of the various diodes (of diodes 100-100J) have been discussed in which silicon and GaN may be or are the selected semiconductors, other inorganic or organic semiconductors may be utilized equivalently and are within the scope of the disclosure. Examples of inorganic semiconductors include, without limitation: silicon, germanium, and mixtures thereof; titanium dioxide, silicon dioxide, zinc oxide, indium-tin oxide, antimony-tin oxide, and mixtures thereof; II-VI semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof; III-V semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof; and group IV semiconductors including hydrogen terminated silicon, carbon, germanium, and alpha-tin, and combinations thereof.

In addition to the GaN light emitting/absorbing region 140 (e.g., A GaN heterostructure deposited over a substrate 105 such as n+ or p+ silicon or deposited over GaN (105) on a sapphire (106) wafer 150A), the plurality of diodes 100-100J may be comprised of any type of semiconductor element, material or compound, such as silicon, gallium arsenide (GaAs), gallium nitride (GaN), or any inorganic or organic semiconductor material, and in any form, including GaP, InAlGaP, InAlGaP, AlinGaAs, InGaNAs, AlInGASb, also for example and without limitation.

FIG. 46 is a cross-sectional view illustrating an exemplary silicon wafer 150 embodiment having a plurality of diodes 100-100J adhered to a holding apparatus 160 (such as a holding, handle or holder wafer). FIG. 47 is a cross-sectional view illustrating an exemplary diode sapphire wafer 150A embodiment adhered to a holding apparatus 160. As illustrated in FIGS. 46 and 47, the diode wafer 150, 150A containing a plurality of unreleased diodes 100-100J (illustrated generally for purposes of explication and without any significant feature detail) is adhered, using any known, commercially available wafer adhesive or wafer bond 165, to a holding apparatus 160 (such as a wafer holder) on the first side of the diode wafer 150, 150A having the fabricated diodes 100-100J. As illustrated and as described above, a nitride passivated, singulation or individuation trench 155 between each diode 100-100J, has been formed during wafer processing, such as through etching, and is then utilized to separate each diode 100-100J from adjacent diodes 100-100J without a mechanical process such as sawing. As illustrated in FIG. 46, while the diode wafer 150 is still adhered to the holding apparatus 160, the second, backside 180 of the diode wafer 150 is then mechanically ground and polished to a level (illustrated as a dashed line) to expose the nitride passivated trenches 155. When sufficiently ground and polished, each individual diode 100-100J has been released from each other and any remaining diode wafer 150, while still adhered with the adhesive 165 to the holding apparatus 160. As illustrated in FIG. 47, also while the diode wafer 150A is still adhered to the holding apparatus 160, the second, backside 180 of the diode wafer 150A is then exposed to laser light (illustrated as one or more laser beams 162) which then cleaves (illustrated as a dashed line) the GaN substrate 105 from the sapphire 106 of the wafer 150A (also referred to as laser lift-off), thereby releasing each individual diode 100-100J from each other and the wafer 150A, while still adhered with the adhesive 165 to the holding apparatus 160. In this exemplary embodiment, the wafer 150A may then be ground and/or polished and re-used.

An epoxy bead (not separately illustrated) is also generally applied about the periphery of the wafer 150, to prevent non-diode fragments from the edge of the wafer from being released into the diode (100-100J) fluid during the diode release process discussed below.

FIG. 48 is a cross-sectional view illustrating an exemplary diode 100J embodiment adhered to a holding apparatus. Following singulation of the diodes 100-100J (as described above with reference to FIGS. 46 and 47), and while the diodes 100-100J are still adhered with adhesive 165 to the holding apparatus 160, the second, back side of the diode 100-100J is exposed. As illustrated in FIG. 48, metallization may then be deposited to the second, back side, such as through vapor deposition (angled to avoid filling the trenches 155), forming second, back side metal layer 122 and a diode 100J embodiment. Also as illustrated, diode 100J has one center through via 131 having an ohmic contact with the n+ GaN layer 110 and contact with the second, back side metal layer 122 for current conduction between the n+ GaN layer 110 and the second, back side metal layer 122. Exemplary diode 100D is quite similar, with exemplary diode 100J having the second, back side metal layer 122 to form a second terminal 127. As previously mentioned, the second, back side metal layer 122 (or the substrate 105 or any of the various through vias 131, 133, 134) may be used to make an electrical connection with a first conductor 310 in an apparatus 300, 300A, 300B for energizing the diode 100-100J.

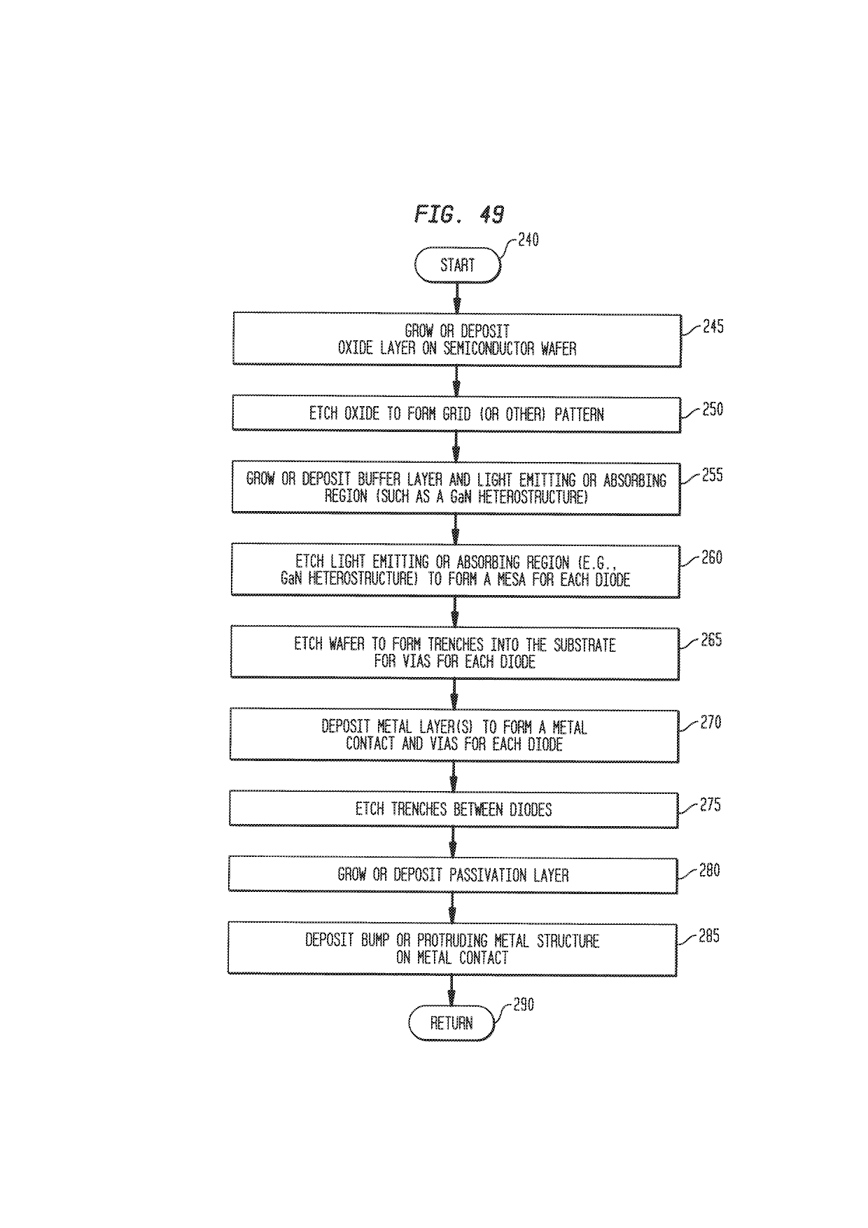

FIGS. 49, 50 and 51 are flow diagrams illustrating exemplary first, second and third method embodiments for diode 100-100J fabrication, respectively, and provide a useful summary. It should be noted that many of the steps of these methods may be performed in any of various orders, and that steps of one exemplary method may also be utilized in the other exemplary methods. Accordingly, each of the methods will refer generally to fabrication of any of the diodes 100-100J, rather than fabrication of a specific diode 100-100J embodiment, and those having skill in the art will recognize which steps may be “mixed and matched” to create any selected diode 100-100J embodiment.

Referring to FIG. 49, beginning with start step 240, an oxide layer is grown or deposited on a semiconductor wafer, step 245, such as a silicon wafer. The oxide layer is etched, step 250, such as to form a grid or other pattern. A buffer layer and a light emitting or absorbing region (such as a GaN heterostructure) is grown or deposited, step 255, and then etched to form a mesa structure for each diode 100-100J, step 260. The wafer 150 is then etched to form via trenches into the substrate 105 for each diode 100-100J, step 265. One or more metallization layers are then deposited to form a metal contact and vias for each diode 100-100J, step 270. Singulation trenches are then etched between diodes 100-100J, step 275. A passivation layer is then grown or deposited, step 280. A bump or protruding metal structure is then deposited or grown on the metal contact, step 285, and the method may end, return step 290. It should be noted that many of these fabrication steps may be performed by different entities and agents, and that the method may include the other variations and ordering of steps discussed above.

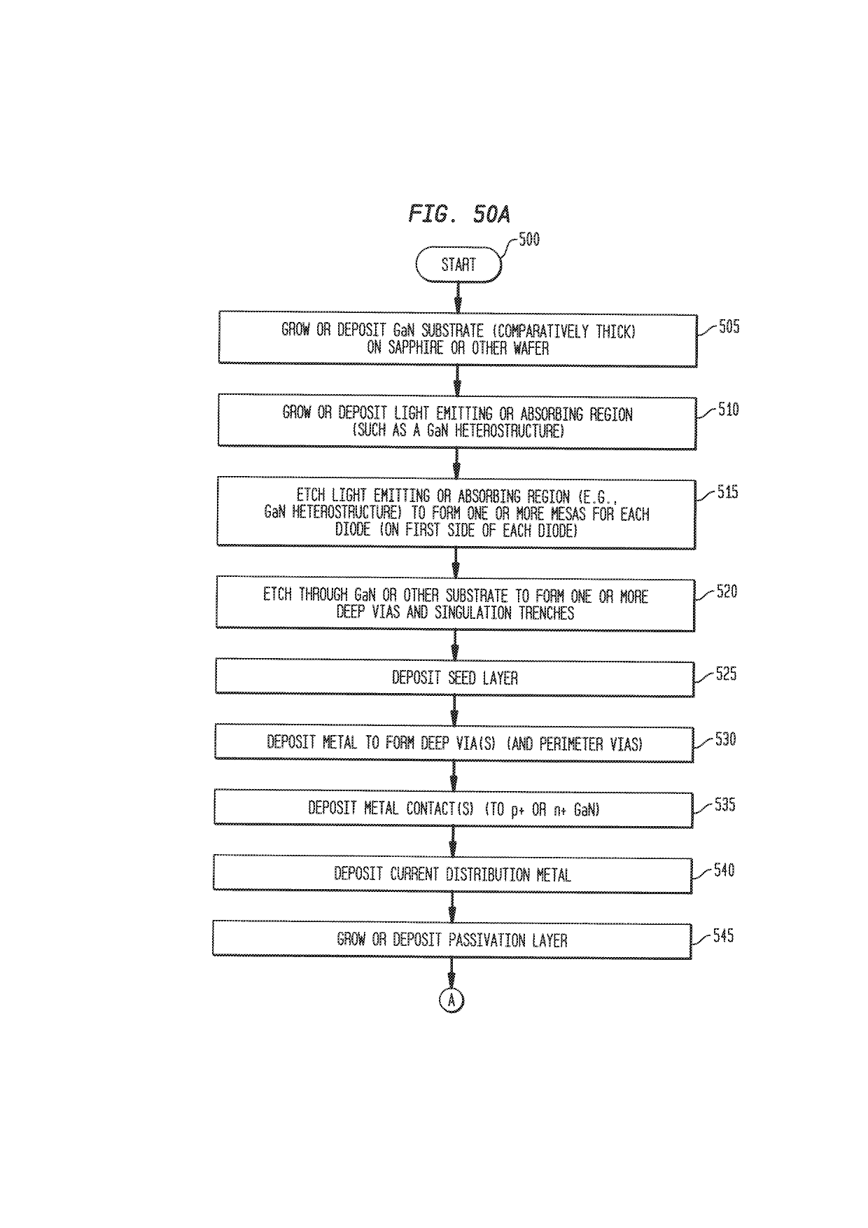

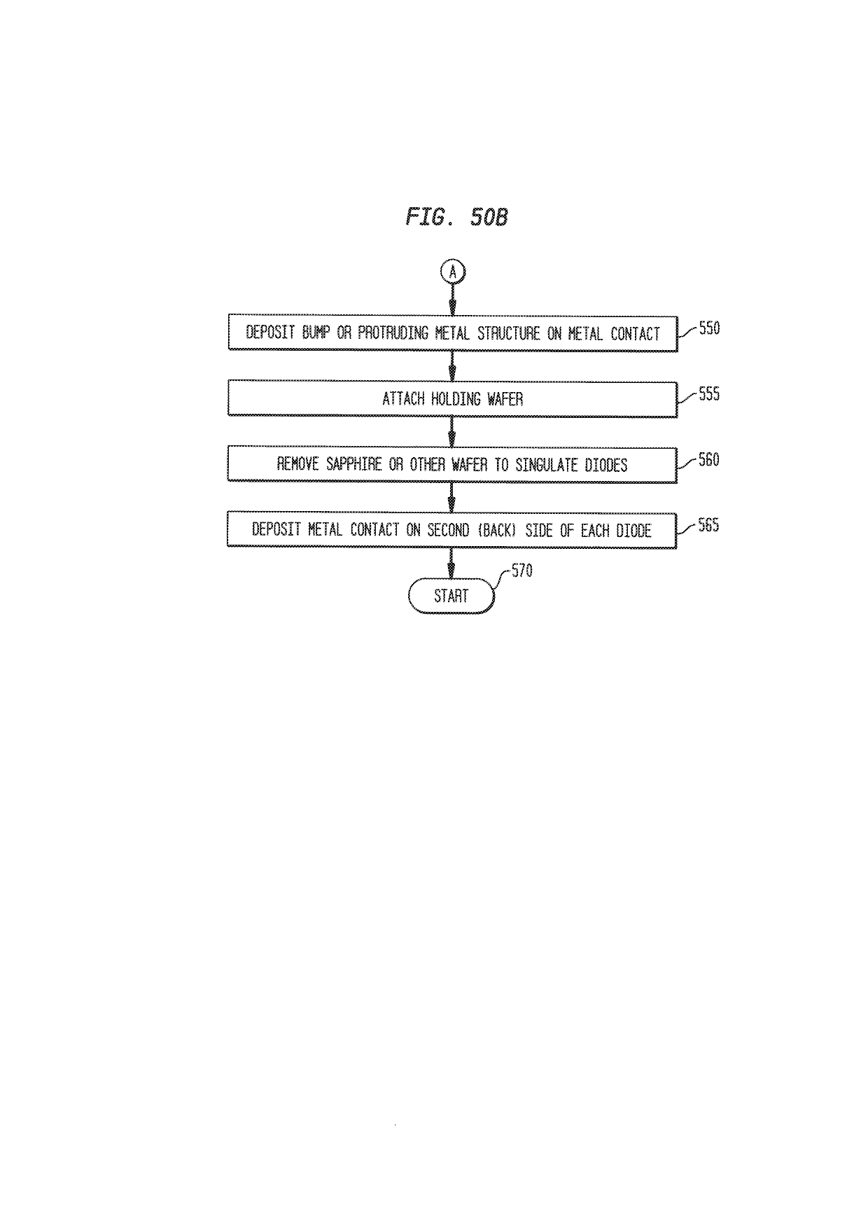

Referring to FIG. 50, beginning with start step 500, a comparatively thick GaN layer (e.g., 7-8 microns) is grown or deposited on a wafer, step 505, such as a sapphire wafer 150A. A light emitting or absorbing region (such as a GaN heterostructure) is grown or deposited, step 510, and then etched to form a mesa structure for each diode 100-100J (on a first side of each diode 100-100J), step 515. The wafer 150 is then etched to form one or more through or deep via trenches and singulation trenches into the substrate 105 for each diode 100-100J, step 520. One or more metallization layers are then deposited to form through vias for each diode 100-100J, which may be center, peripheral or perimeter through vias (131, 134, 133, respectively), typically by depositing a seed layer, step 525, followed by additional metal deposition using any of the methods described above. Metal is also deposited to form one or more metal contacts to the GaN heterostructure (such as to the p+ GaN layer 115 or to the n+GaN layer 110), step 535, and to form any additional current distribution metal (e.g., 120A, 126), step 540. A passivation layer is then grown or deposited, step 545, with areas etched or removed as previously described and illustrated. A bump or protruding metal structure (120B) is then deposited or grown on the metal contact(s), step 550. The wafer 150A is then attached to a holding wafer, step 555, and the sapphire or other wafer is removed (e.g., through laser cleaving) to singulate or individuate the diodes 100-100J, step 560. Metal is then deposited on the second, back side of the diodes 100-100J to form the second, back side metal layer 122, step 565, and the method may end, return step 570. It also should be noted that many of these fabrication steps may be performed by different entities and agents, and that the method may include the other variations and ordering of steps discussed above.

Referring to FIG. 51, beginning with start step 600, a comparatively thick GaN layer (e.g., 7-8 microns) is grown or deposited on a wafer 150, step 605, such as a sapphire wafer 150A. A light emitting or absorbing region (such as a GaN heterostructure) is grown or deposited, step 610. Metal is deposited to form one or more metal contacts to the GaN heterostructure (such as to the p+ GaN layer 115 as illustrated in FIG. 40), step 615. The light emitting or absorbing region (such as the GaN heterostructure) with the metal contact layer (119) are then etched to form a mesa structure for each diode 100-100J (on a first side of each diode 100-100J), step 620. Metal is deposited to form one or more metal contacts to the GaN heterostructure (such as n+ metal contact layer 129 to the n+ GaN layer 110 as illustrated in FIG. 42), step 625. The wafer 150A is then etched to form one or more through or deep via trenches and/or singulation trenches into the substrate 105 for each diode 100-100J, step 630. One or more metallization layers are then deposited to form through vias for each diode 100-100J, step 635, which may be center, peripheral or perimeter through vias (131, 134, 133, respectively), using any of the metal deposition methods described above. Metal is also deposited to form one or more metal contacts to the GaN heterostructure (such as the p+ GaN layer 115 or to the n+ GaN layer 110), and to form any additional current distribution metal (e.g., 120A, 126), step 640. If singulation trenches were not previously created (in step 630), then singulation trenches are etched, step 645. A passivation layer is then grown or deposited, step 650, with areas etched or removed as previously described and illustrated. A bump or protruding metal structure (120B) is then deposited or grown on the metal contact(s), step 655. The wafer 150, 150A is then attached to a holding wafer, step 660, and the sapphire or other wafer is removed (e.g., through laser cleaving or back side grinding and polishing) to singulate or individuate the diodes 100-100J, step 665. Metal is then deposited on the second, back side of the diodes 100-100J to form the second, back side conductive (e.g., metal) layer 122, step 670, and the method may end, return step 675. It also should be noted that many of these fabrication steps may be performed by different entities and agents, and that the method may include the other variations and ordering of steps discussed above.

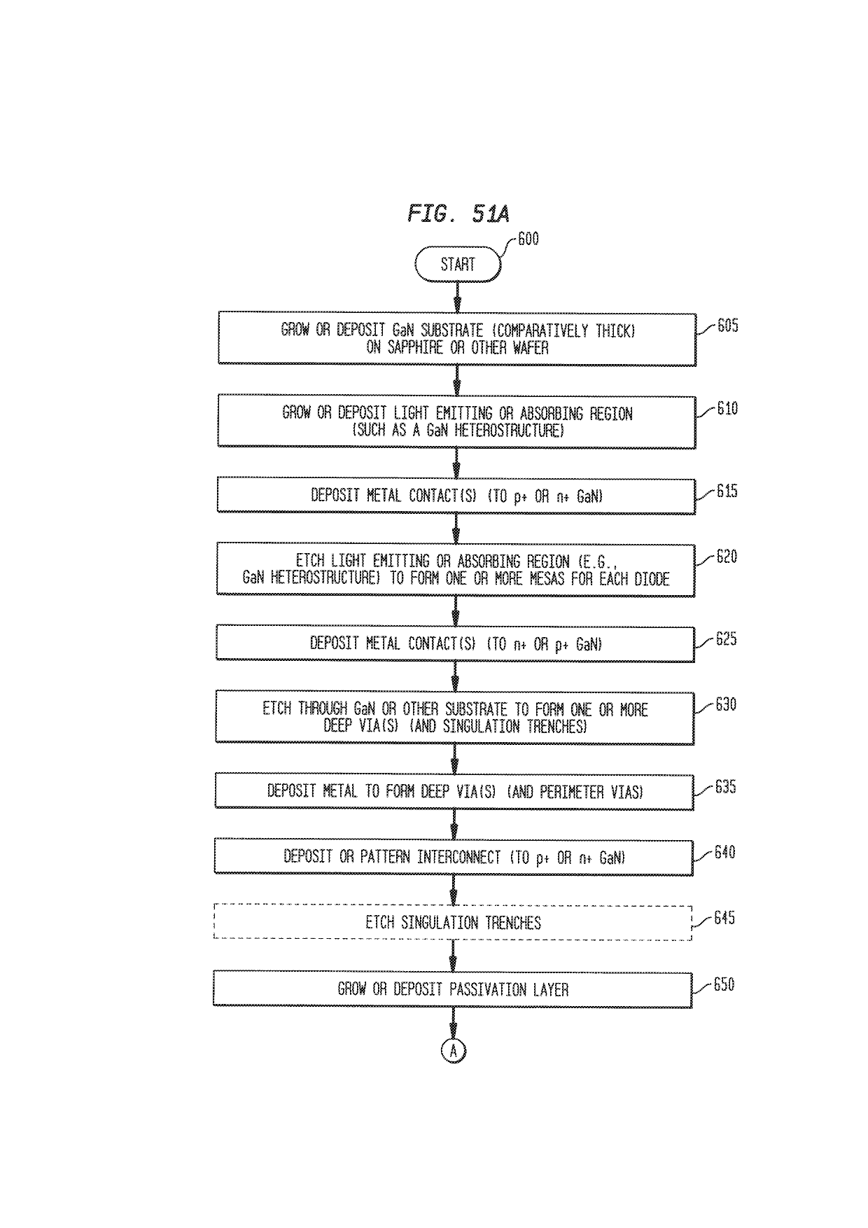

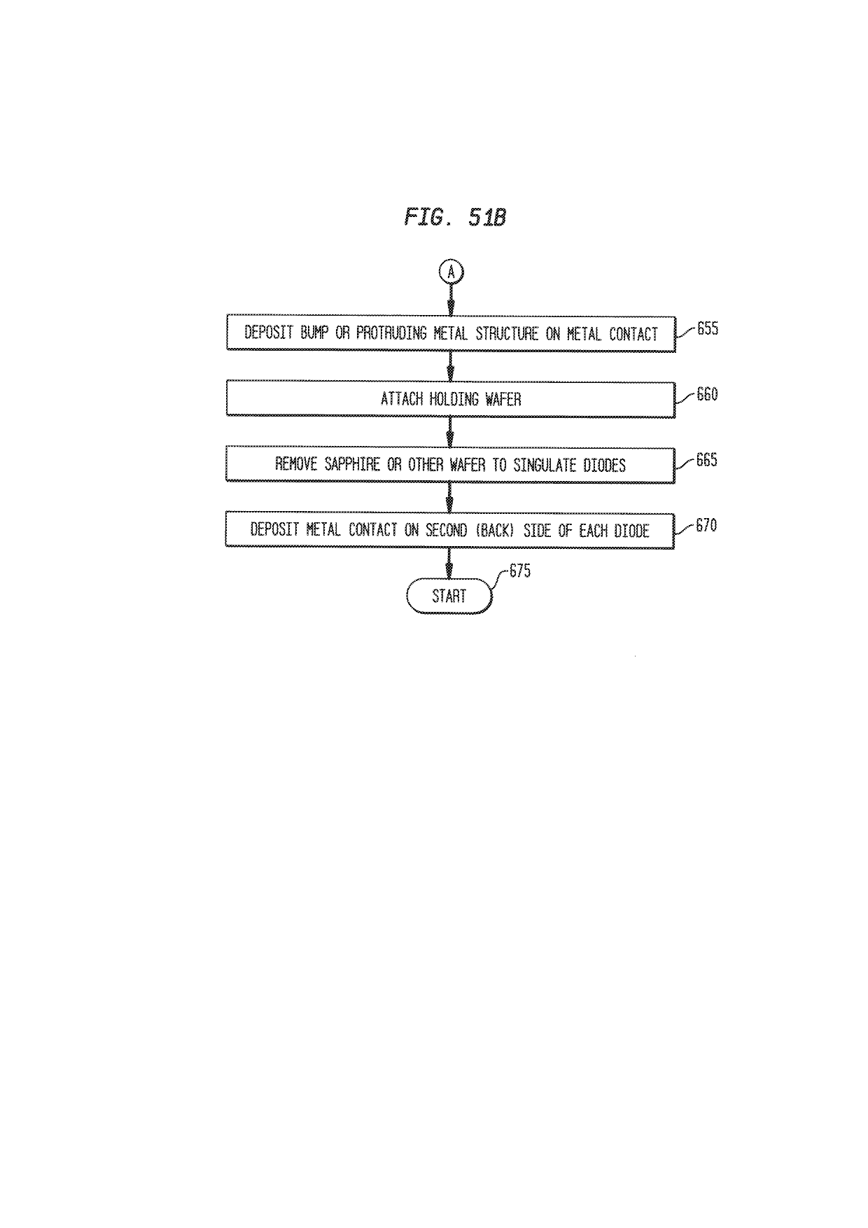

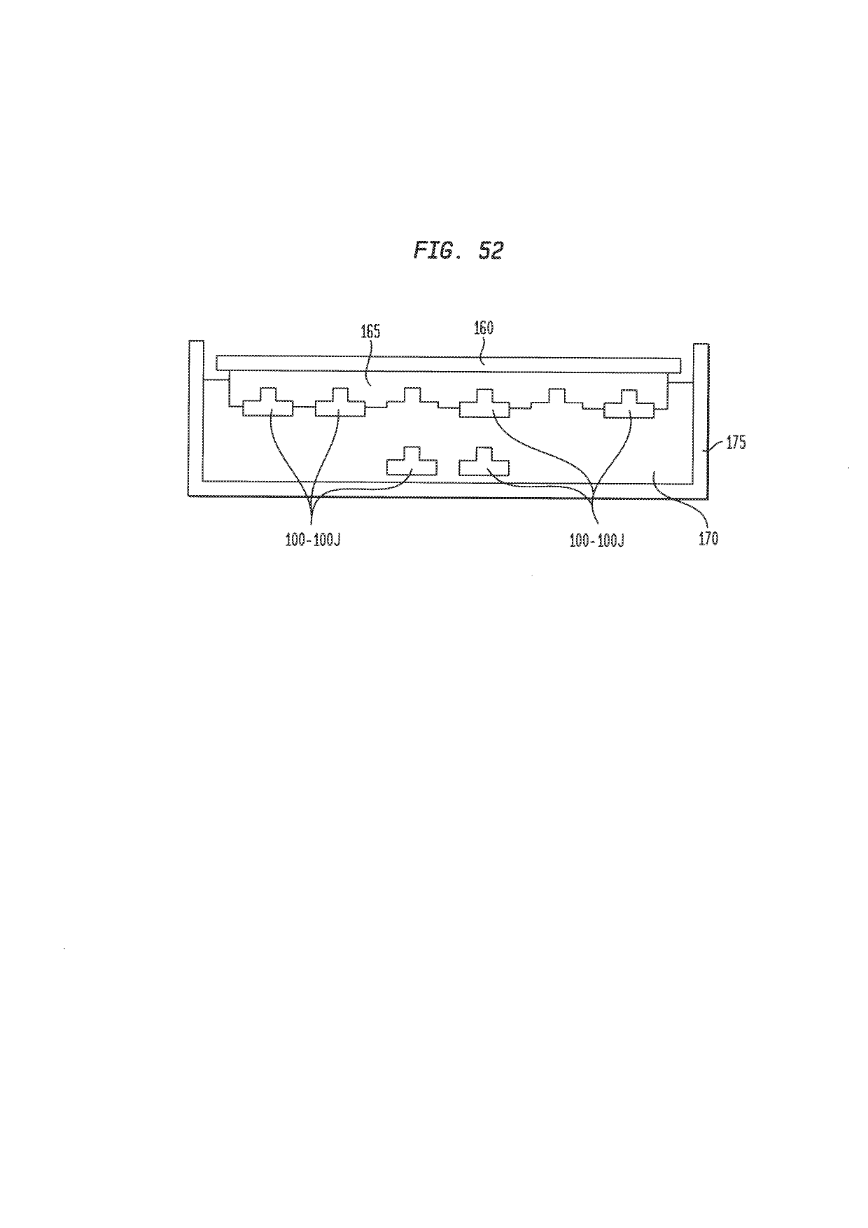

FIG. 52 is a cross-sectional view illustrating individual diodes 100-100J (also illustrated generally for purposes of explication and without any significant feature detail) which are no longer coupled together on the diode wafer 150, 150A (as the second side of the diode wafer 150, 150A has now been ground or polished or cleaved (laser lift-off) to fully expose the singulation (individuation) trenches 155), but which are adhered with wafer adhesive 165 to a holding apparatus 160 and suspended or submerged in a dish 175 with wafer adhesive solvent 170. Any suitable dish 175 may be utilized, such as a petri dish, with an exemplary method utilizing a polytetrafluoroethylene (PTFE or Teflon) dish 175. The wafer adhesive solvent 170 may be any commercially available wafer adhesive solvent or wafer bond remover, including without limitation 2-dodecene wafer bond remover available from Brewer Science, Inc. of Rolla, Mo. USA, for example, or any other comparatively long chain alkane or alkene or shorter chain heptane or heptene. The diodes 100-100J adhered to the holding apparatus 160 are submerged in the wafer adhesive solvent 170 for about five to about fifteen minutes, typically at room temperature (e.g., about 65° F.-75° F. or a higher temperature, and may also be sonicated in exemplary embodiments. As the wafer adhesive solvent 170 dissolves the adhesive 165, the diodes 100-100J separate from the adhesive 165 and holding apparatus 160 and mostly or generally sink to the bottom of the dish 175, individually or in groups or clumps. When all or most diodes 100-100J have been released from the holding apparatus 160 and have settled to the bottom of the dish 175, the holding apparatus 160 and a portion of the currently used wafer adhesive solvent 170 are removed from the dish 175. More wafer adhesive solvent 170 is then added (about 120-140 ml), and the mixture of wafer adhesive solvent 170 and diodes 100-100J is agitated (e.g., using a sonicator or an impeller mixer) for about five to fifteen minutes, typically at room or higher temperature, followed by once again allowing the diodes 100-100J to settle to the bottom of the dish 175. This process is then repeated generally at least once more, such that when all or most diodes 100-100J have settled to the bottom of the dish 175, a portion of the currently used wafer adhesive solvent 170 is removed from the dish 175 and more (about 120-140 ml) wafer adhesive solvent 170 is then added, followed by agitating the mixture of wafer adhesive solvent 170 and diodes 100-100J for about five to fifteen minutes, at room or higher temperature, followed by once again allowing the diodes 100-100J to settle to the bottom of the dish 175 and removing a portion of the remaining wafer adhesive solvent 170. At this stage, a sufficient amount of any residual wafer adhesive 165 generally will have been removed from the diodes 100-100J, or the wafer adhesive solvent 170 process repeated, to no longer potentially interfere with the printing or functioning of the diodes 100-100J.

Removal of the wafer adhesive solvent 170 (having the dissolved wafer adhesive 165), or of any of the other solvents, solutions or other liquids discussed below, may be accomplished in any of various ways. For example, wafer adhesive solvent 170 or other liquids may be removed by vacuum, aspiration, suction, pumping, etc., such as through a pipette. Also for example, wafer adhesive solvent 170 or other liquids may be removed by filtering the mixture of diodes 100-100J and wafer adhesive solvent 170 (or other liquids), such as by using a screen or porous silicon membrane having an appropriate opening or pore size. It should also be mentioned that all of the various fluids used in the diode ink (and dielectric ink discussed below) are filtered to remove particles larger than about 10 microns.

Diode Ink Example 1:
A composition comprising:
a plurality of diodes 100-100J; and
a solvent.

Substantially all or most of the wafer adhesive solvent 170 is then removed. A solvent, and more particularly a polar solvent such as isopropyl alcohol (“IPA”) in an exemplary embodiment and for example, is added to the mixture of wafer adhesive solvent 170 and diodes 100-100J, followed by agitating the mixture of IPA, wafer adhesive solvent 170 and diodes 100-100J for about five to fifteen minutes, generally at room temperature (although a higher temperature may be utilized equivalently), followed by once again allowing the diodes 100-100J to settle to the bottom of the dish 175 and removing a portion of the mixture of IPA and wafer adhesive solvent 170. More IPA is added (120-140 ml), and the process is repeated two or more times, namely, agitating the mixture of IPA, wafer adhesive solvent 170 and diodes 100-100J for about five to fifteen minutes, generally at room temperature, followed by once again allowing the diodes 100-100J to settle to the bottom of the dish 175, removing a portion of the mixture of IPA and wafer adhesive solvent 170 and adding more IPA. In an exemplary embodiment, the resulting mixture is about 100-110 ml of IPA with approximately 9-10 million diodes 100-100J from a four inch wafer (approximately 9.7 million diodes 100-100J per four inch wafer 150), and is then transferred to another, larger container, such as a PTFE jar, which may include additional washing of diodes into the jar with additional IPA, for example. One or more solvents may be used equivalently, for example and without limitation: water; alcohols such as methanol, ethanol, N-propanol (including 1-propanol, 2-propanol (IPA)), butanol (including 1-butanol, 2-butanol (isobutanol)), pentanol (including 1-pentanol, 2-pentanol, 3-pentanol), octanol, tetrahydrofurfuryl alcohol (THFA), cyclohexanol, terpineol; ethers such as methyl ethyl ether, diethyl ether, ethyl propyl ether, and polyethers; esters such ethyl acetate; glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof. The resulting mixture of diodes 100-100J and a solvent such as IPA is a first example of a diode ink, as Example 1 above, and may be provided as a stand-alone composition, for example, for subsequent modification or use in printing, also for example. In other exemplary embodiments discussed below, the resulting mixture of diodes 100-100J and a solvent such as IPA is an intermediate mixture which is further modified to form a diode ink for use in printing, as described below.

In various exemplary embodiments, the selection of a first (or second) solvent is based upon at least two properties or characteristics. A first characteristic of the solvent is its ability be soluble in or to solubilize a viscosity modifier or an adhesive viscosity modifier such as methoxyl cellulose or hydroxypropyl cellulose resin. A second characteristic or property is its evaporation rate, which should be slow enough to allow sufficient screen residence (for screen printing) of the diode ink or to meet other printing parameters. In various exemplary embodiments, an exemplary evaporation rate is less than one (<1, as a relative rate compared with butyl acetate), or more specifically, between 0.0001 and 0.9999.

Diode Ink Example 2:
A composition comprising:
a plurality of diodes 100-100J; and
a viscosity modifier.

Diode Ink Example 3:
A composition comprising:
a plurality of diodes 100-100J; and
a solvating agent.

Diode Ink Example 4:
A composition comprising:
a plurality of diodes 100-100J; and
a wetting solvent.

Diode Ink Example 5:
A composition comprising:
a plurality of diodes 100-100J;
a solvent; and
a viscosity modifier.

Diode Ink Example 6:
A composition comprising:
a plurality of diodes 100-100J;
a solvent; and
an adhesive viscosity modifier.

Diode Ink Example 7:
A composition comprising:
a plurality of diodes 100-100J;
a solvent; and
a viscosity modifier;
wherein the composition is opaque when wet and substantially clear when dried.

Diode Ink Example 8:
A composition comprising:
a plurality of diodes 100-100J;
a first, polar solvent;
a viscosity modifier; and
a second, nonpolar solvent (or rewetting agent).

Diode Ink Example 9:
A composition comprising:
a plurality of diodes 100-100J, each diode of the plurality of diodes 100-100J having a size less than 450 microns in any dimension; and a solvent.

Diode Ink Example 10:
A composition comprising:
a plurality of diodes 100-100J; and
at least one substantially non-insulating carrier or solvent.

Diode Ink Example 11:
A composition comprising:
a plurality of diodes 100-100J;
a solvent; and
a viscosity modifier;
wherein the composition has a dewetting or contact angle greater than 25 degrees, or greater than 40 degrees.

Referring to Diode Ink Examples 1-10, there are a wide variety of exemplary diode ink compositions within the scope of the present invention. Generally, as in Example 1, a liquid suspension of diodes (100-100J) comprises a plurality of diodes (100-100J) and a first solvent (such as IPA discussed above or N-propanol, terpineol or diethylene glycol discussed below); as in Examples 2, a liquid suspension of diodes (100-100J) comprises a plurality of diodes (100-100J) and a viscosity modifier (such those discussed below, which may also be an adhesive viscosity modifier as in Example 6); and as in Examples 3 and 4, a liquid suspension of diodes (100-100J) comprises a plurality of diodes (100-100J) and a solvating agent or a wetting solvent (such as one of the second solvents discussed, below, e.g., a dibasic ester). More particularly, such as in Examples 2, 5, 6, 7 and 8, a liquid suspension of diodes (100-100J) comprises a plurality of diodes (100-100J) (and/or plurality of diodes (100-100J) and a first solvent (such as N-propanol, terpineol or diethylene glycol)), and a viscosity modifier (or equivalently, a viscous compound, a viscous agent, a viscous polymer, a viscous resin, a viscous binder, a thickener, and/or a rheology modifier) or an adhesive viscosity modifier (discussed in greater detail below), to provide a diode ink having a viscosity between about 1,000 centipoise (cps) and 20,000 cps at room temperature (about 25° C.) (or between about 20,000 cps to 60,000 cps at a refrigerated temperature (e.g., 5-10° C.)), such as an E-10 viscosity modifier described below, for example and without limitation. Depending upon the viscosity, the resulting composition may be referred to equivalently as a liquid or as a gel suspension of diodes, and any reference to liquid or gel herein shall be understood to mean and include the other.

In addition, the resulting viscosity of the diode ink will generally vary depending upon the type of printing process to be utilized and may also vary depending upon the diode composition, such as a silicon substrate 105 or a GaN substrate 105. For example, a diode ink for screen printing in which the diodes 100-100J have a silicon substrate 105 may have a viscosity between about 5,000 centipoise (cps) and 20,000 cps at room temperature, or more specifically between about 6,000 centipoise (cps) and 15,000 cps at room temperature, or more specifically between about 8,000 centipoise (cps) and 12,000 cps at room temperature, or more specifically between about 9,000 centipoise (cps) and 11,000 cps at room temperature. For another example, a diode ink for screen printing in which the diodes 100-100J have a GaN substrate 105 may have a viscosity between about 10,000 centipoise (cps) and 25,000 cps at room temperature, or more specifically between about 15,000 centipoise (cps) and 22,000 cps at room temperature, or more specifically between about 17,500 centipoise (cps) and 20,500 cps at room temperature, or more specifically between about 18,000 centipoise (cps) and 20,000 cps at room temperature. Also for example, a diode ink for flexographic printing in which the diodes 100-100J have a silicon substrate 105 may have a viscosity between about 1,000 centipoise (cps) and 10,000 cps at room temperature, or more specifically between about 1,500 centipoise (cps) and 4,000 cps at room temperature, or more specifically between about 1,700 centipoise (cps) and 3,000 cps at room temperature, or more specifically between about 1,800 centipoise (cps) and 2,200 cps at room temperature. Also for example, a diode ink for flexographic printing in which the diodes 100-100J have a GaN substrate 105 may have a viscosity between about 1,000 centipoise (cps) and 10,000 cps at room temperature, or more specifically between about 2,000 centipoise (cps) and 6,000 cps at room temperature, or more specifically between about 2,500 centipoise (cps) and 4,500 cps at room temperature, or more specifically between about 2,000 centipoise (cps) and 4,000 cps at room temperature.

Viscosity may be measured in a wide variety of ways. For purposes of comparison, the various specified and/or claimed ranges of viscosity herein have been measured using a Brookfield viscometer (available from Brookfield Engineering Laboratories of Middleboro, Mass., USA) at a shear stress of about 200 pascals (or more generally between 190 and 210 pascals), in a water jacket at about 25° C., using a spindle SC₄₋₂₇ at a speed of about 10 rpm (or more generally between 1 and 30 rpm, particularly for refrigerated fluids, for example and without limitation).

One or more thickeners (as a viscosity modifier) may be used, for example and without limitation: clays such as hectorite clays, garamite clays, organo-modified clays; saccharides and polysaccharides such as guar gum, xanthan gum; celluloses and modified celluloses such as hydroxylmethyl cellulose, methyl cellulose, methoxyl cellulose, carboxymethyl cellulose, hydroxyethyl cellulose and hydroxypropyl cellulose, cellulose ether, cellulose ethyl ether, chitosan; polymers such as acrylate and (meth)acrylate polymers and copolymers, diethylene glycol, propylene glycol, fumed silica (such as Cabosil), silica powders and modified ureas such as BYK® 420 (available from BYK Chemie GmbH); and mixtures thereof. Other viscosity modifiers may be used, as well as particle addition to control viscosity, as described in Lewis et al., Patent Application Publication Pub. No. US 2003/0091647. Other viscosity modifiers discussed below with reference to dielectric inks may also be utilized, but are not preferred.

Referring to Diode Ink Example 6, the liquid suspension of diodes (100-100J) may further comprise an adhesive viscosity modifier, namely, any of the viscosity modifiers mentioned above which have the additional property of adhesion. Such an adhesive viscosity modifier provides for both adhering the diodes (100-100J) to a first conductor (e.g., 310A) during apparatus (300, 300A, 300B) fabrication (e.g., printing), and then further provides for an infrastructure (e.g., polymeric) (when dried or cured) for holding the diodes (100-100J) in place in an apparatus (300, 300A, 300B). While providing such adhesion, such a viscosity modifier should also have some capability to de-wet from the contacts of the diodes (100-100J), such as the terminals 125 and/or 127. Such adhesive, viscosity and de-wetting properties are among the reasons methoxyl cellulose or hydroxypropyl cellulose resins have been utilized in various exemplary embodiments. Other suitable viscosity modifiers may also be selected empirically.

Additional properties of the viscosity modifier or adhesive viscosity modifier are also useful and within the scope of the disclosure. First, such a viscosity modifier should prevent the suspended diodes (100-100J) from settling out at a selected temperature. Second, such a viscosity modifier should aid in orienting the diodes (100-100J) and printing the diodes (100-100J) in a uniform manner during apparatus (300, 300A, 300B) fabrication. Third, the viscosity modifier should also serve to cushion or otherwise protect the diodes (100-100J) during the printing process.

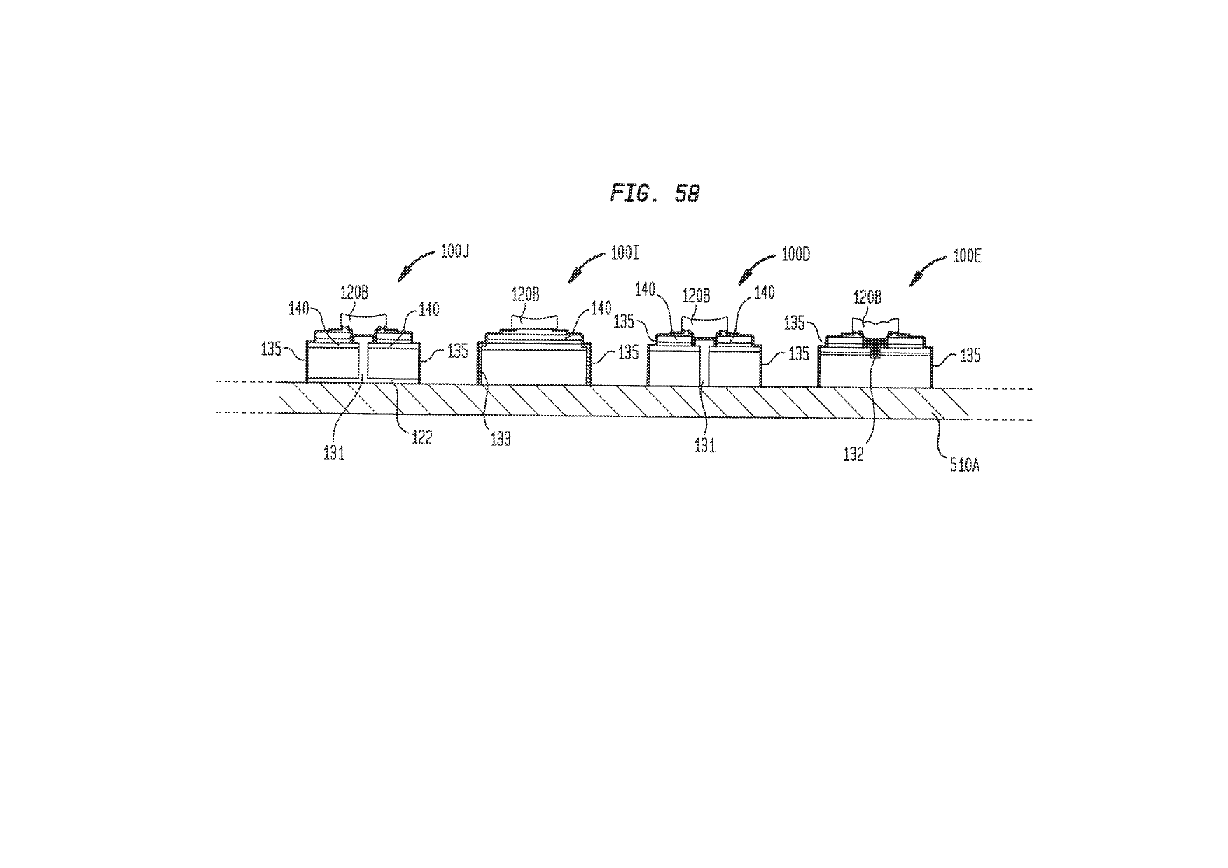

Referring to Diode Ink Examples 3, 4 and 8, the liquid suspension of diodes (100-100J) may further comprise a second solvent (Example 8) or a solvating agent (Example 3) or a wetting solvent (Example 4), with many examples discussed in greater detail below. Such a (first or second) solvent is selected as a wetting (equivalently, solvating) or rewetting agent for facilitating ohmic contact between a first conductor (e.g., 310A, which may be comprised of a conductive polymer such as a silver ink, a carbon ink, or mixture of silver and carbon ink) and the diodes 100-100J (through the substrate 105, a through via structures (131, 133, 134), and/or a second, back side metal layer 122, as illustrated in FIG. 58), following printing and drying of the diode ink during subsequent device manufacture, such as a nonpolar resin solvent, including one or more dibasic esters, also for example and without limitation. For example, when the diode ink is printed over a first conductor 310, the wetting or solvating agent partially dissolves the first conductor 310; as the wetting or solvating agent subsequently dissipates, the first conductor 310 re-hardens and forms a contact with the diodes (100-100J).

The balance of the liquid or gel suspension of diodes (100-100J) is generally another, third solvent, such as deionized water, and any descriptions of percentages herein shall assume that the balance of the liquid or gel suspension of diodes (100-100J) is such a third solvent such as water, and all described percentages are based on weight, rather than volume or some other measure. It should also be noted that the various diode ink suspensions may all be mixed in a typical atmospheric setting, without requiring any particular composition of air or other contained or filtered environment.

Solvent selection may also be based upon the polarity of the solvent. In an exemplary embodiment, a first solvent such as an alcohol may be selected as a polar or hydrophilic solvent, to facilitate de-wetting off of the diodes (100-100J) and other conductors (e.g., 310) during apparatus 300, 300A, 300B fabrication, while concomitantly being able to be soluble in or solubilize a viscosity modifier.

Another useful property of an exemplary diode ink is illustrated by Example 7. For this exemplary embodiment, the diode ink is opaque when wet during printing, to aid in various printing processes such as registration. When dried or cured, however, the dried or cured diode ink is substantially clear at selected wavelengths, such as clear to substantially allow or not interfere with the emission of visible light generated by the diodes (100-100J).

Another way to characterize an exemplary diode ink is based upon the size of the diodes (100-100J), as illustrated by Example 7, in which the diodes 100-100J are generally less than about 450 microns in any dimension, and more specifically less than about 200 microns in any dimension, and more specifically less than about 100 microns in any dimension, and more specifically less than 50 microns in any dimension. In the illustrated exemplary embodiments, the diodes 100-100J are generally on the order of about 15 to 40 microns in width, or more specifically about 20 to 30 microns in width, and about 10 to 15 microns in height, or from about 25 to 28 microns in diameter (measured side face to face rather than apex to apex) and 10 to 15 microns in height. In exemplary embodiments, the height of the diodes 100-100J excluding the metal layer 120B forming the bump or protruding structure (i.e., the height of the lateral sides 121 including the GaN heterostructure) is on the order of about 5 to 15 microns, or more specifically 7 to 12 microns, or more specifically 8 to 11 microns, or more specifically 9 to 10 microns, or more specifically less than 10 to 30 microns, while the height of the metal layer 120B forming the bump or protruding structure is generally on the order of about 3 to 7 microns.

The diode ink may also be characterized by its electrical properties, as illustrated in Example 10. In this exemplary embodiment, the diodes (100-100J) are suspended in at least one substantially non-insulating carrier or solvent, in contrast with an insulating binder, for example.

The diode ink may also be characterized by its surface properties, as illustrated in Example 10. In this exemplary embodiment, the diode ink has a dewetting or contact angle greater than 25 degrees, or greater than 40 degrees, depending upon the surface energy of the substrate utilized for measurement, such as between 34 and 38 dynes, for example.

Diode Ink Example 12:
A composition comprising:
a plurality of diodes 100-100J;
a first solvent comprising about 5% to 50% N-propanol, terpineol or diethylene glycol, ethanol, tetrahydrofurfuryl alcohol, and/or cyclohexanol, or mixtures thereof;
a viscosity modifier comprising about 0.75% to 5.0% methoxyl cellulose or hydroxypropyl cellulose resin, or mixtures thereof;
a second solvent (or rewetting agent) comprising about 0.5% to 10% of a nonpolar resin solvent such as a dibasic ester; and
with the balance comprising a third solvent such as water.

Diode Ink Example 13:
A composition comprising:
a plurality of diodes 100-100J;
a first solvent comprising about 15% to 40% N-propanol, terpineol or diethylene glycol, ethanol, tetrahydrofurfuryl alcohol, and/or cyclohexanol, or mixtures thereof;
a viscosity modifier comprising about 1.25% to 2.5% methoxyl cellulose or hydroxypropyl cellulose resin or mixtures thereof;
a second solvent (or rewetting agent) comprising about 0.5% to 10% of a nonpolar resin solvent such as a dibasic ester; and
with the balance comprising a third solvent such as water.

Diode Ink Example 14:
A composition comprising:
a plurality of diodes 100-100J;
a first solvent comprising about 17.5% to 22.5% N-propanol, terpineol or diethylene glycol, ethanol, tetrahydrofurfuryl alcohol, and/or cyclohexanol or mixtures thereof;
a viscosity modifier comprising about 1.5% to 2.25% methoxyl cellulose or hydroxypropyl cellulose resin or mixtures thereof;
a second solvent (or rewetting agent) comprising between about 0.0% to 6.0% of at least one dibasic ester; and
with the balance comprising a third solvent such as water, wherein the viscosity of the composition is substantially between about 5,000 cps to about 20,000 cps at 25° C.

Diode Ink Example 15:
A composition comprising:
a plurality of diodes 100-100J;
a first solvent comprising about 20% to 40% N-propanol, terpineol or diethylene glycol, ethanol, tetrahydrofurfuryl alcohol, and/or cyclohexanol, or mixtures thereof;
a viscosity modifier comprising about 1.25% to 1.75% methoxyl cellulose or hydroxypropyl cellulose resin or mixtures thereof;
a second solvent (or rewetting agent) comprising between about 0% to 6.0% of at least one dibasic ester; and
with the balance comprising a third solvent such as water, wherein the viscosity of the composition is substantially between about 1,000 cps to about 5,000 cps at 25° C.

Referring to Diode Ink Examples 12, 13, 14 and 15, in an exemplary embodiment, another alcohol as the first solvent, N-propanol (“NPA”) (and/or terpineol, diethylene glycol, tetrahydrofurfuryl alcohol, or cyclohexanol), is substituted for substantially all or most of the IPA. With the diodes 100-100J generally or mostly settled at the bottom of the container, IPA is removed, NPA is added, the mixture of IPA, NPA and diodes 100-100J is agitated or mixed at room temperature, followed by once again allowing the diodes 100-100J to settle to the bottom of the container, and removing a portion of the mixture of IPA and NPA, and adding more NPA (about 120-140 ml). This process of adding NPA and removing a mixture of IPA and NPA, is generally repeated twice, resulting in a mixture of predominantly NPA, diodes 100-100J, trace or otherwise small amounts of IPA, and potentially residual wafer adhesive and wafer adhesive solvent 170, generally also in trace or otherwise small amounts. In an exemplary embodiment, the residual or trace amounts of IPA remaining are less than about 1%, and more generally about 0.4%. Also in an exemplary embodiment, the final percentage of NPA in an exemplary diode ink is about 5% to 50%, or more specifically about 15% to 40%, or more specifically about 17.5% to 22.5%, or more specifically about 25% to about 35%, depending upon the type of printing to be utilized. When terpineol and/or diethylene glycol are utilized with or instead of NPA, a typical concentration of terpineol is about 0.5% to 2.0%, and a typical concentration of diethylene glycol is about 15% to 25%. The IPA, NPA, rewetting agents, deionized water (and other compounds and mixtures utilized to form exemplary diode inks) may also be filtered to about 25 microns or smaller to remove particle contaminants which are larger than or on the same scale as the diodes 100-100J.

The mixture of substantially NPA and diodes 100-100J is then added to and mixed or stirred briefly with a viscosity modifier, for example, such as a methoxyl cellulose resin or hydroxypropyl cellulose resin. In an exemplary embodiment, E-3 and E-10 methoxyl cellulose resins available from The Dow Chemical Company (www.dow.com) and Hercules Chemical Company, Inc. (www.herchem.com) are utilized, resulting in a final percentage in an exemplary diode ink of about 0.75% to 5.0%, more specifically about 1.25% to 2.5%, more specifically 1.5% to 2.0%, and even more specifically less than or equal to 1.75%. In an exemplary embodiment, about a 3.0% E-10 formulation is utilized and is diluted with deionized and filtered water to result in the final percentage in the completed composition. Other viscosity modifiers may be utilized equivalently, including those discussed above and those discussed below with reference to dielectric inks. The viscosity modifier provides sufficient viscosity for the diodes 100-100J that they are substantially maintained in suspension and do not settle out of the liquid or gel suspension, particularly under refrigeration.

As mentioned above, a second solvent (or a first solvent for Examples 3 and 4), generally a nonpolar resin solvent such as one or more dibasic esters, is then added. In an exemplary embodiment, a mixture of two dibasic esters is utilized to reach a final percentage of about 0.0% to about 10%, or more specifically about 0.5% to about 6.0%, or more specifically about 1.0% to about 5.0%, or more specifically about 2.0% to about 4.0%, or more specifically about 2.5% to about 3.5%, such as dimethyl glutarate or such as a mixture of about two thirds (⅔) dimethyl glutarate and about one third (⅓) dimethyl succinate at a final percentage of about 3.73%, e.g., respectively using DBE-5 or DBE-9 available from Invista USA of Wilmington, Del., USA, which also has trace or otherwise small amounts of impurities such as about 0.2% of dimethyl adipate and 0.04% water). A third solvent such as deionized water is also added, to adjust the relative percentages and reduce viscosity, as may be necessary or desirable. In addition to dibasic esters, other second solvents which may be utilized equivalently include, for example and without limitation, water; alcohols such as methanol, ethanol, N-propanol (including 1-propanol, 2-propanol (isopropanol)), isobutanol, butanol (including 1-butanol, 2-butanol), pentanol (including 1-pentanol, 2-pentanol, 3-pentanol), octanol, tetrahydrofurfuryl alcohol, cyclohexanol; ethers such as methyl ethyl ether, diethyl ether, ethyl propyl ether, and polyethers; esters such ethyl acetate, dimethyl adipate, proplyene glycol monomethyl ether acetate (and dimethyl glutarate and dimethyl succinate as mentioned above); glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof. In an exemplary embodiment, molar ratios of the amount of first solvent to the amount of second solvent are in the range of at least about 2 to 1, and more specifically in the range of at least about 5 to 1, and more specifically in the range of at least about 12 to 1 or higher; in other instances, the functionality of the two solvents may be combined into a single agent, with one polar or nonpolar solvent utilized in an exemplary embodiment. Also in addition to the dibasic esters discussed above, exemplary dissolving, wetting or solvating agents, for example and without limitation, also as mentioned below, include proplyene glycol monomethyl ether acetate (C₆H₁₂O₃) (sold by Eastman under the name “PM Acetate”), used in an approximately 1:8 molar ratio (or 22:78 by weight) with 1-propanol (or isopropanol) to form the suspending medium, and a variety of dibasic esters, and mixtures thereof, such as dimethyl succinate, dimethyl adipate and dimethyl glutarate (which are available in varying mixtures from Invista under the product names DBE, DBE-2, DBE-3, DBE-4, DBE-5, DBE-6, DBE-9 and DBE-IB). In an exemplary embodiment, DBE-9 has been utilized. The molar ratios of solvents will vary based upon the selected solvents, with 1:8 and 1:12 being typical ratios.

While generally the various diode inks are mixed in the order described above, it should also be noted that the various first solvent, viscosity modifier, second solvent, and third solvent (such as water) may be added or mixed together in other orders, any and all of which are within the scope of the disclosure. For example, deionized water (as a third solvent) may be added first, followed by 1-propanol and DBE-9, followed by a viscosity modifier, and then followed by additional water, as may be needed, to adjust relative percentages and viscosity, also for example.

The mixture of substantially a first solvent such as NPA, diodes 100-100J, a viscosity modifier, a second solvent, and a third solvent such as water are then mixed or agitated, such as by using an impeller mixer, at a comparatively low speed to avoid incorporating air into the mixture, for about 25-30 minutes at room temperature in an air atmosphere. In an exemplary embodiment, the resulting volume of diode ink is typically on the order of about one-half to one liter (per wafer) containing 9-10 million diodes 100-100J, and the concentration of diodes 100-100J may be adjusted up or down as desired, such as depending upon the concentration desired for a selected printed LED or photovoltaic device, described below, with exemplary viscosity ranges described above for different types of printing and different types of diodes 100-100J. A first solvent such as NPA also tends to act as a preservative and inhibits bacterial and fungal growth for storage of the resulting diode ink. When other first solvents are to be utilized, a separate preserving, inhibiting or fungicidal agent may also be added. For an exemplary embodiment, additional surfactants or non-foaming agents for printing may be utilized as an option, but are not required for proper functioning and exemplary printing.

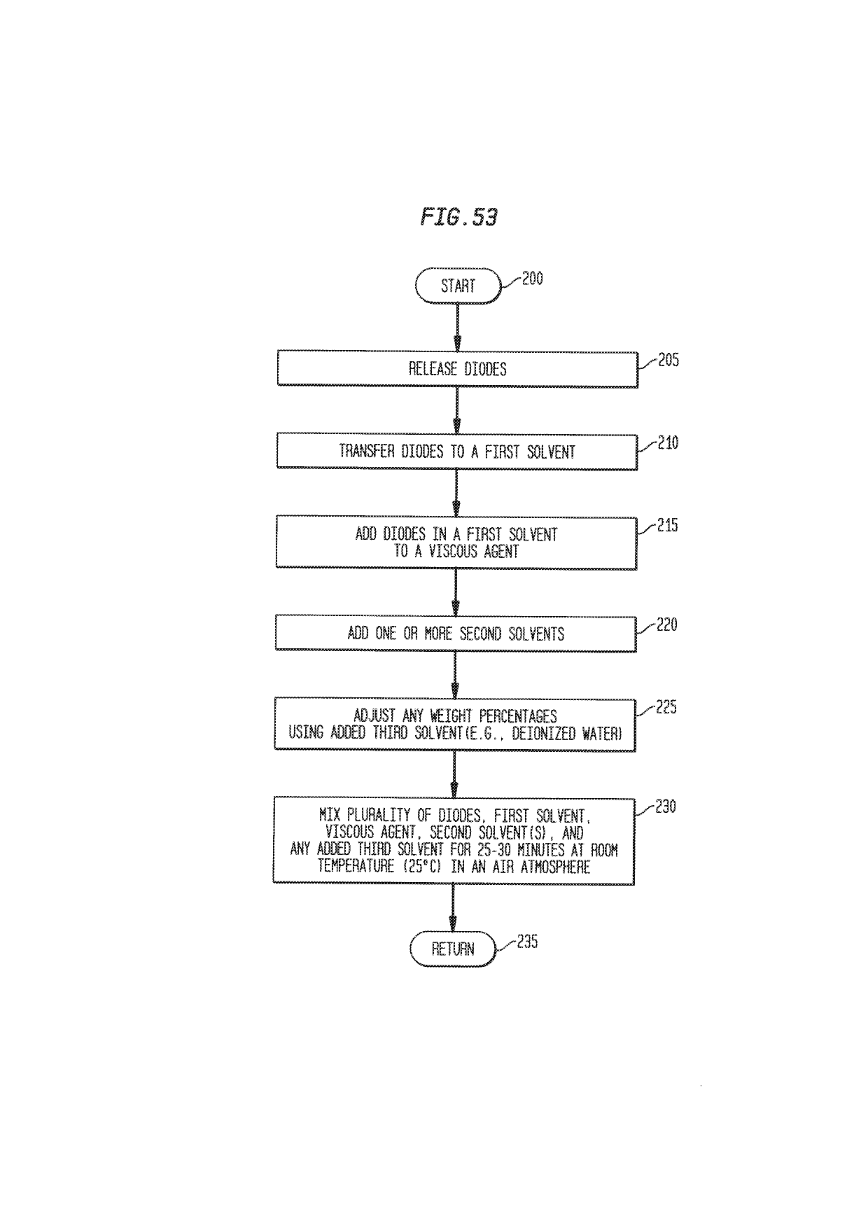

FIG. 53 is a flow diagram illustrating an exemplary method embodiment for manufacturing diode ink, and provides a useful summary. The method begins, start step 200, with releasing the diodes 100-100J from the wafer 150, 150A, step 205. As discussed above, this step involves attaching the wafer on a first, diode side to a wafer holder with a wafer bond adhesive, using laser lift-off or grinding and/or polishing the second, back side of the wafer to reveal the singulation trenches, and dissolving the wafer bond adhesive to release the diodes 100-100J into a solvent such as IPA or into another solvent such as NPA. When IPA is utilized, the method includes optional step 210, of transferring the diodes 100-100J to a (first) solvent such as NPA. The method then adds the diodes 100-100J in the first solvent to a viscosity modifier such as methyl cellulose, step 215, and adds one or more second solvents, such as one or two dibasic esters, such as dimethyl glutarate and/or dimethyl succinate, step 220. Any weight percentages may be adjusted using a third solvent such as deionized water, step 225. In step 230, the method then mixes the plurality of diodes 100-100J, first solvent, viscosity modifier, second solvent, and any additional deionized water for about 25-30 minutes at room temperature (about 25° C.) in an air atmosphere, with a resulting viscosity between about 1,000 cps to about 25,000 cps. The method may then end, return step 235. It should also be noted that steps 215, 220, and 225 may occur in other orders, as described above, and may be repeated as needed, and that optional, additional mixing steps may also be utilized.

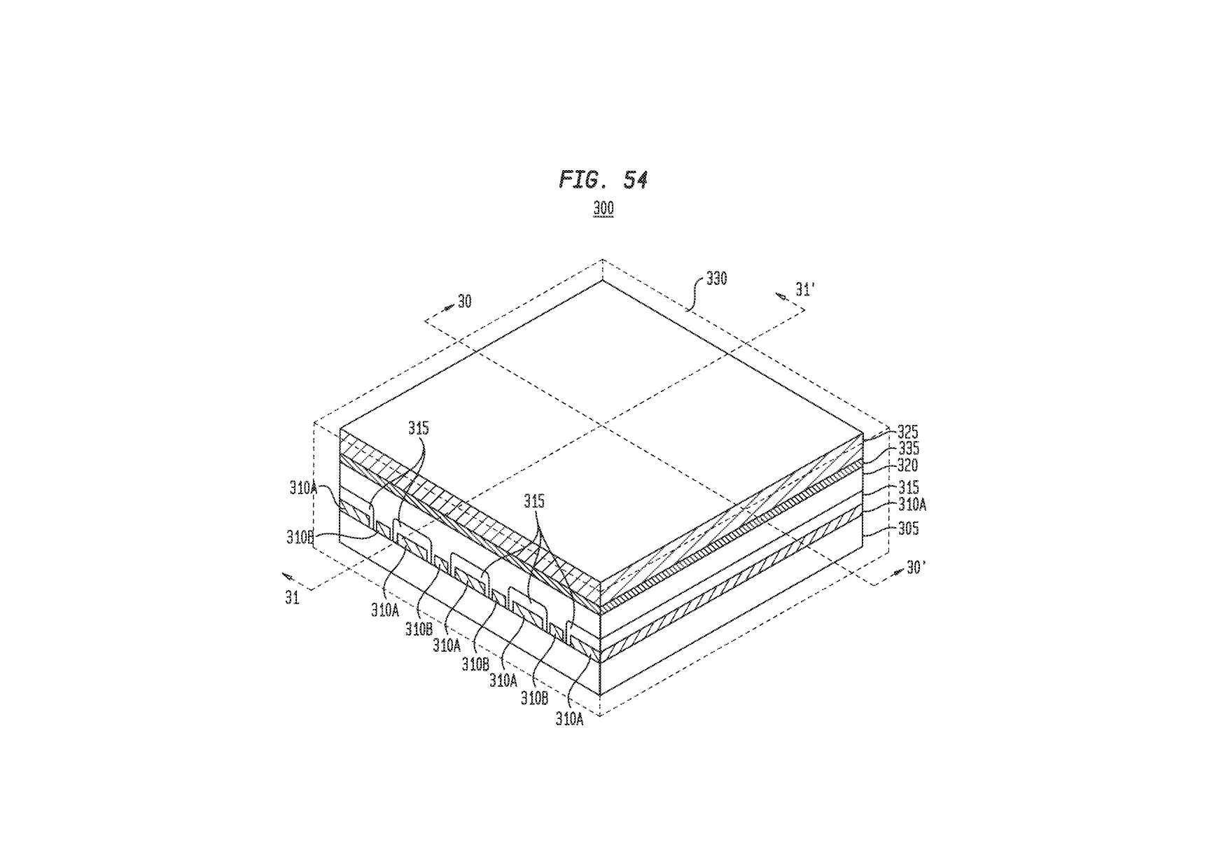

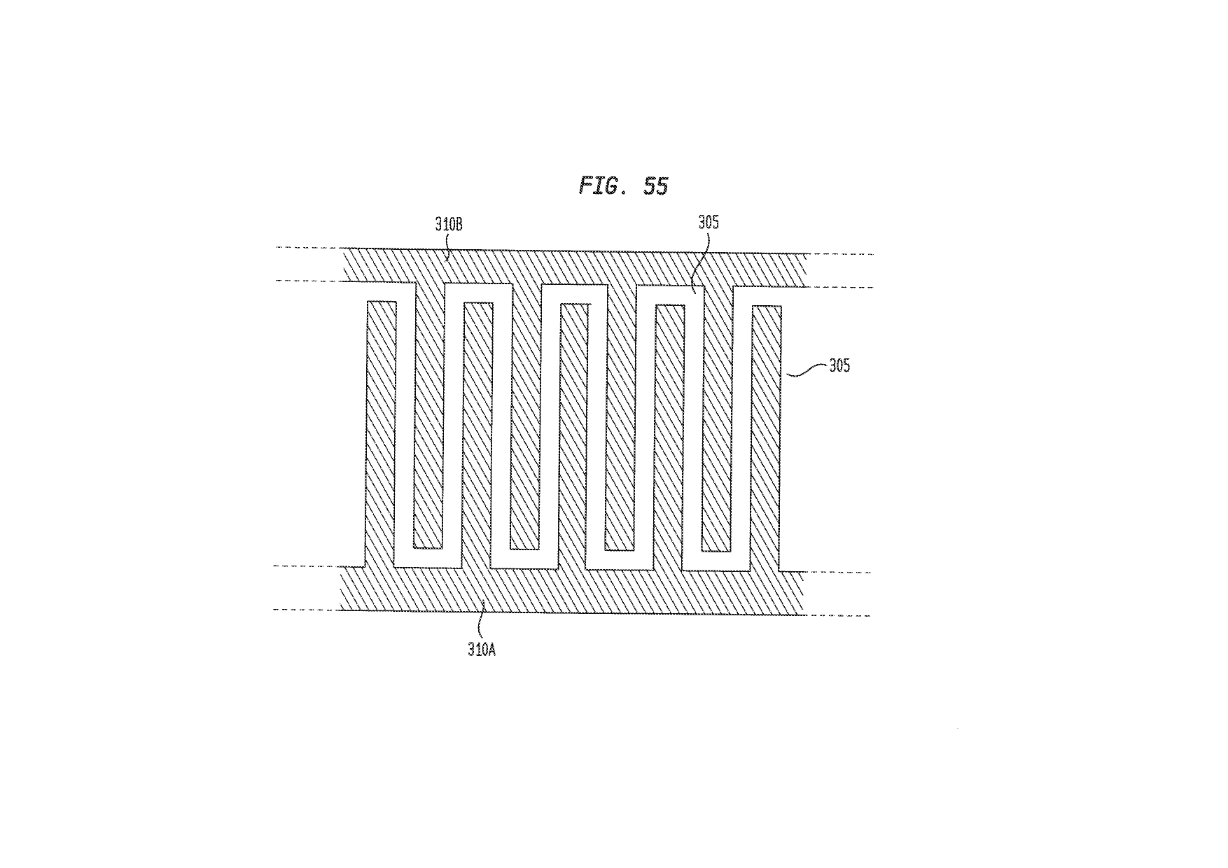

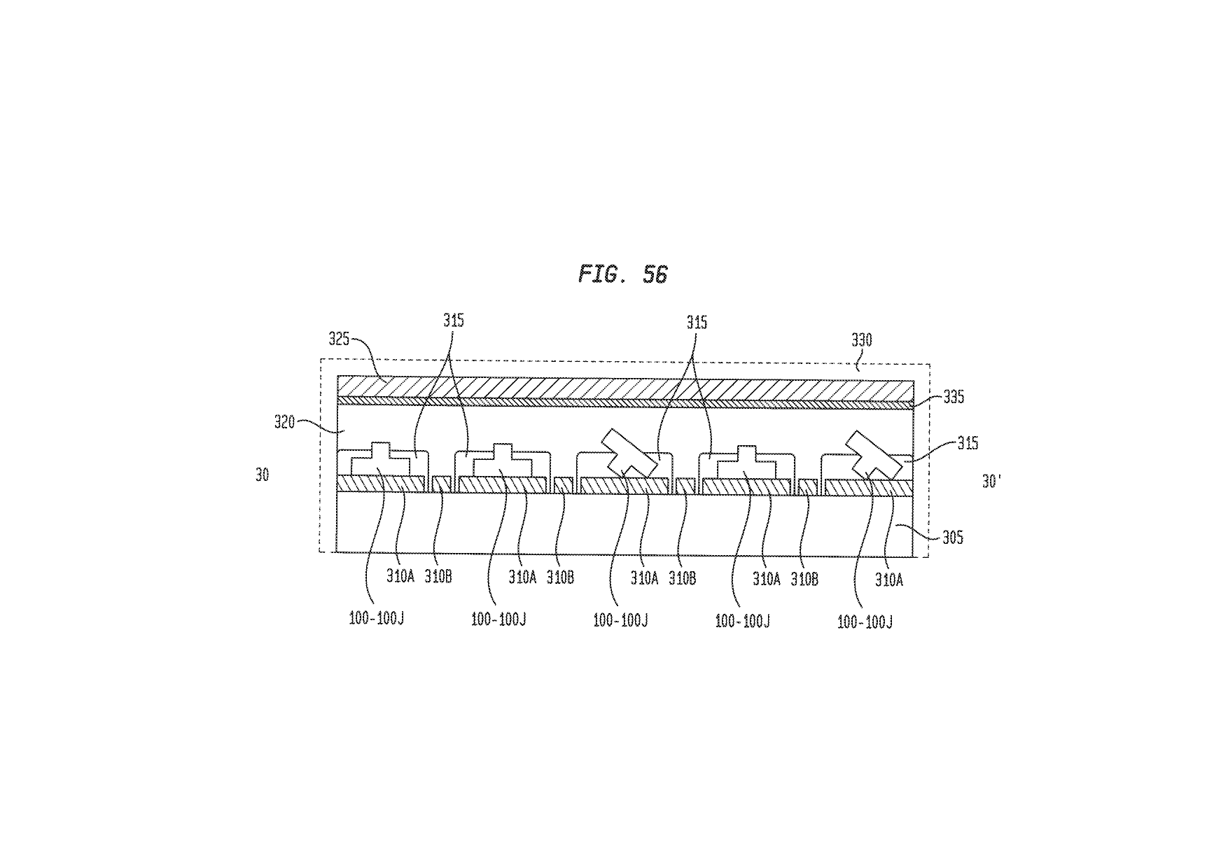

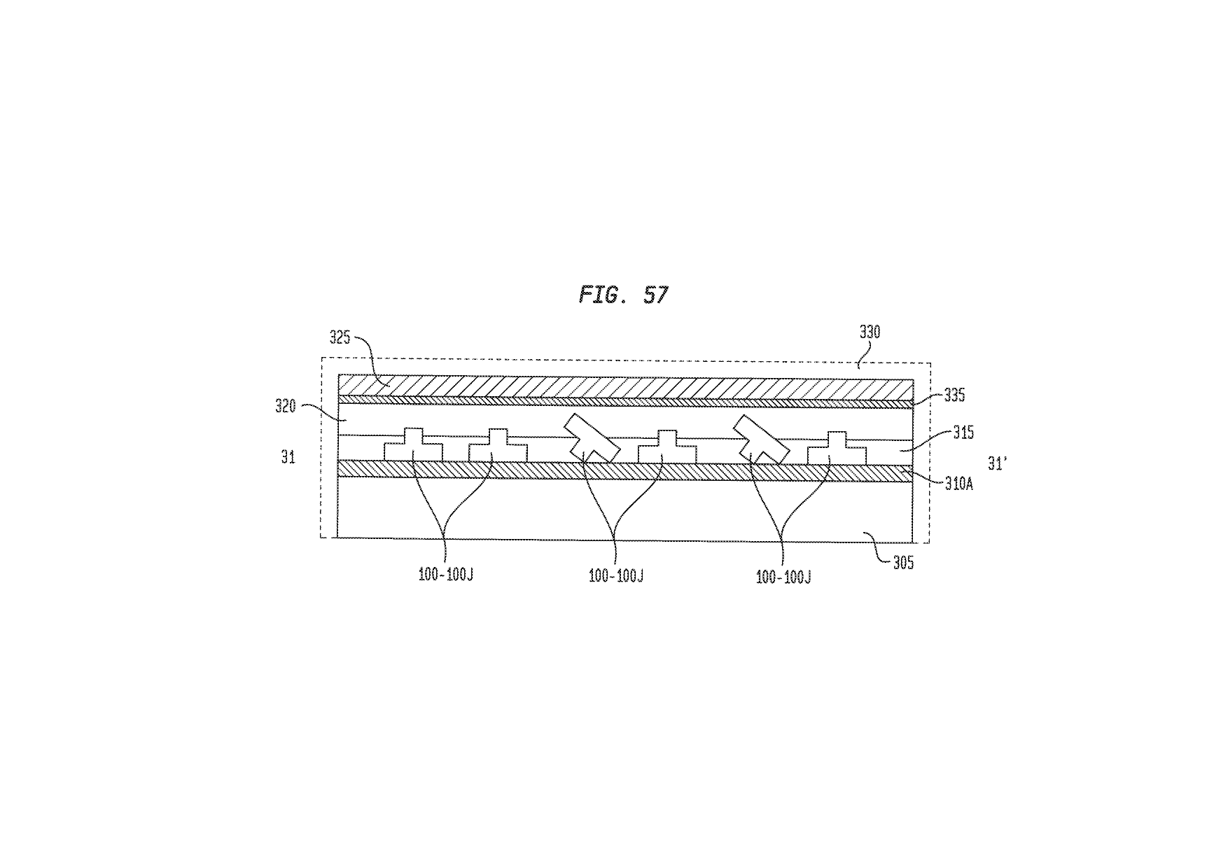

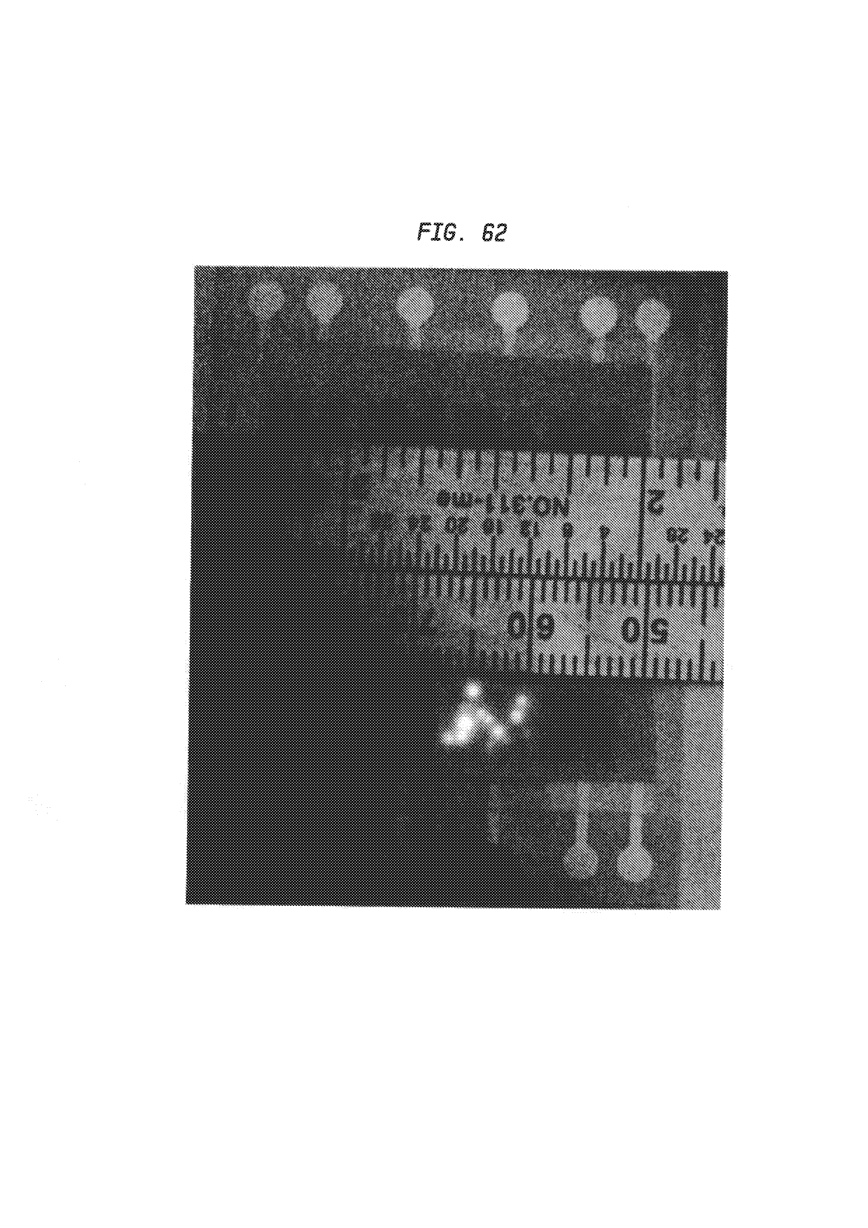

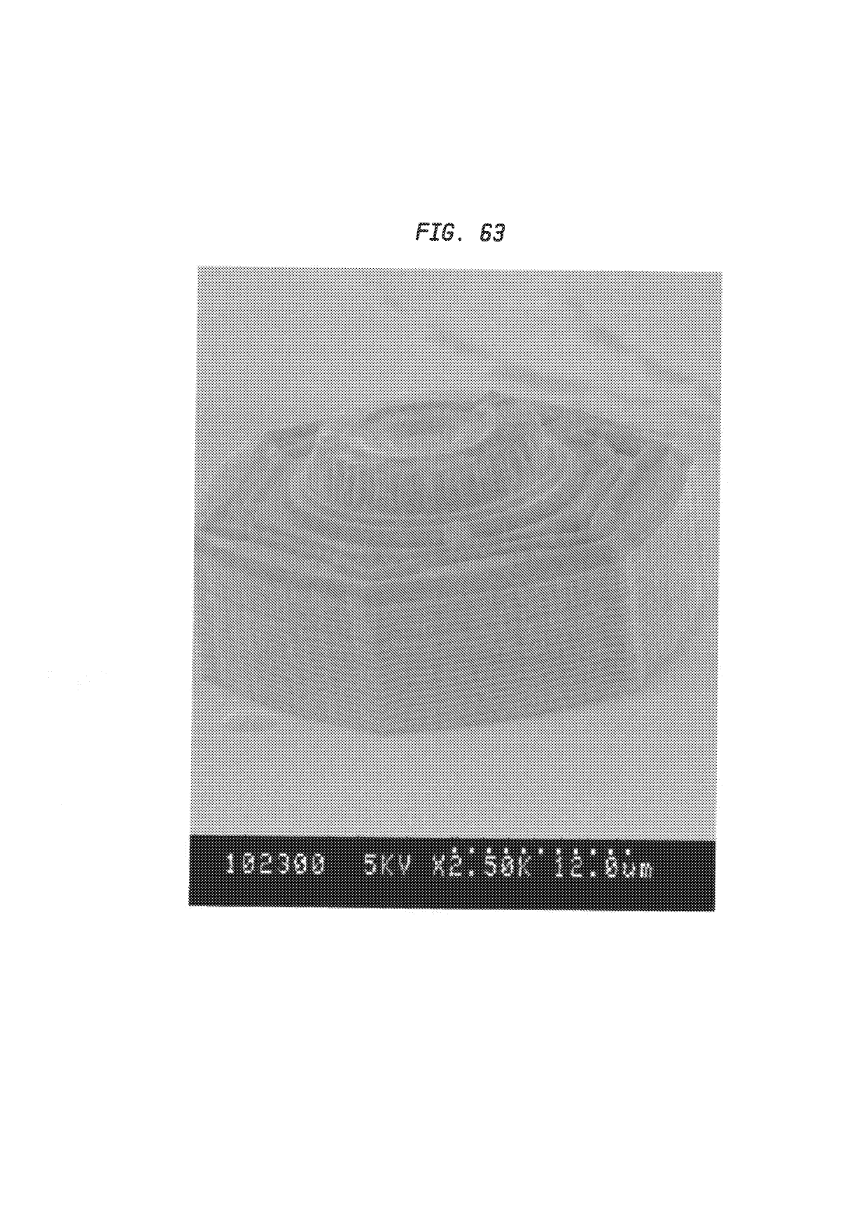

FIG. 54 is a perspective view of an exemplary apparatus 300 embodiment. FIG. 55 is a top view illustrating an exemplary electrode structure of a first conductive layer for an exemplary apparatus embodiment. FIG. 56 is a first cross-sectional view (through the 30-30′ plane of FIG. 54) of an exemplary apparatus 300 embodiment. FIG. 57 is a second cross-sectional view (through the 31-31′ plane of FIG. 54) of an exemplary apparatus embodiment. FIG. 58 is a second cross-sectional view of exemplary diodes 100J, 100I, 100D and 100E coupled to a first conductor 310A. FIG. 62 is a photograph of an energized exemplary apparatus 300A embodiment emitting light. As mentioned above, the apparatus 300 is formed by depositing (e.g., printing) a plurality of layers on a base 305, namely, depositing one or more first conductors 310 on the base 305, either as a layer or a plurality of conductors 310, followed by depositing the diodes 100-100J while in the liquid or gel suspension (to a wet film thickness of about 18 or more microns) and evaporating or otherwise dispersing the liquid/gel portion of the suspension, with the diodes 100-100J physically and electrically coupled to the one or more first conductors 310A in either a first orientation (up direction) or in a second orientation (down direction). In the first, up orientation or direction, as illustrated in FIG. 58, the metal layer 120B forming the bump or protruding structure is oriented upward, and the diodes 100-100J are coupled to the one or more first conductors 310A through second terminal 127 (back side metal layer 122) as illustrated for diode 100J, or through a perimeter via 133 as illustrated for diode 100I, or through a center via 131 as illustrated for diode 100D (embodied without the optional back side metal layer 122 of a diode 100J), or through a peripheral via 134 (not separately illustrated), or through substrate 105 as illustrated for diode 100E. In the second, down orientation or direction, the metal layer 120B forming the bump or protruding structure is oriented downward, and the diodes 100-100J are or may be coupled to the one or more first conductors 310A through the first terminal 125 (e.g., the metal layer 120B forming the bump or protruding structure).

The diodes 100-100J are deposited in an effectively random orientation, and may be up in a first orientation (first terminal 125 up and substrate 105 down), which is typically the direction of a forward bias voltage (depending upon the polarity of the applied voltage), or down in a second orientation (first terminal 125 down and substrate 105 up), which is typically the direction of a reverse bias voltage (also depending upon the polarity of the applied voltage), or sideways in a third orientation (a diode lateral side 121 down and another diode lateral side 121 up). Fluid dynamics, the viscosity of the diode ink, mesh count, print speed, orientation of the tines of the interdigitated or comb structure of the first conductors 310 (tines being perpendicular to the direction of the motion of the base 305), and size of the diode lateral sides 121 appear to influence the predominance of one orientation over another orientation. For example, diode lateral sides 121 being less than about 10 microns in height significantly decreases the percentage of diodes 100-100J having the third orientation. Similarly, fluid dynamics, higher viscosities, and lower mesh count appear to increase the prevalence of the first orientation, resulting in a first orientation of as many as 80% of the diodes 100-100J or more. It should be noted that even with a significantly high percentage of diodes 100-100J coupled to the first conductor 310A in the first, up orientation or direction, statistically at least one or more diodes 100-100J will have the second, down orientation or direction, and that statistically the first or second orientations of the diodes 100-100J will also be distributed randomly over the first conductors 310A. Stated another way, depending upon the polarity of the applied voltage, while a significantly high percentage of diodes 100-100J are or will be coupled to the first conductor 310A in a first, forward bias orientation or direction, statistically at least one or more diodes 100-100J will have a second, reverse bias orientation or direction. In the event the light emitting or absorbing region 140 is oriented differently, then those having skill in the art will recognize that also depending upon the polarity of the applied voltage, the first orientation will be a reverse bias orientation, and the second orientation will be a forward bias orientation. (This is a significant departure from existing apparatus structures, in which all such diodes (such as LEDs) have a single orientation with respect to the voltage rails, namely, all having their corresponding anodes coupled to the higher voltage and their cathodes coupled to the lower voltage.) As a result of the random orientation, and depending upon various diode characteristics such as tolerances for reverse bias, the diodes 100-100J may be energized using either an AC or a DC voltage or current.

Also notably, all of the individual diodes (100-100J) in the fabricated apparatus are electrically in parallel with each other. This is also a significant departure from existing apparatus structures, in which at least some diodes are in series with each other, and such series connections of pluralities of diodes may then be in parallel with each other).

Referring to FIG. 55, a plurality of first conductors 310 are utilized, forming at least two separate electrode structures, illustrated as an interdigitated or comb electrode structures of a first (first) conductor 310A and a second (first) conductor 310B. As illustrated in FIG. 55, the conductors 310A and 310B have the same widths, and are illustrated in FIGS. 54 and 56 as having different widths, with all such variations within the scope of the disclosure. For this exemplary embodiment, the diode ink or suspension (having the diodes 100-100J) is deposited over the conductor 310A. A second, transparent conductor 320 (discussed below) is subsequently deposited (over a dielectric layer, as discussed below) to make separate electrical contact with the conductor 310B, as illustrated in FIG. 56.

It should be noted that when the first conductors 310 have the interdigitated or comb structure illustrated in FIG. 55, the second conductor 320 may be energized using first conductor 310B. The interdigitated or comb structure of the first conductors provides electrical current balancing, such that every current path through the first conductor 310A, diodes 100-100J, second conductor 320, and first conductor 310B is substantially within a predetermined range. This serves to minimize the distance current must travel through the second, transparent conductor, thereby decreasing resistance and heat generation, and generally providing current to all or most of the diodes 100-100J within a predetermined range of current levels. In addition, multiple interdigitated or comb structures for the first conductors 310 may also be wired in series, such as to produce an overall device voltage having the desired multiple of diode 100-100J forward voltages, such as up to typical household voltages, for example and without limitation.

One or more dielectric layers 315 are then deposited over the diodes 100-100J, in a way which leaves exposed either or both the first terminal 125 in the first orientation or the second, back side of the diode 100-100J when in the second orientation, in an amount sufficient to provide electrical insulation between the one or more first conductors 310 (coupled to the diodes 100-100J) and a second, transparent conductor 320 deposited over the one or more dielectric layers 315 and which makes a corresponding physical and electrical contact with the first terminal 125 or the second, back side of the diode 100-100J, depending on the orientation. An optional luminescent (or emissive) layer 325 may then be deposited, followed by any lensing, dispersion or sealing layer 330. For example, such an optional luminescent (or emissive) layer 325 may comprise a stokes shifting phosphor layer to produce a lamp or other apparatus emitting a desired color or other selected wavelength range or spectrum. These various layers, conductors and other deposited compounds are discussed in greater detail below.

A base 305 may be formed from or comprise any suitable material, such as plastic, paper, cardboard, or coated paper or cardboard, for example and without limitation. The base 305 may comprise any flexible material having the strength to withstand the intended use conditions. In an exemplary embodiment, a base 305 comprises a polyester or plastic sheet, such as a CT-7 seven mil polyester sheet treated for print receptiveness commercially available from MacDermid Autotype, Inc. of MacDermid, Inc. of Denver, Colo., USA, for example. In another exemplary embodiment, a base 305 comprises a polyimide film such as Kapton commercially available from DuPont, Inc. of Wilmington Del., USA, also for example. Also in an exemplary embodiment, base 305 comprises a material having a dielectric constant capable of or suitable for providing sufficient electrical insulation for the excitation voltages which may be selected. A base 305 may comprise, also for example, any one or more of the following: paper, coated paper, plastic coated paper, fiber paper, cardboard, poster paper, poster board, books, magazines, newspapers, wooden boards, plywood, and other paper or wood-based products in any selected form; plastic or polymer materials in any selected form (sheets, film, boards, and so on); natural and synthetic rubber materials and products in any selected form; natural and synthetic fabrics in any selected form; glass, ceramic, and other silicon or silica-derived materials and products, in any selected form; concrete (cured), stone, and other building materials and products; or any other product, currently existing or created in the future. In a first exemplary embodiment, a base 305 may be selected which provides a degree of electrical insulation (i.e., has a dielectric constant or insulating properties sufficient to provide electrical insulation of the one or more first conductors 310 deposited or applied on a first (front) side of the base 305, either electrical insulation from each other or from other apparatus or system components. For example, while comparatively expensive choices, a glass sheet or a silicon wafer also could be utilized as a base 305. In other exemplary embodiments, however, a plastic sheet or a plastic-coated paper product is utilized to form the base 305 such as the polyester mentioned above or patent stock and 100 lb. cover stock available from Sappi, Ltd., or similar coated papers from other paper manufacturers such as Mitsubishi Paper Mills, Mead, and other paper products. In another exemplary embodiment, an embossed plastic sheet or a plastic-coated paper product having a plurality of grooves, also available from Sappi, Ltd. is utilized, with the grooves utilized for forming the conductors 310. In additional exemplary embodiments, any type of base 305 may be utilized, including without limitation, those with additional sealing or encapsulating layers (such as plastic, lacquer and vinyl) deposited to one or more surfaces of the base 305. Suitable bases 305 also include extruded polyolefinic films, including LDPE films; polymeric nonwovens, including carded, meltblown and spunbond nowovens, and cellulosic paper, including tissue grades of paper. The base 305 may also comprise laminates of any of the foregoing materials. Two or more laminae may be adhesively joined, thermally bonded, or autogenously bonded together to form the laminate comprising the substrate. If desired, the laminae may be embossed.

In one embodiment, given the low heat emitted by the diodes of the present invention, a wide range of materials available be as base including those materials having a relatively low flash-ignition temperature. These temperatures may include at or above 50 C, alternatively at or above 75 C, alternatively 100 C, or 125 C, or 150 C, or 200 C, or 300 C. ISO 871:2006 specifies a laboratory method for determining the flash-ignition temperature and spontaneous-ignition temperature of plastics using a hot-air furnace.

The exemplary base 305 as illustrated in the various Figures have a form factor which is substantially flat in an overall sense, such as comprising a sheet of a selected material (e.g., paper or plastic) which may be fed through a printing press, for example and without limitation, and which may have a topology on a first surface (or side) which includes surface roughness, cavities, channels or grooves or having a first surface which is substantially smooth within a predetermined tolerance (and does not include cavities, channels or grooves). Those having skill in the art will recognize that innumerable, additional shapes and surface topologies are available, are considered equivalent and within the scope of the disclosure.

One or more first conductors 310 are then applied or deposited (on a first side or surface of the base 305), such as through a printing process, to a thickness depending upon the type of conductive ink or polymer, such as to about 0.1 to 6 microns (e.g., about 3 microns for a typical silver ink, and to less than one micron for a nanosilver ink). In other exemplary embodiments, depending upon the applied thickness, the first conductors 310 also may be sanded to smooth the surface and also may be calendarized to compress the conductive particles, such as silver. In an exemplary method of manufacturing the exemplary apparatus 300, a conductive ink, polymer, or other conductive liquid or gel (such as a silver (Ag) ink or polymer, a nano silver ink composition, a carbon nanotube ink or polymer, or silver/carbon mixture such as amorphous nanocarbon (having particle sizes between about 75-100 nm) dispersed in a silver ink) is deposited on a base 305, such as through a printing or other deposition process, and may be subsequently cured or partially cured (such as through an ultraviolet (uv) curing process), to form the one or more first conductors 310. In another exemplary embodiment, the one or more first conductors 310 may be formed by sputtering, spin casting (or spin coating), vapor deposition, or electroplating of a conductive compound or element, such as a metal (e.g., aluminum, copper, silver, gold, nickel). Combinations of different types of conductors and/or conductive compounds or materials (e.g., ink, polymer, elemental metal, etc.) may also be utilized to generate one or more composite first conductors 310. Multiple layers and/or types of metal or other conductive materials may be combined to form the one or more first conductors 310, such as first conductors 310 comprising gold plate over nickel, for example and without limitation. For example, vapor-deposited aluminum or silver, or mixed carbon-silver inks, may be utilized. In various exemplary embodiments, a plurality of first conductors 310 are deposited, and in other embodiments, a first conductor 310 may be deposited as a single conductive sheet or otherwise attached (e.g., a sheet of aluminum coupled to a base 305) (not separately illustrated). Also in various embodiments, conductive inks or polymers which may be utilized to form the one or more first conductors 310 may not be cured or may be only partially cured prior to deposition of a plurality of diodes 100-100J, and then fully cured while in contact with the plurality of diodes 100-100J, such as for creation of ohmic contacts with the plurality of diodes 100-100J. In an exemplary embodiment, the one or more first conductors 310 are fully cured prior to deposition of the plurality of diodes 100-100J, with other compounds of the diode ink providing some dissolving of the one or more first conductors 310 which subsequently re-cures in contact with the plurality of diodes 100-100J.

Other conductive inks or materials may also be utilized to form the one or more first conductors 310, second conductor(s) 320, third conductors (not separately illustrated), and any other conductors discussed below, such as copper, tin, aluminum, gold, noble metals, carbon, carbon black, carbon nanotube (“CNT”), single or double or multi-walled CNTs, graphene, graphene platelets, nanographene platelets, nanocarbon and nanocarbon and silver compositions, nano silver compositions with good or acceptable optical transmission, or other organic or inorganic conductive polymers, inks, gels or other liquid or semi-solid materials. In an exemplary embodiment, carbon black (having a particle diameter of about 100 nm) is added to a silver ink to have a resulting carbon concentration in the range of about 0.025% to 0.1%, to enhance the ohmic contact and adhesion between the diodes 100-100J and the first conductors 310. In addition, any other printable or coatable conductive substances may be utilized equivalently to form the first conductor(s) 310, second conductor(s) 320 and/or third conductors, and exemplary conductive compounds include: (1) from Conductive Compounds (Londonberry, N.H., USA), AG-500, AG-800 and AG-510 Silver conductive inks, which may also include an additional coating UV-1006S ultraviolet curable dielectric (such as part of a first dielectric layer 125); (2) from DuPont, 7102 Carbon Conductor (if overprinting 5000 Ag), 7105 Carbon Conductor, 5000 Silver Conductor, 7144 Carbon Conductor (with UV Encapsulants), 7152 Carbon Conductor (with 7165 Encapsulant), and 9145 Silver Conductor; (3) from SunPoly, Inc., 128A Silver conductive ink, 129A Silver and Carbon Conductive Ink, 140A Conductive Ink, and 150A Silver Conductive Ink; (4) from Dow Corning, Inc., PI-2000 Series Highly Conductive Silver Ink; (5) from Henkel/Emerson & Cumings, Electrodag 725A; and (6) Monarch M120 available from Cabot Corporation of Boston, Mass., USA, for use as a carbon black additive, such as to a silver ink to form a mixture of carbon and silver ink. As discussed below, these compounds may also be utilized to form other conductors, including the second conductor(s) 320 and any other conductive traces or connections. In addition, conductive inks and compounds may be available from a wide variety of other sources.

Conductive polymers which are substantially optically transmissive may also be utilized to form the one or more first conductors 310, and also the second conductor(s) 320 and/or third conductors. For example, polyethylene-dioxithiophene may be utilized, such as the polyethylene-dioxithiophene commercially available under the trade name “Orgacon” from AGFA Corp. of Ridgefield Park, N.J., USA, in addition to any of the other transmissive conductors discussed below and their equivalents. Other conductive polymers, without limitation, which may be utilized equivalently include polyaniline and polypyrrole polymers, for example. In another exemplary embodiment, carbon nanotubes which have been suspended or dispersed in a polymerizable ionic liquid or other fluids are utilized to form various conductors which are substantially optically transmissive or transparent, such as one or more second conductors 320.

Organic semiconductors, variously called π-conjugated polymers, conducting polymers, or synthetic metals, are inherently semiconductive due to π-conjugation between carbon atoms along the polymer backbone. Their structure contains a one-dimensional organic backbone which enables electrical conduction following n− or p+ type doping. Well-studied classes of organic conductive polymers include poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, and polynaphthalene. Other examples include polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, and polynaphthalene derivatives, polyisothianaphthene (PITN), polyheteroarylenvinylene (ParV), in which the heteroarylene group can be, e.g., thiophene, furan or pyrrol, polyphenylene-sulphide (PPS), polyperinaphthalene (PPN), polyphthalocyanine (PPhc) etc., and their derivatives, copolymers thereof and mixtures thereof. As used herein, the term derivatives means the polymer is made from monomers substituted with side chains or groups.

The method for polymerizing the conductive polymers is not particularly limited, and the usable methods include uv or other electromagnetic polymerization, heat polymerization, electrolytic oxidation polymerization, chemical oxidation polymerization, and catalytic polymerization, for example and without limitation. The polymer obtained by the polymerizing method is often neutral and not conductive until doped. Therefore, the polymer is subjected to p-doping or n-doping to be transformed into a conductive polymer. The semiconductor polymer may be doped chemically, or electrochemically. The substance used for the doping is not particularly limited; generally, a substance capable of accepting an electron pair, such as a Lewis acid, is used. Examples include hydrochloric acid, sulfuric acid, organic sulfonic acid derivatives such as parasulfonic acid, polystyrenesulfonic acid, alkylbenzenesulfonic acid, camphorsulfonic acid, alkylsulfonic acid, sulfosalycilic acid, etc., ferric chloride, copper chloride, and iron sulfate.

It should be noted that for a “reverse” build of the apparatus 300, the base 305 and the one or more first conductors 310 are selected to be optically transmissive, for light to enter and/or exit through the second side of the base 305. In addition, when the second conductor(s) 320 are also transparent, light may be emitted or absorbed from or in both sides of the apparatus 300.

Various textures may be provided for the one or more first conductors 310, such as having a comparatively smooth surface, or conversely, a rough or spiky surface, or an engineered micro-embossed structure (e.g., available from Sappi, Ltd.) to potentially improve the adhesion of other layers (such as the dielectric layer 315 and/or to facilitate subsequent forming of ohmic contacts with diodes 100-100J. One or more first conductors 310 may also be given a corona treatment prior to deposition of the diodes 100-100J, which may tend to remove any oxides which may have formed, and also facilitate subsequent forming of ohmic contacts with the plurality of diodes 100-100J. Those having skill in the electronic or printing arts will recognize innumerable variations in the ways in which the one or more first conductors 310 may be formed, with all such variations considered equivalent and within the scope of the disclosure. For example, the one or more first conductors 310 may also be deposited through sputtering or vapor deposition, without limitation. In addition, for other various embodiments, the one or more first conductors 310 may be deposited as a single or continuous layer, such as through coating, printing, sputtering, or vapor deposition.

As a consequence, as used herein, “deposition” includes any and all printing, coating, rolling, spraying, layering, sputtering, plating, spin casting (or spin coating), vapor deposition, lamination, affixing and/or other deposition processes, whether impact or non-impact, known in the art. “Printing” includes any and all printing, coating, rolling, spraying, layering, spin coating, lamination and/or affixing processes, whether impact or non-impact, known in the art, and specifically includes, for example and without limitation, screen printing, inkjet printing, electro-optical printing, electroink printing, photoresist and other resist printing, thermal printing, laser jet printing, magnetic printing, pad printing, flexographic printing, hybrid offset lithography, Gravure and other intaglio printing, for example. All such processes are considered deposition processes herein and may be utilized. The exemplary deposition or printing processes do not require significant manufacturing controls or restrictions. No specific temperatures or pressures are required. Some clean room or filtered air may be useful, but potentially at a level consistent with the standards of known printing or other deposition processes. For consistency, however, such as for proper alignment (registration) of the various successively deposited layers forming the various embodiments, relatively constant temperature (with a possible exception, discussed below) and humidity may be desirable. In addition, the various compounds utilized may be contained within various polymers, binders or other dispersion agents which may be heat-cured or dried, air dried under ambient conditions, or IR or uv cured.

It should also be noted, generally for any of the applications of various compounds herein, such as through printing or other deposition, the surface properties or surface energies may also be controlled, such as through the use of resist coatings or by otherwise modifying the “wetability” of such a surface, for example, by modifying the hydrophilic, hydrophobic, or electrical (positive or negative charge) characteristics, for example, of surfaces such as the surface of the base 305, the surfaces of the various first or second conductors (310, 320, respectively), and/or the surfaces of the diodes 100-100J. In conjunction with the characteristics of the compound, suspension, polymer or ink being deposited, such as the surface tension, the deposited compounds may be made to adhere to desired or selected locations, and effectively repelled from other areas or regions.

For example and without limitation, the plurality of diodes 100-100J are suspended in a liquid, semi-liquid or gel carrier using any evaporative or volatile organic or inorganic compound, such as water, an alcohol, an ether, etc., which may also include an adhesive component, such as a resin, and/or a surfactant or other flow aid. In an exemplary embodiment, for example and without limitation, the plurality of diodes 100-100J are suspended as described above in the Examples. A surfactant or flow aid may also be utilized, such as octanol, methanol, isopropanol, or deionized water, and may also use a binder such as an anisotropic conductive binder containing substantially or comparatively small nickel beads (e.g., 1 micron) (which provides conduction after compression and curing and may serve to improve or enhance creation of ohmic contacts, for example), or any other uv, heat or air curable binder or polymer, including those discussed in greater detail below (and which also may be utilized with dielectric compounds, lenses, and so on).

In addition, the various diodes 100-100J may be configured, for example, as light emitting diodes having any of various colors, such as red, green, blue, yellow, amber, etc. Light emitting diodes 100-100J having different colors may then be mixed within an exemplary diode ink, such that when energized in an apparatus 300, 300A, a selected color temperature is generated.

Dried or Cured Diode Ink Example 1
A composition comprising:
a plurality of diodes 100-100J; and
a cured or polymerized resin or polymer.

Dried or Cured Diode Ink Example 2
A composition comprising:
a plurality of diodes 100-100J;
a cured or polymerized resin or polymer; and
at least trace amounts of a solvent.

Dried or Cured Diode Ink Example 3
A composition comprising:
a plurality of diodes 100-100J;
a cured or polymerized resin or polymer;
at least trace amounts of a solvent; and
at least trace amounts of a surfactant.

The diode ink (suspended diodes 100-100J) is then deposited over the one or more first conductors 310, such as by printing using a 280 mesh polyester or PTFE-coated screen, and the volatile or evaporative components are dissipated, such as through a heating, uv cure or any drying process, for example, to leave the diodes 100-100J substantially or at least partially in contact with and adhering to the one or more first conductors 310. In an exemplary embodiment, the deposited diode ink is cured at about 110° C., typically for 5 minutes or less. The remaining dried or cured diode ink, as in Dried or Cured Diode Ink Example 1, generally comprises a plurality of diodes 100-100J and a cured or polymerized resin or polymer (which, as mentioned above, generally secures or holds the diodes 100-100J in place). While the volatile or evaporative components (such as first and/or second solvents and/or surfactants) are substantially dissipated, trace or more amounts may remain, as illustrated in Dried or Cured Diode Ink Examples 2 and 3. As used herein, a “trace amount” of an ingredient should be understood to be an amount greater than zero and less than or equal to 5% of the amount of the ingredient originally present in the diode ink when initially deposited over the first conductors 310 and/or base 305.

The resulting density or concentration of diodes 100-100J, as the number of diodes 100-100J per square centimeter, for example, in the completed apparatus 300, 300A, 300B, will vary depending upon the concentration of diodes 100-100J in the diode ink. When the diodes 100-100J are in the range of 20-30 microns in size, very high densities are available which still cover only a small percentage of the surface area (one of the advantages allowing greater heat dissipation without a separate need for heat sinks). For example, when the diodes 100-100J are in the range of 20-30 microns in size are utilized, 10,000 diodes in a square inch covers only about 1% of the surface area. Also for example, in an exemplary embodiment, a wide variety of diode densities are available and within the scope of the disclosure, including without limitation: 2 to 10,000 diodes 100-100J per square centimeter are utilized in the apparatus 300, 300A, 300B; or more specifically, 5 to 10,000 diodes 100-100J per square centimeter are utilized in the apparatus 300, 300A, 300B; or more specifically, 5 to 1,000 diodes 100-100J per square centimeter are utilized in the apparatus 300, 300A, 300B; or more specifically, 5 to 100 diodes 100-100J per square centimeter are utilized in the apparatus 300, 300A, 300B; or more specifically, 5 to 50 diodes 100-100J per square centimeter are utilized in the apparatus 300, 300A, 300B; or more specifically, 5 to 25 diodes 100-100J per square centimeter are utilized in the apparatus 300, 300A, 300B; or more specifically, 10 to 8,000 diodes 100-100J per square centimeter are utilized in the apparatus 300, 300A, 300B; or more specifically, 15 to 5,000 diodes 100-100J per square centimeter are utilized in the apparatus 300, 300A, 300B; or more specifically, 20 to 1,000 diodes 100-100J per square centimeter are utilized in the apparatus 300, 300A, 300B; or more specifically, 25 to 100 diodes 100-100J per square centimeter are utilized in the apparatus 300, 300A, 300B; or more specifically, 25 to 50 diodes 100-100J per square centimeter are utilized in the apparatus 300, 300A, 300B.

Additional steps or several step processes may also be utilized for deposition of the diodes 100-100J over the one or more first conductors 310. Also for example and without limitation, a binder such as a methoxylated glycol ether acrylate monomer (which may also include a water soluble photoinitiator such TPO (triphosphene oxides)) or an anisotropic conductive binder may be deposited first, followed by deposition of the diodes 100-100J which have been suspended in a liquid or gel as discussed above.

In an exemplary embodiment, the suspending medium for the diodes 100-100J also comprises a dissolving solvent or other reactive agent, such as the one or more dibasic esters, which initially dissolves or re-wets some of the one or more first conductors 310. When the suspension of the plurality of diodes 100-100J is deposited and the surfaces of the one or more first conductors 310 then become partially dissolved or uncured, the plurality of diodes 100-100J may become slightly or partially embedded within the one or more first conductors 310, also helping to form ohmic contacts, and creating an adhesive bonding or adhesive coupling between the plurality of diodes 100-100J and the one or more first conductors 310. As the dissolving or reactive agent dissipates, such as through evaporation, the one or more first conductors 310 re-hardens (or re-cures) in substantial contact with the plurality of diodes 100-100J. In addition to the dibasic esters discussed above, exemplary dissolving, wetting or solvating agents, for example and without limitation, also as mentioned above, include proplyene glycol monomethyl ether acetate (C₆H₁₂O₃) (sold by Eastman under the name “PM Acetate”), used in an approximately 1:8 molar ratio (or 22:78 by weight) with 1-propanol (or isopropanol) to form the suspending medium, and a variety of dibasic esters, and mixtures thereof, such as dimethyl succinate, dimethyl adipate and dimethyl glutarate (which are available in varying mixtures from Invista under the product names DBE, DBE-2, DBE-3, DBE-4, DBE-5, DBE-6, DBE-9 and DBE-IB). In an exemplary embodiment, DBE-9 has been utilized. The molar ratios of solvents will vary based upon the selected solvents, with 1:8 and 1:12 being typical ratios. Various compounds or other agents may also be utilized to control this reaction: for example, the combination or mixture of 1-propanol and water may apparently suppress the dissolving or re-wetting of the one or more first conductors 310 by DBE-9 until comparatively later in the curing process when various compounds of the diode ink have evaporated or otherwise dissipated and the thickness of the diode ink is less than the height of the diodes 100-100J, so that any dissolved material (such as silver ink resin and silver ink particles) of the first conductors 310 are not deposited on the upper surface of the diodes 100-100J (which are then capable of forming electrical contacts with the second conductor(s) 320).

Dielectric Ink Example 1:
A composition comprising:
a dielectric resin comprising about 0.5% to about 30% methyl cellulose resin;
a first solvent comprising an alcohol; and
a surfactant.

Dielectric Ink Example 2:
A composition comprising:
a dielectric resin comprising about 4% to about 6% methyl cellulose resin;
a first solvent comprising about 0.5% to about 1.5% octanol;
a second solvent comprising about 3% to about 5% IPA; and
a surfactant.

Dielectric Ink Example 3:
A composition comprising:
about 10% to about 30% dielectric resin;
a first solvent comprising a glycol ether acetate;
a second solvent comprising a glycol ether; and
a third solvent.

Dielectric Ink Example 4:
A composition comprising:
about 10% to about 30% dielectric resin;
a first solvent comprising about 35% to 50% ethylene glycol monobutyl ether acetate;
a second solvent comprising about 20% to 35% dipropylene glycol monomethyl ether; and
a third solvent comprising about 0.01% to 0.5% toluene.

Dielectric Ink Example 5:
A composition comprising:
about 15% to about 20% dielectric resin;
a first solvent comprising about 35% to 50% ethylene glycol monobutyl ether acetate;
a second solvent comprising about 20% to 35% dipropylene glycol monomethyl ether; and
a third solvent comprising about 0.01% to 0.5% toluene.

Dielectric Ink Example 6:
A composition comprising:
about 10% to about 30% dielectric resin;
a first solvent comprising about 50% to 85% dipropylene glycol monomethyl ether; and
a second solvent comprising about 0.01% to 0.5% toluene.

Dielectric Ink Example 7:
A composition comprising:
about 15% to about 20% dielectric resin;
a first solvent comprising about 50% to 90% ethylene glycol monobutyl ether acetate; and
a second solvent comprising about 0.01% to 0.5% toluene.

An insulating material (referred to as a dielectric ink, such as those described as Dielectric Ink Examples 1-7) is then deposited over the diodes 100-100J or the peripheral or lateral portions of the diodes 100-100J to form an insulating or dielectric layer 315, such as through a printing or coating process, prior to deposition of second conductor(s) 320. The insulating or dielectric layer 315 may be comprised of any of the insulating or dielectric compounds suspended in any of various media, as discussed above and below. In an exemplary embodiment, insulating or dielectric layer 315 comprises a methyl cellulose resin, in an amount ranging from about 0.5% to 15%, or more specifically about 1.0% to about 8.0%, or more specifically about 3.0% to about 6.0%, or more specifically about 4.5% to about 5.5%, such as E-3 “methocel” available from Dow Chemical; with a surfactant in an amount ranging from about 0.1% to 1.5%, or more specifically about 0.2% to about 1.0%, or more specifically about 0.4% to about 0.6%, such as 0.5% BYK 381 from BYK Chemie GmbH; in a suspension with a first solvent in an amount ranging from about 0.01% to 0.5%, or more specifically about 0.05% to about 0.25%, or more specifically about 0.08% to about 0.12%, such as about 0.1% octanol; and a second solvent in an amount ranging from about 0.0% to 8%, or more specifically about 1.0% to about 7.0%, or more specifically about 2.0% to about 6.0%, or more specifically about 3.0% to about 5.0%, such as about 4% IPA, with the balance being a third solvent such as deionized water. With the E-3 formulation, four to five coatings are deposited, to create an insulating or dielectric layer 315 having a total thickness on the order of 6-10 microns, with each coating cured at about 110° C. for about five minutes. In other exemplary embodiments, the dielectric layer 315 may be IR (infrared) cured, uv cured, or both. Also in other exemplary embodiments, different dielectric formulations may be applied as different layers to form the insulating or dielectric layer 315; for example and without limitation, a first layer of a solvent-based clear dielectric available from Henkel Corporation of Dusseldorf, Germany is applied, such as Henkel BIK-20181-40A, Henkel BIK-20181-40B, and/or Henkel BIK-20181-24B followed by the water-based E-3 formulation described above, to form the dielectric layer 315. The dielectric layer 315 may be transparent but also may include a comparatively low concentration of light diffusing, scattering or reflective particles, as well as heat conductive particles such as aluminum oxide, for example and without limitation. In various exemplary embodiments, the dielectric ink will also de-wet from the upper surface of the diodes 100-100J, leaving at least some of the first terminal 125 or the second, back side of the diodes 100-100J (depending on the orientation) exposed for subsequent contact with the second conductor(s) 320.

Exemplary one or more solvents may be used in the exemplary dielectric inks, for example and without limitation: water; alcohols such as methanol, ethanol, N-propanol (including 1-propanol, 2-propanol (isopropanol)), isobutanol, butanol (including 1-butanol, 2-butanol), pentanol (including 1-pentanol, 2-pentanol, 3-pentanol), octanol; ethers such as methyl ethyl ether, diethyl ether, ethyl propyl ether, and polyethers; esters such ethyl acetate, dibasic esters (e.g., Invista DBE-9); glycols such as ethylene glycols, diethylene glycol, polyethylene glycols, propylene glycols, glycol ethers, glycol ether acetates, PM acetate (propylene glycol monomethyl ether acetate), dipropylene glycol monomethyl ether, ethylene glycol monobutyl ether acetate; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof. In addition to water-soluble resins, other solvent-based resins may also be utilized. One or more thickeners may be used, for example clays such as hectorite clays, garamite clays, organo-modified clays; saccharides and polysaccharides such as guar gum, xanthan gum; celluloses and modified celluloses such as hydroxylmethyl cellulose, methyl cellulose, methoxyl cellulose, carboxymethyl cellulose, hydroxyethyl cellulose and hydroxypropyl cellulose, cellulose ether, cellulose ethyl ether, chitosan; polymers such as acrylate and (meth)acrylate polymers and copolymers, polyvinyl pyrrolidone, polyethylene glycol, polyvinyl acetate (PVA), polyvinyl alcohols, polyacrylic acids, polyethylene oxides, polyvinyl butyral (PVB); diethylene glycol, propylene glycol, 2-ethyl oxazoline, fumed silica (such as Cabosil), silica powders and modified ureas such as BYK® 420 (available from BYK Chemie). Other viscosity modifiers may be used, as well as particle addition to control viscosity, as described in Lewis et al., Patent Application Publication Pub. No. US 2003/0091647. Flow aids or surfactants may also be utilized, such as octanol and Emerald Performance Materials Foamblast 339, for example. In other exemplary embodiments, one or more insulators 135 may polymeric, such as comprising PVA or PVB in deionized water, typically less than 12 percent.

Following deposition of insulating or dielectric layer 315, one or more second conductor(s) 320 are deposited (e.g., through printing a conductive ink, polymer, or other conductor such as metal), which may be any type of conductor, conductive ink or polymer discussed above, or may be an optically transmissive (or transparent) conductor, to form an ohmic contact with exposed or non-insulated portions of the diodes 100-100J. For example, an optically transmissive second conductor may be deposited as a single continuous layer (forming a single electrode), such as for lighting or photovoltaic applications. For a reverse build mentioned above, the second conductor(s) 320 do not need to be, although they can be, optically transmissive, allowing light to enter or exit from both top and bottom sides of the apparatus 300, 300A, 300B. An optically transmissive second conductor(s) 320 may be comprised of any compound which: (1) has sufficient conductivity to energize or receive energy from the first or upper portions of the apparatus 300 (and generally with a sufficiently low resistance or impedance to reduce or minimize power losses and heat generation, as may be necessary or desirable); and (2) has at least a predetermined or selected level of transparency or transmissibility for the selected wavelength(s) of electromagnetic radiation, such as for portions of the visible spectrum. The choice of materials to form the optically transmissive or non-transmissive second conductor(s) 320 may differ, depending on the selected application of the apparatus 300 and depending upon the utilization of optional one or more third conductors. The one or more second conductor(s) 320 are deposited over exposed and/or non-insulated portions of the diodes 100-100J, and/or also over any of the insulating or dielectric layer 315, such as by using a printing or coating process as known or may become known in the printing or coating arts, with proper control provided for any selected alignment or registration, as may be necessary or desirable.

In an exemplary embodiment, in addition to the conductors described above, carbon nanotubes (CNTs), nano silvers, polyethylene-dioxithiophene (e.g., AGFA Orgacon), a combination of poly-3,4-ethylenedioxythiophene and polystyrenesulfonic acid (marketed as Baytron P and available from Bayer AG of Leverkusen, Germany), a polyaniline or polypyrrole polymer, indium tin oxide (ITO) and/or antimony tin oxide (ATO) (with the ITO or ATO typically suspended as particles in any of the various binders, polymers or carriers previously discussed) may be utilized to form optically transmissive second conductor(s) 320. In an exemplary embodiment, carbon nanotubes are suspended in a volatile liquid with a surfactant, such as carbon nanotube compositions available from SouthWest NanoTechnologies, Inc. of Norman, Okla., USA. In addition, one or more third conductors (not separately illustrated) having a comparatively lower impedance or resistance is or may be incorporated into corresponding transmissive second conductor(s) 320. For example, to form one or more third conductors, one or more fine wires may be formed using a conductive ink or polymer (e.g., a silver ink, CNT or a polyethylene-dioxithiophene polymer) printed over corresponding sections or layers of the transmissive second conductor(s) 320, or one or more fine wires (e.g., having a grid or ladder pattern) may be formed using a conductive ink or polymer printed over a larger, unitary transparent second conductor(s) 320 in larger displays.

Other compounds which may be utilized equivalently to form substantially optically transmissive second conductor(s) 320 include indium tin oxide (ITO) as mentioned above, and other transmissive conductors as are currently known or may become known in the art, including one or more of the conductive polymers discussed above, such as polyethylene-dioxithiophene available under the trade name “Orgacon”, and various carbon and/or carbon nanotube-based transparent conductors. Representative transmissive conductive materials are available, for example, from DuPont, such as 7162 and 7164 ATO translucent conductor. Transmissive second conductor(s) 320 may also be combined with various binders, polymers or carriers, including those previously discussed, such as binders which are curable under various conditions, such as exposure to ultraviolet radiation (uv curable).

An optional stabilization layer 335 may be deposited over the second conductor(s) 320, as may be necessary or desirable, and is utilized to protect the second conductor(s) 320, such as to prevent the luminescent (or emissive) layers 325 or any intervening conformal coatings from degrading the conductivity of the second conductor(s) 320. One or more comparatively thin coatings of any of the inks, compounds or coatings discussed below (with reference to protective coating 330) may be utilized, such as Nazdar 9727 clear base. In addition, heat dissipation and/or light scattering particles may also be optionally included in the stabilization layer 335.

One or more luminescent (or emissive) layers 325 (e.g., comprising one or more phosphor layers or coatings) may be deposited over the stabilization layer 335 (or over the second conductor(s) 320 when no stabilization layer 335 is utilized). In an exemplary embodiment, such as an LED embodiment, one or more emissive layers 325 may be deposited, such as through printing or coating processes discussed above, over the entire surface of the stabilization layer 335 (or over the second conductor(s) 320 when no stabilization layer 335 is utilized). The one or more emissive layers 325 may be formed of any substance or compound capable of or adapted to emit light in the visible spectrum or to shift (e.g., stokes shift) the frequency of the emitted light (or other electromagnetic radiation at any selected frequency) in response to light (or other electromagnetic radiation) emitted from diodes 100-100J. For example, a yellow phosphor-based emissive layer 325 may be utilized with a blue light emitting diode 100-100J to produce a substantially white light. Such luminescent compounds include various phosphors, which may be provided in any of various forms and with any of various dopants. The luminescent compounds or particles forming the one or more emissive layers 325 may be utilized in or suspended in a polymer form having various binders, and also may be separately combined with various binders (such as phosphor binders available from DuPont or Conductive Compounds), both to aid the printing or other deposition process, and to provide adhesion of the phosphor to the underlying and subsequent overlying layers. The one or more emissive layers 325 may also be provided in either uv-curable or heat-curable forms.

A wide variety of equivalent luminescent or otherwise light emissive compounds are available and are within the scope of the disclosure, including without limitation: (1) G1758, G2060, G2262, G3161, EG2762, EG 3261, EG3560, EG3759, Y3957, EY4156, EY4254, EY4453, EY4651, EY4750, O5446, O5544, O5742, O6040, R630, R650, R6733, R660, R670, NYAG-1, NYAG-4, NYAG-2, NYAG-5, NYAG-3, NYAG-6, TAG-1, TAG-2, SY450-A, SY450-B, SY460-A, SY460-B, OG450-75, OG450-27, OG460-75, OG460-27, RG450-75, RG450-65, RG450-55, RG450-50, RG450-45, RG450-40, RG450-35, RG450-30, RG450-27, RG460-75, RG460-65, RG460-55, RG460-50, RG460-45, RG460-40, RG460-35, RG460-30, and RG460-27, available from Internatix of Fremont, Calif. USA; (2) 13C1380, 13D1380, 14C1220, and GG-84 available from Global Tungsten & Powders Corp. of Towanda, Pa., USA; (3) FL63/S-D1, HPL63/F-F1, HL63/S-D1, QMK58/F-U1, QUMK58/F-D1, KEMK63/F-P1, CPK63/N-U1, ZMK58/N-D1, and UKL63/F-U1 available from Phosphor Technology Ltd. of Herts, England; (4) BYW01A/PTCW01AN, BYW01B/PTCW01BN, BUVOR02, BUVG01, BUVR02, BUVY02, BUVG02, BUVR03/PTCR03, and BUVY03 available from Phosphor Tech Corp. of Lithia Springs, Ga., USA; and (5) Hawaii655, Maui535, Bermuda465, and Bahama560 available from Lightscape Materials, Inc. of Princeton, N.J. USA. In addition, depending upon the selected embodiment, colorants, dyes and/or dopants may be included within any such luminescent (or emissive) layer 325. In an exemplary embodiment, a yittrium aluminum garnet (“YAG”) phosphor is utilized, available from Phosphor Technology Ltd. and from Global Tungsten & Powders Corp. In addition, the phosphors or other compounds utilized to form an emissive layer 325 may include dopants which emit in a particular spectrum, such as green or blue. In those cases, the emissive layer may be printed to define pixels for any given or selected color, such as RGB or CMYK, to provide a color display. Those having skill in the art will recognize that any of the apparatus 300 embodiments may also comprise such one or more emissive layers 325 coupled to or deposited over the stabilization layer 335 or second conductor(s) 320.

The apparatus 300 may also include an optional protective or sealing coating 330, which may also include any type of lensing or light diffusion or dispersion structure or filter, such as a substantially clear plastic or other polymer, for protection from various elements, such as weather, airborn corrosive substances, etc., or such a sealing and/or protective function may be provided by the polymer (resin or other binder) utilized with the emissive layer 325. For ease of illustration, FIGS. 54, 56 and 57 illustrate such a polymer (resin or other binder) forming a protective or sealing coating 330 using the dotted lines to indicate substantial transparency.) In an exemplary embodiment, protective or sealing coating 330 is deposited as one or more conformal coatings using a urethane-based material such as a proprietary resin available as NAZDAR 9727 (www.nazdar.com) or a uv curable urethane acrylate PF 455 BC available from Henkel Corporation of Dusseldorf, Germany to a thickness of between about 10-40 microns. In another exemplary embodiment, protective or sealing coating 330 is performed by laminating the apparatus 300. Not separately illustrated, but as discussed in related U.S. Patent Applications (U.S. patent application Ser. No. 12/560,334, U.S. patent application Ser. No. 12/560,340, U.S. patent application Ser. No. 12/560,355, U.S. patent application Ser. No. 12/560,364, and U.S. patent application Ser. No. 12/560,371, incorporated in their entireties herein by reference with the same full force and effect as if set forth in their entireties herein), a plurality of lenses (suspended in a polymer (resin or other binder)) also may be deposited directly over the one or more emissive layers 325 and other features, to create any of the various light emitting apparatus 300 embodiments.

Those having skill in the art will recognize that any number of first conductors 310, insulators 315, second conductors 340, etc., be utilized within the scope of the claimed invention. In addition, there may be a wide variety of orientations and configurations of the plurality of first conductors 310, one or more of insulators (or dielectric layer) 315, and a plurality of second conductor(s) 320 (with any incorporated corresponding and optional one or more third conductors) for any of the apparatuses 300, such as substantially parallel orientations, in addition to the orientations illustrated. For example, a plurality of first conductors 310 may be all substantially parallel to each other, and a plurality of second conductor(s) 320 also may be all substantially parallel to each other. In turn, the plurality of first conductors 310 and plurality of second conductor(s) 320 may be perpendicular to each other (defining rows and columns), such that their area of overlap may be utilized to define a picture element (“pixel”) and may be separately and independently addressable. When either or both the plurality of first conductors 310 and the plurality of second conductor(s) 320 may be implemented as spaced-apart and substantially parallel lines having a predetermined width (both defining rows or both defining columns), they may also be addressable by row and/or column, such as sequential addressing of one row after another, for example and without limitation. In addition, either or both the plurality of first conductors 310 and the plurality of second conductor(s) 320 may be implemented as a layer or sheet as mentioned above.

As may be apparent from the disclosure, an exemplary apparatus 300, 300A, 300B, depending upon the choices of composite materials such as a base 305, may be designed and fabricated to be highly flexible and deformable, potentially even foldable, stretchable and potentially wearable, rather than rigid. For example, an exemplary apparatus 300, 300A, 300B, may comprise flexible, foldable, and wearable clothing, or a flexible lamp, or a wallpaper lamp, without limitation. With such flexibility, an exemplary apparatus 300, 300A, 300B, may be rolled, such as a poster, or folded like a piece of paper, and fully functional when re-opened. Also for example, with such flexibility, an exemplary apparatus 300, 300A, 300B, may have many shapes and sizes, and be configured for any of a wide variety of styles and other aesthetic goals. Such an exemplary apparatus 300, 300A, 300B, is also considerably more resilient than prior art devices, being much less breakable and fragile than, for example, a typical large screen television.

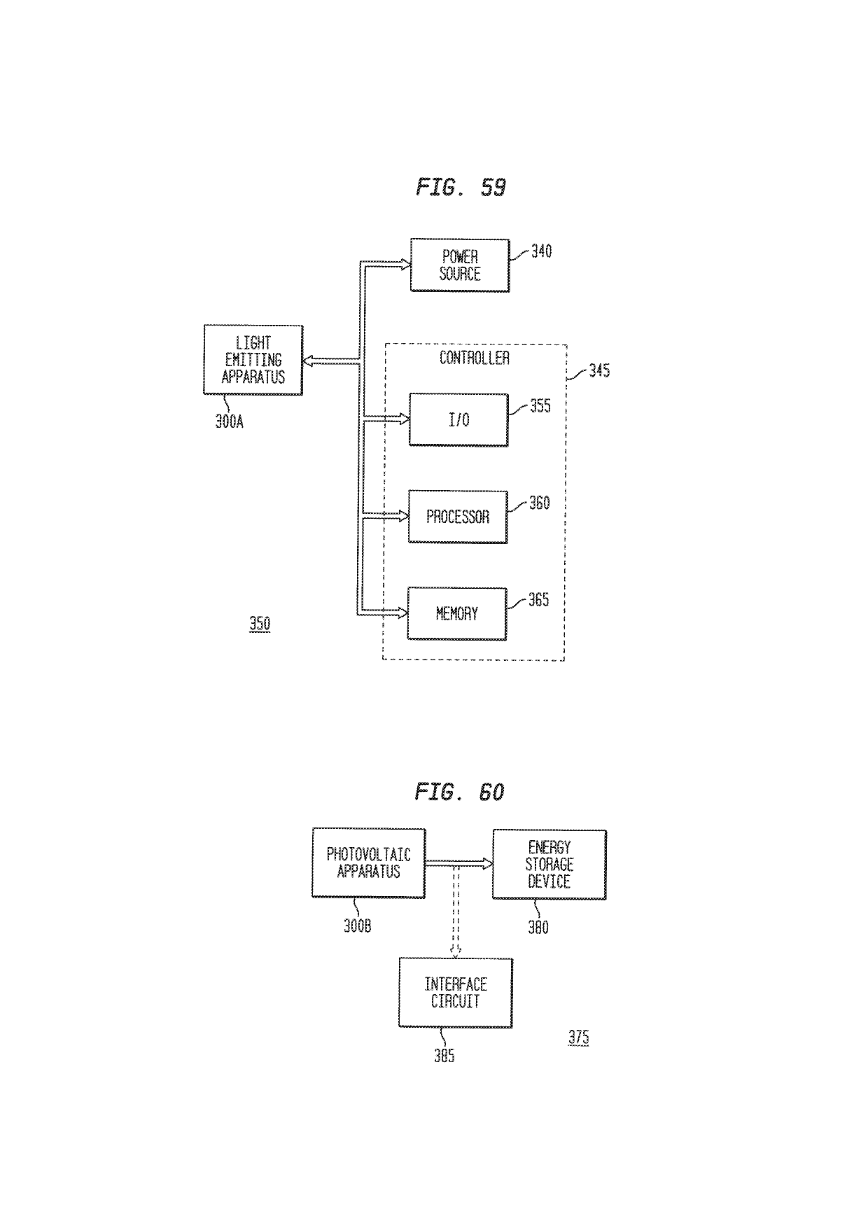

As indicated above, the plurality of diodes 100-100J may be configured (through material selection and corresponding doping) to be photovoltaic (PV) diodes or LEDs, as examples and without limitation. FIG. 59 is a block diagram of a first exemplary system 350 embodiment, in which the plurality of diodes 100-100J are implemented as LEDs, of any type or color. The system 350 comprises an apparatus 300A (which is otherwise generally the same as an apparatus 300 but having the plurality of diodes 100-100J implemented as LEDs), a power source 340, and may also include an optional controller (control logic circuit) 345. When one or more first conductors 310 and one or more second conductor(s) 320 are energized, such as through the application of a corresponding voltage (e.g., from power source 340), energy will be supplied to one or more of the plurality of LEDs (diodes 100-100J), either entirely across the apparatus 300A when the conductors and insulators are each implemented as single layers, or at the corresponding intersections (overlapping areas) of the energized first conductors 310 and second conductor(s) 320, which depending upon their orientation and configuration, define a pixel, a sheet, or a row/column, for example. Accordingly, by selectively energizing the first conductors 310 and second conductor(s) 320, the apparatus 300A (and/or system 350) provides a pixel-addressable, dynamic display, or a lighting device, or signage, etc. For example, the plurality of first conductors 310 may comprise a corresponding plurality of rows, with the plurality of transmissive second conductor(s) 320 comprising a corresponding plurality of columns, with each pixel defined by the intersection or overlapping of a corresponding row and corresponding column. When either or both the plurality of first conductors 310 and the plurality of second conductor(s) 320 may be implemented as illustrated in FIGS. 54-57, also for example, energizing of the conductors 310, 320 will provide power to substantially all (or most) of the plurality of LEDs (diodes 100-100J), such as to provide light emission for a lighting device or a static display, such as signage. Such a pixel count may be quite high, well above typical high definition levels.

Continuing to refer to FIG. 59, the apparatus 300A is coupled through lines or connectors (which may be two or more corresponding connectors or may also be in the form of a bus, for example) to a power source 340, which may be a DC power source (such as a battery or a photovoltaic cell) or an AC power source (such as household or building power), and also for coupling to an optional controller (or, equivalently, control logic block) 345. The power source 340 may be embodied in a wide variety of ways, such as a switching power supply for coupling to an AC line, and may include a wide variety of components (not separately illustrated) for controlling the energizing of the diodes 100-100J, for example and without limitation. When the controller 345 is implemented, such as for an addressable light emitting display system 350 embodiment and/or a dynamic light emitting display system 350 embodiment, the controller 345 may be utilized to control the energizing of the diodes 100-100J (via the various pluralities of first conductors 310 and the plurality of transmissive second conductor(s) 320) as known or becomes known in the electronic arts, and typically comprises a processor 360, a memory 365, and an input/output (I/O) interface 355. When the controller 345 is not implemented, such as for various lighting system 350 embodiments (which are typically non-addressable and/or a non-dynamic light emitting display system 350 embodiments), the system 350 is typically coupled to an electrical or electronic switch (not separately illustrated), which may comprise any suitable type of switching arrangement, such as for turning on, off, and/or dimming a lighting system.

A “processor” 360 may be any type of controller. processor or control logic circuit, and may be embodied as one or more processors 360, to perform the functionality discussed herein. As the term processor is used herein, a processor 360 may include use of a single integrated circuit (“IC”), or may include use of a plurality of integrated circuits or other components connected, arranged or grouped together, such as controllers, microprocessors, digital signal processors (“DSPs”), parallel processors, multiple core processors, custom ICs, application specific integrated circuits (“ASICs”), field programmable gate arrays (“FPGAs”), adaptive computing ICs, associated memory (such as RAM, DRAM and ROM), and other ICs and components. As a consequence, as used herein, the term processor should be understood to equivalently mean and include a single IC, or arrangement of custom ICs, ASICs, processors, microprocessors, controllers, FPGAs, adaptive computing ICs, or some other grouping of integrated circuits which perform the functions discussed below, with associated memory, such as microprocessor memory or additional RAM, DRAM, SDRAM, SRAM, MRAM, ROM, FLASH, EPROM or EPROM. A processor (such as processor 360), with its associated memory, may be adapted or configured (via programming, FPGA interconnection, or hard-wiring) to perform the methodology of the invention, such as selective pixel addressing for a dynamic display embodiment, or row/column addressing, such as for a signage embodiment. For example, the methodology may be programmed and stored, in a processor 360 with its associated memory (and/or memory 365) and other equivalent components, as a set of program instructions or other code (or equivalent configuration or other program) for subsequent execution when the processor is operative (i.e., powered on and functioning). Equivalently, when the processor 360 may implemented in whole or part as FPGAs, custom ICs and/or ASICs, the FPGAs, custom ICs or ASICs also may be designed, configured and/or hard-wired to implement the methodology of the invention. For example, the processor 360 may be implemented as an arrangement of processors, controllers, microprocessors, DSPs and/or ASICs, collectively referred to as a “controller” or “processor”, which are respectively programmed, designed, adapted or configured to implement the methodology of the invention, in conjunction with a memory 365.

A processor (such as processor 360), with its associated memory, may be configured (via programming, FPGA interconnection, or hard-wiring) to control the energizing of (applied voltages to) the various pluralities of first conductors 310 and the plurality of second conductor(s) 320 (and the optional one or more third conductors 145), for corresponding control over what information is being displayed. For example, static or time-varying display information may be programmed and stored, configured and/or hard-wired, in a processor 360 with its associated memory (and/or memory 365) and other equivalent components, as a set of program instructions (or equivalent configuration or other program) for subsequent execution when the processor 360 is operative.

The memory 365, which may include a data repository (or database), may be embodied in any number of forms, including within any computer or other machine-readable data storage medium, memory device or other storage or communication device for storage or communication of information, currently known or which becomes available in the future, including, but not limited to, a memory integrated circuit (“IC”), or memory portion of an integrated circuit (such as the resident memory within a processor 360), whether volatile or non-volatile, whether removable or non-removable, including without limitation RAM, FLASH, DRAM, SDRAM, SRAM, MRAM, FeRAM, ROM, EPROM or EPROM, or any other form of memory device, such as a magnetic hard drive, an optical drive, a magnetic disk or tape drive, a hard disk drive, other machine-readable storage or memory media such as a floppy disk, a CDROM, a CD-RW, digital versatile disk (DVD) or other optical memory, or any other type of memory, storage medium, or data storage apparatus or circuit, which is known or which becomes known, depending upon the selected embodiment. In addition, such computer readable media includes any form of communication media which embodies computer readable instructions, data structures, program modules or other data in a data signal or modulated signal, such as an electromagnetic or optical carrier wave or other transport mechanism, including any information delivery media, which may encode data or other information in a signal, wired or wirelessly, including electromagnetic, optical, acoustic, RF or infrared signals, and so on. The memory 365 may be adapted to store various look up tables, parameters, coefficients, other information and data, programs or instructions (of the software of the present invention), and other types of tables such as database tables.

As indicated above, the processor 360 is programmed, using software and data structures of the invention, for example, to perform the methodology of the present invention. As a consequence, the system and method of the present invention may be embodied as software which provides such programming or other instructions, such as a set of instructions and/or metadata embodied within a computer readable medium, discussed above. In addition, metadata may also be utilized to define the various data structures of a look up table or a database. Such software may be in the form of source or object code, by way of example and without limitation. Source code further may be compiled into some form of instructions or object code (including assembly language instructions or configuration information). The software, source code or metadata of the present invention may be embodied as any type of code, such as C, C++, SystemC, LISA, XML, Java, Brew, SQL and its variations, or any other type of programming language which performs the functionality discussed herein, including various hardware definition or hardware modeling languages (e.g., Verilog, VHDL, RTL) and resulting database files (e.g., GDSII). As a consequence, a “construct”, “program construct”, “software construct” or “software”, as used equivalently herein, means and refers to any programming language, of any kind, with any syntax or signatures, which provides or can be interpreted to provide the associated functionality or methodology specified (when instantiated or loaded into a processor or computer and executed, including the processor 360, for example).

The software, metadata, or other source code of the present invention and any resulting bit file (object code, database, or look up table) may be embodied within any tangible storage medium, such as any of the computer or other machine-readable data storage media, as computer-readable instructions, data structures, program modules or other data, such as discussed above with respect to the memory 365, e.g., a floppy disk, a CDROM, a CD-RW, a DVD, a magnetic hard drive, an optical drive, or any other type of data storage apparatus or medium, as mentioned above.

The I/O interface 355 may be implemented as known or may become known in the art, and may include impedance matching capability, voltage translation for a low voltage processor to interface with a higher voltage control bus for example, various switching mechanisms (e.g., transistors) to turn various lines or connectors on or off in response to signaling from the processor 360, and/or physical coupling mechanisms. In addition, the I/O interface 355 may also be adapted to receive and/or transmit signals externally to the system 350, such as through hard-wiring or RF signaling, for example, to receive information in real-time to control a dynamic display, for example.

For example, an exemplary first system embodiment 350 comprises an apparatus 300A, in which the plurality of diodes 100-100J are light emitting diodes, and an I/O interface 355 to fit any of the various standard Edison sockets for light bulbs. Continuing with the example and without limitation, the I/O interface 355 may be sized and shaped to conform to one or more of the standardized screw configurations, such as the E12, E14, E26, and/or E27 screw base standards, such as a medium screw base (E26) or a candelabra screw base (E12), and/or the other various standards promulgated by the American National Standards Institute (“ANSI”) and/or the Illuminating Engineering Society, also for example. In other exemplary embodiments, the I/O interface 355 may be sized and shaped to conform to a standard fluorescent bulb socket or a two plug base, such as a GU-10 base, also for example and without limitation. Such an exemplary first system embodiment 350 also may be viewed equivalently as another type of apparatus, particularly when having a form factor compatible for insertion into an Edison or fluorescent socket, for example and without limitation.

For example, an LED-based bulb may be formed having a design which resembles a traditional incandescent light bulb, having a screw-type connection as part of I/O 355, such as ES, E27, SES, or E14, which may be adapted to connect with any power socket type, including connection types selected from L1—dedicated low energy, PL—2 pin—dedicated low energy, PL—4 pin—dedicated low energy, G9 halogen capsule, G4 halogen capsule, GU10, GU5.3, bayonet, small bayonet, or any other connection known in the art.

In addition to the controller 345 illustrated in FIG. 41, those having skill in the art will recognize that there are innumerable equivalent configurations, layouts, kinds and types of control circuitry known in the art, which are within the scope of the present invention.

The apparatus 300 and first system 350 may be applied to a wide variety of articles, and may otherwise be adapted for many purposes. Nonlimiting examples of such articles and uses include lighting devices such as light bulbs, lighting tubes, lamps, lamp shades, task lighting, decorative lighting, bendable lighting, overhead lighting, safety lighting, “mood lighting”—which may or may not include dimmable lighting, colored lighting, and/or color-changeable lighting, drafting lighting, accent lighting, and display lighting—for example to illuminate wall art. The first system 350 will generally also include sufficient mechanical structures to support the illuminating elements of the apparatus 300, and may take the general shape of the type of light bulb or other lighting it is designed to replace.

The first system 350 having the apparatus 300 may provide various levels of light output. One method for managing output potential of the apparatus is to increase or decrease the concentration of the diodes 100-100J which are present on the one or more conductors 310 of the apparatus 300. Generally, the apparatus may provide light output of at least about 25 to 1300 lumens.

The small size of the diodes 100-100J embodied as LEDs provided herein allows for very fast dissipation of heat. Therefore, the first system 350 and apparatus 300 provide very efficient light output by minimizing heat generation. Accordingly, the apparatus 300 herein may be provided in the absence of a heat sink for the purpose of dissipating heat. Further, the apparatus 300 has an average operating temperature of less than about 150° C., or less than about 125° C., or less than about 100° C. or less than about 75° C., or less than about 50° C.

The term, “average operating temperature”, as used herein, is the temperature recorded according to the following steps:
1. The light emitting device or apparatus is turned on, such that it is providing its maximum lumen output for a period of at least 10 minutes. Therefore, any “warm up” period required to achieve maximum lumen output should be dismissed.
2. Ten temperature measurements are recorded in 10 minute increments using an infrared thermometer, such as a Raytek ST20XB® Handheld Infrared Thermometer. An average value of the recorded temperatures is calculated, and the calculated average is the “average operating temperature”.

Temperature measurement should be made under the following conditions:
1. Ambient temperature should be about 20° C.
2. The temperature measurement is measured directly on the outermost light-emissive surface of the device or apparatus.
3. The outermost light-emissive surface and light-emissive source (i.e., LED) are not separated by an intervening heat sink, insulating layer, or other heat-dissipating material.

As indicated above, the plurality of diodes 100-100J also may be configured (through material selection and corresponding doping) to be photovoltaic (PV) diodes. FIG. 60 is a block diagram of a second exemplary system 375 embodiment, in which the diodes 100-100J are implemented as photovoltaic (PV) diodes. The system 375 comprises an apparatus 300B (which is otherwise generally the same as an apparatus 300 but having the plurality of diodes 100-100J implemented as photovoltaic (PV) diodes), and either or both an energy storage device 380, such as a battery, or an interface circuit 385 to deliver power to an energy using apparatus or system or energy distributing apparatus or system, for example, such as a motorized device or an electric utility. (In other exemplary embodiments which do not comprise an interface circuit 385, other circuit configurations may be utilized to provide energy or power directly to such an energy using apparatus or system or energy distributing apparatus or system.) Within the system 375, the one or more first conductors 310 of an apparatus 300B are coupled to form a first terminal (such as a negative or positive terminal), and the one or more second conductor(s) 320 of the apparatus 300B are coupled to form a second terminal (such as a correspondingly positive or negative terminal), which are then couplable for connection to either or both an energy storage device 380 or an interface circuit 385. When light (such as sunlight) is incident upon the apparatus 300B, the light may be concentrated on one of more photovoltaic (PV) diodes 100-100J which, in turn, convert the incident photons to electron-hole pairs, resulting in an output voltage generated across the first and second terminals, and output to either or both an energy storage device 380 or an interface circuit 385.

It should be noted that when the first conductors 310 have the interdigitated or comb structure illustrated in FIG. 55, the second conductor 320 may be energized using first conductor 310B or, similarly, a generated voltage may be received across first conductors 310A and 310B.

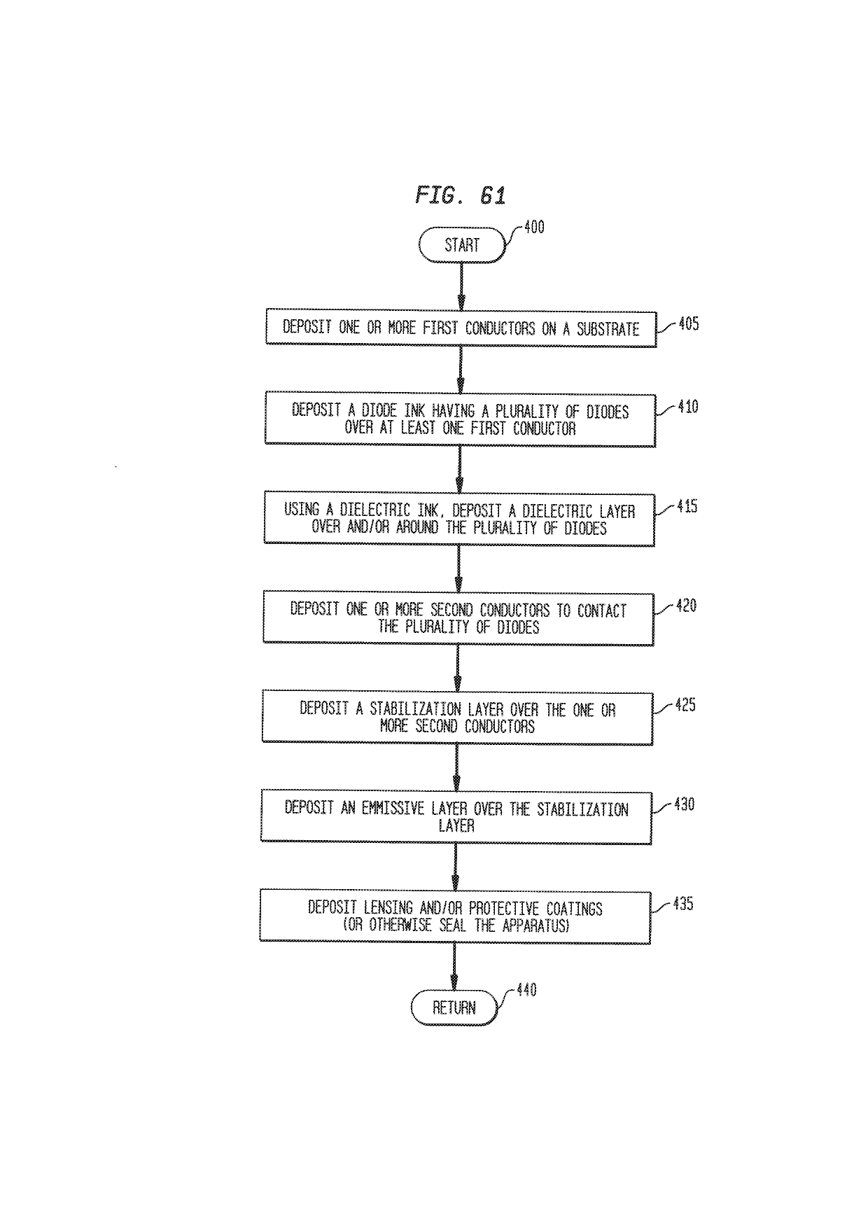

FIG. 61 is a flow diagram illustrating an exemplary method embodiment for apparatus 300, 300A, 300B fabrication, and provides a useful summary. Beginning with start step 400, deposits one or more first conductors (310) onto a base (305), such as by printing a conductive ink or polymer or vapor depositing, sputtering or coating the base (305) with one or more metals, followed by curing or partially curing the conductive ink or polymer, or potentially removing a deposited metal from unwanted locations, depending upon the implementation, step 405. A plurality of diodes 100-100J, having typically been suspended in a liquid, gel or other compound or mixture (e.g., suspended in diode ink), are then deposited over the one or more first conductors, step 410, also typically through printing or coating, to form an ohmic contact between the plurality of diodes 100-100J and the one or more first conductors (which may also involve various chemical reactions, compression and/or heating, for example and without limitation).

A dielectric or insulating material, such as a dielectric ink, is then deposited on or about the plurality of diodes 100-100J, such as about the periphery of the diodes 100-100J (and cured or heated), step 415, to form one or more insulators or dielectric layer 315. Next, one or more second conductors 320 (which may or may not be optically transmissive) are then deposited over and form contacts with the plurality of diodes 100-100J, such as over the dielectric layer 315 and about the upper surface of the diodes 100, 100A, 100B, 100C, and cured (or heated), step 420, also to form ohmic contacts between the one or more second conductors (320) and the plurality of plurality of diodes 100-100J. In exemplary embodiments, such as for an addressable display, a plurality of (transmissive) second conductors 320 are oriented substantially perpendicular to a plurality of first conductors 310. (Optionally, one or more third conductors may be deposited (and cured or heated) over the corresponding one or more (transmissive) second conductors).

As another option, before or during step 420, testing may be performed, with non-functioning or otherwise defective diodes 100-100J removed or disabled. For example, for PV diodes, the surface (first side) of the partially completed apparatus may be scanned with a laser or other light source and, when a region (or individual diode 100, 100A, 100B, 100C) does not provide the expected electrical response, it may be removed using a high intensity laser or other removal technique. Also for example, for light emitting diodes which have been powered on, the surface (first side) may be scanned with a photosensor, and, when a region (or individual diode 100-100J) does not provide the expected light output and/or draws excessive current (i.e., current in excess of a predetermined amount), it also may be removed using a high intensity laser or other removal technique. Depending upon the implementation, such as depending upon how non-functioning or defective diodes 100-100J are removed, such a testing step may be performed instead after steps 425, 430 or 435 discussed below. A stabilization layer 335 is then deposited over the one or more second conductors 320, step 425, followed by depositing an emissive layer 325 over the stabilization layer, step 430. A plurality of lenses (not separately illustrated), also typically having been suspended in a polymer, a binder, or other compound or mixture to form a lensing or lens particle ink or suspension, are then place or deposited over the emissive layer, also typically through printing, or a preformed lens panel comprising a plurality of lenses suspended in a polymer is attached to the first side of the partially completed apparatus (such as through a lamination process), followed by any optional deposition (such as through printing) of protective coatings (and/or selected colors), step 355, and the method may end, return step 440.

Given the low heat output of the present LED, in one embodiment, the apparatus is free of heat sinks and/or cooling fins and the like.

Given that the LED of the present invention may be printed on a variety of materials, the shapes and sizes of the “bulb” portion of the device are nearly endless. In one embodiment, the light emitting power consumption component comprises a substrate formed in the shape of a cone where LEDs on printed on the inside of the cone and the outside of the cone. In one iteration, the LEDs on the inside of the cone are activated to produce a “spot light” lightening effect. In a second iteration, the LEDs on the outside of the cone are activated to produce a “shading” or “diffuse” effect. In a third iteration, the LEDs on both the inside and outside of the cone are activated to produce the greatest amount of light.

Various configurations of power supply components and power consumption components are contemplated. The power supply component may include a track system and the power consumption component may include a LED light strip. The LED light strip may be detachably connected to the track system for receiving power and/or data. Alternatively, the power supply component may comprise a plug suitable for plugging into a wall socket and the light emitting power consumption component is a LED sheet, preferably a flexible sheet.

As previously discussed, the shapes and sizes of the “bulb” portion (i.e., the light emitting power consumption component, or the bulb assembly 702) of the device are nearly endless. For example, as illustrated in FIG. 65, the lighting device 700 may have a bulb assembly 702 that may include an illuminating element, such as a side wall 703, that is coupled to a bulb base 710 in a manner that will be described in more detail below. The side wall 703 comprises the LED composition previously described. As used herein, when a surface is described as illuminated or capable of illumination, the indicated surface comprises an LED composition. As will be described in more detail below, the front side, the back side, or both sides (as well as portions of the front and/or back sides) of the material comprising the side wall 703 may illuminate. The side wall 703 of the bulb assembly 702 may be formed from a single sheet of material or may be formed by two or more sheets of material that are electrically coupled in a manner that allows each of the individual sheets to collectively function as a single sheet of material. The two or more sheets of material may be secured to collectively form the side wall 703 by any method known in the art, including sonic welding, adhesives, or mechanical coupling, for example. The side wall 703, or any of the illuminating sheets or elements in the embodiments described below, may have a textured surface (not shown). The texturing process may be performed during the manufacturing of the illuminated sheet, or may be performed as a secondary operation on the manufactured sheet. The surface texture may have any appropriate surface roughness and or waviness. For example, the roughness of the surface texture may give the illuminating sheet the appearance of frosted glass when the sheet is not illuminated. Additionally, a transparent layer may be disposed on the surface of the illuminating sheets, and the thickness of the transparent layer may vary to provide a surface texture.

Still referring to FIG. 65, the side wall 703 of the bulb assembly 702 may include a top edge portion 704 having a diameter that is substantially equal to a diameter of a bottom edge portion 706 such that the side wall 703 forms a cylinder. The top edge portion 704 may be confined to a plane, and the plane may be substantially horizontal. So configured, the bulb assembly 702 may have external dimensions similar to conventional light bulbs to allow the bulb assembly 702 to be inserted into lighting devices that are designed to use conventional light bulbs. For example, the side wall 703 of the bulb assembly 702 illustrated in FIG. 65 may have a height H and an outer diameter D that are each substantially equal to the bulb height (excluding the screw base) and the maximum outer diameter of a conventional light bulb. More specifically, the side wall 703 of the bulb assembly 702 illustrated in FIG. 65 may have a height H and an outer diameter D that are each substantially equal to the bulb height (excluding the screw base) and the maximum outer diameter of an A19 incandescent light bulb—namely, approximately 3½ inches (88.9 mm) and approximately 2⅜ inches (60.3 mm) respectively. However, the height H and the outer diameter D may each have any suitable value, including values that do not correspond to the height H and/or the outer diameter D (or the maximum outer diameter) of a conventional light bulb.

Any number of variations of the shape and size of the side wall 703 of the bulb assembly 702 described above are contemplated. For example, the plane of the top edge portion 704 of the side wall 703 may be disposed at an angle relative to a horizontal reference plane, as illustrated in FIG. 66. Further still, as illustrated in FIG. 67, the top edge portion 704 may be comprised of two or more edge segments 712, and each of the two or more edge segments 712 may be disposed at a different angle than adjacent edge segments 712 to form, for example, a saw-tooth pattern. However, each of the two or more edge segments 712 may be identical such that a pattern is repeated. For example, each of the two or more edge segments 712 may have a semicircular shape or may have a sinusoidal shape, as illustrated in FIG. 68. Further embodiments may have a top edge portion 704 that may have any combination of repeating or non-repeating edge segments 712 that may form any shape or combination of shapes. The maximum height and outer diameter of any of the side walls 703 of the embodiments illustrated in FIGS. 66, 67, 68, or any of the embodiments described below may be substantially equal to the bulb height (excluding the screw base) and the maximum outer diameter of a conventional light bulb, such as the A19 light bulb, for example. However, the maximum height H and the maximum outer diameter D may each have any suitable value, including values that do not correspond to the height H and/or the outer diameter D (or the maximum outer diameter) of a conventional light bulb. The bulb assembly 702 may also include a covering element (not shown) that may be at least partially disposed over the side wall 703, and the covering element may be rigidly secured to the bulb base 710 to provide protection to the side wall 703. The covering element may be made from a clear plastic material, for example. Alternatively, the covering element may be made of any material, or have any shape, suitable for a particular application.

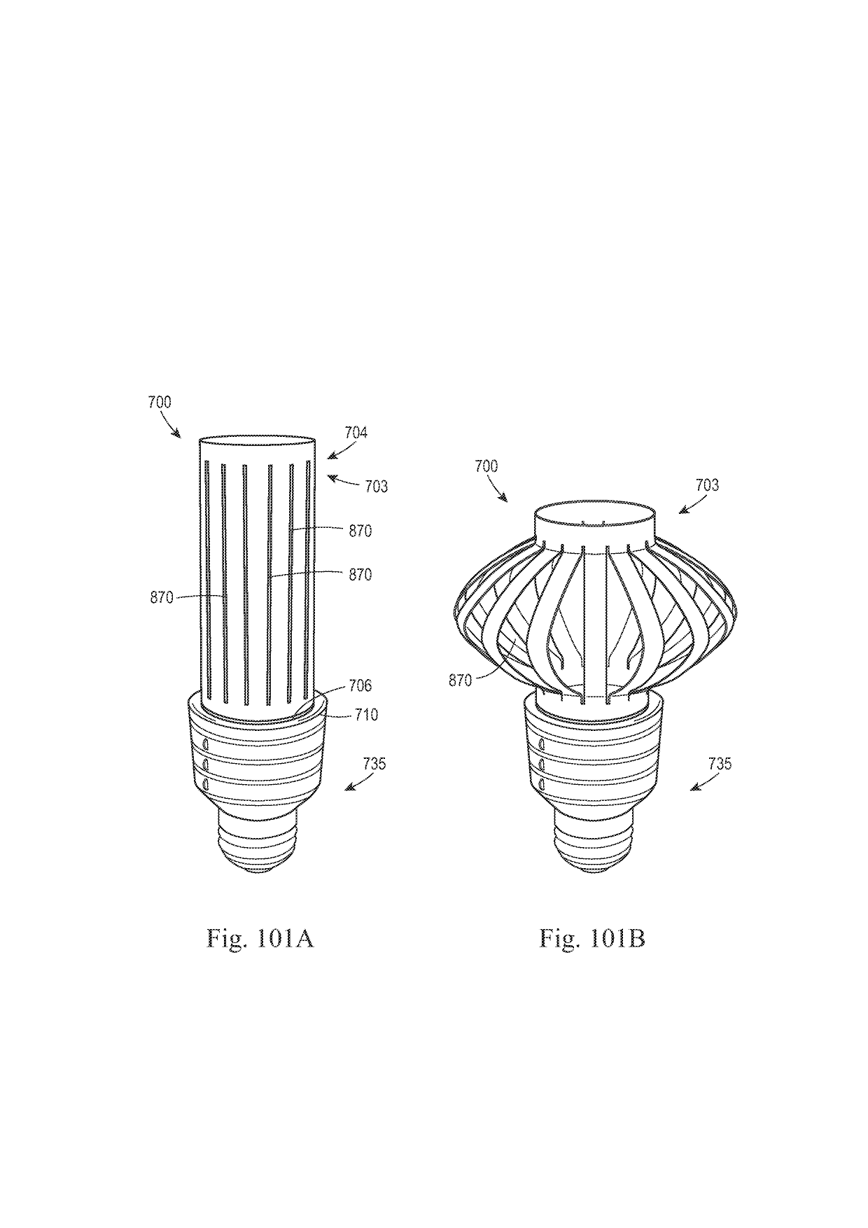

As illustrated in FIG. 101A, an embodiment of the side wall 703 may have a plurality of longitudinal slots 870 that may extend to a point adjacent to the top edge portion 704 and to a point adjacent to the bottom edge portion 706. As such, when the top edge portion 704 of the side wall 703 is displaced in a longitudinal direction towards the bottom edge portion 706, the portions of the side wall 703 disposed between the slots 870 outwardly flare in a radial direction, as illustrated in FIG. 101B. The side wall 703 may comprise a memory material that allows the outwardly flared portions of the side wall 703 to remain in a desired position. Alternatively, a support structure, such as a hub (not shown) that is slidably disposed about a central stem, may be used to maintain the side wall 703 in a desired position.

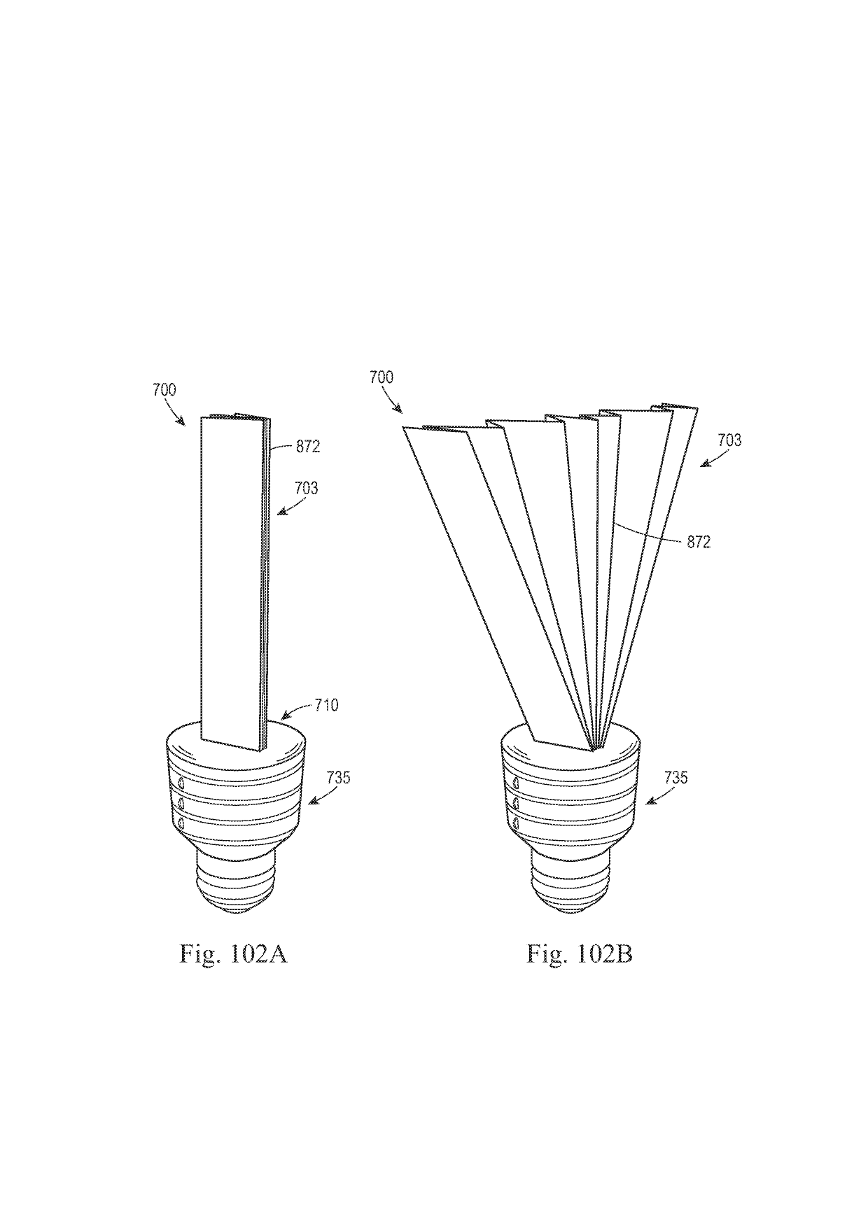

In a further embodiment illustrated in FIGS. 102A and 102B, the side wall 703 may be formed into a fan-like shape by a plurality of alternating folds 872, and a first end of the side wall 703 may be fixed to the bulb base 710 (or the base assembly 735). Accordingly, in a first position illustrated in FIG. 102A, the side wall 703 may extend in a relatively flat configuration along or parallel to the longitudinal axis of the bulb base 710. In a second position illustrated in FIG. 102B, the second end of the side wall 703 may be outwardly displaced relative to the first end, thereby giving the side wall 703 a fan-like shape. The side wall 703 may comprise a memory material that allows the side wall 703 to remain in a desired position. Alternatively, the outermost portions of the side wall 703 may be weighted to allow gravity to maintain the side wall 703 the fan-like shape. Any portion of the first and/or second side of the side wall 703 may be capable of illumination.

In an additional embodiment, the top edge portion 704 of the side wall 703 may define an opening 708 that may, for example, allow illumination generated on an interior surface 714 of the side wall 703 to be upwardly projected. However, as illustrated in FIG. 69, a substantially horizontal top surface 716 may intersect the top edge portion 704 of the side wall 703 such that the bulb assembly 702 does not have an opening 708. Alternatively, the top surface 716 may be inwardly offset from the top edge portion 704 such that a lip (not shown) extends in the axial direction beyond the top surface 716. In another embodiment of the bulb assembly 702, the top surface 716 may not be horizontal, but may instead be disposed at an angle relative to a horizontal reference plane. Alternatively, the top surface 716 may be contoured or have any other non-planar shape or combination of planar and/or non-planar shapes, for example. More specifically, the top surface may have a conical shape or a semi-spherical shape, for example. The top surface 716 may be coupled to the side wall 703 by an adhesive or by mechanical coupling, such as a tab/slot arrangement or by the use of a collar that attaches to one or more of the side wall 703 or the top surface 716, for example. Alternatively, the side wall 703 and the top surface 716 may be formed from a single piece of material such that the single piece of material can be folded to form both the side wall 703 and the top surface 716.

As shown in FIG. 70, the bulb assembly 702 may include a circumferential wall 718 that extends in an axial direction beyond the top edge portion 704 of the side wall 703 to intersect the top surface 716. The circumferential wall 718 may have any suitable shape, such a frustoconical shape or a rounded shape, for example. Moreover, instead of intersecting the top surface 716, the top edge of the circumferential wall 718 may define an opening 708, or the circumferential wall 718 may include an inwardly extending lip that defines an opening 708. The circumferential wall 718 may include a plurality of wall segments (not shown) that collectively comprise the circumferential wall 718, and the wall segments may be planar and/or contoured.

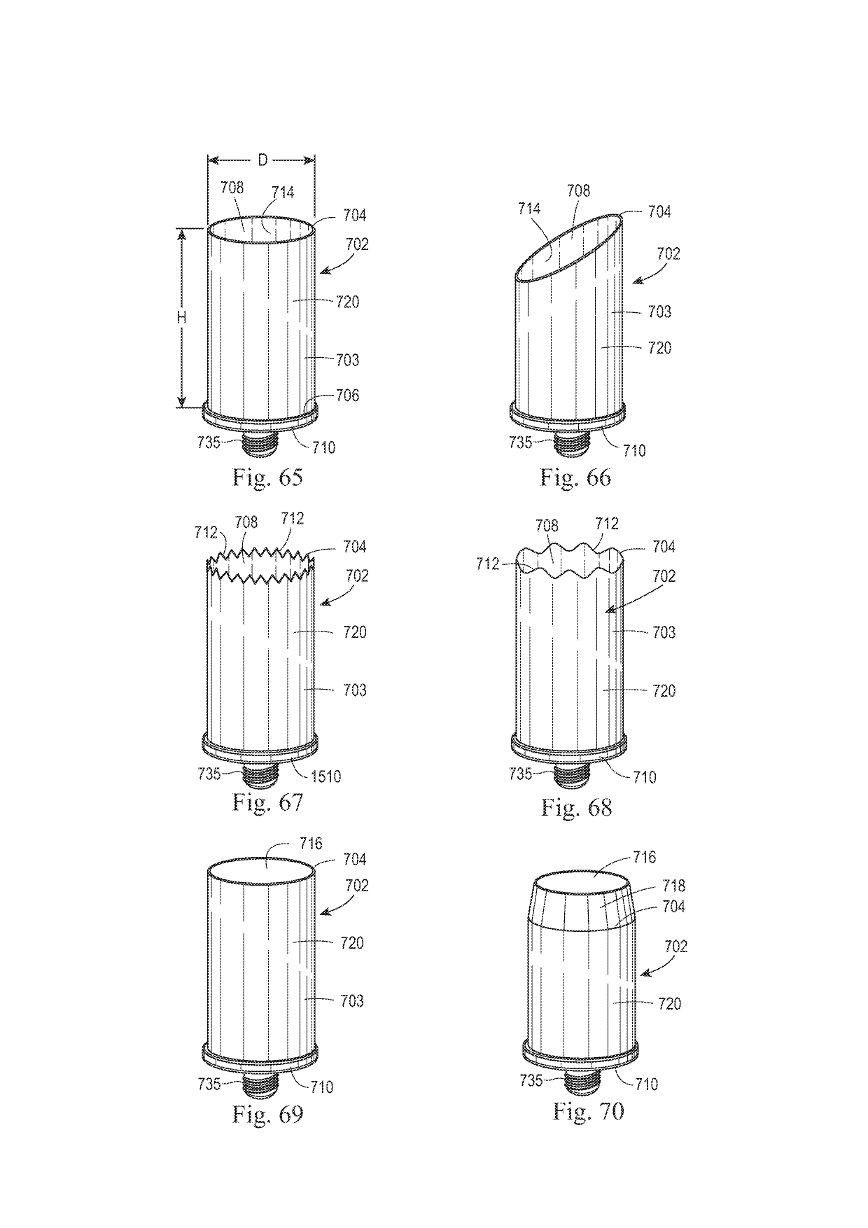

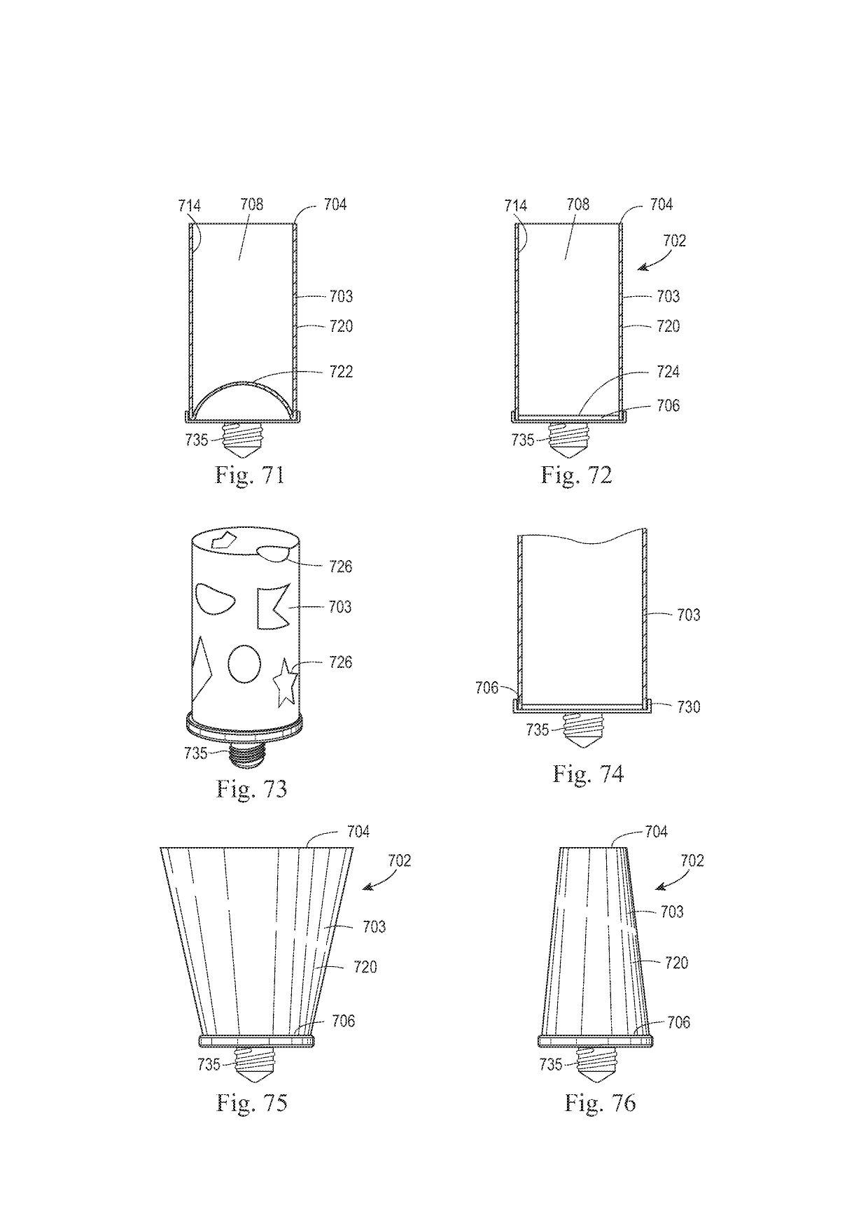

As will be described in more detail below, any portion of the side wall 703 of the bulb assembly 702 may illuminate. For example, in the embodiment illustrated in FIG. 65, an exterior surface 720 of side wall 703 may illuminate in a first color, and the interior surface 714 of the side wall 703 may illuminate in a second color. Alternatively, both the exterior surface 720 and the interior surface 714 may illuminate in the same color. In another embodiment, only the interior surface 714 illuminates. In this configuration, illustrated in FIG. 71, a reflective surface 722 may be disposed in the interior of the cylinder formed by the side wall 703 adjacent to the bulb base 710, and the reflective surface 722 may have a substantially parabolic shape to reflect inwardly directed light from the interior surface 714 of the side wall 703 out of the opening 708. Instead of the parabolic shape shown above, the reflective surface 422 may have any suitable shape or combination of shapes, such as planar, ellipsoidal, hyperbolic, or faceted, for example. Instead of a reflective surface 722, the bulb assembly 702 may include an interior insert 724 that may illuminate to project directed light through the opening 708, as illustrated in FIG. 72. The interior insert 724 may be planar and may be disposed adjacent to, or contacting, the bottom edge portion 706 of the side wall 703. However, the interior insert 724 may be disposed at any axial location in the interior of the side wall 703, and the interior insert 724 may have any shape or combination of shapes suitable to direct light through the opening 708. The interior insert 724, or the reflective surface 722, may have an outer diameter that is slightly smaller than the diameter of the interior surface 714 of the side wall 703. For example, if the outer diameter D of the side wall 703 corresponds to the maximum outer diameter of an A19 incandescent light bulb approximately 2% inches (60.3 mm)—the outer diameter of the interior insert 724 or the reflective surface 722 may be approximately 2¼ inches (57.2 mm). However, the interior insert 724, or the reflective surface 722, may have any diameter. In further a embodiment of the bulb assembly 702, two of more interior inserts 724 may be disposed within the side wall 703, and the interior inserts 724 may have any shape or size suitable for a particular application. Similarly, two of more reflective surfaces 722 may be disposed within the side wall 703, and the reflective surfaces 722 may have any shape or size suitable for a particular application. Additionally, a combination of reflective surfaces 722 and interior inserts 724 may be disposed in the interior of the side wall 703.

As illustrated in FIG. 73, one or more windows 726 may be disposed any or both of the side wall 703 and the top surface 716. Each of the one or more windows 726 may have any shape or combination of shapes, such as that shape of a star, an oval, a circle, or a polygon. Additionally, one of more of the windows 726 may take the shape of letters, symbols, logos, words, or numbers. In an embodiment of the bulb assembly 702, one or more windows 726 may be disposed on the side wall 703, and the side wall 703 may be illuminated on the interior surface 714 only. The total surface area of the one or more windows 726 may comprise a percentage of the overall available surface area of the side wall 703 (i.e., the total surface area of the side wall 703 if no windows 726 were present), and this percentage may be any suitable value. For example, the total surface area of the windows 726 illustrated in FIG. 73 may comprise 25% the overall available surface area of the side wall 703.

As briefly discussed above, the bottom edge portion 706 of the side wall 703 may be coupled to a bulb base 710, which will be described in more detail below, by any manner known in the art, such as by an adhesive or a mechanical coupling, for example. More specifically, as illustrated in FIG. 74, a portion of the side wall 703 adjacent to the bottom edge portion 706 may be adhesively secured to an upwardly-projecting circumferential ridge 730 of the bulb base 710. As shown, an interior surface of the ridge 730 may be adhesively coupled to the exterior surface 720 of the side wall 703, but an exterior surface of the ridge 730 may be adhesively coupled to the interior surface 714 of the side wall 703. Alternatively, tabs (not shown) extending from the bottom edge portion 706 of the side wall 703 may be received into elongated slots (not shown) formed on a surface of the bulb base 710. In addition, one or more inwardly-directed features, such as a post or a stub, may project from an interior surface of the bulb base 710, and each inwardly-directed feature of the bulb base 710 may be received into an aperture disposed adjacent to the bottom edge portion 706 of the side wall 703. In an alternate embodiment, one or more plastic tabs (not shown) may be secured to side wall 703 adjacent the bottom edge portion 706 by any means known in the art, such as by adhesives or by mechanical fastening, and the plastic tabs may be received into tab slots (not shown) formed in the bulb base 710. In a further embodiment of the bulb assembly 702, a collar (not shown) may be coupled to the bulb base 710 in a manner that secures a portion of the side wall 703, such as, for example, an outwardly-extending tab disposed adjacent to the bottom edge portion 706 of the side wall 703. The collar may be coupled to the bulb base 710 by a tab/slot connection or by a threaded connection, for example.

As will be described in more detail below, the side wall 703 (and the top surface 716 and circumferential wall 718) may be electrically coupled to the bulb base 710 by any means known in the art. For example, one or more male pins or blades may downwardly project from the bottom edge portion 706 of the side wall 703, and the male pins or blades may be received into receptacles or slots formed in the bulb base.

In the embodiment illustrated in FIG. 84, the side wall 703 may be removably placed on the bulb base 710, which is integrally formed with a base assembly 735. As will be described in more detail below, the base assembly 735 is adapted to couple to any source of power to allow the side wall 703 to illuminate. For example, as illustrated in FIG. 84, the base assembly 735 includes a lower portion having an Edison screw for coupling to a power source. The side wall 703 of the bulb assembly 702 may have a truncated converging frustoconical shape, and a circumferential conducting strip 738 may be disposed adjacent to the bottom edge portion 706 of the side wall 703. The diameter of the bottom edge portion 706 and the top edge portion 704 of the side wall 703 may have any value, with the diameter of the bottom edge portion 706 being greater than the diameter of the top edge portion 704. For example, the diameter of the bottom edge portion 706 may be approximately equal to the maximum outer diameter of an A19 incandescent light bulb—approximately 2% inches (60.3 mm), and the diameter of the top edge portion 704 may be approximately 1¾ inches (44.5 mm). The bulb base 710 may have a truncated converging frustoconical shape that generally corresponds to the shape of the side wall 703 such that the interior surface 714 of the side wall 703 adjacent to the bottom edge portion 706 may snugly fit over a circumferential exterior surface 740, thereby coupling the side wall 703 to the bulb base 710. The bulb base 710 may have a maximum outer diameter that is any suitable value. For example, the maximum outer diameter may be approximately equal to or slightly larger than the diameter of the bottom edge portion 706. In addition, one or more magnets may be disposed on the bulb base 710 and the side wall 703 to mutually secure the side wall 703 to the bulb base 710. Alternatively, one or more ridges (or detents) may be formed on one of the side wall 703, and the one or more ridges may engage corresponding ridges (or detents) formed on the bulb base 710. So assembled, a conducting strip 742 disposed around the circumference of the bulb base 710 may contact the conducting strip 738 disposed on the side wall 703 such that the side wall 703 is electrically coupled to the bulb base 710.

In a further embodiment illustrated in FIG. 75, the side wall 703 of the bulb assembly 702 may have a substantially diverging frustoconical shape instead of the cylindrical shape illustrated in FIG. 65. More specifically, the side wall 703 may include a top edge portion 704 having a diameter that is greater than the diameter of a bottom edge portion 706. For example, the diameter of the top edge portion 704 may be approximately equal to the maximum outer diameter of an A19 incandescent light bulb—approximately 2% inches (60.3 mm), and the diameter of the bottom edge portion 706 may be approximately 1¾ inches (44.5 mm). However, other than the difference in the shape of the side wall 703, the bulb assembly 702 of FIG. 75 may be substantially identical to the embodiment of the bulb assembly 702 illustrated in FIG. 65, and the bulb assembly 702 of FIG. 75 may include any or all of the features of the embodiment of FIG. 65 that are discussed above. For example, as illustrated in FIG. 75, the top edge portion 704 of the frustoconically-shaped side wall 703 may be confined to a plane, and the plane may be substantially horizontal. Alternatively, the plane may be disposed at an angle relative to a horizontal reference plane, similar to the embodiment illustrated in FIG. 66. In addition, the embodiment of the bulb assembly 702 having a frustoconically-shaped side wall 703 may also include, for example, edge segments 712 along the top edge portion 704, a circumferential wall 718, a reflective surface 722, and interior insert 724, and/or one or more windows 726. Moreover, the functionality of the embodiment of the bulb assembly 702 having a frustoconically-shaped side wall 703 may be identical to the functionality of the embodiment of the bulb assembly 702 illustrated in FIG. 65 that is discussed above. For example, any or both of the interior surface 714 or the exterior surface 720 of the side wall may illuminate in the manner discussed above.

In a further embodiment illustrated in FIG. 76, the side wall 703 of the bulb assembly 702 may have a substantially converging frustoconical shape instead of the cylindrical shape illustrated in FIG. 65. More specifically, the side wall 703 may include a top edge portion 704 having a diameter that is less than the diameter of a bottom edge portion 706. For example, the diameter of the bottom edge portion 706 may be approximately equal to the maximum outer diameter of an A19 incandescent light bulb—approximately 2% inches (60.3 mm), and the diameter of the top edge portion 704 may be approximately 1¾ inches (44.5 mm). However, other than the difference in the shape of the side wall 703, the bulb assembly 702 of FIG. 76 may be substantially identical to the embodiment of the bulb assembly 702 illustrated in FIG. 65, and the bulb assembly 702 of FIG. 76 may include any or all of the features of the embodiment of FIG. 65 that are discussed above. For example, as illustrated in FIG. 76, the top edge portion 704 of the frustoconically-shaped side wall 703 may be confined to a plane, and the plane may be substantially horizontal. Alternatively, the plane may be disposed at an angle relative to a horizontal reference plane, similar to the embodiment illustrated in FIG. 66. In addition, the embodiment of the bulb assembly 702 having a frustoconically-shaped side wall 703 may also include, for example, edge segments 712 along the top edge portion 704, a circumferential wall 718, a reflective surface 722, and interior insert 724, and/or one or more windows 726. Moreover, the functionality of the embodiment of the bulb assembly 702 having a frustoconically-shaped side wall 703 may be identical to the functionality of the embodiment of the bulb assembly 702 illustrated in FIG. 65 that is discussed above. For example, any or both of the interior surface 714 or the exterior surface 720 of the side wall may illuminate in the manner discussed above.

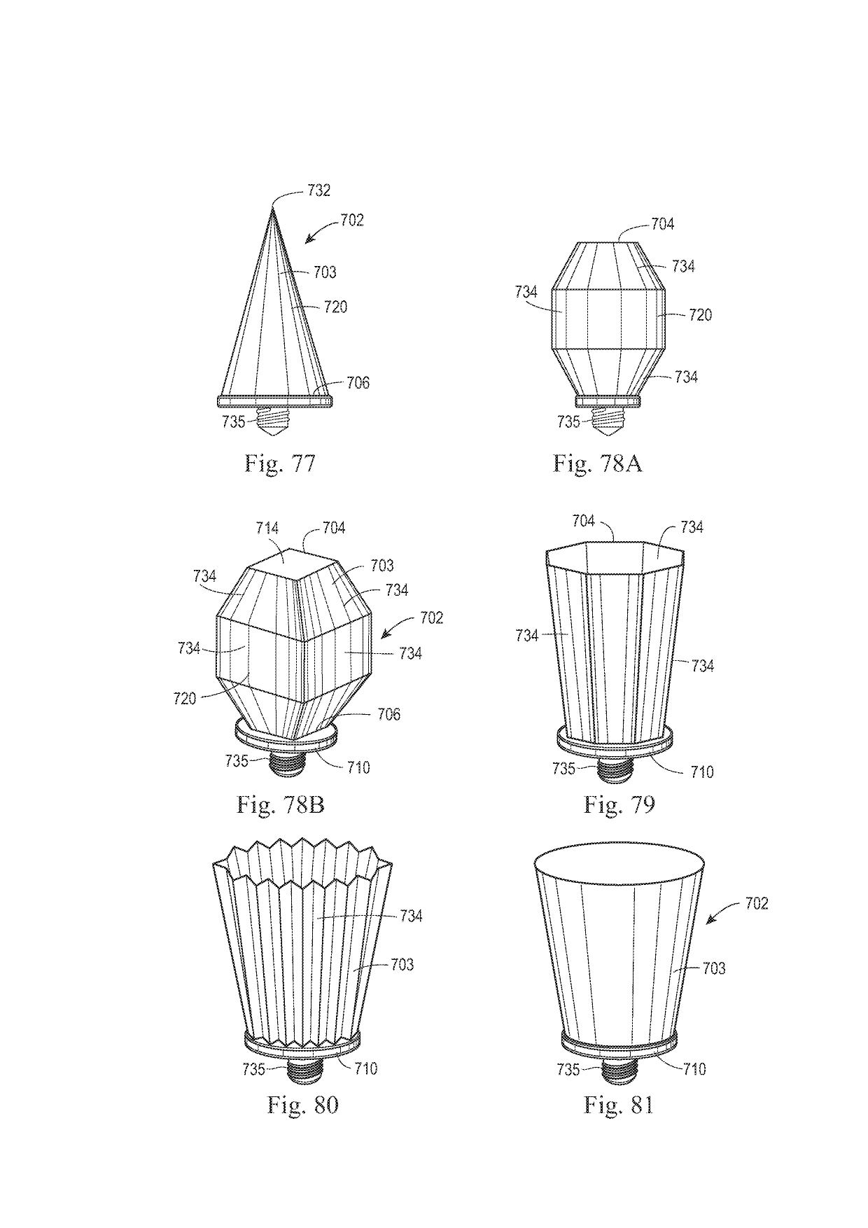

In a still further embodiment illustrated in FIG. 77, the side wall 703 of the bulb assembly 702 may have a substantially conical shape instead of the converging frustoconical shape described above. More specifically, the cross-sectional diameter of the side wall 703 may constantly reduce in an axial direction from the bottom edge portion 706 to a tip 732 disposed at the topmost portion of the side wall 703. The height and diameter of the cone may have any suitable values. For example, the diameter of the bottom edge portion 706 may be approximately equal to the maximum outer diameter of an A19 incandescent light bulb—approximately 2% inches (60.3 mm), and the height of the cone may be approximately equal to the height of an A19 incandescent light bulb—approximately 3½ inches (88.9 mm). Other than the difference in the shape of the side wall 703, the bulb assembly 702 of FIG. 77 may be substantially identical to the embodiment of the bulb assembly 702 illustrated in FIGS. 65 and 76. For example, the embodiment of the bulb assembly 702 having a conically-shaped side wall 703 may also include one or more windows 726. Moreover, the functionality of the embodiment of the bulb assembly 702 having a conically-shaped side wall 703 may be identical to the functionality of the embodiment of the bulb assembly 702 illustrated in FIG. 65 that is discussed above. For example, any or both of the interior surface 714 or the exterior surface 720 of the side wall may illuminate in the manner discussed above.

In a further embodiment illustrated in FIGS. 78A and 78B, the side wall 703 of the bulb assembly 702 may be comprised of a plurality of faceted surfaces 734. The side wall 703 may include any number of faceted surfaces 734, and the side wall 703 may take on any overall shape. For example, as illustrated in FIGS. 78A and 78B, a top portion of the side wall 703 may take the shape of a truncated converging pyramid, an intermediate portion of the side wall 703 may take the shape of a cube, and a lower portion of the side wall 703 may take the shape of a truncated diverging pyramid. However, other than the difference in the shape of the side wall 703, the bulb assembly 702 of FIGS. 78A and 78B may be substantially identical to the embodiment of the bulb assembly 702 illustrated in FIG. 65, and the bulb assembly 702 of FIGS. 78A and 78B may include any or all of the features of the embodiment of FIG. 65 that are discussed above. For example, as illustrated in FIGS. 78A and 78B, the top edge portion 704 of the frustoconically-shaped side wall 703 may be confined to a plane, and the plane may be substantially horizontal. In addition, the embodiment of FIGS. 78A and 78B may also include, for example, edge segments 712 along the top edge portion 704, a circumferential wall 718, a reflective surface 722, and interior insert 724, and/or one or more windows 726. Moreover, the functionality of the embodiment of the bulb assembly 702 of FIGS. 78A and 78B may be identical to the functionality of the embodiment of the bulb assembly 702 illustrated in FIG. 65 that is discussed above. For example, any or both of the interior surface 714 or the exterior surface 720 of the side wall may illuminate in the manner discussed above.

In a further embodiment of a bulb assembly 702 having faceted surfaces 734, the faceted surfaces 734 illustrated in FIG. 79 of the side wall 703 may form a converging, truncated conical shape that may be substantially identical to the embodiment of FIG. 75 having a diverging frustoconically-shaped side wall 703. Alternatively, the faceted surfaces illustrated in FIG. 79 may be substantially horizontal such that the cross-section shape of the side wall 703 is constant along the longitudinal axis of the side wall 703. Further, as illustrated in FIG. 80, the side wall 703 may include longitudinally disposed faceted surfaces 734 that are disposed at an angle relative to adjacent faceted surfaces 734, and the longitudinally disposed faceted surfaces 734 may be vertical or may be disposed at an angle relative to a vertical reference axis so as to converge or diverge as the side wall 703 axially extends away from the bulb base 710. Although the faceted surfaces above are substantially planar, one or more of the faceted surfaces 734 may be contoured, curved, or otherwise non-planar. In any of embodiments discussed above, the maximum outer diameter and the overall height of the side wall 703 may have any value. For example, the maximum outer diameter of the side wall 703 may be approximately equal to the maximum outer diameter of an A19 incandescent light bulb—approximately 2% inches (60.3 mm), and the overall height of the side wall 703 may be approximately equal to the maximum height of an A19 incandescent light bulb—approximately 3½ inches (88.9 mm).

In a still further embodiment of the bulb assembly 702, the side wall 703 may have the shape of an oval, as shown in FIG. 81, or any other non-circular shape. Such a non-circular shape may be substantially cylindrical or may converge towards the bulb base 710 or diverge away from the bulb base 710. In addition, the side wall 703 may have a cross-sectional shape that may include both planar and curved surfaces. Moreover, the side wall 703 may have a non-uniform cross-sectional shape such that the cross-sectional shape changes along the longitudinal and he is a well-known and is and that no one will axis of the side wall 703. For example, as illustrated in FIG. 83, the side wall may have a substantially spiral shape, and the interior surface 714 of the side wall 703 may illuminate in a first color and the exterior surface 720 may illuminate in a second color. In an alternative embodiment, the spiral-shaped side wall 703 may be formed from a sheet having a circular, ovular, or other rounded shape, as illustrated in FIG. 110. Other than the difference in the shape of the side wall 703, the bulb assembly 702 of FIGS. 81 and 83 may be substantially identical to the embodiment of the bulb assembly 702 illustrated in FIG. 65, and the bulb assembly 702 of FIGS. 81 and 83 may include any or all of the features of the embodiments that are discussed above. In any of embodiments discussed above, the maximum outer diameter and the overall height of the side wall 703 may have any value. For example, the maximum outer diameter of the side wall 703 may be approximately equal to the maximum outer diameter of an A19 incandescent light bulb—approximately 2% inches (60.3 mm), and the overall height of the side wall 703 may be approximately equal to the maximum height of an A19 incandescent light bulb—approximately 3½ inches (88.9 mm).

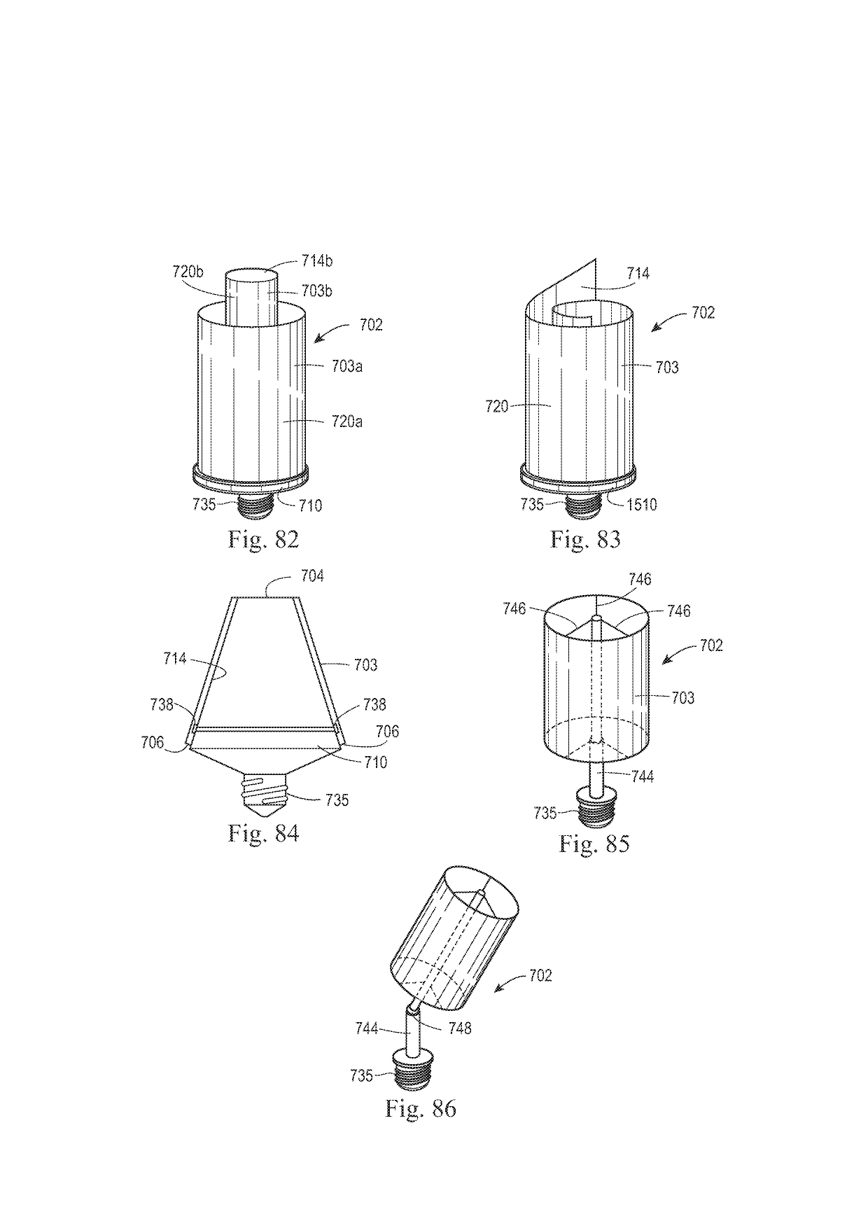

In a still further embodiment illustrated in FIG. 82, more than one side wall 703 may be included in the bulb assembly 702. For example, a cylindrical first side wall 703a having a first diameter may be secured to the bulb base 710 in a manner previously described. A cylindrical second side wall 703b having a second diameter that is smaller than the first diameter may also be coupled to the bulb base 710 in any known manner such that the axes of the first side wall 703 and the second side wall 703 are co-axially aligned. However, the first side wall 703a and the second side wall 703b may each have any suitable cross-sectional shape and may be axially offset. In addition, the second side wall 703b may extend beyond the first side wall 703a in the axial direction, as illustrated in FIG. 82. Alternatively, the first side wall 703a and the second side wall 703b may have any suitable height. For example, the maximum outer diameter of the first side wall 703a may be approximately equal to the maximum outer diameter of an A19 incandescent light bulb—approximately 2% inches (60.3 mm), and the overall height of the second side wall 703b may be approximately equal to the maximum height of an A19 incandescent light bulb—approximately 3½ inches (88.9 mm). In addition, one or more additional side walls (not shown) may also be secured to the bulb is 710, and the one or more additional side walls may have any suitable size, shape, or relative orientation.

Other than the difference in the shape of the side wall 703, the bulb assembly 702 of FIG. 82 may be substantially identical to the embodiment of the bulb assembly 702 illustrated in FIG. 65, and the bulb assembly 702 of FIG. 82 may include any or all suitable features or functions of the embodiments that are discussed above. For example, the exterior surface 720a of the first side wall 703a may illuminate in a first color, and the exterior surface 720b of the second side wall 703b may illuminate in a second color. In addition, any or all of the side walls 703a, 703b may have one or more windows 726 having any suitable shape. As an additional example, a reflective surface 720 may be disposed within the interior of the second side wall 703b, and the interior surface 714b of the second side wall 703b may illuminate to provide focused lighting at a point above the device 700. While the interior surface 714b of the second side wall 703b is illuminated, the exterior surface 720a of the first side wall 703a may be illuminated and dimmed.

In a still further embodiment illustrated in FIG. 85, a stem 744 may upwardly extend from the bulb base 710, and the stem 744 may be formed as a unitary part with at least a portion of the bulb base 710 or may be secured to the bulb base 710. A plurality of rods 746 may radially extend from the stem 744 to support a cylindrical side wall 503, and the electrical connections coupling the bulb base 710 to the side wall 703 may be extend within the interior of the stem 744 and at least one of the rods. Instead of a single cylindrical side wall 703, the side wall 503 may have any shape and two or more side walls 503 may be used as illustrated in FIG. 82. Any of the functionality and features described above may also be incorporated into the bulb assembly 702 illustrated in FIG. 85. In addition, as shown in FIG. 86, a hinge 748 may be disposed along the length of the stem 744 adjacent to the bulb base 710 such that a lower portion of the stem 744 may be pivoted relative to an upper portion of the stem 744.

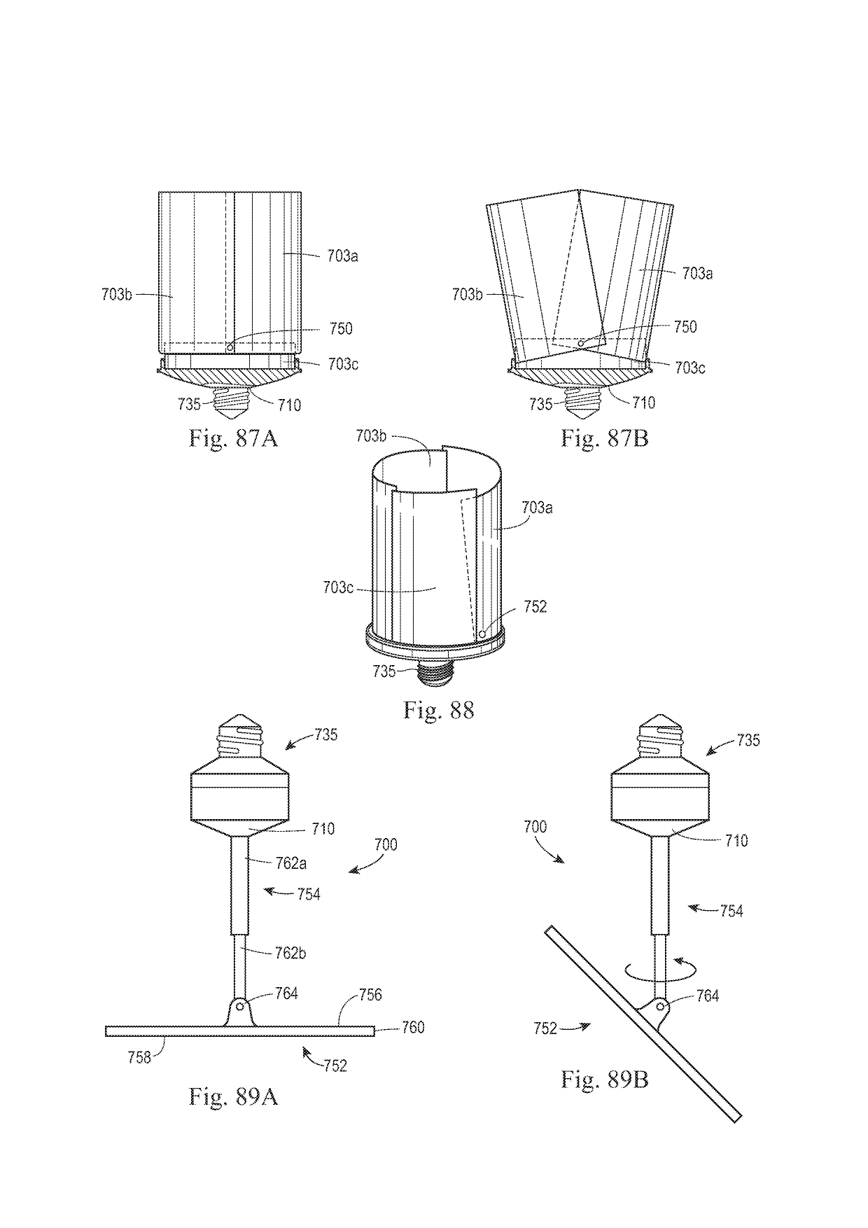

In a further embodiment, the side wall 703 may convert from a substantially cylindrical shape to a substantially frustoconical shape, and vice versa. For example, in the embodiment illustrated in FIGS. 87A and 87B, a semi-cylindrical first side wall 703a may be coupled to a semi-cylindrical second side wall 703b about a pair of oppositely-disposed hinges 750 such that the first and second side walls 703a, 703b have a substantially cylindrical shape. The hinges 750 may secure the first and second side walls 703a, 703b to a cylindrical side wall portion 703c, and the inner diameter of the first and second side walls 703a, 703b may be slightly greater than the outer diameter of the cylindrical side wall portion 703c. So configured, each of the first and second side walls 703a, 703b may pivot about the hinges 750 such that the first and second side walls 703a, 703b have a substantially frustoconical shape. The hinges 750 may be tightly secured around the first and second side walls 703a, 703b and the cylindrical portion 703c such that friction maintains the first and second side walls 703a, 703b in a desired position. The hinges may also form one or more electrical connections between the first and second side walls 703a, 703b.

Still referring to FIGS. 87A and 87B, the first and second side walls 703a, 703b may be pivoted to a desired position in any manner known in the art. For example, the first and second side walls 703a, 703b may be manually pivoted to a desired position. Alternatively, a mechanical coupling between the bulb base 710 and the first and second side walls 703a, 703b may pivot the first and second side walls 703a, 703b into a desired position. For example, a rotating collar (not shown) may be threadedly coupled to the bulb base 710 such that rotation of the collar relative to the bulb base 710 results in an axial displacement of the collar. Specifically, each of the first and second side walls 703a, 703b may be fixed to the collar at a location between the hinges 750, and a rotation of the collar relative to the bulb base 710 causes the points of the first and second side walls 703a, 703b fixed to the collar to upwardly or downwardly displace, thereby pivoting the first and second side walls 703a, 703b into a desired position. The collar may be manually rotated, or may be rotated by a motor disposed within or external to the bulb base 710. The motor may be triggered by a switch, a timer, a light sensor, voice command, or by any method known in the art.

Although first and second side walls 703a, 703b were discussed above, any number or shape of side walls may be used. For example, in the embodiment illustrated in FIG. 88, first, second, and third side walls 703a, 703b, 703c may be used. Moreover, any means to move the first and second side walls 703a, 703b (or any additional side walls) from a substantially cylindrical shape to a substantially frustoconical shape may be incorporated in the device 500. For example, an elongated handle (not shown) may extend through the interior of the side walls 703, and a rigid rod (not shown) may be pivotaby secured to the handle and each side wall such that when the handle is axially displaced (either manually or by other means), the rod may push or pull the side walls into a desired position. Telescoping actuators that radially extend from a central axial stem to pivot the side walls 703 are also contemplated, as are levers that pivot the side walls 703 relative to the bulb base 710, for example.

In the embodiment illustrated in FIGS. 89A and 89B, an illuminating element 752 is disposed at a distal end of an elongated stem 754. The illuminating element 752 may be substantially planar, and may have the overall shape of a disk. For example, the disk may have a diameter greater than the standard diameter of a conventional recessed lighting canister. That is, if the recessed lighting canister has a diameter of 5 inches (127 mm), the illuminating element 752 may have a diameter of 7 inches (177.8 mm). In some embodiments, the illuminating element may have a diameter (or maximum dimension) of about 3 cm to about 50 cm; alternately from about 5 cm to about 40 cm; alternately from about 10 cm to about 30 cm; alternately from about 15 cm to about 30 cm; alternately from about 15 cm to 50 cm; alternately from about 15 cm to 25 cm, alternately from about 20 cm to 40 cm, alternately from about 20 cm to 50 cm; alternately from about 25 cm to 50 cm. The illuminating element may have two illuminating surfaces. The illuminating surfaces may be generally planar, may be convex, concave, or some combination of planar, convex, and concave. Each of the illuminating surfaces may have a similar or same surface area as another. In particular, each illuminating surface may have a surface area of about 7 cm² to about 2000 cm²; alternately from about 20 cm² to about 1300 cm²; alternately from about 75 cm² to about 700 cm²; alternately from about 175 cm² to about 700 cm²; alternately from about 175 cm² to about 2000 cm²; alternately from about 175 cm² to about 500 cm²; alternately from about 300 cm² to about 1300 cm²; alternately from about 300 cm² to about 2000 cm²; alternately from about 500 cm² to 2000 cm². However, the illuminating element 752 may have any size, shape, or combination of shapes suitable for a desired application. For example, instead of a disk, the illuminating element 752 may have a square shape. The illuminating element 752 may have a top portion 756, a bottom portion 758, and a circumferential side portion 760, and any of these surfaces may be capable of illuminating.

Still referring to FIGS. 89A and 89B, the stem 754 may extend from the bulb base 710, and the bulb base 710 is integrally formed with the base assembly 735. The stem 754 may include a first stem portion 762a that extends from the bulb base 710 and a second stem portion 762b extends from the first stem portion 762a. More particularly, the second stem portion 762b may telescopically extend from the first stem portion 762a such that the overall axial length of the stem 754 may be adjustable. For example, the maximum overall axial length of the stem 754 may be greater than the depth of a conventional recessed-lighting canister. For example, a recessed lighting canister may have a depth of about 7 cm to about 8 cm, and the stem may have an axial length of about 7 cm to about 30 cm; alternately, the recessed lighting canister may have a depth of about 10 cm and the stem may have an axial length of about 10 cm to about 35 cm; alternately, the recessed lighting canister may have a depth of about 12 cm to about 13 cm and the stem may have an axial length of about 12 cm to about 40 cm; alternately, the recessed lighting canister may have a depth of about 15 cm and the stem may have an axial length of about 15 cm to about 45 cm. In any event, the stem, whether fixed or extendable, may have an overall length from about 5 cm to about 100 cm; alternately from about 5 cm to about 50 cm; alternately from about 5 cm to about 40 cm; alternately from about 5 cm to about 75 cm; alternately from about 15 cm to about 100 cm; alternately from about 15 cm to about 75 cm; alternately from about 15 cm to about 50 cm; alternately from about 15 cm to about 35 cm; alternately from about 25 cm to about 100 cm; alternately from about 25 cm to 50 cm; alternately from about 25 cm to about 40 cm. Moreover, the second stem portion 762b may rotate relative to the first stem portion 762a. This relative rotation (or length adjustment) may trigger or adjust a function of the device, such as dimming or brightening the illumination of the top portion 756, the bottom portion 758, or the side portion 760 of the illuminating element 752, as well as illuminating or de-illuminating any of the portions 756, 758, 760. In some embodiments, the first stem portion may rotate as much as 360 degrees with relative to the second stem portion; alternately as much as 330 degrees; alternately as much as 300 degrees; alternately as much as 270 degrees; alternately as much as 240 degrees; alternately as much as 210 degrees; alternately as much as 180 degrees; alternately as much as 150 degrees; alternately as much as 120 degrees; alternately as much as 90 degrees; alternately as much 60 degrees; alternately as much as 30 degreees. However, the stem 754 may be rigid with no functional capabilities. A hinge 764 may couple the illuminating element 752 to the second stem portion 762b, thereby allowing the illuminating element 752 to pivot relative to the stem 754. However, the illuminating element 752 may be rigidly fixed to the second stem portion 762b, and the hinge may be disposed at any desirable location along the stem 754. Alternatively, no hinge may be included, and the illuminating element 752 may be non-pivotable relative to the stem 754. In operation, the base assembly 735 may be inserted into a socket in a recessed lighting cavity, and the illuminating element 752 may be rotated such that the illuminated bottom portion 758 provides directed lighting to a desired area, for example.

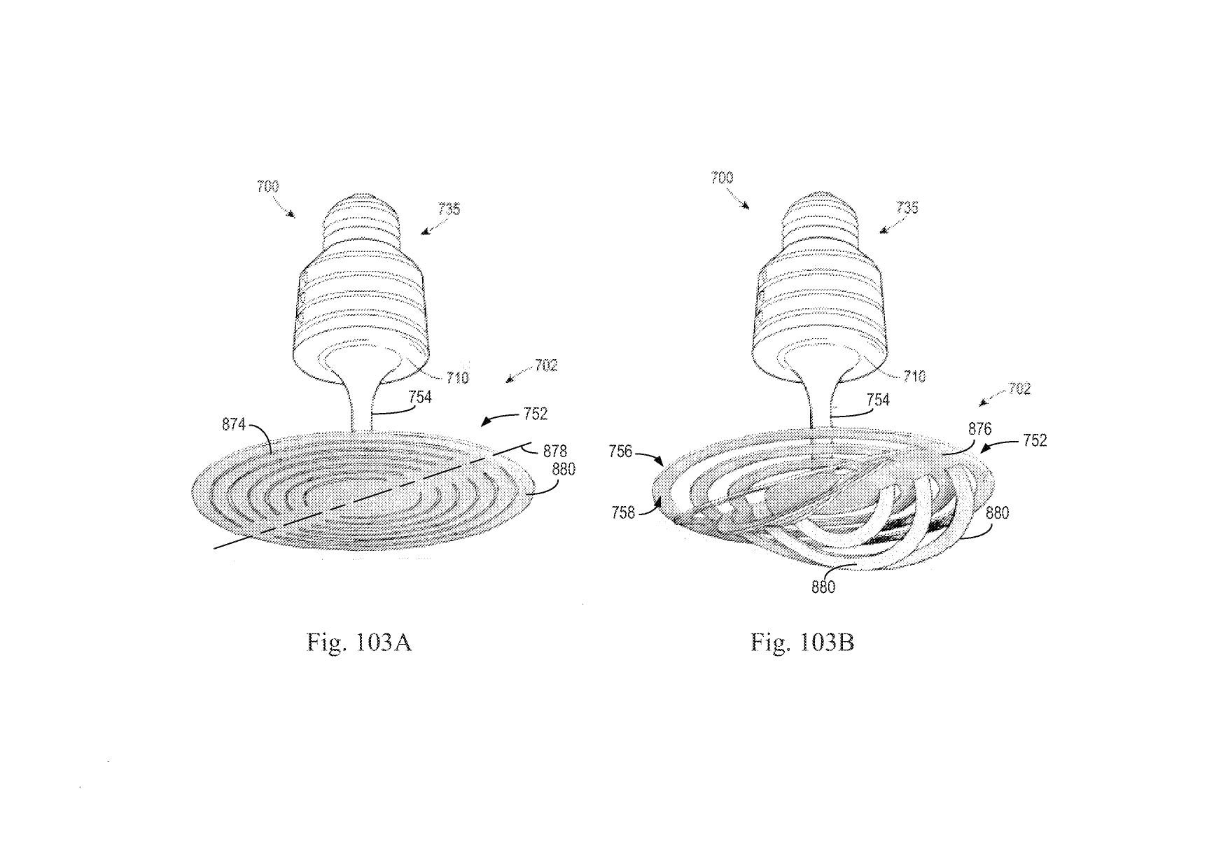

In an embodiment illustrated in FIGS. 103A and 103B, the illuminating element 752 may have a plurality of slots 874 that extend from the top portion 756 of the illuminating element 752 to the bottom portion 758. The slots 874 may be disposed at any desired location. For example, as illustrated in FIGS. 103A and 103B, the slots may be concentrically disposed about the center of the disk-shaped illuminating element 752. The ends of the concentric slots may extend up to a central transverse portion 876 of the disk, and the transverse portion 876 of the disk may extend along an axis 878 that passes through the center of the disk. The plurality of concentric slots 876 may define a plurality of arc-shaped displaceable portions 880, and the displaceable portions 880 may be pivoted at the junction of the ends of the displaceable portions 880 and the transverse portion 876. As such, in a first configuration illustrated in FIG. 103A, the displaceable portions 880 may be substantially coplanar. However, one or more of the displaceable portions 80 may be pivoted relative to the transverse portion 876. More specifically, as illustrated in FIG. 145B, a plane passing through a top surface of a first displaceable portion 880 may be disposed at a first angle (e.g., between 0 degrees and 90 degrees) relative to a plane passing through the transverse portion 876, and a plane passing through a top surface of a second displaceable portion 880 may be disposed at a second angle (e.g., between 0 degrees and 90 degrees) relative to the plane passing through the transverse portion 876. The illuminating element 752 may comprise a memory material that allows a displaceable portion to remain in a desired position upon being displaced relative to the central transverse portion.

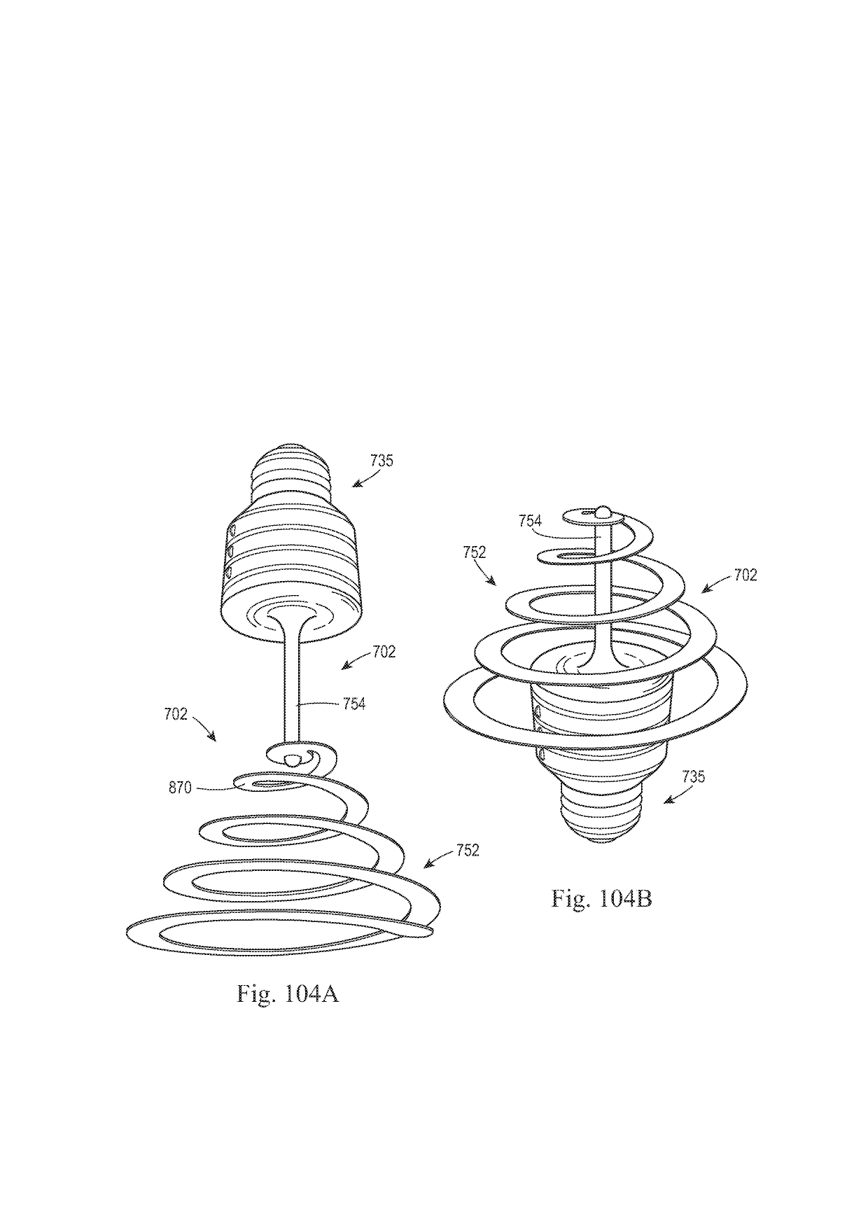

In an alternative embodiment illustrated in FIGS. 104A and 104B, the disk-shaped illuminating element 752 may have a single slot 874 that forms a spiral pattern disposed about the center of the illuminating element 752. So configured, when bulb assembly 702 is oriented such that the stem 754 extends upward as illustrated in FIG. 104B, the weight of the material comprising the illuminating element 752 causes the illuminating element 752 to downwardly displace around the stem 754 such that the illuminating element 752 wraps around the stem 754. Alternatively, when bulb assembly 702 is oriented such that the stem 754 extends downward (such as when the base assembly 735 is disposed in a recessed lighting power receptacle) as illustrated in FIG. 104A, the weight of the material comprising the illuminating element 752 causes the illuminating element 752 to downwardly displace from the stem 754.

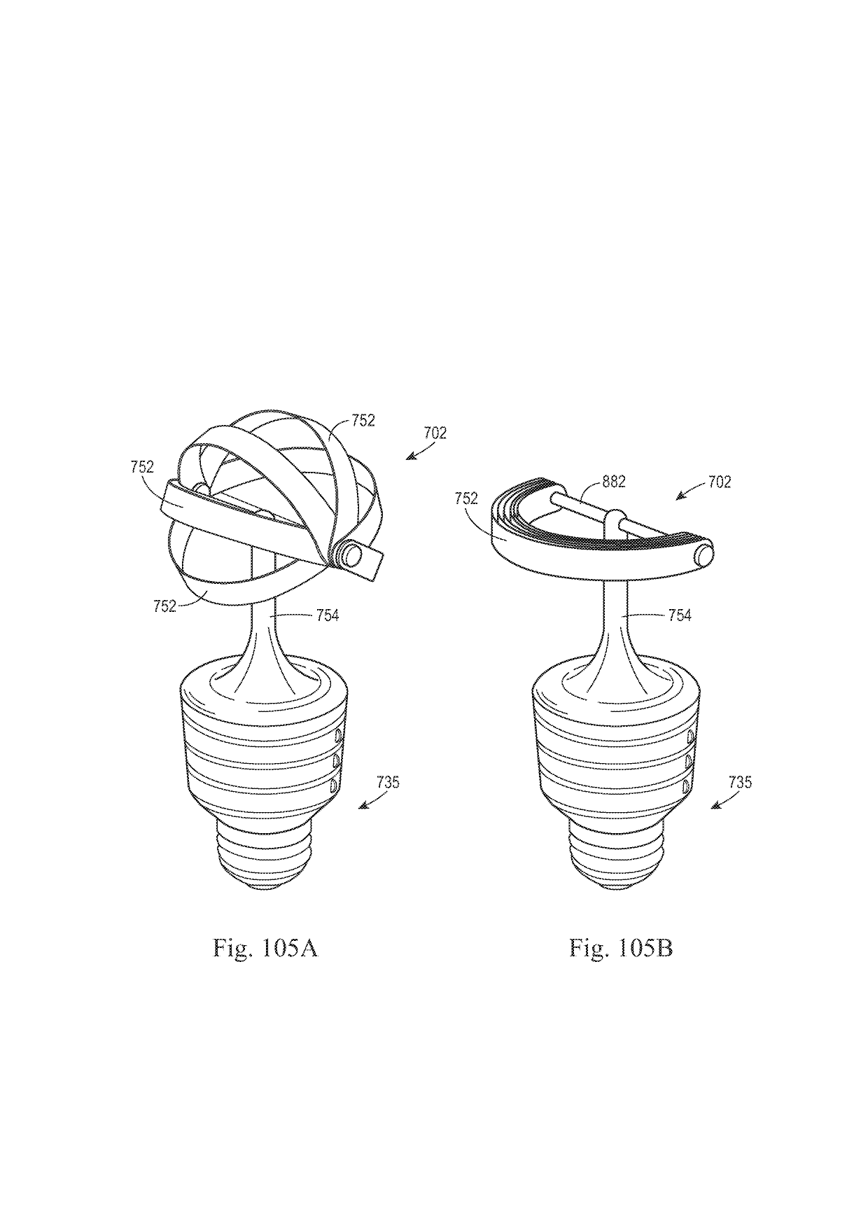

In a still further alternative embodiment illustrated in FIGS. 105A and 105B, a horizontal rod 882 may be coupled to a distal end of the stem 754 of the bulb assembly 702. A plurality of arc-shaped illuminating elements 752 may be rotatably coupled to the rod 882. More particularly, a first end portion of each illuminating element 752 may be rotatably connected to a first end portion of the rod 882 and a second end portion of the illuminating element 752 may be rotatably connected to a second end portion of the rod 882. So configured, any or all of the arc-shaped illuminating elements 752 may be rotated about the rod 882 to a desired position. Moreover, each of the arc-shaped illuminating elements 752 may be positioned and dimensioned to allow the illuminating elements 752 to be maintained in a nested position, as illustrated in FIG. 105B.

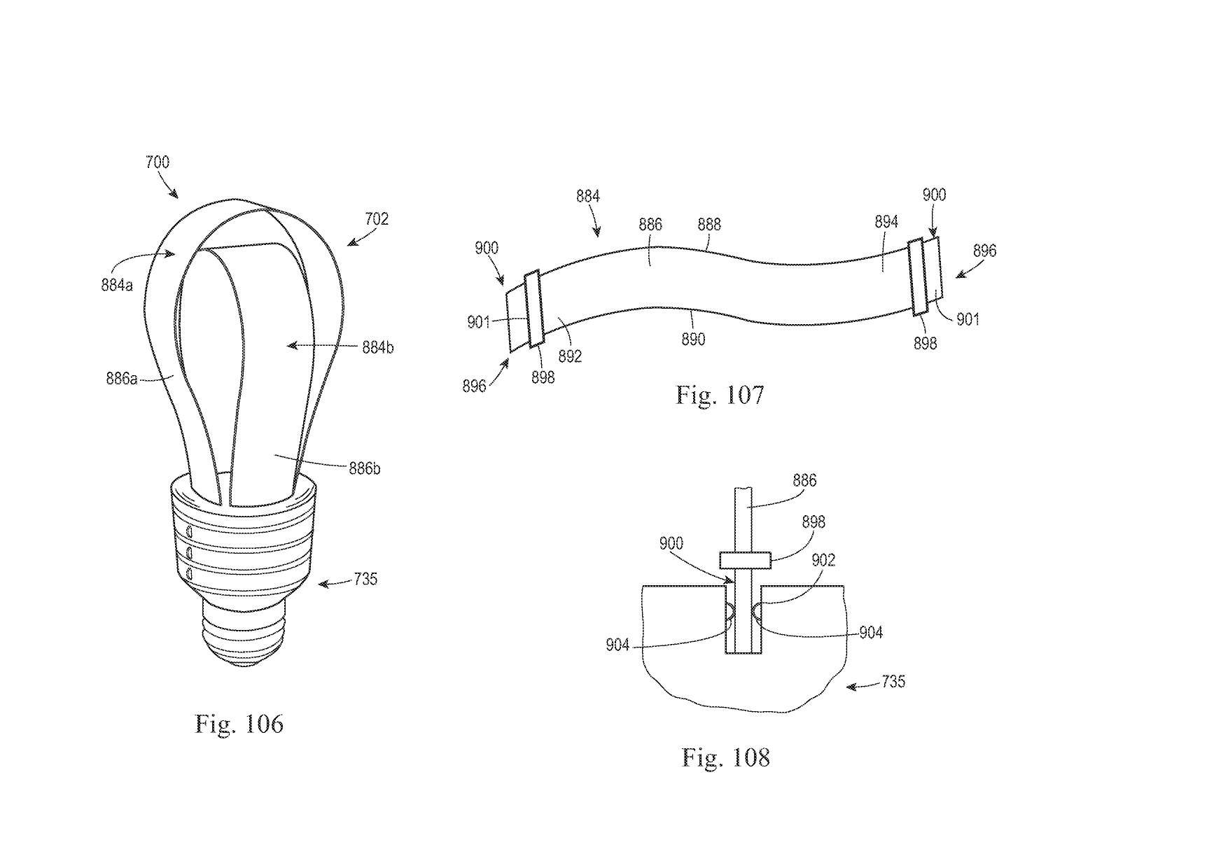

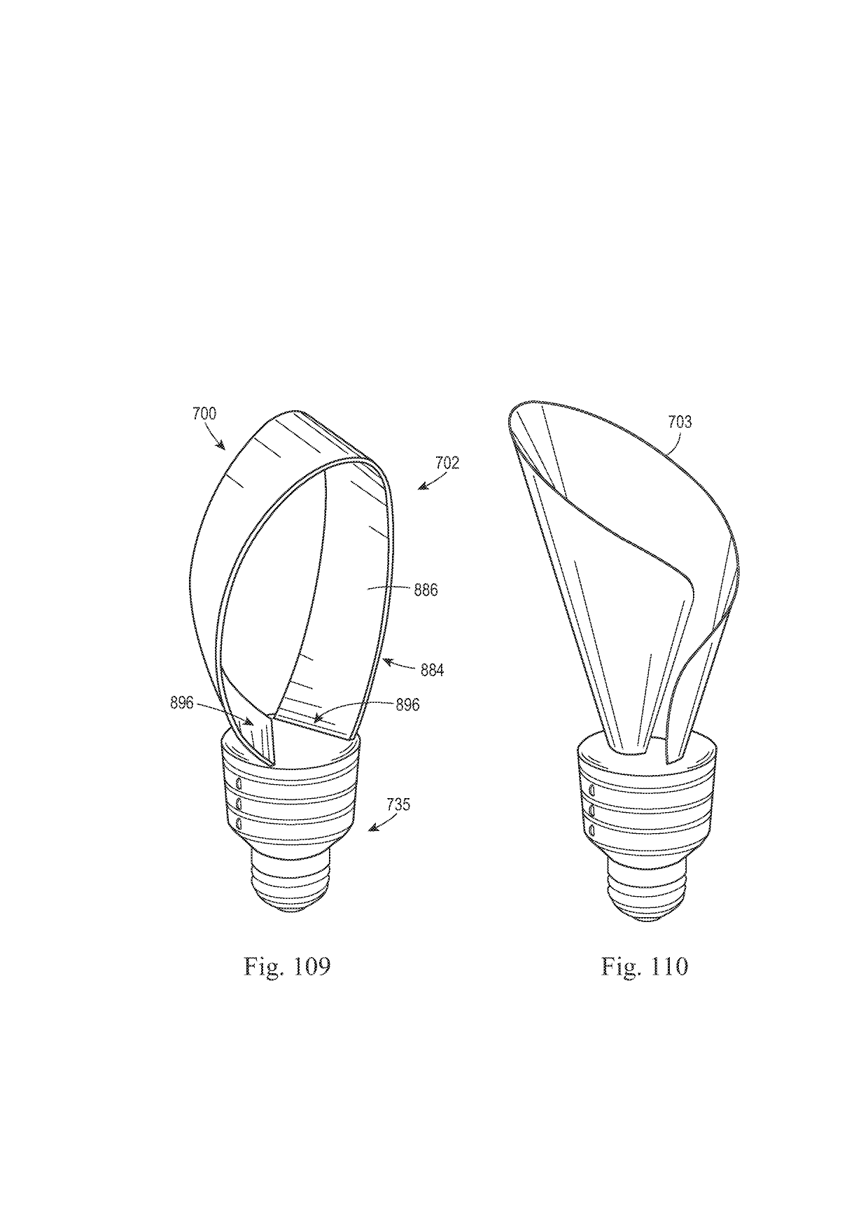

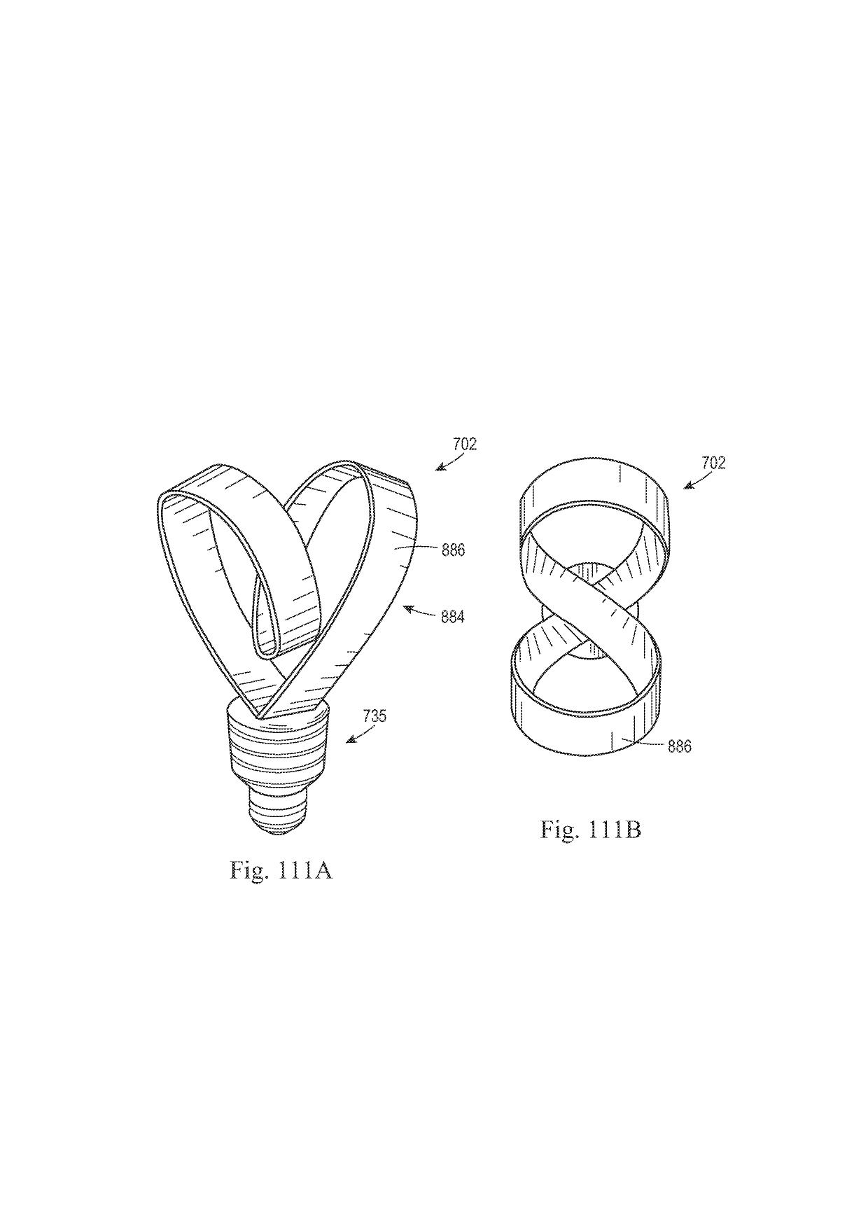

In further embodiments, the lighting element of the bulb assembly may be one or more flexible lighting strip assemblies 884. For example, in the embodiment of the bulb assembly illustrated in FIG. 106, the bulb assembly 702 may include a first lighting strip assembly 884a and a second lighting strip assembly 884b. Each lighting strip assembly 884a, 884b may include a lighting strip 886 comprising the previously-described flexible illuminating material.

The lighting strips 886 of each lighting strip assembly 884a, 884b may have any shape suitable for a desired application. For example, as illustrated in FIGS. 148 and 149, the first lighting strip 886a and the second lighting strip 886b may each have an elongated, ribbon-like shape. More specifically, each of the first and second lighting strips 886a, 886b may be partially defined by a linear first longitudinal edge 888 and a linear second longitudinal edge 890 that is parallel to and offset from the first longitudinal edge 888. The transverse distance (i.e., the distance normal to the longitudinal axis of each lighting strip 886, or the width) may have any suitable value. For example, the transverse distance may be within a first width range of approximately from about 50 mm to about 5 mm, alternatively from 40 mm to about 10 mm, alternatively from 30 mm to about 10 mm, alternatively from 25 mm to about 5 mm, alternatively from about 20 mm to about 10 mm, or alternatively combinations thereof. More specifically, the distance may be about 20 mm. Alternatively, the transverse distance may within a second width range of about 10 mm to approximately 3 mm. As an additional alternative, the transverse distance may within a third width range of approximately 50 mm to approximately 25 mm. In additional embodiments, the first longitudinal edge 888 and the second longitudinal edge 890 may be non-liner (or linear, but non-parallel), and the edges 888, 890 may converge or diverge or may be curved, partially curved, or angled relative to one or more portions of the edge. One having ordinary skill in the art would recognize that the transverse distance of embodiments having curved edges, or, for example, serrated edges, would be the distance between reference lines bisecting (or substantially bisecting) the curved or serrated edges 888, 890. In further embodiments, the transverse distance of each lighting strip 884 may be pre-established, or may be determined by the user. More specifically, individual lighting strips 884 may be removed from a master sheet, and the master sheet may be longitudinally perforated to allow the user to choose a desired width of each lighting strip 884.

The elongated lighting strip 886 of the lighting strip assembly 884 may have a first end portion 892 and a second end portion 894 opposite the first end portion 892. In some embodiments, the lighting strip assembly may have exposed conductive layers at each of the first end portion 892 and the second end portion 894. In other embodiments, the lighting strip assembly 884 may further include a connector assembly 896 that may be disposed at or adjacent to one or both of the first end portion 892 and the second end portion 894. The first longitudinal edge 888 and the second longitudinal edge 890 may each extend from the first end portion 892 to the second end portion 894 of the lighting strip 884. The connector assembly 896 may include an base portion 898, and the base portion 898 may be elongated and disposed substantially normal to a longitudinal axis of the lighting strip. The base portion 898 may be secured to the first end portion 892 and/or the second end portion 894 of the lighting strip 886 by any method known in the art, such as by mechanical coupling, by an interference fit, by ultrasonic welding, or by snap-fitting a multiple part base portion assembly around the first end portion 892 and/or second end portion 894 of the lighting strip 886, for example. The connector assembly 896 may be connected to a lighting strip 884 at the time of manufacturing, or may be secured to the end portions 892, 894 by the user if the width of each lighting strip 884 can be determined by a user.

The connector assembly 896 may also include one or more contact elements 900 adapted to electrically couple the lighting strip 886 to a source of power, and the contact element 900 may comprise any part or any assembly of parts capable of electrically coupling the lighting strip 886 to the source of power. Each contact element 900 may be coupled to the lighting strip 886 by the base portion 898. For example, the base portion 898 may be secured to the first end portion 892 and/or the second end portion 894 of the lighting strip 886, and one or more contact elements 900 may be coupled to (or retained by) the base portion 898 such that the one or more contact elements 900 are electrically coupled to the lighting strip 886. In alternative embodiments, the one or more contact elements 900 may be directly coupled to the first end portion 892 and/or the second end portion 894 of the lighting strip 886. As illustrated in FIGS. 149 and 150, the connector assembly 896 may include a single contact element 900, and the contact element 900 may take the shape of an elongated plate 901. In an alternative embodiment, each contact element 900 may include one or more cylindrical plugs. The elongated plate 901 (or any embodiment of the contact element 900) may be dimensioned to be received into a corresponding slot 902 formed in the base assembly 735, such as a top portion 735a of the base assembly 735. The one or more contact elements 900 may be removably coupled to the top portion 735a of the base assembly 735. For example, one or more slots 902 may be formed in the top portion 735a of the base assembly 735, and, more particularly, the one or more slots 902 may be formed in or on a top surface 905 of the top portion 735a of the base assembly 735. However, the one or more slots may be formed on any desired location of the base assembly 735, such as an outer cylindrical surface of the top portion 735a of the base assembly 735. The one or more contact elements 900 may be adapted to be removably received into the one or more slots 902. One or more contacts 904, such as spring contacts, may be disposed within the slot 902, and the one or more contacts 904 may be adapted to maintain physical contact with the elongated plate 901 when the elongated plate 901 is disposed in the slot 902. The one or more contacts 904 disposed in the slot 902 are electrically coupled to a power source to provide power to the lighting strip 886. The elongated plate 901 may have a detent feature (not shown) that may be positioned on the elongated plate such that the contacts 904 in the slot 902 engage the detent feature when the connector assembly 896 is properly inserted into the slot 902. The connector assembly 896 and/or the base assembly 735 may include one or more features (not shown) that ensure that the contact element is inserted into the slot 902 in a proper orientation relative to the contacts 904 in the slot 902 (to, for example, maintain correct polarity between the contacts in the slot and the elongated plate). Moreover, the connector assembly 896 and/or the base assembly 735 may include one or more features (not shown) that provide a releasable engagement feature that prevents the connector assembly from inadvertently being removed from the slot 902 of the base assembly 735.

As previously discussed, each of the lighting strips 886 of the one or more lighting strip assemblies 884 may be flexible, and the connector assembly 896 disposed at one or both ends of each of the lighting strip assemblies 884 may be removably coupled to the base assembly 735. Consequently, a user may customize the configuration of the bulb assembly 702. For example, a plurality of slots 902 may be provided in the base assembly 735, and the user may insert a first contact element 900 of a first lighting strip assembly 884a into a desired first slot 902 and the second contact element 900 of the first lighting strip assembly 884a into a desired second slot 902. The user may also insert a first contact element 900 of a second lighting strip assembly 884b into a third desired slot 902 and the second contact element 900 of the second lighting strip assembly 884b into a fourth desired slot 902. If desired, the user may then remove the first contact element 900 of the first lighting strip assembly 884a from the first slot 902 and insert the first contact element 900 of the first lighting strip assembly 884a into a fifth slot 902, for example. By being provided with a plurality of slots 902, the user is able to customize the configuration or position of the one or more lighting strip assemblies 884 relative to the base assembly 735, thereby allowing the user to create an esthetically pleasing and personalized illuminating arrangement. One having ordinary skill in the art would recognize that a lighting strip assembly 884 may be formed into any of a number of shapes, such as a round shape or a shape having one or more sharp edges.

The lighting strip or strips 886 may have any suitable length. For example, as illustrated in FIG. 148, a first lighting strip 886a may have a first length and a second lighting strip 886b may have a second length that is less than the first length. In some embodiments, the lighting strip or strips 886 may have a length of about 20 cm; alternately of about 15 cm; alternately of about 10 cm; alternately of about 25 cm; alternately of about 30 cm. Likewise, in embodiments employing two or more lighting strips 886, the lighting strips 886 may vary in length by about 1 cm; alternately by about 2 cm; alternately by about 3 cm; alternately by about 4 cm; alternately by about 5 cm; alternately by about 6 cm; alternately by about 7 cm. In some embodiments, a ratio of lengths of any two strips will be between about 1:1 and about 1:2; alternately between about 1:1 and 1:1.5; alternately between about 1:1 and 1:3; alternately between about 1:1 and 1:4; alternately between about 1:1 and 1:5. Although not shown, there may be three, four, five, or more strips of varying dimensions. The first and second contact elements 900 of the second lighting strip assembly 884b may be inserted into a first pair of slots 902 formed in the base assembly 735 such that the lighting strip 886b has the shape of a rounded arch (or loop) when viewed from the front. More particularly, the lighting strip 886b may have the general shape of a cross-section of a conventional light bulb (such as, for example, an A19 incandescent light bulb). In addition, the first and second contact elements 900 of the first lighting strip assembly 886a may be inserted into a second pair of slots 902 disposed orthogonal to the first pair of slots 902, and the lighting strip 886a of the first lighting strip assembly 884a may take the shape of a rounded arch (or loop) when viewed from the front. Similar to the second lighting strip 886b, the first lighting strip 886a may have the general shape of a cross-section of a conventional light bulb (such as, for example, an A19 incandescent light bulb). Because the first lighting strip assembly 884a has a greater length than the second lighting strip assembly 884b, a top rounded portion of the second lighting strip 886b is disposed below a top rounded portion of the first lighting strip 886b. Because the first lighting strip assembly 884a is disposed orthogonally to the second lighting strip assembly 884b, the overall shape of the first lighting strip assembly 884a and the second lighting strip assembly 884b resembles that of a stylized conventional light bulb.

Instead of a first lighting strip 886a having a first length and a second lighting strip 886b having a second length, a single lighting strip assembly 884 may be coupled to the base assembly 735, as illustrated in FIGS. 154A and 154B. The single lighting strip assembly 884 may have a connector assembly 896 disposed adjacent to the first end portion 892 and the second end portion 894 of the lighting strip 886, and the connector assemblies 896 may each be received into appropriate slots 902 formed in the base assembly 735 in the manner discussed above. The lighting strip 886 of the lighting strip assembly 884 may take the shape of a rounded arch (or loop) when viewed from the front, and the lighting strip 886 may have the general shape of a cross-section of a conventional light bulb (such as, for example, an A19 incandescent light bulb). As such, dimensions of the lighting strip assembly 884 may correspond to the cross-sectional dimensions of a conventional light bulb, such as the A19 incandescent light bulb. As a specific example, the height of the rounded arch (or loop) may correspond to the height of the A19 incandescent light bulb, and such a height may be approximately 3½ inches (88.9 mm). The height may be defined, for example, as the vertical distance between an uppermost portion of the arch (or loop) and a horizontal or substantially horizontal top surface of the base assembly 735. However, the height may the distance between the uppermost portion of the arch (or loop) and any suitable portion of the top surface of the base assembly 735, such as an edge that partially defines one of more of the slots 902 formed in the top surface of the base assembly 735. As a further example, the maximum outer diameter of the rounded arch (or loop) may correspond to the maximum outer diameter of the A19 incandescent light bulb, and such a diameter may be approximately 2% inches (60.3 mm).

Instead of a height and maximum outer diameter values that correspond to those of a conventional light bulb, such as the A19 incandescent light bulb, the height and maximum outer diameter values of the rounded arch (or loop) may have any suitable values. For example, the height of the rounded arch (or loop) may be less than (or significantly less than) the height of the A19 incandescent light bulb, as illustrated in FIGS. 155A and 155B. More specifically, the height may be from about 1 cm to about 20 cm; alternately, from about 1 cm to about 15 cm; alternately from about 1 cm to about 10 cm; alternately from about 3 cm to about 20 cm; alternately from about 3 cm to about 15 cm; alternately from about 3 cm to about 10 cm; alternately from about 5 cm to about 20 cm; alternately from about 5 cm to about 15 cm; alternately from about 5 cm to about 10 cm. Similarly, also as illustrated in FIGS. 155A and 155B, the maximum width of the rounded arch (or loop) may be more or less than the maximum width of the A19 incandescent light bulb, and the maximum width may or may not maintain the general proportions of the A19 incandescent light bulb, for example. Specifically, in some embodiments, the maximum width of the rounded arch (e.g., in the loop formed by the lighting strip 886), may be about 2 cm to about 20 cm; alternately about 2 cm to about 15 cm; alternately about 2 cm to 10 cm; alternately about 2 cm to 5 cm; alternately about 4 cm to about 20 cm; alternately about 4 cm to about 15 cm; alternately about 4 cm to about 10 cm. As such, if the height of the rounded arch (or loop) is 1.5″ (38.1 mm), the maximum width would be approximately 1″ (25.4 mm). That is, the ratio of width:height of the lighting strips 886 when formed into loops and/or arches may be from about 1:1 to about 1:3; alternately about 1:1 to about 1:2; alternately about 1:1 to about 3:4.

In additional embodiments, the height of the rounded arch (or loop) may be greater than (or significantly greater than) the height of the A19 incandescent light bulb, as illustrated in FIGS. 156A and 156B. More specifically, the height may be approximately 5 inches (127 mm), 6″ (152.4 mm), or 7″ (177.8 mm), for example. Similarly, also as illustrated in FIGS. 156A and 156B, the maximum width of the rounded arch (or loop) may be significantly greater than the maximum width of the A19 incandescent light bulb, and the maximum width may maintain the general proportions of the A19 incandescent light bulb, for example. As such, if the height of the rounded arch (or loop) is 7″ (177.8 mm), the maximum width would be approximately 4.75″ (120.6 mm).

In further embodiments, a first lighting strip 886a may have a first length and a second lighting strip 886b may have a second length that is less than the first length, as discussed above with reference to FIG. 148. However, as illustrated in FIGS. 157A and 157B, the height of the rounded arch (or loop) of the first lighting strip 886a may be greater than (or significantly greater than) the height of the A19 incandescent light bulb, and the height of the rounded arch (or loop) of the second lighting strip 886b may be significantly less than the height of the rounded arch (or loop) of the first lighting strip 886a. For example, the height of the rounded arch (or loop) of the second lighting strip 886b may equal to or significantly less than the height of the rounded arch (or loop) of the A19 incandescent light bulb. For example, the height of the rounded arch (or loop) of the first lighting strip 886a may be approximately 7″ (177.8 mm), for example, and the height of the rounded arch (or loop) of the second lighting strip 886b may be approximately 1″ (25.4 mm). Alternatively, the height of the rounded arch (or loop) of the second lighting strip 886b may be slightly less than the height of the rounded arch (or loop) of the first lighting strip 886a. In an additional embodiment, both the height of the rounded arch (or loop) of the first lighting strip 886a and the height of the rounded arch (or loop) of the second lighting strip 886b may be significantly less than the height of the A19 incandescent light bulb. One having ordinary skill in the art would recognize that any number of additional lighting strip assemblies 884 having various sizes and various mutual orientations can be coupled to a base assembly 735 to emulate the shape of a conventional light bulb (such as, for example, an A19 incandescent light bulb).

In any of the embodiments previously discussed (or discussed below), the widths of each of the lighting strips 886 may vary. For example, in the embodiment illustrated in FIGS. 157A and 157B, the first lighting strip 886a and the second lighting strip 886b may have a transverse distance (i.e., the distance normal to the longitudinal axis of each lighting strip 886, or the width) within the first range of transverse distances, and both of the transverse distances may be equal. However, the first lighting strip 886a and the second lighting strip 886b may have different transverse widths, and each of the transverse distance may be chosen from the first range, the second range, and the third range, as described above. Moreover, if more than two lighting strips 886 are used, the transverse width of any of the lighting strips 886 may be chosen from the first range, the second range, and the third range. For example, if ten lighting strips 886 are coupled to the base assembly 735 (or are capable of being coupled to the base assembly 735), all ten lighting strips 886 may have an equal transverse distance, and the transverse distance may be within the second range. One having ordinary skill in the art would recognize that the lengths of all of the lighting strips may be equal, or the length of any or all of the lighting strips may vary.

As discussed above, the lighting strip 886 of the lighting strip assembly 884 may be flexible. More specifically, the lighting strips 886 may have any suitable flexural modulus according to the materials used to manufacture the material. Moreover, regardless of the flexural modulus of the material, the material may have a minimum radius to which it can be bent without compromising the electrical and/or physical integrity of the structure (e.g., causing layers of materials to shear, without shorting electrical components, etc.). As used herein, this minimum radius is referred to as a “minimum bending radius.” Both the minimum bending radius and the flexural modulus may vary according to a particular application, depending on the substrate materials used and the desired flexibility of the material. For example, a lighting strip 886 using a first substrate material may have a minimum bending radius of between 4 mm and 25 mm, while an illumination element 782 in the form of a disk using a second substrate material may have a minimum bending significantly greater, on the order of 100 mm to 200 mm or more. Thus, in some embodiments the lighting strip 886 has a minimum bending radius of about 10 mm to about 20 cm; alternately about 10 mm to about 10 cm; alternately about 10 mm to about 5 cm; alternately about 3 cm to about 5 cm; alternately about 3 cm to about 10 cm; alternately about 3 cm to about 20 cm. Alternatively, the sheet 788 may be relatively rigid, having a larger bending radius of approximately 15 cm, for example. If more than one lighting strip assembly 884 is used for an application, one having ordinary skill in the art would recognize that the minimum bending radius of all of the lighting strips 886 may be equal, or the minimum bending radius of any or all of the lighting strips 886 may vary.

Due to the flexibility of the lighting strip 886, a first connector assembly 896 may be rotated relative to a second connector assembly 896 to twist the lighting strip. For example, as illustrated in FIG. 151, the first and second contact elements 900 of a single lighting strip assembly may be inserted into slots 902 that are disposed at an angle of between 145 degrees and 45 degrees, alternatively from 100 degrees to 45 degrees alternatively from 100 degrees to 145 degrees, alternatively from 80 degrees to 100 degrees, alternatively about 90 degrees, to create an elongated arc that extends from the base assembly 735. Alternatively, as illustrated in FIGS. 152A, 152B, the lighting strip 886 of a single lighting strip assembly 884 can be twisted to form multiple loops. Moreover, as illustrated in FIGS. 153A, 153B, the lighting strips 886 of more than one lighting strip assembly 884 can be twisted to form a desired configuration.

Each of the lighting strips 886 of the lighting strip assemblies 884 may be capable of illuminating in any desired manner. For example, the entire front surface of any or all of the lighting strips 886 may be capable of illumination. Alternatively, only portions of the front surface may be capable of illumination. In other embodiments, portions of the front surface may be capable of selective illumination such that the entire front surface of the lighting strip 886 may be illuminated or only portions of the front surface of the lighting strip may be illuminated. Similarly, the entire back surface of any or all of the lighting strips 886 may be capable of illumination. Alternatively, only portions of the back surface may be capable of illumination, or portions of the back surface may be capable of selective illumination. Selective illumination may be controlled by any method, including those previously described. In some instances, selective illumination may be by lighting strip (i.e., a first lighting strip may be illuminated, while a second lighting strip remains unilluminated, etc.).

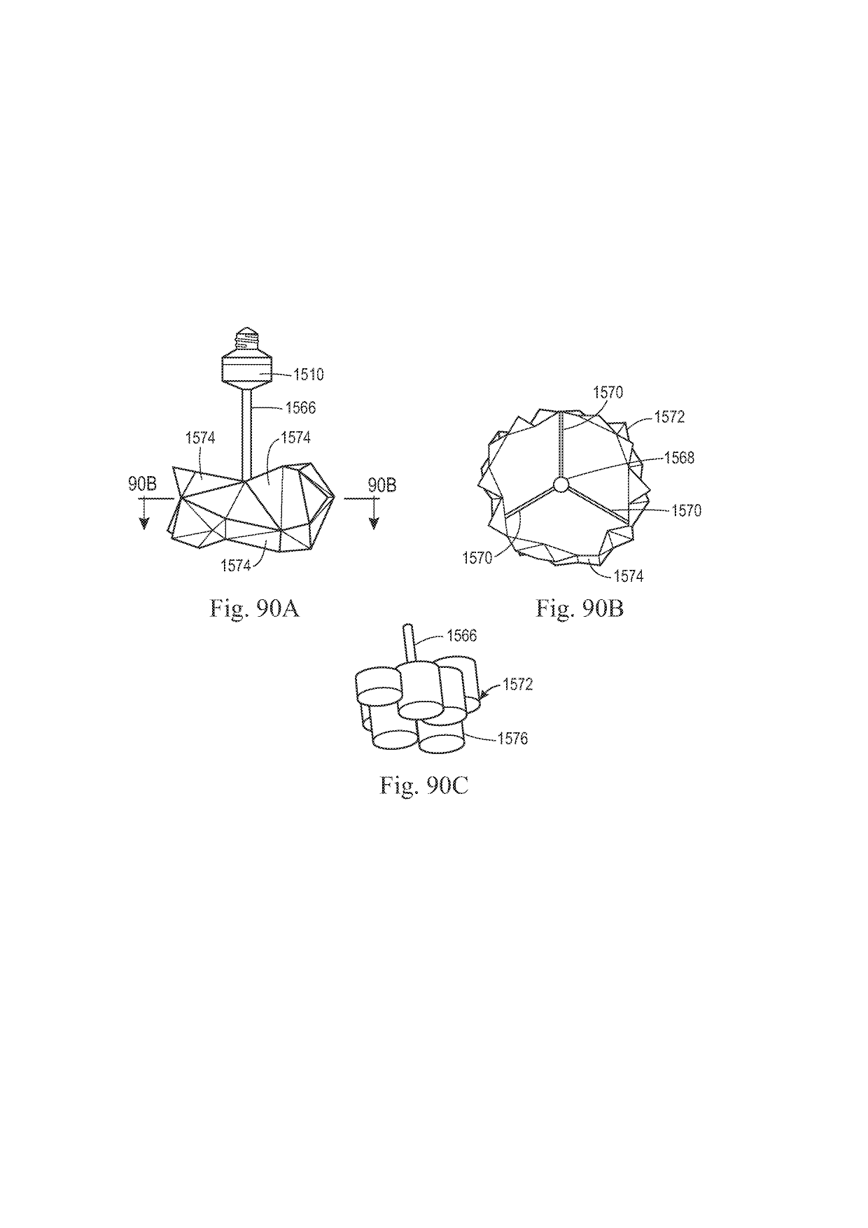

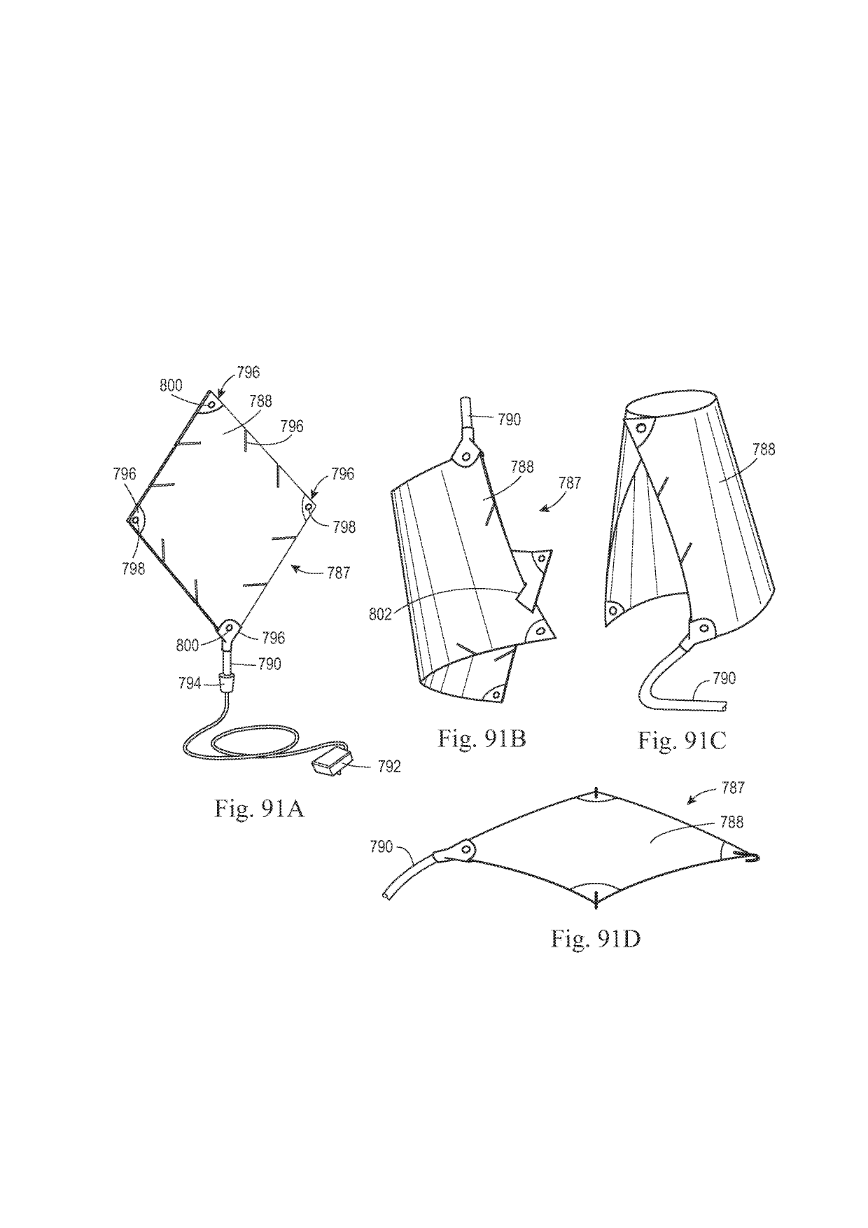

In a still further embodiment of the lighting device 700 illustrated in FIGS. 90A and 90B, a flexible cord 766 may extend from a bulb base 710, and the bulb base 710 is integrally formed with the base assembly 735. A hub 768 may be disposed at the distal end of the cord 766, and a plurality of support rods 770 may radially extend from the hub 768. A lighting element 772 may be supported by the plurality of support rods 770, and the support rods 770, the hub 768, and the cord 766 may provide a means to electrically connect the base assembly 735 with the lighting element 772. The lighting element 772 may have any shape, and any interior and/or exterior surface of the lighting element 772 may illuminate. For example, as shown in FIGS. 90A and 90B, the lighting element 772 may include a plurality of faceted surfaces 774 that form a generally cylindrical shape, and all (or some) of the faceted surfaces 774 may be capable of illumination. Another example is shown in FIG. 90C, where the lighting element 772 is comprised of a plurality of cylinders 776. The hub 768 may have an interface to allow a user to select or adjust a functional setting, such as to dim the lighting or switch on the illumination of internal faceted surfaces 774 only.

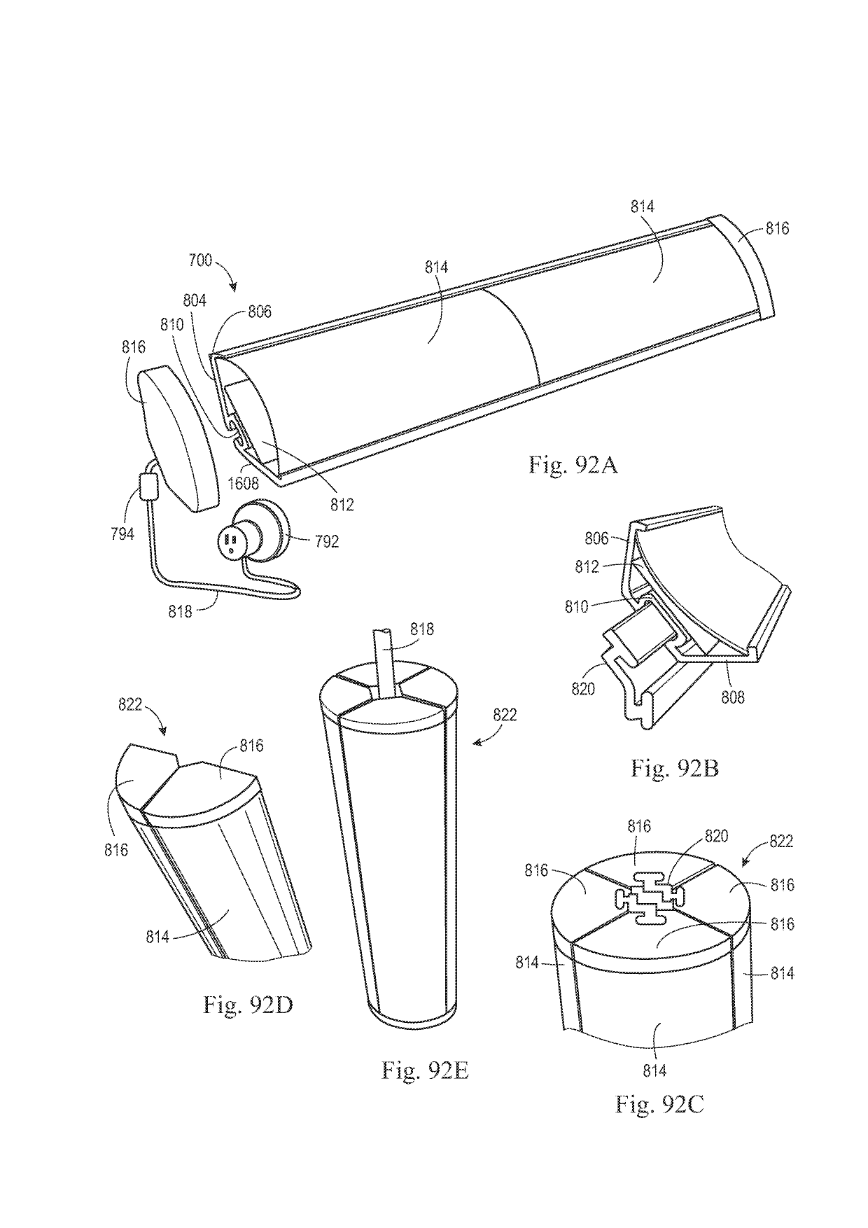

In another embodiment illustrated in FIGS. 93A, 93B, 93C, and 93D, a sheet assembly 787 may include a sheet 788, and both sides of the sheet 788 may be capable of illumination. The sheet 788 may be flexible, and the sheet may have any suitable minimum bending radius suitable for a given application. For example, the sheet 788 may have a minimum bending radius of between 1″ (25.4 mm) and 6″ (152.4 mm). Alternatively, the sheet 788 may be substantially rigid, having a larger bending radius of approximately 24″ (60.96 cm), for example. Alternately, the sheet 788 may have any minimal bending radius or range of minimum bending radii previously described. The sheet 788 may have a diamond shape and may be substantially planar, as illustrated in FIGS. 93A, 93B, 93C. However, the sheet 788 may have any shape or combination of shapes, such as the contoured shape illustrated in FIG. 93D. Optionally, the sheet 788 may include a printed pattern or image or other type or ornamentation. A power cord 790 may be electrically coupled to the sheet 788, and the power cord 790 may also be electrically coupled to a power interface 792 that may be capable of coupling to a source of power, such as, for example, a standard wall outlet, to provide power to illuminate the sheet 788. However, the power interface 792 may be capable of interfacing with any source of power, such as the socket of a standard light or a car lighter outlet. The power cord 790 may be permanently coupled to the sheet 788 or it may be releaseably coupled. A functional interface 794 may be electrically coupled to the sheet 788 and the power interface 792, and the functional interface 794 may include interfaces to control the functions of the sheet 788, such as a power switch, a dimmer, or any other suitable function. The sheet assembly 787 may include at least two coupling elements 796 to allow a first portion of the sheet 788 to attach to a second portion of the sheet. For example, a first coupling element may be coupled to the first portion of the sheet and a second coupling element may be coupled to the second portion of the sheet, and the first coupling element may be adapted to engage the second coupling element to removably secure the first portion of the sheet to the second portion of the sheet.

The coupling elements 796 of the embodiment illustrated in FIGS. 93A, 93B, 93C, and 93D may be any mechanism known in the art capable of releaseably coupling at least two portions of the sheet 788 such as, for example, hook and loop fasteners or magnetic fasteners. As an additional example, a coupling element 796 may be disposed at each of the four corners of the diamond-shaped sheet illustrated in FIG. 93A. The coupling elements 796 may include a male projection 798 that can be releaseably secured within a female aperture 800 to secure the sheet in a desired shape, as illustrated in FIG. 93C. More than one type of coupling element 796 may be included, such as, for example, a plurality of inwardly-directed slits 802, and an edge portion of the sheet can be inserted into one of the silts 802 to secure the sheet in a desired position as illustrated in FIG. 93B. It is contemplated that the sheet assembly 787 can be hung from a wall, suspended from an overhead power source, hung from the ceiling, or be disposed on a flat surface.

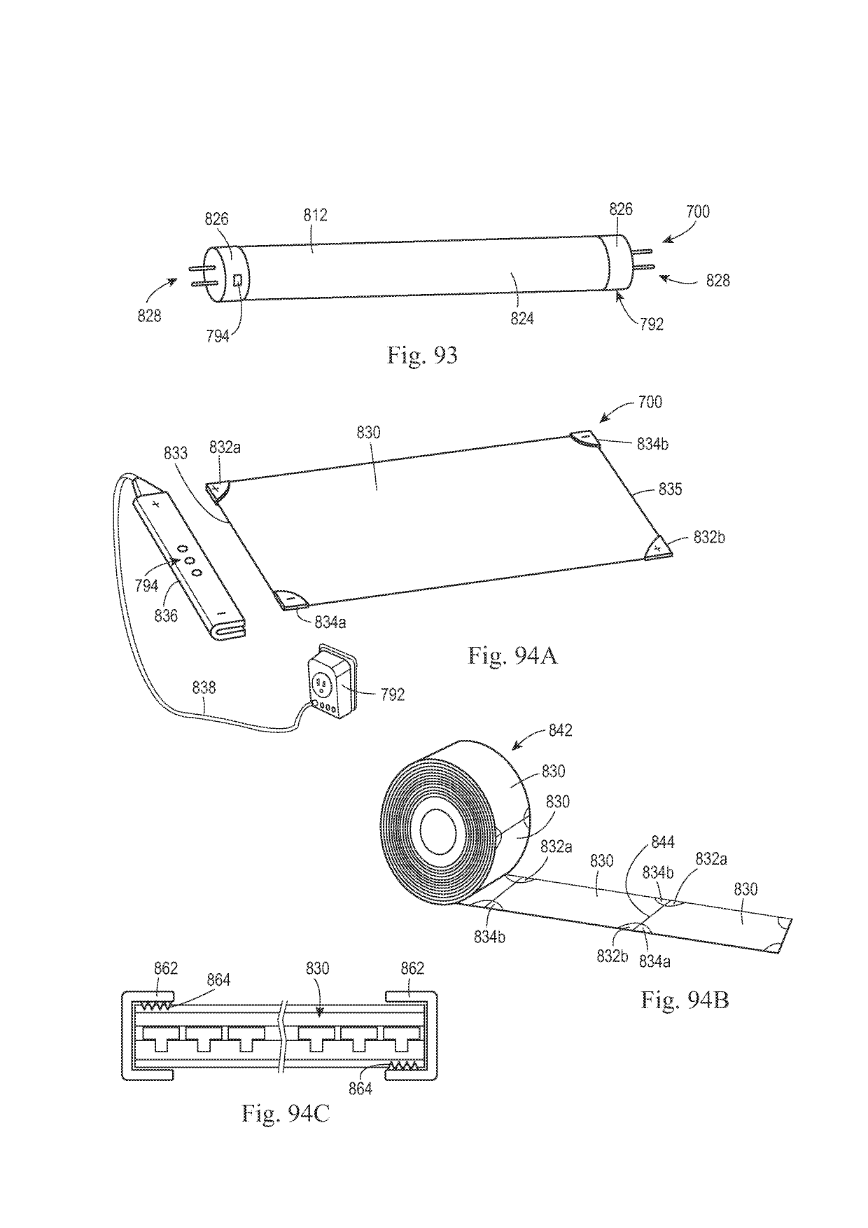

In a further embodiment illustrated in FIGS. 94A to 94E, the device 700 may have a generally elongated shape. Specifically, a base 804 may extend in a substantially longitudinal direction. The base 804 may have any suitable length for a particular application, and the base may be dimensioned such that the overall length of the device 700 is approximately equal to a conventional fluorescent lighting fixture. For example, the base 804 may be dimensioned such that the overall length of the device 700 is 12 inches (304.8 mm), 24 inches (609.6 mm), 36 inches (914.4 mm) or 48 inches (1219.2 mm) long. The base 804 may have any shape suitable for a particular application. For example, as shown in FIG. 94A, the base 804 may be comprised of a first wall 806 and a second wall 808, and the first wall 806 and the second wall 808 may be symmetrically formed about a centrally-disposed slot wall 810 such that the base 804 has a wedge-like shape. The base 804 may be manufactured as a unitarily formed feature, or may be assembled from two or more components. A lighting element 812 may be coupled to the base 804, and the lighting element 812 may have any shape or size suitable for a particular application. For example, the lighting element 812 may be substantially planar, as illustrated in FIGS. 94A and 94B, and the lighting element 812 may extend along the entire length of the base 804 along the slot wall 810. However, the lighting element 812 may be comprised of segments that are spaced along the length of the base 804, for example. Any portion of the lighting element 812, including the entire lighting element 812, may be capable of illumination, as will be described in more detail below.

Still referring to FIGS. 94A to 94E, a cover 814 may be coupled to the base 804 by any means known in the art, including permanent coupling or removable coupling. For example, the top and bottom edges of the cover 814 may each slide into slots formed at the terminal ends of the first wall 806 and the second wall 808, respectively. When secured to the base 804, the cover 814 may have any cross-sectional shape, such as convex, concave, or flat, for example. In addition, the cover 814 may be comprised of a single unitary part, or may be comprised of several segments that collectively form the cover 814, and one segment of the cover 814 may be convex, and a second segment may be concave, for example. The cover 814 may be substantially frosted or may be transparent, and the cover 814 may also have a surface texture or be untextured. In addition, the cover 814 may have any suitable color. In an alternative embodiment, the cover 814 may illuminate instead of the lighting element 812.

Referring again to FIGS. 94A to 94E, an end cap 816 may be secured to each end of the base 804. Each end cap 816 may have any shape, and the end cap 816 may have a cross-sectional shape that is substantially identical to the cross-sectional shape of the cover 814/base 804 assembly, for example. Each end cap 816 may be secured to each end of the base 804 by any manner known in the art, such as by a tab/slot assembly or an interference fit, for example. At least one of the end caps 816 may be coupled to a power interface 792. For example, a flexible cord 818 may extend from an end cap 816 to the power interface 792 such that when the end cap 816 is secured to the base 804, the lighting element 812 (or the cover 814 if the cover 814 is capable of illumination) is electrically coupled to the power interface 792. A functional interface 794 may be electrically coupled to the lighting element 812 (or the cover 814 if the cover 814 is capable of illumination) and the power interface 792, and the functional interface 794 may include interfaces to control the functions of the lighting element 812 (or the cover 814 if the cover 814 is capable of illumination), such as a power switch, a dimmer, or any other suitable function. The functional interface 794 may be disposed at any suitable location of the device 700, including as a module coupled to the power cord 818. Alternatively, the functional interface 794 may be integrally formed with an end cap 816 or the power interface 792.

Still referring to FIGS. 94A to 94E, two or more of the cover 814/base 804 assemblies may be secured together to form a multi-unit assembly 822. Because the individual cover 814 and base 804 shapes can vary, the multi-unit assembly 822 may have any cross-sectional shape or combination of shapes. For example, as shown in FIGS. 94C and 94E, the multi-unit assembly 822 may have a substantially cylindrical shape. Alternatively, the multi-unit assembly 822 may have a semi-cylindrical shape as illustrated in FIG. 94D. The cover 814/base 804 assemblies may be secured together by any means known in the art, such as by the use of a tab/slot configuration or by magnetic coupling. For example, a portion of an elongated tab 820 may be inserted into a slot formed by the slot wall 810 of the base 804 of each of two adjacent cover 814/base 804 assemblies to form a semi-cylinder, or a portion of the elongated tab 820 may be inserted into a slot formed by the slot wall 810 of the base 804 of each of four cover 814/base 804 assemblies to form a cylinder. If the multi-unit assembly 822 is to be suspended from the power cord 818, the power cord 818 may be coupled to a hub that may be coupled to one or all of the lowermost end caps 816 to support the multi-unit assembly 822.

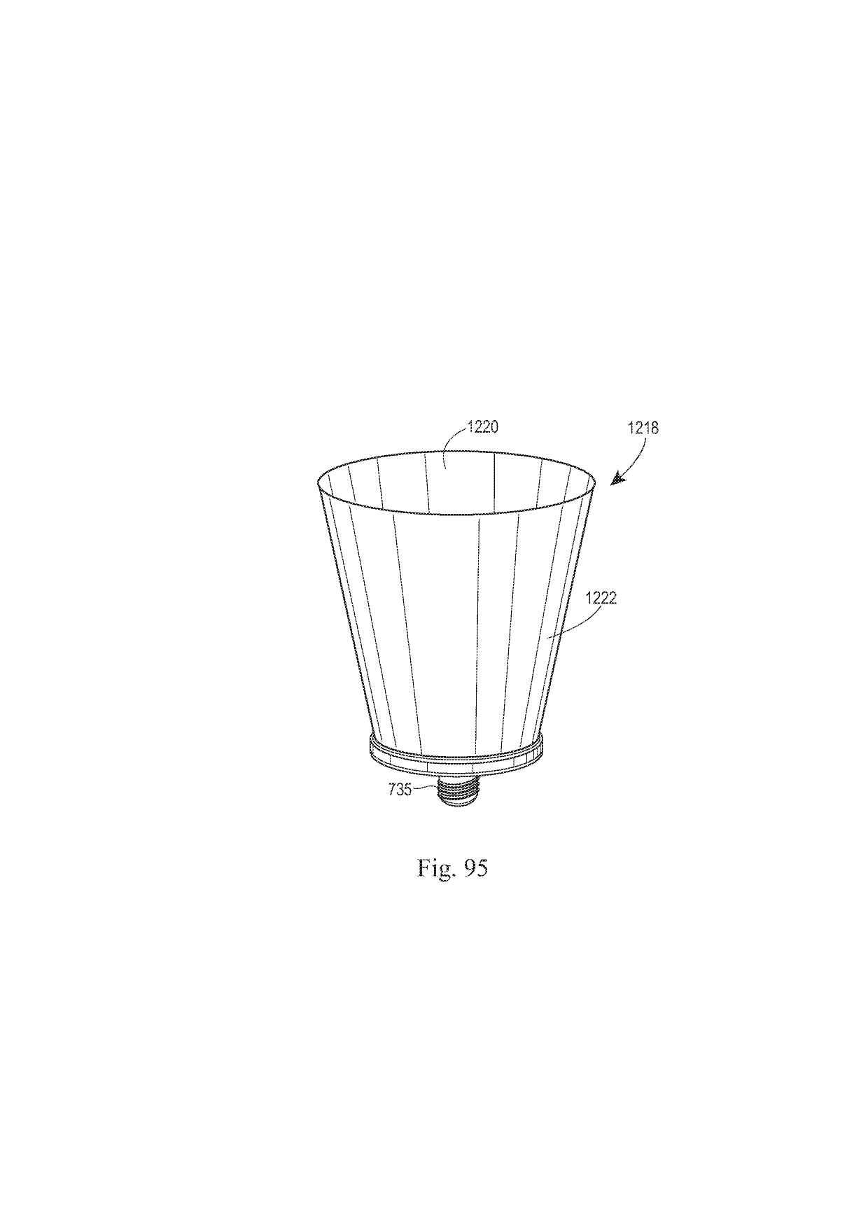

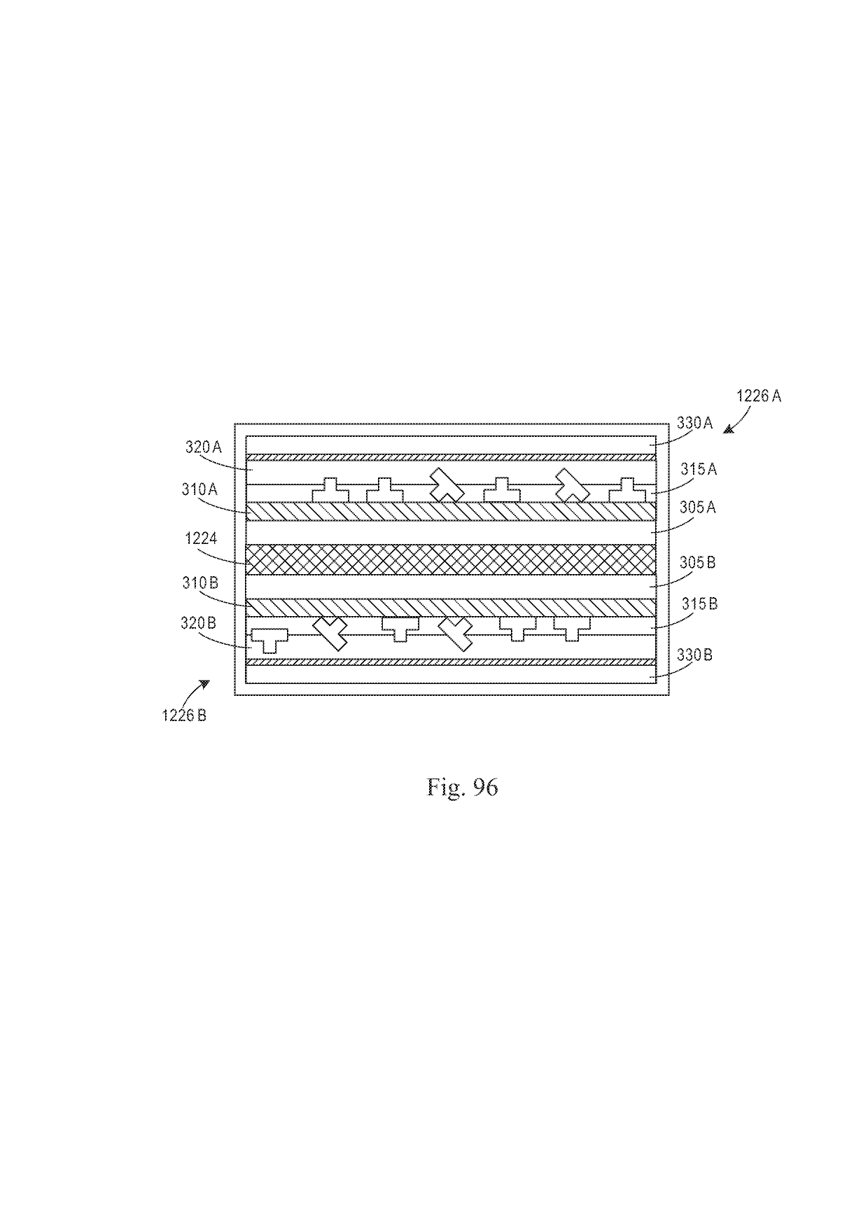

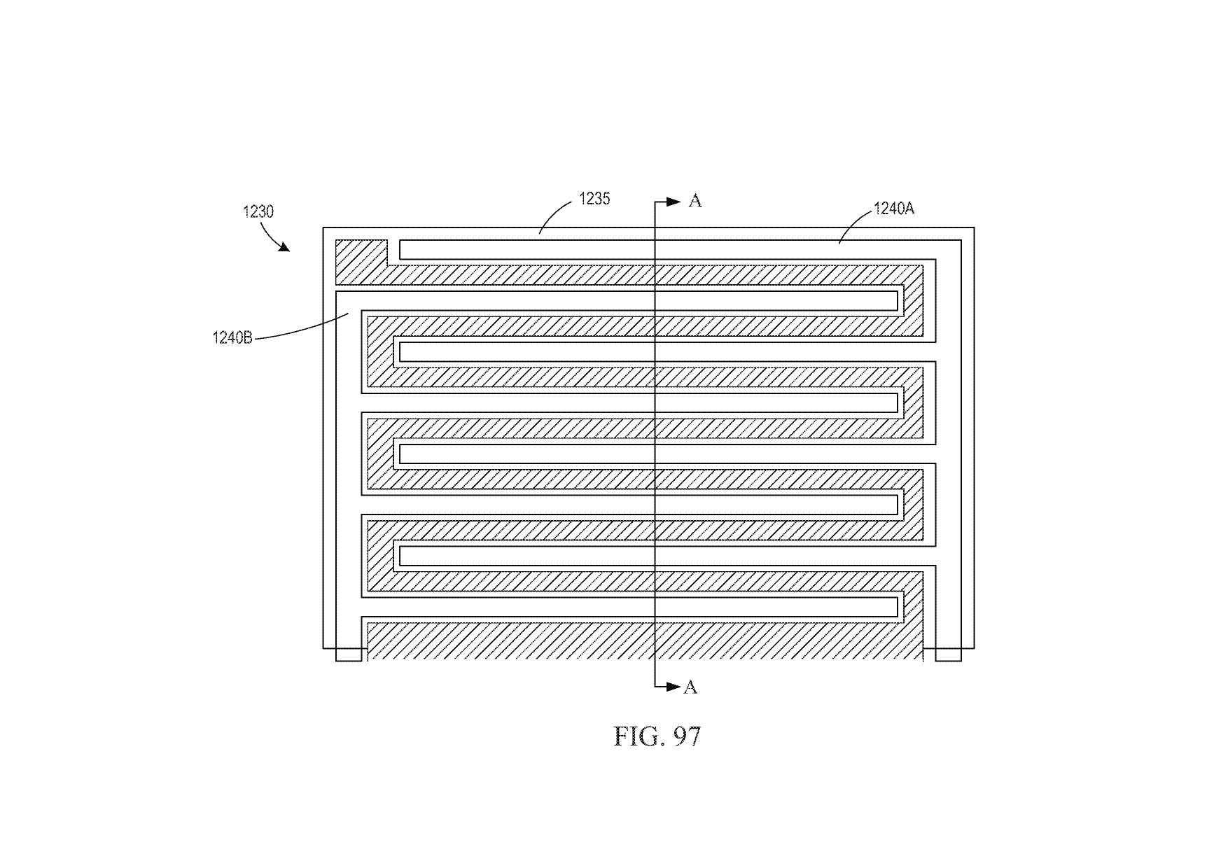

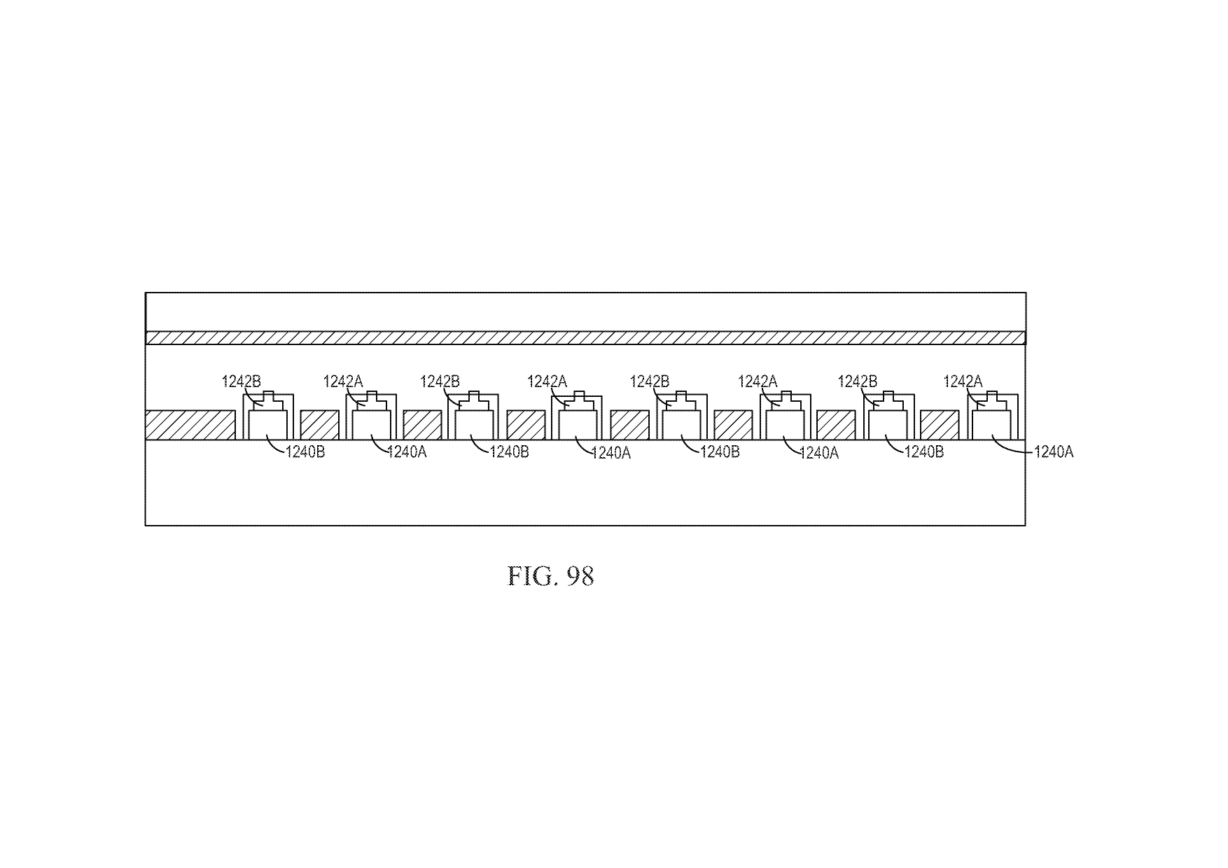

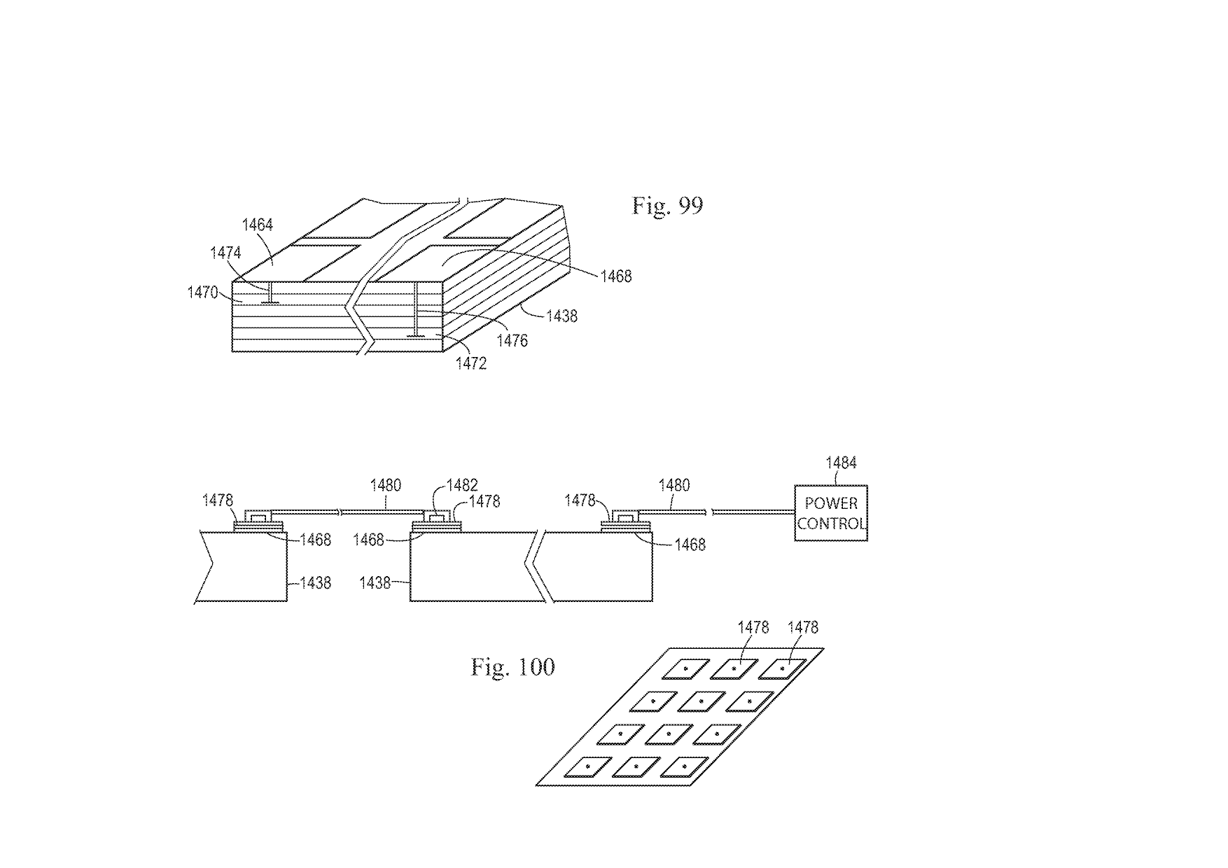

In a further elongated embodiment illustrated in FIGS. 95, a fluorescent replacement assembly 823 may have the shape of a conventional tube-type fluorescent bulb such that the fluorescent replacement assembly 823 may be inserted into conventional tube-type fluorescent sockets to replace conventional tube-type fluorescent bulbs. Specifically, the lighting element 812 of the fluorescent replacement assembly 823 may be capable of illumination, and the lighting element 812 may be substantially cylindrical. The lighting element 812 may be disposed within a rigid outer cylinder 824, and the outer cylinder 824 may be made of any suitable material, such as plastic or glass, for example. The lighting element 812 and the outer cylinder 824 may, as shown, be cylindrical in shape, or may have any cross-sectional shape or combination of shapes. Moreover, if the lighting element 812 is sufficiently rigid to withstand the torque applied upon installation, no outer cylinder 824 may be used. An end cap 826 may be disposed on both ends of the lighting element 812. The end caps 826 may have any suitable shape, and may be cylindrical and have an outer diameter substantially equal to that of the outer cylinder 824. The end caps 826 may be rigidly secured to the outer cylinder 824 (or to the lighting element 812 if no outer cylinder 824 is used) by any method known in the art, such as by threaded coupling or tab/slot locking. One or more pins 828 may extend from each of the end caps 826, and the pins 828 may collectively form any of several conventional configurations that are used to couple a conventional fluorescent bulb with a socket. The pins 828 may be electrically coupled to a power interface 792, and the power interface 792 may be electrically coupled to the lighting element 812 such that the power interface 792 may convert the voltage from the conventional socket to a voltage suitable to illuminate the lighting element 812. One or both of the end caps 826 may include a power interface 792, and the power interface 792 may be electrically coupled to the pins 828 and the lighting element 812. A functional interface 794 may be electrically coupled to the lighting element 812 and the power interface 792, and the functional interface 794 may include interfaces to control the functions of the lighting element 812 such as a power switch, a dimmer, or any other suitable function. The functional interface 794 and the power interfaces 792 may be integrally formed in one or both end caps 726. The outer diameter of the outer cylinder 824 (or the lighting element 812 if no outer cylinder 824 is necessary) may be substantially equal to the outer diameter of a conventional fluorescent bulb. For example, the outer diameter of the outer cylinder 824 may be 1½ inches (38.1 mm). The overall length of the fluorescent replacement assembly 823 (excluding the length of the pins 828) may be substantially equal to the length of a conventional fluorescent bulb. For example, the length of the fluorescent replacement assembly 823 may be 12 inches (304.8 mm), 24 inches (609.6 mm), 36 inches (914.4 mm) or 48 inches (1219.2 mm). However, the outer diameter of the outer cylinder 824 and the length of the fluorescent replacement assembly 823 may have any suitable value.

In a further embodiment illustrated in FIGS. 94A and 94B, the device 700 may include an illuminating element 830 having a front side or a front and back side that is capable of illumination. The illuminating element 830 may be flexible or rigid, and may have any suitable size. A positive terminal 832 may be disposed on a first corner of the illuminating element 830 along a first edge 833. The positive terminal 832a may be integrally formed with the illuminating element 830 or may be secured to the illuminating element 830. A negative terminal 834a may be disposed on a second corner of the illuminating element 830 along the first edge 833, and the negative terminal 834a may be integrally formed with the illuminating element 830 or may be secured to the illuminating element 830. An identical positive and negative terminal 832b, 834b may be coupled to opposite corners of the second edge 835. One of the positive terminals 832a, 832b and one of the negative terminals 834a, 834b may be coupled to an element interface 836, and the element interface 836 may include a power cord 838 that is electrically coupled to a power interface 792. The element interface 836 may be any shape or configuration capable of receiving both a positive terminal 832a, 832b and a negative terminal 834a, 832b. For example, the element interface 836 may have a generally elongated shape having a receiving slot 840 that extends along all or a portion of the length of the element interface 836. The receiving slot 840 may be adapted to receive the first edge 833 of the illuminating element 830 such that the positive terminal 832a of the illuminating element 830 is electrically connected to a corresponding positive terminal of the element interface 836 and the negative terminal 834a of the illuminating element 830 is electrically connected to a corresponding negative terminal of the element interface 836. So assembled, power from any conventional power source, such as a wall outlet, can be delivered from the power interface 792 to the illuminating element 830 to cause the entire illuminating element 830 (or portions of the illuminating element 830) to illuminate. A functional interface 794 may be electrically coupled to the element interface 836 and the power interface 792, and the functional interface 794 may include interfaces to control the functions of the illuminating element 830 such as a power switch, a dimmer, or any other suitable function. The functional interface 794 and the power interface 792 may be integrally formed, or the functional interface 794 may be disposed on the element interface 836 as illustrated in FIG. 94A.

Referring to FIG. 94B, the illuminating element 830 may be packaged in a roll 842 of illuminating elements 830 such that, prior to assembly, an appropriate number of illuminating elements 830 may be selected to result in a desired overall length. For example, if each illuminating element 830 is 12 inches long, and a length of 24 inches is desired, two illuminating elements 830 may be removed from the roll 842. Individual illuminating elements 830 may be separated by, for example, perforated portions 844, and adjacent positive terminals 832a and negative terminals 834b (as well as adjacent negative terminals 834a and positive terminals 832b) may be separable along each perforated portion 844. However, when the terminals 832a, 832b, 834a, 834b are not separated along the perforated portion 844, an electrical connection is maintained between adjacent illuminating element 830.

Instead of the pre-connected terminals described above, the terminals 832a, 832b, 834a, 834b may be manually-insertable at any position along any edge of the illuminating element 830. For example, as illustrated in FIG. 94C, a substantially C-shaped body 862 with a plurality of conductive members 864 may be disposed around a desired edge of the illuminating element 830, and the body 862 may be compressed such that the conductive members 864 are inserted into an interior portion of the illuminating element 830 in a manner that will be described in more detail below. A first body 862 may be a positive terminal (for example, the body 862 on the left side of FIG. 94C), and a second body 862 (for example, the body 862 on the right side of FIG. 94C) may be disposed on the illuminating element 830 in an orientation that is substantially opposite to that of the first body 862. With appropriate positive and negative terminals applied in each of the appropriate corners of the illuminating element 830, the illuminating element 830 may be inserted into an element interface 836 and be illuminated in the manner described above. Because the terminals can be applied to a desired location, the illuminating element 830 can be manually cut to a desired size from a roll similar to the roll 842 illustrated in FIG. 94B.

As discussed above, the illuminated sheet, such as the side wall 703, may be formed as a developable surface. More specifically, a developable surface is surface that can be flattened onto a plane without distortion (i.e., “stretching” or “compressing”). Conversely, a developable surface is a surface which can be made by transforming a plane (i.e., “folding”, “bending”, “rolling”, “cutting” and/or “gluing”). In three dimensions, all developable surfaces are ruled surfaces. A surface is ruled if through every point of the surface there is a straight line that lies on the surface. The most familiar examples are the plane and the curved surface of a cylinder or cone. Other examples are a conical surface with elliptical directrix, the right conoid, the helicoid, and the tangent developable of a smooth curve in space. A ruled surface can always be described (at least locally) as the set of points swept by a moving straight line. For example, a cone is formed by keeping one point of a line fixed whilst moving another point along a circle.

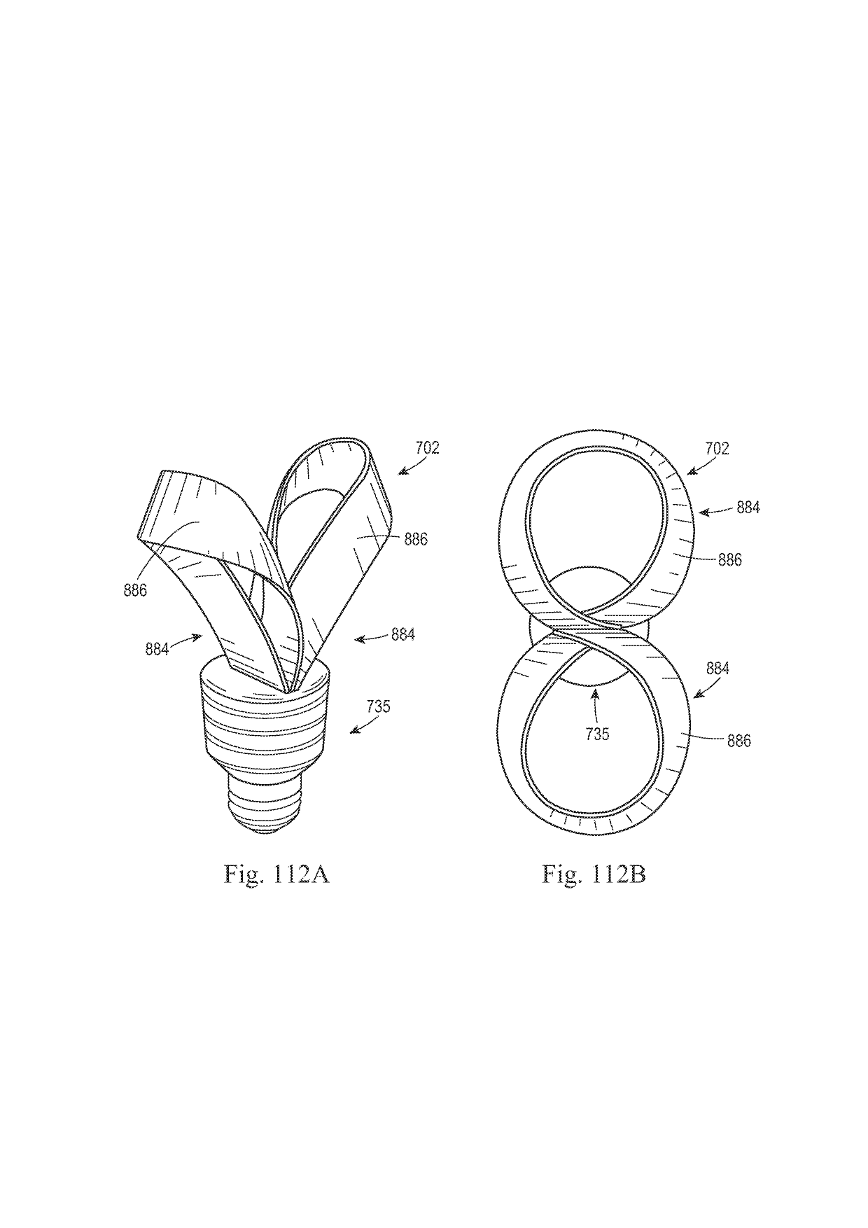

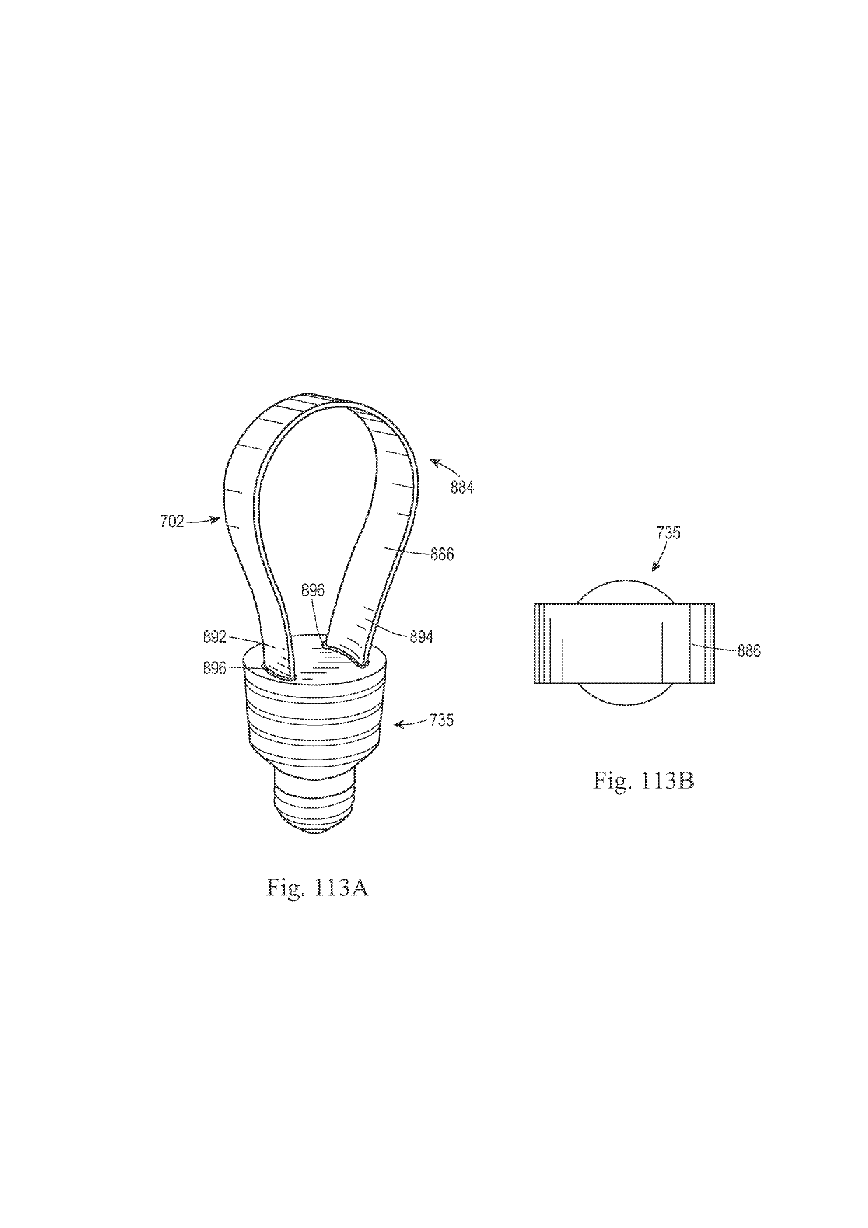

FIG. 112 depicts one exemplary embodiment of a bulb 1218 that includes a photovoltaic circuit. The bulb 1218 may take the form of a truncated right circular cone, formed from a multilayer material having disposed on a layer of the multilayer material a plurality of discrete light-emitting devices, as described with reference to FIG. 57. The multilayer material and/or the discrete diode devices, formed substantially as described throughout this specification, form a layered diode apparatus. In particular, the bulb 1218 may be an apparatus 1228 formed of back-to-back apparatuses similar to the diode apparatus depicted in FIG. 57. FIG. 113 shows a cross-sectional view of the apparatus 1228. The apparatus 1228 if formed of two parts, each of which is substantially the same as the single apparatus shown in FIG. 57, and which may be joined such that the base of each is joined to an opposing side of a reflective or opaque material 1224. Alternatively, the apparatuses 1226A and 1226B may be formed on opposite sides of a single base 305 to form the apparatus 1228. In any event, so arranged, the diodes on each of the apparatuses 1226A and 1226B are exposed in opposite directions.

Referring again to FIG. 112, the bulb 1218, formed of the apparatus 1228 in FIG. 113, has an interior surface 1220 and an exterior surface 1222, which may correspond, respectively, to the layers 330A and 330B of the apparatus 1228. Thus, the diodes exposed along the exterior surface 1222 may correspond to the diodes 100B depicted in FIG. 113, and the diodes exposed along the interior surface 1220 may correspond to the diodes 100A. Though in some embodiments, the diodes 100A and the diodes 100B may be light emitting diodes, in other embodiments, the diodes 100A may be light emitting diodes, and the diodes 100B may be photovoltaic diodes. In this manner, the interior surface 1220 may be adapted to collect light and convert the collected light to energy for storage in, for example, the secondary power source 1214, while the exterior surface 1222 may be adapted to convert energy from the primary power source 1208 and/or the secondary power source 1214 into light.

It should be appreciated that there is no requirement that either of the primary power source 1208 or the secondary power source 1214 be a mains line. In fact, some embodiments may omit the secondary power source 1214 and implement an energy storage device as the primary power source 1208, and in some embodiments both the primary power supply 1208 and the secondary power supply 1214 may be energy storage devices. When coupled to a bulb having both light emitting and photovoltaic devices, such as the bulb 1218 depicted in FIG. 112, the lighting apparatus may be self-charging. For example, photovoltaic diodes on one surface (e.g., the exterior surface 1222) may convert light into energy to charge an energy storage device during the day, and light emitting diodes on the same or a different surface (e.g., the interior surface 1220) may convert the stored energy back into light at night.

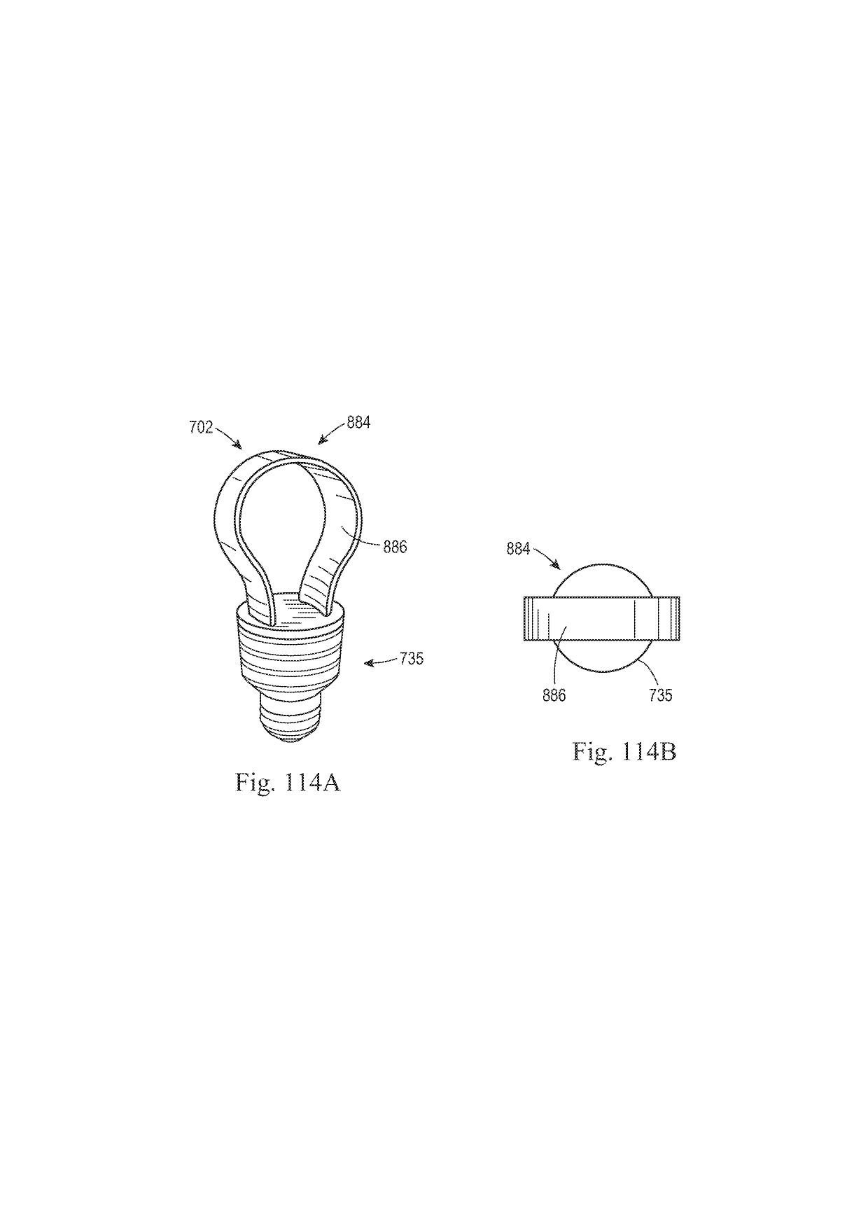

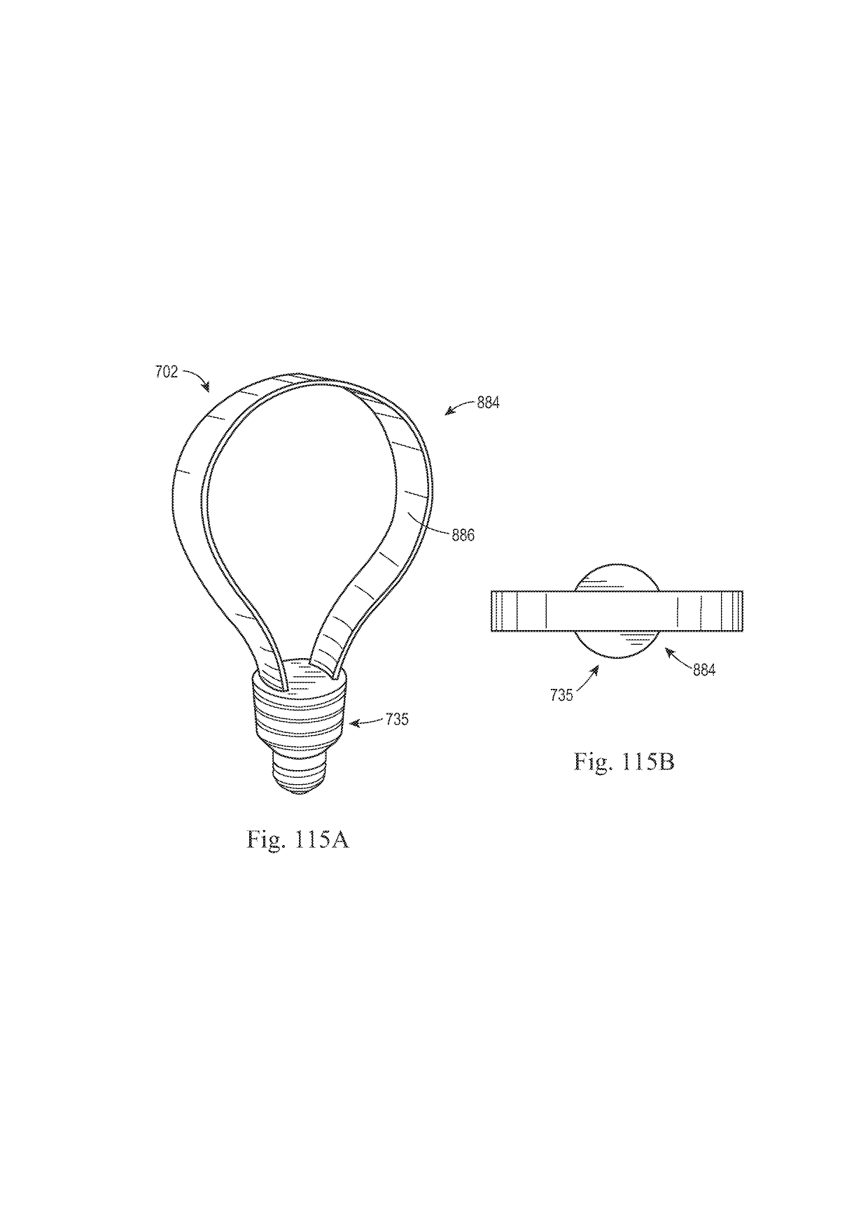

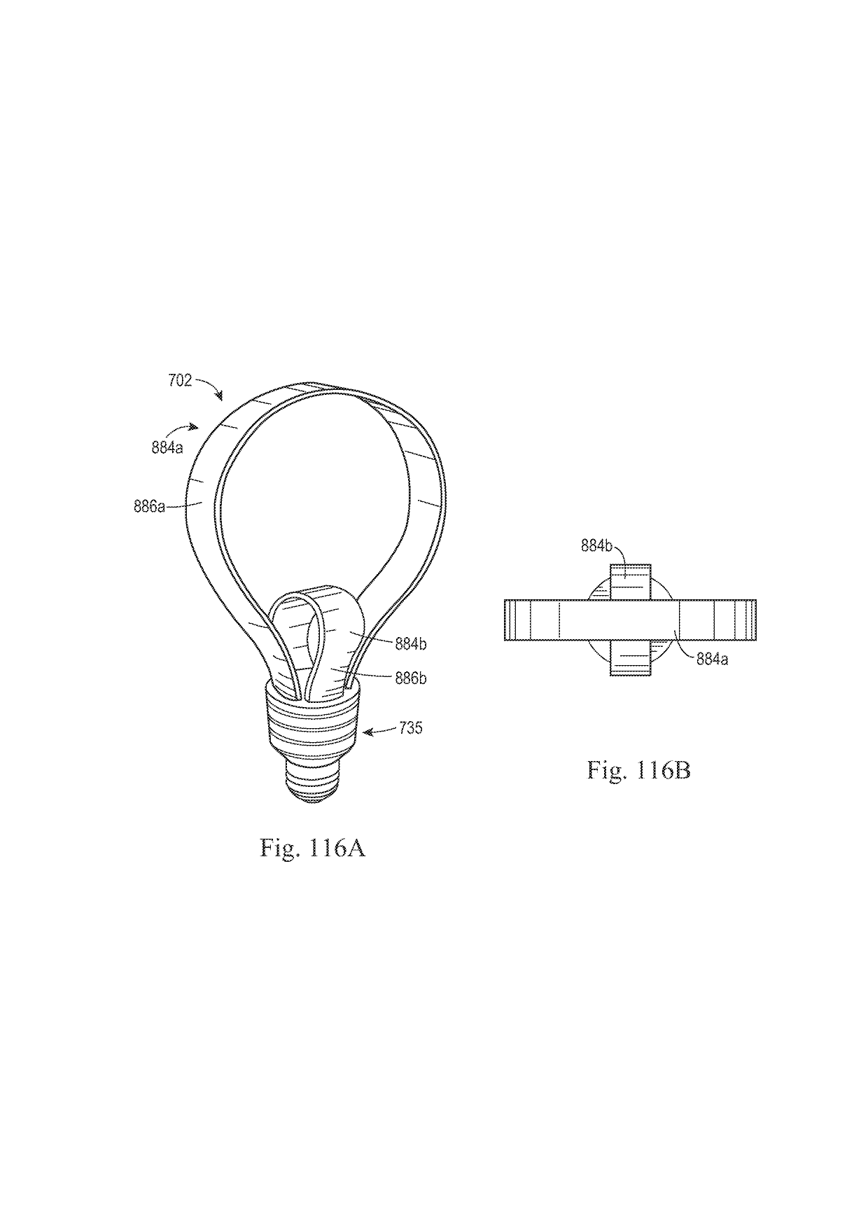

The use of multiple illuminating circuits within a bulb also lends itself to other applications. In some embodiments, each of two or more illuminating circuits may energize LEDs of different colors or color temperatures. FIG. 114 illustrates two layers 1235 and 1240 of a light emitting apparatus 1230. The layer 1235 may correspond to the base layer 305 of FIG. 57, and the layer 1240 may correspond to the conductive layer 310 of FIG. 57. The layer 1240 of the light emitting apparatus 1230 includes a first illuminating circuit 1240A and a second illuminating circuit 1240B. A first plurality of light emitting diodes 1242A of a first color or color temperature may be deposited on the first illuminating circuit 1240A so as to be electrically coupled to the first illuminating circuit 1240A. A second plurality of light emitting diodes 1242B of a second color or color temperature may be deposited on the second illuminating circuit 1240B so as to be electrically coupled to the second illuminating circuit 1240B. FIG. 115 as a cross-sectional diagram of the apparatus 1230 taken along the line A-A. By selectively energizing one or both of the first and second illuminating circuits 1240A and 1240B, the color and/or color temperature of the light emitted from the apparatus 1230 may be selected. For example, if the first plurality of light emitting diodes 1242A emit red light and the second plurality of light emitting diodes 1242B emit blue light, red, blue, or magenta lighting may in be selected by selectively or combinatorially energizing the first and second illuminating circuits 1240A and 1240B. If a third illuminating circuit (not shown) is added to the apparatus 1230, an additional color or color temperature of light emitting diode may be deposited on the third illuminating circuit. In some embodiments, the third illuminating circuit may have deposited thereon a plurality of light emitting diodes that emit green light. Implementing red, blue, and green light emitting diodes on separate illuminating circuits allows selection of red, blue, green, magenta, yellow, cyan, or white light.

The generally planar form of the illuminating apparatus (i.e., the apparatus 300) described herein makes the apparatus suitable for use in countless lighting applications taking any number of forms. Many of the embodiments described above are described with reference to conical and/or cylindrical bulb assemblies coupled to base assemblies having an Edison-screw for coupling to a power source. However, as repeatedly indicated, many of the embodiments described do not require a base having an Edison-screw.

In some embodiments, the illuminating element may have contact surfaces incorporated into its structure. FIG. 139 illustrates the illuminating element 1438 as having two contact surfaces 1464 and 1468 fixed in place on the illuminating element 1438. Each of the contact surfaces 1464 and 1468 is electrically coupled to a respective conductive layer 1470 and 1472 within the illuminating element 1438. In some embodiments, the contact surface 1464 is electrically coupled to the conductive layer 1470 by a via 1474, while the contact surface 1468 is electrically coupled to the conductive layer 1472 by a via 1476.

In some embodiments, the contact surfaces 1464 and 1468 may be coupled to a power source via self-adhesive electrodes 1478, such as those depicted in FIG. 140. The self-adhesive electrodes 1478 may be attached to the conductive surfaces 1468 and 1464. Conductors 1480 may be coupled to the adhesive electrodes 1478 by any known method and, in some embodiments, may be coupled to the adhesive electrodes 1478 by a snap mechanism 1482. The modular scheme illustrated in FIG. 140 allows a user to couple more than one of the illuminating elements 1438 in series to a power supply and/or controller 1484.

Although the invention has been described with respect to specific embodiments thereof, these embodiments are merely illustrative and not restrictive of the invention. In the description herein, numerous specific details are provided, such as examples of electronic components, electronic and structural connections, materials, and structural variations, to provide a thorough understanding of embodiments of the present invention. One skilled in the relevant art will recognize, however, that an embodiment of the invention can be practiced without one or more of the specific details, or with other apparatus, systems, assemblies, components, materials, parts, etc. In other instances, well-known structures, materials, or operations are not specifically shown or described in detail to avoid obscuring aspects of embodiments of the present invention. One having skill in the art will further recognize that additional or equivalent method steps may be utilized, or may be combined with other steps, or may be performed in different orders, any and all of which are within the scope of the claimed invention. In addition, the various Figures are not drawn to scale and should not be regarded as limiting.

Reference throughout this specification to “one embodiment”, “an embodiment”, or a specific “embodiment” means that a particular feature, structure, or characteristic described in connection with the embodiment is included in at least one embodiment and not necessarily in all embodiments, and further, are not necessarily referring to the same embodiment. Furthermore, the particular features, structures, or characteristics of any specific embodiment may be combined in any suitable manner and in any suitable combination with one or more other embodiments, including the use of selected features without corresponding use of other features. In addition, many modifications may be made to adapt a particular application, situation or material to the essential scope and spirit of the present invention. It is to be understood that other variations and modifications of the embodiments of the present invention described and illustrated herein are possible in light of the teachings herein and are to be considered part of the spirit and scope of the present invention.

It will also be appreciated that one or more of the elements depicted in the Figures can also be implemented in a more separate or integrated manner, or even removed or rendered inoperable in certain cases, as may be useful in accordance with a particular application. Integrally formed combinations of components are also within the scope of the invention, particularly for embodiments in which a separation or combination of discrete components is unclear or indiscernible. In addition, use of the term “coupled” herein, including in its various forms such as “coupling” or “couplable”, means and includes any direct or indirect electrical, structural or magnetic coupling, connection or attachment, or adaptation or capability for such a direct or indirect electrical, structural or magnetic coupling, connection or attachment, including integrally formed components and components which are coupled via or through another component.

As used herein for purposes of the present invention, the term “LED” and its plural form “LEDs” should be understood to include any electroluminescent diode or other type of carrier injection- or junction-based system which is capable of generating radiation in response to an electrical signal, including without limitation, various semiconductor- or carbon-based structures which emit light in response to a current or voltage, light emitting polymers, organic LEDs, and so on, including within the visible spectrum, or other spectra such as ultraviolet or infrared, of any bandwidth, or of any color or color temperature. Also as used herein for purposes of the present invention, the term “photovoltaic diode” (or PV) and its plural form “PVs” should be understood to include any photovoltaic diode or other type of carrier injection- or junction-based system which is capable of generating an electrical signal (such as a voltage) in response to incident energy (such as light or other electromagnetic waves) including without limitation, various semiconductor- or carbon-based structures which generate of provide an electrical signal in response to light, including within the visible spectrum, or other spectra such as ultraviolet or infrared, of any bandwidth or spectrum.

The dimensions and values disclosed herein are not to be understood as being strictly limited to the exact numerical values recited. Instead, unless otherwise specified, each such dimension is intended to mean both the recited value and a functionally equivalent range surrounding that value. For example, a dimension disclosed as “40 mm” is intended to mean “about 40 mm.”

All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Furthermore, any signal arrows in the drawings/Figures should be considered only exemplary, and not limiting, unless otherwise specifically noted. Combinations of components of steps will also be considered within the scope of the present invention, particularly where the ability to separate or combine is unclear or foreseeable. The disjunctive term “or”, as used herein and throughout the claims that follow, is generally intended to mean “and/or”, having both conjunctive and disjunctive meanings (and is not confined to an “exclusive or” meaning), unless otherwise indicated. As used in the description herein and throughout the claims that follow, “a”, “an”, and “the” include plural references unless the context clearly dictates otherwise. Also as used in the description herein and throughout the claims that follow, the meaning of “in” includes “in” and “on” unless the context clearly dictates otherwise.

The foregoing description of illustrated embodiments of the present invention, including what is described in the summary or in the abstract, is not intended to be exhaustive or to limit the invention to the precise forms disclosed herein. From the foregoing, it will be observed that numerous variations, modifications and substitutions are intended and may be effected without departing from the spirit and scope of the novel concept of the invention. It is to be understood that no limitation with respect to the specific methods and apparatus illustrated herein is intended or should be inferred. It is, of course, intended to cover by the appended claims all such modifications as fall within the scope of the claims.

It is claimed:

1. A lighting apparatus for private use and/or consumption by individuals or households comprising:
(a) a composition comprising:
a plurality of diodes;
a first solvent; and
a viscosity modifier;
(b) an electrical interface configured to receive a electrical signal and transmit the electrical signal to the plurality of diodes; and
(c) wherein the apparatus is for private use and/or consumption by individuals or households.

2. The apparatus of claim 1, wherein the first solvent comprises at least one solvent selected from the group consisting of: water; alcohols such as methanol, ethanol, N-propanol (including 1-propanol, 2-propanol (IPA)), butanol (including 1-butanol, 2-butanol (isobutanol)), pentanol (including 1-pentanol, 2-pentanol, 3-pentanol), octanol, tetrahydrofurfuryl alcohol (THFA), cyclohexanol, terpineol; ethers such as methyl ethyl ether, diethyl ether, ethyl propyl ether, and polyethers; esters such ethyl acetate; glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof.

3. The apparatus of claim 1, wherein the first solvent is present in an amount of about 5 percent to about 50 percent by weight of the composition.

4. The apparatus of claim 1, wherein the viscosity modifier is present in an amount of about 0.75% to about 5% by weight of the composition.

5. The apparatus of claim 1, wherein the viscosity modifier comprises at least one viscosity modifier selected from the group consisting of: clays such as hectorite clays, garamite clays, organo-modified clays; saccharides and polysaccharides such as guar gum, xanthan gum; celluloses and modified celluloses such as hydroxylmethyl cellulose, methyl cellulose, methoxyl cellulose, carboxymethyl cellulose, hydroxyethyl cellulose and hydroxypropyl cellulose, cellulose ether, cellulose ethyl ether, chitosan; polymers such as acrylate and (meth)acrylate polymers and copolymers, diethylene glycol, propylene glycol, fumed silica, silica powders; modified ureas; and mixtures thereof.

6. The apparatus of claim 1, further comprising a second solvent selected from the group consisting of: water; alcohols such as methanol, ethanol, N-propanol (including 1-propanol, 2-propanol (isopropanol)), isobutanol, butanol (including 1-butanol, 2-butanol), pentanol (including 1-pentanol, 2-pentanol, 3-pentanol), octanol, tetrahydrofurfuryl alcohol, cyclohexanol; ethers such as methyl ethyl ether, diethyl ether, ethyl propyl ether, and polyethers; esters such ethyl acetate, dimethyl adipate, proplyene glycol monomethyl ether acetate, dimethyl glutarate, dimethyl succinate; glycols such as ethylene glycols, diethylene glycol, polyethylene glycols, propylene glycols, glycol ethers, glycol ether acetates; carbonates such as propylene carbonate; glycerin, acetonitrile, tetrahydrofuran (THF), dimethyl formamide (DMF), N-methyl formamide (NMF), dimethyl sulfoxide (DMSO); and mixtures thereof.

7. The apparatus of claim 6, wherein the ratio of dimethyl glutarate to dimethyl succinate is about two to about one (2:1).

8. The apparatus of claim 6, wherein the second solvent is present in an amount of about 0.1% to about 10% by weight of the composition.

9. The apparatus of claim 6, wherein the first solvent comprises N-propanol, ethanol, tetrahydrofurfuryl alcohol, or cyclohexanol, and present in an amount of about 5% to about 50% by weight of the composition; wherein the viscosity modifier comprises methoxyl cellulose or hydroxypropyl cellulose resin, and present in an amount of about 0.75% to about 5.0% by weight of the composition; wherein the second solvent comprises a nonpolar resin solvent present in an amount of about 0.5% to about 10% by weight of the composition; and wherein the balance of the composition further comprises water.

10. A method of making the apparatus of claim 6, the method comprising:
mixing the plurality of diodes with N-propanol;
adding the mixture of the N-propanol and plurality of diodes to the methyl cellulose resin;
adding the dimethyl glutarate and dimethyl succinate; and
mixing the plurality of diodes, N-propanol, methyl cellulose resin, dimethyl glutarate and dimethyl succinate for about 25 to about 30 minutes in an air atmosphere.

11. The method of claim 10, further comprising:
releasing the plurality of diodes from a wafer.

12. The apparatus of claim 1, wherein the composition has a viscosity substantially between about 1,000 cps and about 20,000 cps at about 25° C.

13. The apparatus of claim 1, wherein each diode of the plurality of diodes has a first metal terminal on a first side of the diode and a second metal terminal on a second, back side of the diode.

14. The apparatus of claim 1, wherein each diode of the plurality of diodes is less than about 450 microns in any dimension.

15. The apparatus of claim 1, wherein each diode of the plurality of diodes is substantially hexagonal, is about 20 to about 30 microns in diameter, and is about 10 to about 15 microns in height.

16. The apparatus of claim 1, wherein the composition is visually opaque when wet and substantially optically clear when dried or cured.

17. The apparatus of claim 1, wherein the plurality of diodes comprises at least one inorganic semiconductor selected from the group consisting of: silicon, gallium arsenide (GaAs), gallium nitride (GaN), GaP, InAlGaP, InAlGaP, AlinGaAs, InGaNAs, and AlInGASb; and mixtures thereof.

18. The apparatus of claim 1, wherein the plurality of diodes comprises at least one organic semiconductor selected from the group consisting of: π-conjugated polymers, poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, polynaphthalene, polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, polynaphthalene derivatives, polyisothianaphthene (PITN), polyheteroarylenvinylene (ParV) in which the heteroarylene group is thiophene, furan or pyrrol, polyphenylene-sulphide (PPS), polyperinaphthalene (PPN), polyphthalocyanine (PPhc), and their derivatives, copolymers thereof and mixtures thereof.

19. The apparatus of claim 1, wherein the composition has a relative evaporation rate less than one, wherein the evaporation rate is relative to butyl acetate having a rate of one.

20. The apparatus of claim 1, wherein the composition is printed over a first conductor coupled to a base.
